(19) United States
(12) Patent Application Publication
(10) Pub. No.: US 2025/0051366 A1
(43) Pub. Date: Feb. 13, 2025

(54) ORGANIC ELECTROLUMINESCENT MATERIALS AND DEVICES

(71) Applicant: University of Southern California, Los Angeles, CA (US)

(72) Inventors: Peter I. Djurovich, Long Beach, CA (US); Collin Muniz, Los Angeles, CA (US); Anton Razgoniaev, Los Angeles, CA (US); Jonas Schaab, Los Angeles, CA (US); Mark E. Thompson, Anaheim, CA (US)

(21) Appl. No.: 18/359,080

(22) Filed: Jul. 26, 2023

Related U.S. Application Data
(60) Provisional application No. 63/369,395, filed on Jul. 26, 2022.

(51) Int. Cl. C07F 1/12; C07F 1/08; C07F 1/10; C09K 11/02; H10K 85/20; H10K 85/30; H10K 85/40; H10K 85/60

(52) U.S. Cl. CPC C07F 1/12; C07F 1/08; C07F 1/10; C09K 11/02; H10K 85/20; H10K 85/371; H10K 85/40; H10K 85/622; H10K 85/654; H10K 85/6572; H10K 85/6574; H10K 85/6576

(57) ABSTRACT

The present disclosure provides amide M carbene emitters of Formula (I); organic light emitting device (OLED) comprising an anode, a cathode, and an organic layer, disposed between the anode and the cathode, comprising a compound of Formula (I); and consumer products comprising an OLED comprising a compound of Formula (I):

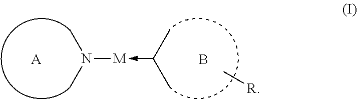

### CROSS-REFERENCE TO RELATED APPLICATIONS

This application claims priority under 35 U.S.C. § 119 (e) to U.S. Provisional Application No. 63/369,395, filed on Jul. 26, 2022, the entire contents of which are incorporated herein by reference.

### STATEMENT REGARDING FEDERALLY SPONSORED RESEARCH OR DEVELOPMENT

This invention was made with government support under EE0009688 and SC0016450 awarded by the U.S. Department of Energy. The government has certain rights in the invention.

### FIELD

The present disclosure generally relates to organometallic compounds and formulations and their various uses including as emitters in devices such as organic light emitting diodes and related electronic devices.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as flat panel displays, illumination, and backlighting.

One application for phosphorescent emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

In one aspect, the present disclosure provides a compound of formula (I):

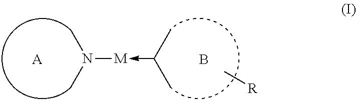

wherein
M is a metal;
ring B is a carbene ligand;
R represents mono to the maximum allowable substitution;
each R is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; wherein any two adjacent R are optionally joined or fused together to form a ring which is optionally substituted;
ring A is an amide ligand selected from the group consisting of formula (A-1) and formula (A-2);

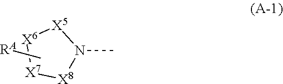

wherein, in formula (A-1),
the dashed line represents coordination to M;
each X⁵, X⁶, X⁷, and X⁸ independently represents N or C;
R^{A} represents mono to the maximum allowable substitution;
wherein any two adjacent groups R^{A} may optionally together form a fused ring having the following formula:

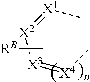

wherein each X¹, X², X³, and X⁴ independently represents N or C;
n is 0 or 1; wherein when n is 0, then X³ binds directly to formula (A-1);
R^{B} represents mono to the maximum allowable substitution;
each occurrence of R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano phosphino, and combinations thereof; wherein any two R^{B} are optionally joined or fused together to form a ring which is optionally substituted;

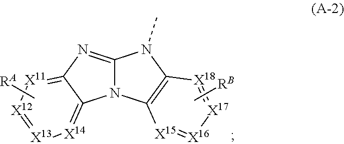

wherein, in formula (A-2);
each X¹¹ to X¹⁸ independently represents N or C;
R^{A} and R^{B} each represent mono to the maximum allowable substitution; and
each occurrence of R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano phosphino, and combinations thereof; wherein any two adjacent R^{A} and R^{B} are optionally joined or fused together to form a ring which is optionally substituted.

In another aspect, the present disclosure provides a formulation comprising a compound of formula (I) as described herein.

In yet another aspect, the present disclosure provides an OLED having an organic layer comprising a compound of formula (I) as described herein.

In yet another aspect, the present disclosure provides a consumer product comprising an OLED with an organic layer comprising a compound of formula (I) as described herein.

### BRIEF DESCRIPTION OF THE DRAWINGS

FIG. 1 shows an organic light emitting device.

FIG. 2 shows an inverted organic light emitting device that does not have a separate electron transport layer.

FIG. 3 depicts the kinetic scheme for emission via TADF, where kᵣ^{S}^{₁} and kᵣ^{TADF} are radiative decay rates of S₁ state and TADF process. K_{eq} indicates the equilibrium constant between T₁ and S₁ states.

FIG. 4 is a scheme of exemplary cMa materials.

FIG. 5 is a plot of CV and DPV traces for cMa complexes Cu_{BCz}^{PAC}, Ag_{BCz}^{PAC}, Au_{BCz}^{PAC}, and Au_{Cz}^{PAC}, collected in DMF with 0.1 TBAPF₆ as an electrolyte.

FIG. 6 is a plot of CV and DPV traces for cMa complexes Au_{BCz}^{BZAC}, Au_{Cz}^{BZAC}, Au_{Bim}^{CAAC}, and Au_{Bim}^{MAC}, collected in DMF with 0.1 TBAPF₆ as an electrolyte.

FIG. 7 is a plot of CV and DPV traces for cMa complexes Au_{Bim}^{PAC}, Au_{Bim}^{BZAC}, Au_{OBim}^{BZI}, and Cu_{BCz}^{BZAC}, collected in DMF with 0.1 TBAPF₆ as an electrolyte.

FIG. 8 is a plot of CV and DPV traces for cMa complexes Au_{Bim}^{Ipr}, Au_{Bim}^{PZI}, and Au_{Cz}^{PZI} collected in DMF with 0.1 TBAPF₆ as an electrolyte.

FIG. 9 is a depiction of the S₀→S₁ transition of Au_{Cz}^{PAC}, which involves an electron moving from the HOMO to LUMO and HOMO to LUMO+1. The hole and electron NTOs (Ψₕ₊ and Ψₑ₋) are appropriate visualizations of the hole and electron wavefunctions corresponding to this transition. One can see that the electron NTO is made up of a linear combination of the Ψ_{LUMO} and Ψ_{LUMO+1}. The isopropyl groups are omitted from the diisopropylphenyl groups for clarity.

FIG. 10 is a depiction of the S₀→S₁ transition of Au_{Cz}^{PAC} which involves an electron moving from the HOMO to LUMO and HOMO to LUMO+1. The hole and electron NTOs (Ψₕ₊ and Ψₑ₋) are appropriate visualizations of the hole and electron wavefunctions corresponding to this transition. One can see that the electron NTO is made up of a linear combination of the Ψ_{LUMO} and Ψ_{LUMO+1}. The isopropyl groups are omitted from the diisopropylphenyl groups for clarity.

FIG. 11 depicts the NTO (left) and center of charge representation (right) for the hole and electron wavefunctions of (BZAC)Au(Cz). The isopropyl groups from the diisopropylphenyl substituents have been deleted for clarity. The iso value was set to 0.1 and the phase information omitted for the wavefunction visualization. The red density represents the hole wavefunction and the blue density represents the electron wavefunction respectively. A red dummy atom was placed at the rₕ₊ coordinate and a blue dummy atom was placed at the rₑ₋ coordinate.

FIG. 12 depicts the HOMO and LUMO energy levels for cMa complexes Cu_{Cz}^{BZAC}, Cu_{Cz}^{MAC}, and Cu_{Cz}^{PAC}.

FIG. 13 depicts the HOMO and LUMO energy levels for cMa complexes Ag_{Cz}^{PAC}, Au_{Cz}^{PZI}, and Au_{Cz}^{PAC}.

FIG. 14 depicts the HOMO and LUMO energy levels for cMa complexes Au_{Cz}^{MAC}, Au_{Cz}^{CAAC}, and Au_{Cz}^{BZAC}.

FIG. 15 depicts the HOMO and LUMO energy levels for cMa complexes Au_{Cz}^{BZI} and Au_{Cz}^{Ipr}.

FIG. 16 depicts the HOMO and LUMO energy levels for cMa complexes Au_{bim}^{PZI}, Au_{bim}^{PAC}, and Au_{bim}^{MAC}.

FIG. 17 depicts the HOMO and LUMO energy levels for cMa complexes Au_{bim}^{CAAC},Au_{bim}^{BZAC}, and Au_{bim}^{BZI}.

FIG. 18 depicts the HOMO and LUMO energy levels for cMa complexes Au_{bim}^{Ipr}, H_{Cz}^{MAC}, and Li_{Cz}^{MAC}.

FIG. 19 depicts the emission solvatochromism plots of cMa complexes Cu_{BCz}^{PAC}, Ag_{BCz}^{PAC}, Au_{BCz}^{PAC}, and Cu_{BCz}^{BZAC}.

FIG. 20 depicts the emission solvatochromism plots of cMa complexes Au_{BCz}^{BZAC}, Au_{Cz}^{PAC}, and Au_{Cz}^{BZAC}.

FIG. 21 depicts a modified sample holder for temperature dependent photophysics.

FIG. 22 depicts the temperature dependent lifetime for (PAC)Cu(BCz) in PS. Boltzmann fit (left) and Arrhenius plot (right).

FIG. 23 depicts the temperature dependent lifetime for (PAC)Ag(BCz) in PS. Boltzmann fit (left) and Arrhenius plot (right).

FIG. 24 depicts the temperature dependent lifetime for (PAC)Au(BCz) in PS. Boltzmann fit (left) and Arrhenius plot (right).

FIG. 25 depicts the temperature dependent lifetime for (BZAC)Au(Cz) in PS. Boltzmann fit (left) and Arrhenius plot (right).

FIG. 26 depicts the temperature dependent lifetime for (MAC)Au(Cz) in PS. Boltzmann fit (left) and Arrhenius plot (right).

FIG. 27 depicts the temperature dependent lifetime for (PAC)Au(Bim) in PS. Boltzmann fit (left) and Arrhenius plot (right).

FIG. 28 depicts the temperature dependent lifetime for (MAC)Au(Bim) in PS. Boltzmann fit (left) and Arrhenius plot (right).

FIG. 29 depicts the temperature dependent lifetime for (CAAC)Au(Bim) in PS. Boltzmann fit (left) and Arrhenius plot (right).

FIG. 30 depicts the temperature dependent lifetime for (BZAC)Au(Bim) in PS. Boltzmann fit (left) and Arrhenius plot (right).

FIG. 31 depicts the temperature dependent lifetime for (BZAC)Cu(Bim) in PS. Boltzmann fit (left) and Arrhenius plot (right).

FIG. 32 depicts the temperature dependent lifetime for (BZI)Au(Bim) in PS. Boltzmann fit (left) and Arrhenius plot (right).

FIG. 33 depicts the temperature dependent lifetime for (BZI)Au(MBim) in PS. Boltzmann fit (left) and Arrhenius plot (right).

FIG. 34 depicts the temperature dependent lifetime for (BZI)Au(OBim) in PS. Boltzmann fit (left) and Arrhenius plot (right).

FIG. 35 depicts the temperature dependent lifetime for (PZI)Au(Cz) in PS. Boltzmann fit (left) and Arrhenius plot (right).

FIG. 36 depicts the temperature dependent lifetime for (PZI)Au(Bim) in PS. Boltzmann fit (left) and Arrhenius plot (right).

FIG. 37 depicts thermal ellipsoid plots Cu_{BCz}^{PAC} (top left), Au_{bim}^{MAC} (top right) and Au_{Mbim}^{BZI} (bottom).

FIG. 38 is a plot of the electrochemical redox potentials and transition energies for the ¹ICT state. The energy of the ¹ICT state (in toluene) was estimated from the onset of the absorption band where the intensity was 0.10 the value at λₘₐₓ.

FIG. 39 depicts the molecular orbitals (MOs) of Au_{Cz}^{BZAC} (left) and Au_{Bim}^{BZAC} (right). The HOMO is displayed with red and blue phases and the LUMO is displayed with turquoise and cream phases (isovalue=0.1). A magnified perspective is presented to highlight contribution of the d orbital to the HOMO and LUMO. The 2,6-isopropyl groups have been removed for clarity.

FIG. 40 is a plot of BZAC/PAC extinction in toluene and polystyrene. Inset shows the spectra of Au_{Cz}^{BZAC} in toluene and polystyrene (1 wt %), normalized at the Cz absorbance.

FIG. 41 is a plot of BZAC/PAC emission in toluene and polystyrene

FIG. 42 is a plot of the extinction spectra in toluene of Au_{bim}^{carbene} complexes.

FIG. 43 is a plot of the emission spectra in polystyrene of Au_{bim}^{carbene} complexes.

FIG. 44 is a plot of the absorption and emission spectra for (BZI) Au (amide), amide=bim, Mbim and Obim. Extinction spectra are recorded in toluene solution (bottom) and emission spectra in 1% doped polystyrene thin films (top).

FIG. 45 depicts the ICT transition and the nature of the interaction between the N lone pairs and carbene p-orbital of the N-heterocycle carbene (NHC) for the cMa complexes are illustrated. In this representation the plane of the NHC ligand is perpendicular to the page.

FIG. 46 depicts LUMO orbitals for M_{bim}^{carbene} complexes. The dipp groups are only shown for the IPr and CAAC complexes. In the other complexes the dipp groups are not involved in the LUMO. The LUMO energies (in eV) from DFT calculations are given below the acronym of each ligand.

FIG. 47 depicts carbene and amide ligands and the structural effect on TADF emission. At left is a scheme depicting the centers of negative charge (blue spheres) and positive charge (red spheres) on the molecular frame for the ICT excited states. Ar=2,6-diisopropylphenyl and Ad=adamantyl. At right is a plot of the rate of TADF emission (kᵣ^{TADF}) at room temperature for a doped polystyrene film is plotted as a function of the hole/electron separation distance.

### DETAILED DESCRIPTION

### A. Terminology

Unless otherwise specified, the below terms used herein are defined as follows:

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule.” and it is believed that all dendrimers currently used in the field of OLEDs are small molecules.

As used herein. “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

The terms “halo,” “halogen,” and “halide” are used interchangeably and refer to fluorine, chlorine, bromine, and iodine.

The term “acyl” refers to a substituted carbonyl radical (C(O)—Rₛ).

The term “ester” refers to a substituted oxycarbonyl (—O—C(O)—Rₛ or —C(O)—O—Rₛ) radical.

The term “ether” refers to an —ORₛ radical.

The terms “sulfanyl” or “thio-ether” are used interchangeably and refer to a —SRs radical.

The term “selenyl” refers to a —SeRₛ radical.

The term “sulfinyl” refers to a —S(O)—Rₛ radical.

The term “sulfonyl” refers to a —SO₂—Rₛ radical.

The term “phosphino” refers to a —P(Rₛ)₃ radical, wherein each Rₛ can be same or different.

The term “silyl” refers to a —Si(Rₛ)₃ radical, wherein each Rₛ can be same or different.

The term “germyl” refers to a —Ge(Rₛ)₃ radical, wherein each Rₛ can be same or different.

The term “boryl” refers to a —B(Rₛ)₂ radical or its Lewis adduct —B(Rₛ)₃ radical, wherein Rₛ can be same or different.

In each of the above. Rₛ can be hydrogen or a substituent selected from the group consisting of deuterium, halogen, alkyl, cycloalkyl, heteroalkyl, heterocycloalkyl, arylalkyl, alkoxy aryloxy, amino, silyl, alkenyl, cycloalkenyl, heteroalkenyl, alkynyl, aryl, heteroaryl, and combination thereof. Preferred Rₛ is selected from the group consisting of alkyl, cycloalkyl, aryl, heteroaryl, and combination thereof.

The term “alkyl” refers to and includes both straight and branched chain alkyl radicals. Preferred alkyl groups are those containing from one to fifteen carbon atoms and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group may be optionally substituted.

The term “cycloalkyl” refers to and includes monocyclic, polycyclic, and spiro alkyl radicals. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group may be optionally substituted.

The terms “heteroalkyl” or “heterocycloalkyl” refer to an alkyl or a cycloalkyl radical, respectively, having at least one carbon atom replaced by a heteroatom. Optionally the at least one heteroatom is selected from O, S, N, P, B, Si and Se, preferably, O, S or N. Additionally, the heteroalkyl or heterocycloalkyl group may be optionally substituted.

The term “alkenyl” refers to and includes both straight and branched chain alkene radicals. Alkenyl groups are essentially alkyl groups that include at least one carbon-carbon double bond in the alkyl chain. Cycloalkenyl groups are essentially cycloalkyl groups that include at least one carbon-carbon double bond in the cycloalkyl ring. The term “heteroalkenyl” as used herein refers to an alkenyl radical having at least one carbon atom replaced by a heteroatom. Optionally the at least one heteroatom is selected from O, S, N, P, B, Si, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group may be optionally substituted.

The term “alkynyl” refers to and includes both straight and branched chain alkyne radicals. Alkynyl groups are essentially alkyl groups that include at least one carbon-carbon triple bond in the alkyl chain. Preferred alkynyl groups are those containing two to fifteen carbon atoms. Additionally, the alkynyl group may be optionally substituted.

The terms “aralkyl” or “arylalkyl” are used interchangeably and refer to an alkyl group that is substituted with an aryl group. Additionally, the aralkyl group may be optionally substituted.

The term “heterocyclic group” refers to and includes aromatic and non-aromatic cyclic radicals containing at least one heteroatom. Optionally the at least one heteroatom is selected from O, S, N, P, B, Si, and Se, preferably, O, S, or N. Hetero-aromatic cyclic radicals may be used interchangeably with heteroaryl. Preferred hetero-non-aromatic cyclic groups are those containing 3 to 7 ring atoms which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group may be optionally substituted.

The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group may be optionally substituted.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The terms alkyl, cycloalkyl, heteroalkyl, heterocycloalkyl, alkenyl, cycloalkenyl, heteroalkenyl, alkynyl, aralkyl, heterocyclic group, aryl, and heteroaryl, as used herein, are independently unsubstituted, or independently substituted, with one or more general substituents.

In many instances, the General Substituents are selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof.

In some instances, the Preferred General Substituents are selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some instances, the More Preferred General Substituents are selected from the group consisting of deuterium, fluorine, alkyl, cycloalkyl, alkoxy, aryloxy, amino, silyl, aryl, heteroaryl, sulfanyl, and combinations thereof.

In yet other instances, the Most Preferred General Substituents are selected from the group consisting of deuterium, fluorine, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents zero or no substitution. R¹, for example, can be a hydrogen for available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e, aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h] quinoxaline and dibenzo[f,h] quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example·U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instances, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein. “adjacent” means that the two substituents involved can be on the same ring next to each other, or on two neighboring rings having the two closest available substitutable positions, such as 2, 2′ positions in a biphenyl, or 1, 8 position in a naphthalene, as long as they can form a stable fused ring system.

### B. The Compounds of the Present Disclosure

In one aspect, the present disclosure provides a compound of Formula (I):

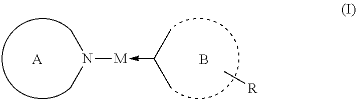

wherein
M is a metal;
ring B is a carbene ligand;
R represents mono to the maximum allowable substitution;
each R is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; wherein any two adjacent R are optionally joined or fused together to form a ring which is optionally substituted;
ring A is an amide ligand selected from the group consisting of formula (A-1) and formula (A-2);

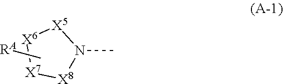

wherein, in formula (A-1),
the dashed line represents coordination to M;
each X³, X⁶, X⁷, and X⁸ independently represents N or C;
R^{A} represents mono to the maximum allowable substitution;
wherein any two adjacent groups R^{A} may optionally together form a fused ring having the following formula:

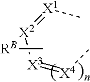

wherein each X¹, X², X³, and X⁴ independently represents N or C;
n is 0 or 1; wherein when n is 0, then X³ binds directly to formula (A-1);
R^{B} represents mono to the maximum allowable substitution;
each occurrence of R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano phosphino, and combinations thereof; wherein any two R^{B} are optionally joined or fused together to form a ring which is optionally substituted;

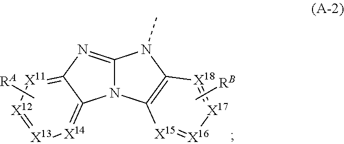

wherein, in formula (A-2);
each X¹¹ to X¹⁸ independently represents N or C;
R^{A} and R^{B} each represent mono to the maximum allowable substitution; and
each occurrence of R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano phosphino, and combinations thereof; wherein any two adjacent R^{A} and R^{B} are optionally joined or fused together to form a ring which is optionally substituted.

In one embodiment, M is selected from the group consisting of Cu, Ag, and Au.

In one embodiment, ring A is represented by formula (A-1). In one embodiment, ring A is represented by formula (A-2).

In one embodiment, ring A is represented by one of the following structures:

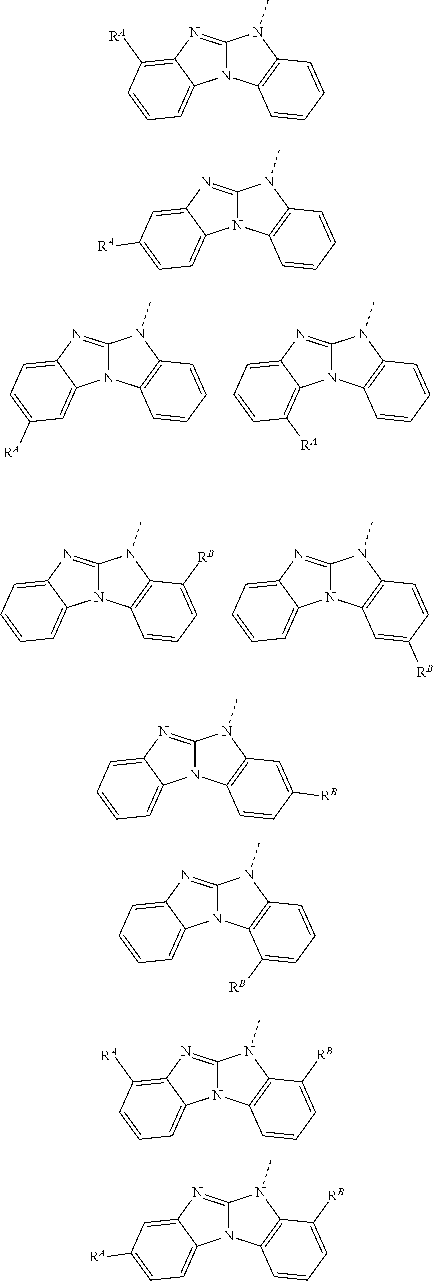

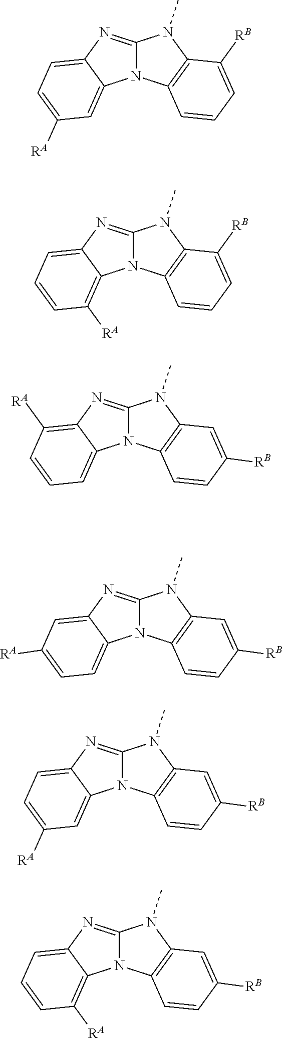

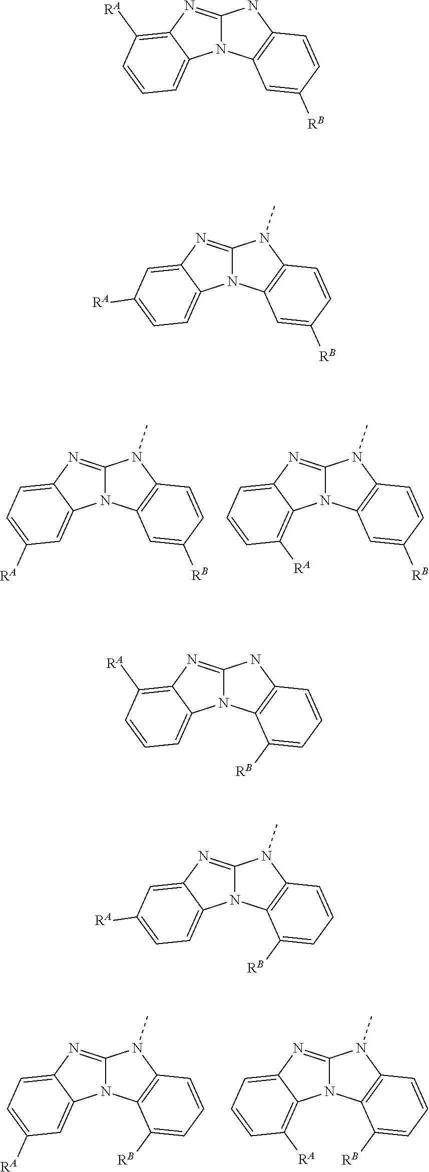

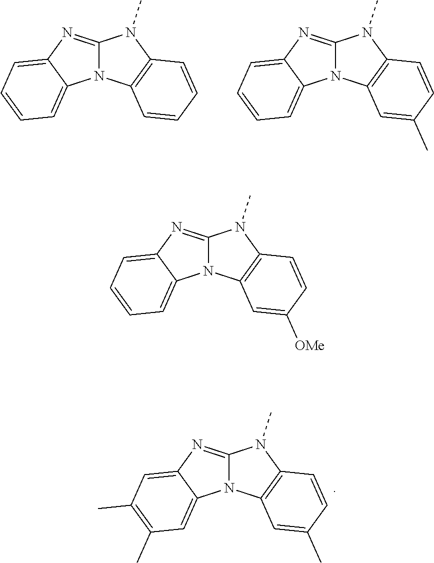

In one embodiment, ring B is selected from the group consisting of Formula A, Formula B, Formula C, Formula D, Formula E, and Formula F:

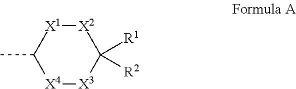

wherein
each X¹ to X⁴ independently represents NR¹, CR¹R², C═O, C═S, O, or S; and
each occurrence of R¹ and R² is independently selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof;
wherein any two adjacent R¹ and R² are optionally joined or fused together to form a ring which is optionally substituted.

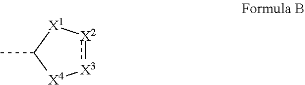

wherein each X¹ and X⁴ independently represents N, NR¹, CR¹, CR¹R², SiR¹, SiR¹R², PR¹, B, BR¹, BR¹R²; O, or S; and
each X² and X³ independently represents CR¹, CR¹R², SiR¹, SiR¹R², N, NR¹, P, PR¹, B, BR¹, O, or S;
each occurrence of R¹ and R² is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof;
wherein any two adjacent R¹ and R² are optionally joined or fused together to form a ring which is optionally substituted; and
the dashed line inside the five-member ring represents zero or one double-bond.

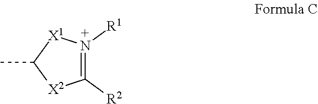

wherein each X¹ and X² independently represents NR¹, CR¹R², O, or S;
each occurrence of R¹ and R² is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; and
wherein any two adjacent R¹ and R² are optionally joined or fused together to form a ring which is optionally substituted.

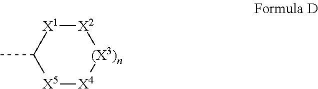

wherein
each X¹ to X⁵ independently represents N, P, NR¹, PR¹, B, BR¹, CR¹, SiR¹, CR¹R², SiR¹R², C═O, C═S, O, or S;
n is 0 or 1;
each occurrence of R¹ and R² is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof;
wherein any two adjacent R¹ and R² are optionally joined or fused together to form a ring which is optionally substituted;

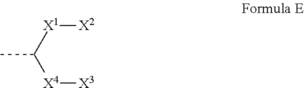

wherein
each X¹ and X⁴ independently represents NR¹, CR¹, SiR¹, CR¹R², SiR¹R², PR¹, BR¹, C═O, C═S, O, or S;
each X² and X³ is independently present or absent, and if present, independently represents H, NR¹R², CR¹, CR¹R², C═O, C═S, O, or S;
each occurrence of R¹ and R² is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof;
wherein any two adjacent R¹ and R² are optionally joined or fused together to form a ring which is optionally substituted

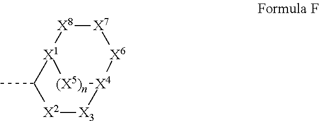

wherein each occurrence of X¹ to X⁸ independently represents N, P, NR¹, PR¹, B, BR¹, CR¹, SiR¹, CR¹R², SiR¹R², C═O, C═S, O, or S;
n is 1 or 2;
each occurrence of R¹ and R² is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof;
wherein any two adjacent R¹ and R² are optionally joined or fused together to form a ring which is optionally substituted.

In one embodiment, ring B is represented by one of the following structures:

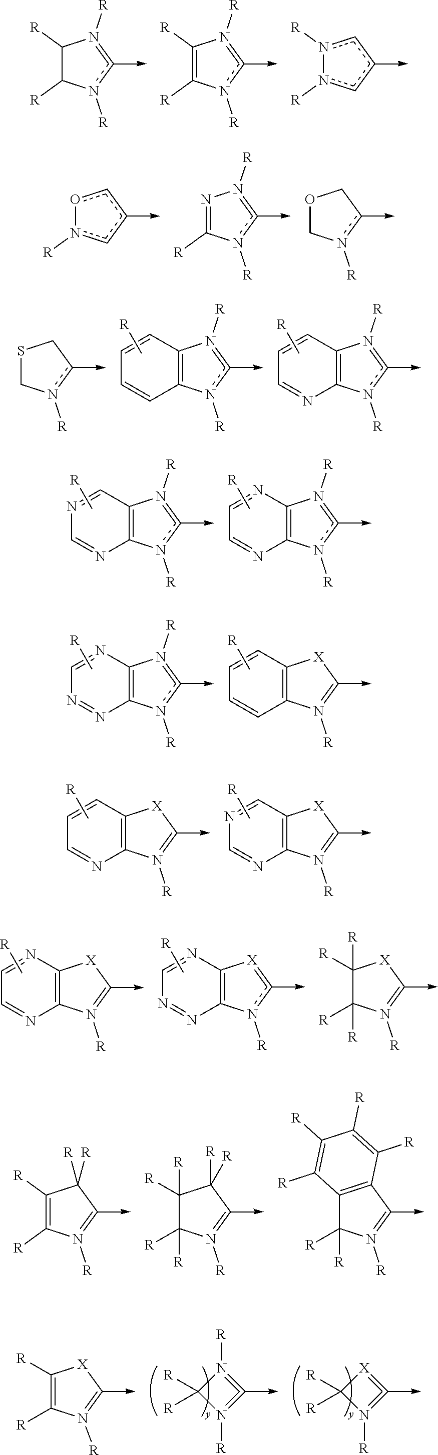

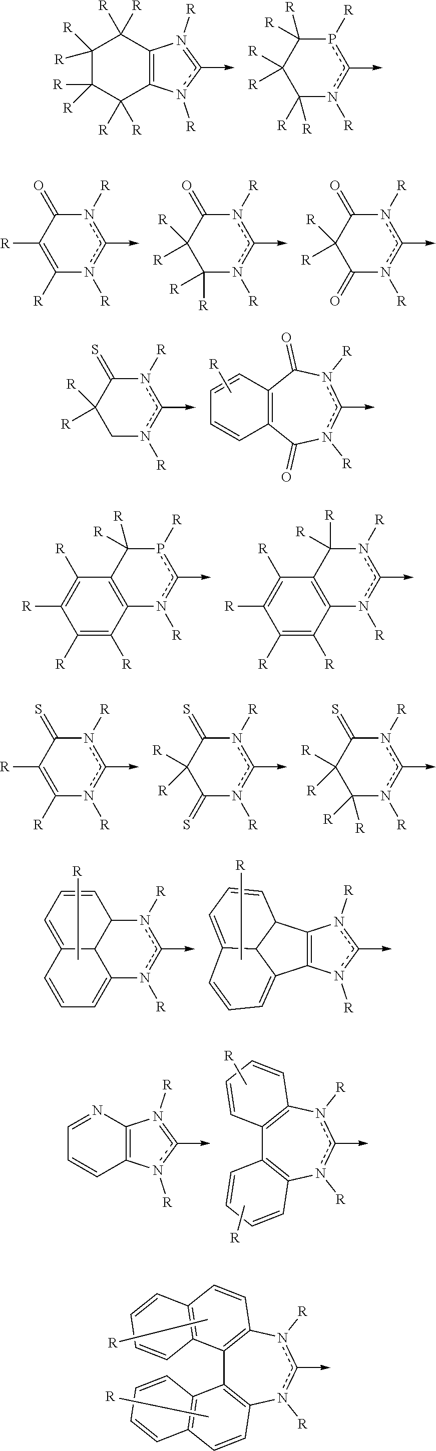

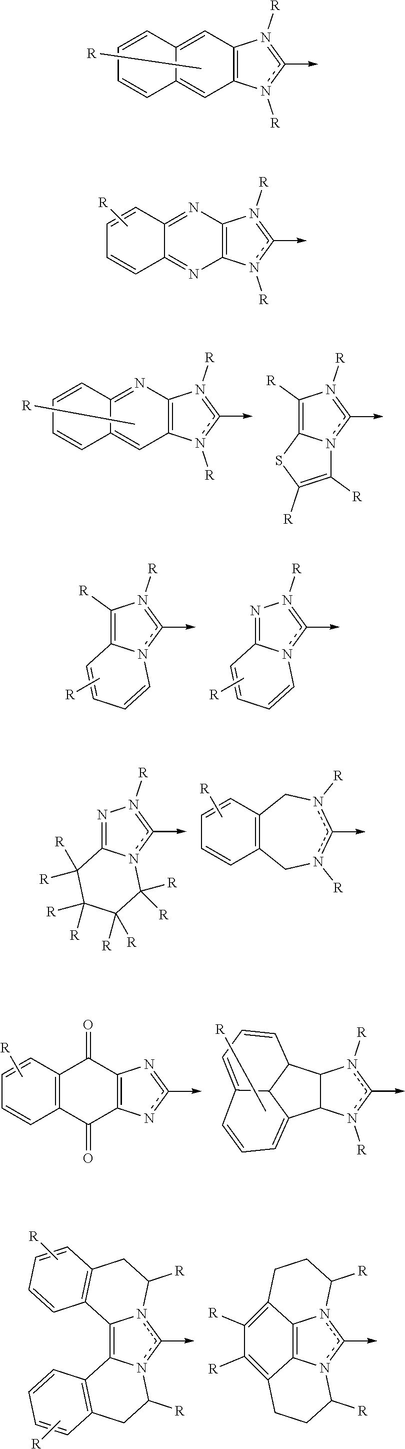

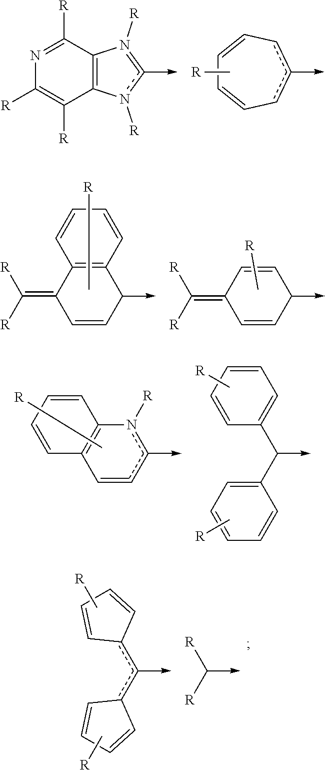

wherein each R is independently selected from the group consisting of hydrogen, deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitro, nitrile, isonitrile, sulfanyl, boryl, acyl, carboxylic acid, benzoyl, ether, ester, vinyl, ketone, sulfinyl, sulfonyl, cyano, phosphino, and combinations thereof; wherein any two adjacent substituents may together join to form a ring.

In one embodiment, ring B is represented by one of the following structures:

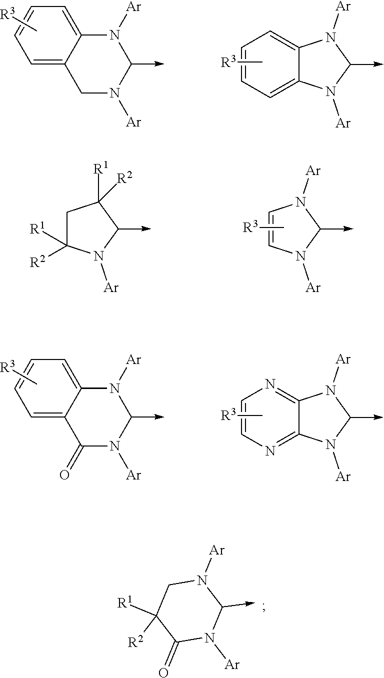

wherein each R¹, R², and R³ is independently selected from the group consisting of hydrogen, deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitro, nitrile, isonitrile, sulfanyl, boryl, acyl, carboxylic acid, benzoyl, ether, ester, vinyl, ketone, sulfinyl, sulfonyl, cyano, phosphino, and combinations thereof; wherein any two adjacent substituents may together join to form a heteroaryl ring, an aryl ring, a cycloalkyl ring, or a bicyclic ring; and
wherein each Ar independently represents aryl or heteroaryl which is optionally further substituted with one or more substituents independently selected from the group consisting of hydrogen, deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitro, nitrile, isonitrile, sulfanyl, boryl, acyl, carboxylic acid, benzoyl, ether, ester, vinyl, ketone, sulfinyl, sulfonyl, cyano, phosphino, and combinations thereof; wherein any two adjacent substituents may together join to form a ring.

In one embodiment, B is represented by one of the following structures:

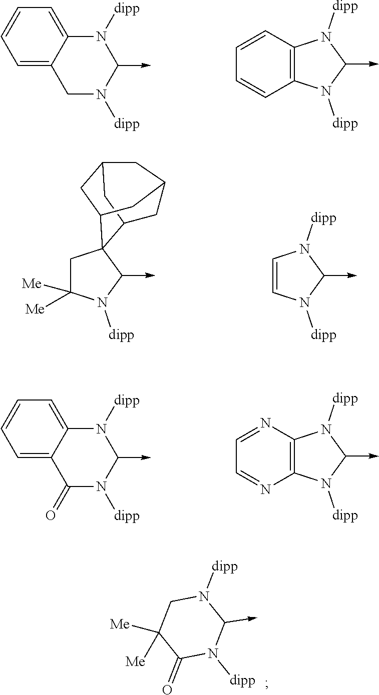

wherein dipp=2,6-disopropylphenyl.

In one embodiment, the compound has one of the following structures:

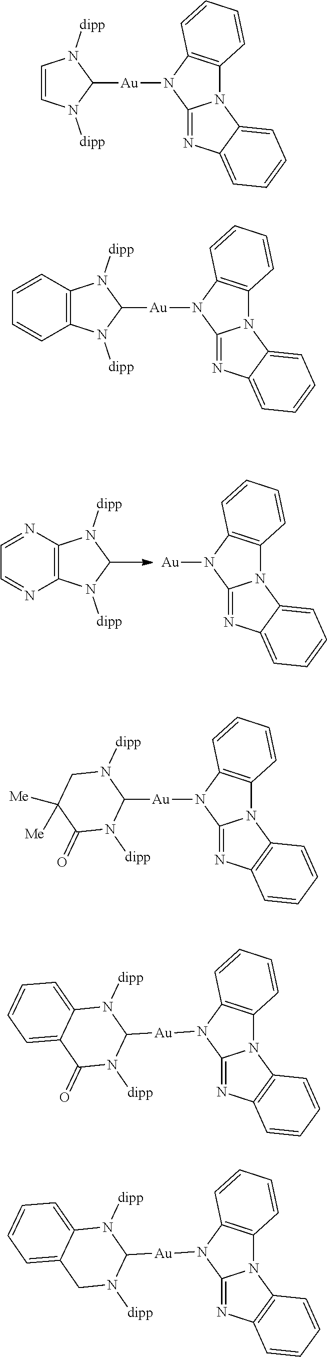

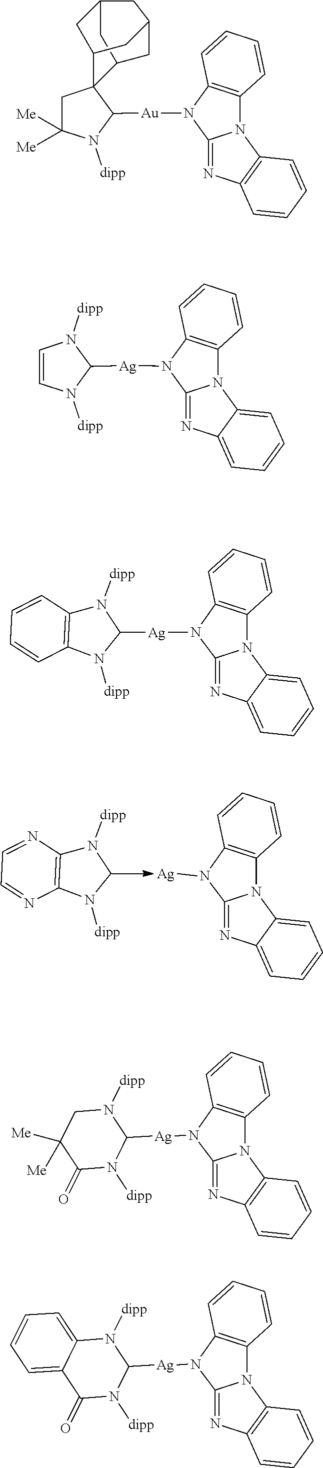

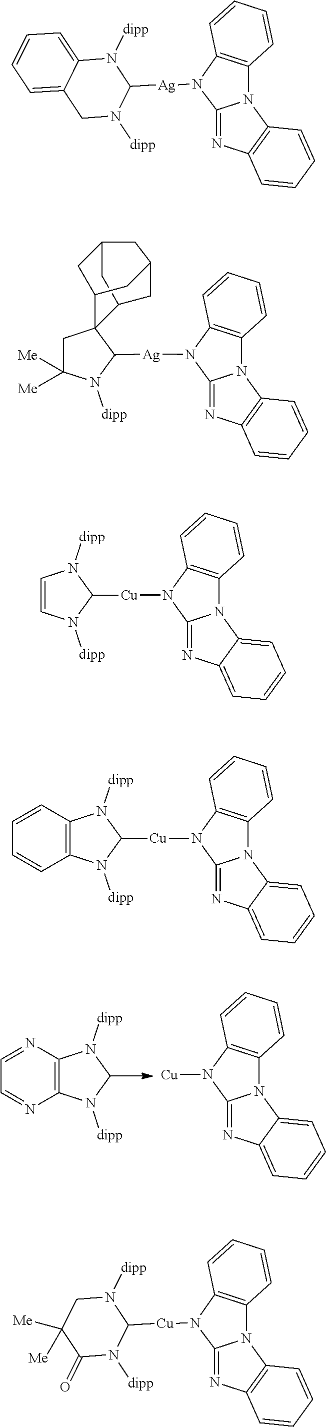

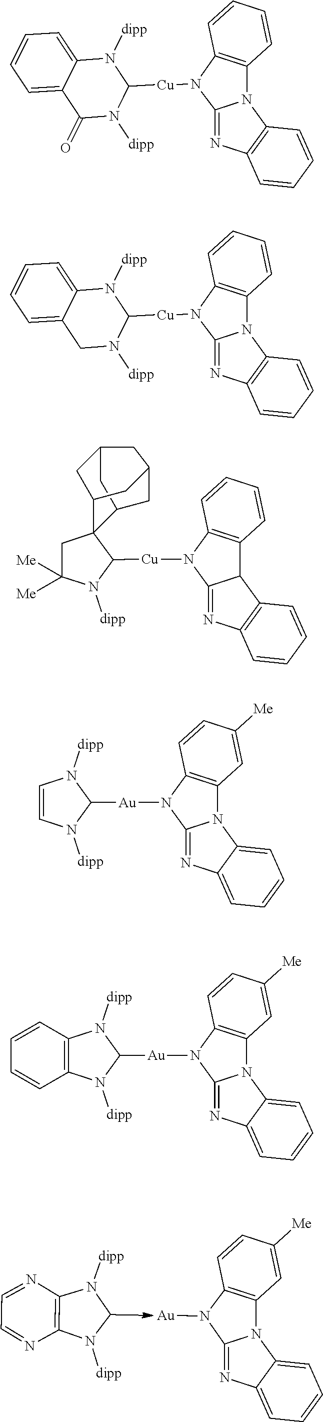

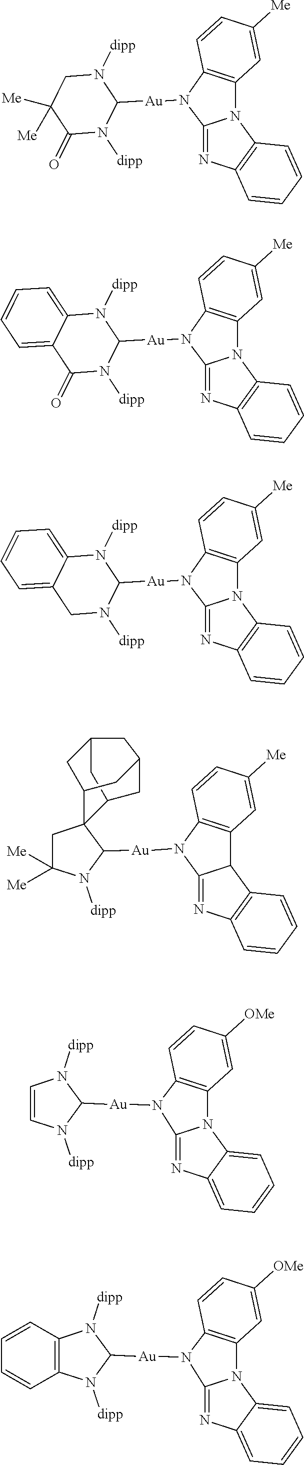

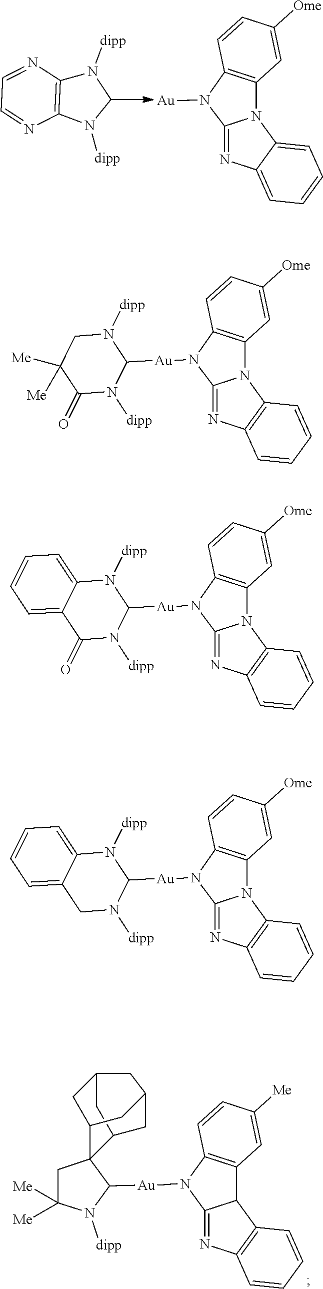

wherein dipp=2,6-disopropylphenyl.

In one embodiment, ring B is represented by formula (B-1):

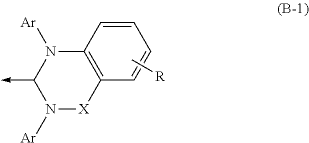

wherein
X represents CR¹R², SiR¹R², C—O, or C═S;
each Ar independently represents an aryl group or a heteroaryl group which may be further substituted with one or more substituents selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; wherein any two adjacent substituents are optionally joined or fused together to form a ring which is optionally substituted;
R represents mono to the maximum allowable substitution; and
each R, R¹, and R² is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; wherein any two adjacent R, R¹, or R² are optionally joined or fused together to form a ring which is optionally substituted.

In one embodiment, ring A is represented by formula (A-3):

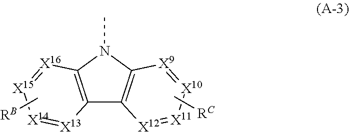

wherein
the dashed line represents coordination to M;
each occurrence of X¹ to X¹⁶ independently represents C or N;
each occurrence of R^{B} and R^{C} independently represents mono to the maximum allowable substitution;
each occurrence of R^{B} and R^{C} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof;
wherein any two adjacent R^{B} and R^{C} are optionally joined or fused together to form a ring which is optionally substituted.

In one embodiment, ring A is selected from the group consisting of:

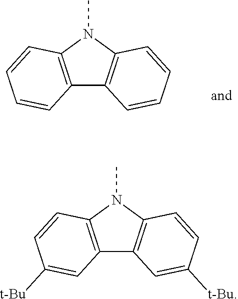

In one embodiment, the compound is represented by one of the following structures:

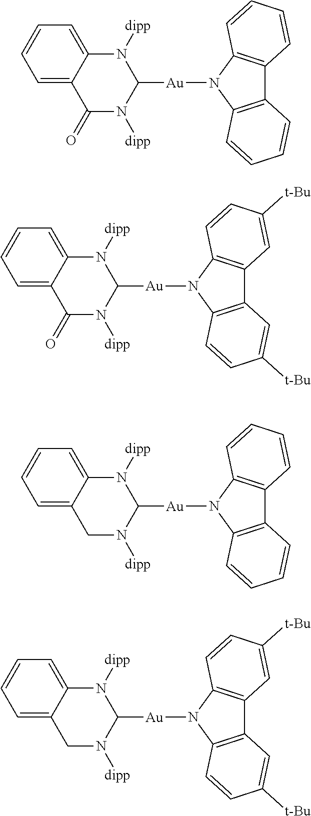

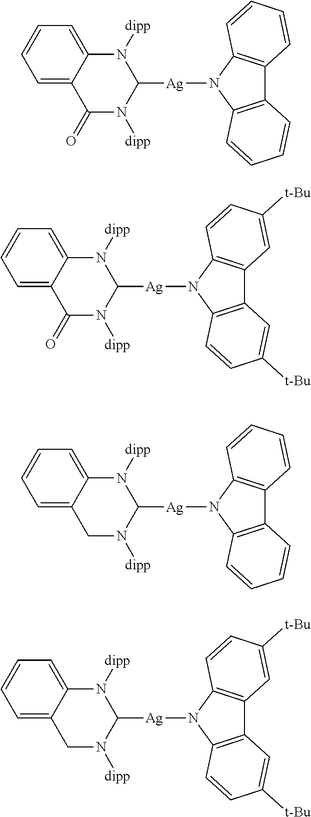

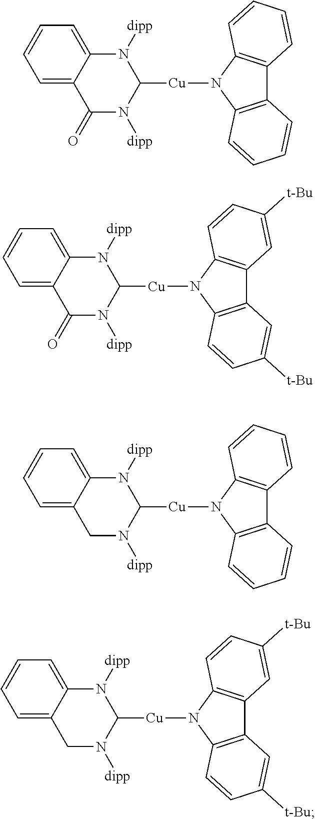

wherein dipp=2,6-disopropylphenyl.

In some embodiments, the compound of formula (I) described herein can be at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated. As used herein, percent deuteration has its ordinary meaning and includes the percent of possible hydrogen atoms (e.g., positions that are hydrogen or deuterium) that are replaced by deuterium atoms.

### C. The OLEDs and the Devices of the Present Disclosure

In another aspect, the present disclosure also provides an OLED device comprising a first organic layer that contains a compound as disclosed in the above compounds section of the present disclosure.

In some embodiments, the OLED comprises: an anode; a cathode; and an organic layer disposed between the anode and the cathode, where the organic layer comprises a compound of formula (I):

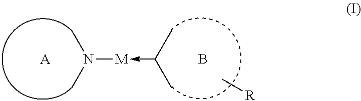

wherein
M is a metal;
ring B is a carbene ligand;
R represents mono to the maximum allowable substitution;
each R is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; wherein any two adjacent R are optionally joined or fused together to form a ring which is optionally substituted;
ring A is an amide ligand selected from the group consisting of formula (A-1) and formula (A-2);

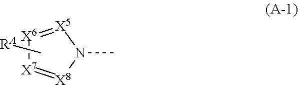

wherein, in formula (A-1),
the dashed line represents coordination to M;
each X³, X⁶, X⁷, and X⁸ independently represents N or C;
R^{A} represents mono to the maximum allowable substitution;
wherein any two adjacent groups R^{A} may optionally together form a fused ring having the following formula:

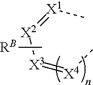

wherein each X¹, X², X³, and X⁴ independently represents N or C;
n is 0 or 1; wherein when n is 0, then X³ binds directly to formula (A-1);
R^{B} represents mono to the maximum allowable substitution;
each occurrence of R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano phosphino, and combinations thereof; wherein any two R^{B} are optionally joined or fused together to form a ring which is optionally substituted;

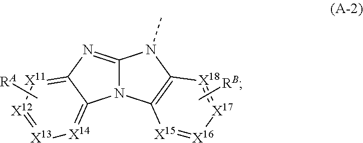

wherein, in formula (A-2);
each X¹¹ to X¹⁸ independently represents N or C;
R^{A} and R^{B} each represent mono to the maximum allowable substitution; and
each occurrence of R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano phosphino, and combinations thereof; wherein any two adjacent R^{A} and R^{B} are optionally joined or fused together to form a ring which is optionally substituted.

In some embodiments, the organic layer may be an emissive layer and the compound as described herein may be an emissive dopant or a non-emissive dopant.

In some embodiments, the emissive layer comprises one or more quantum dots.

In some embodiments, the organic layer may further comprise a host, wherein the host comprises a triphenylene containing benzo-fused thiophene or benzo-fused furan, wherein any substituent in the host is an unfused substituent independently selected from the group consisting of CₙH₂ₙ₊₁, OCₙH₂ₙ₊₁, OAr₁, N(CₙH₂ₙ₊₁)₂, N(Ar₁)(Ar₂), CH═CH—CₙH₂ₙ₊₁, C≡CCₙH₂ₙ₊₁, Ar₁, Ar₁-Ar₂, CₙH₂ₙ—Ar₁, or no substitution, wherein n is an integer from 1 to 10; and wherein Ar₁ and Ar₂ are independently selected from the group consisting of benzene, biphenyl, naphthalene, triphenylene, carbazole, and heteroaromatic analogs thereof.

In some embodiments, the organic layer may further comprise a host, wherein host comprises at least one chemical group selected from the group consisting of triphenylene, carbazole, indolocarbazole, dibenzothiophene, dibenzofuran, dibenzoselenophene, 5λ2-benzo[d]benzo[4,5]imidazo[3,2-a]imidazole, 5,9-dioxa-13b-boranaphtho[3,2,1-de]anthracene, triazine, boryl, silyl, aza-triphenylene, aza-carbazole, aza-indolocarbazole, aza-dibenzothiophene, aza-dibenzofuran, aza-dibenzoselenophene, aza-5λ2-benzo[d]benzo[4.5]imidazo[3,2-a]imidazole, and aza-(5,9-dioxa-13b-boranaphtho[3,2,1-de]anthracene).

In some embodiments, the host may be selected from the HOST Group consisting of:

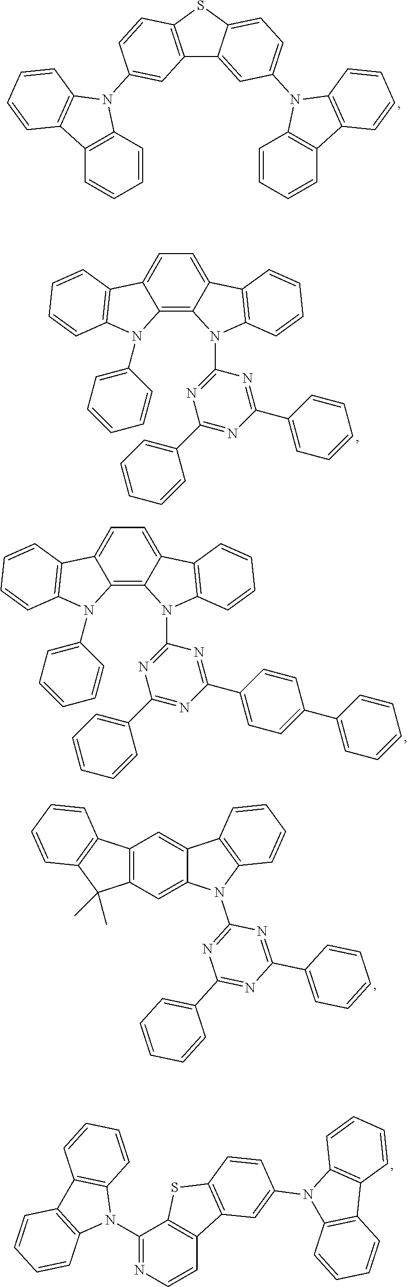

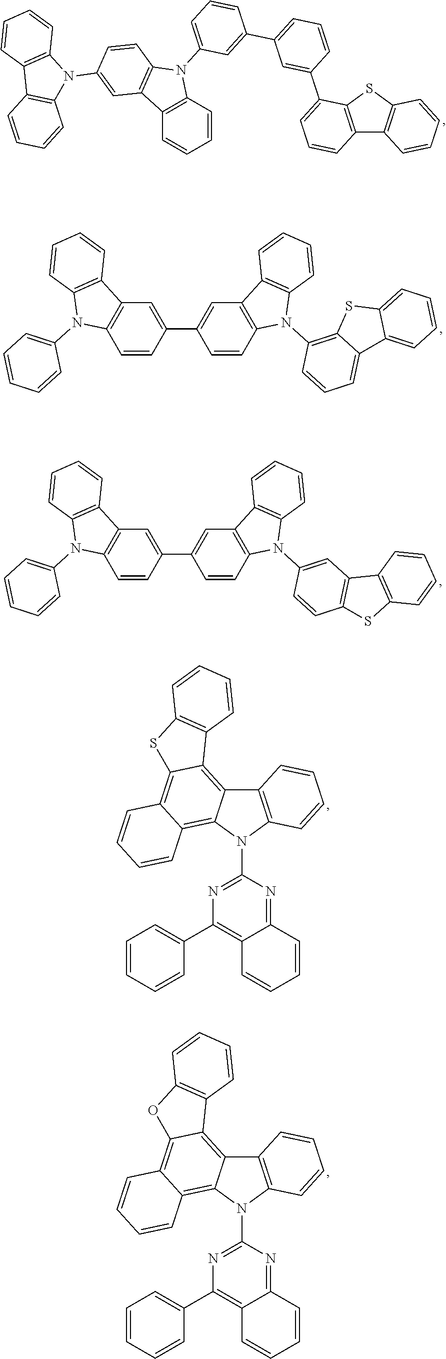 [SMILES: c1cc(-c2cccc(-n3c4ccccc4c4cc(-n5c6ccccc6c6ccccc65)ccc43)c2)cc(-c2cccc3c2sc2ccccc23)c1 ; c1ccc(-n2c3ccccc3c3cc(-c4ccc5c(c4)c4ccccc4n5-c4cccc5c4sc4ccccc45)ccc32)cc1 ; c1ccc(-n2c3ccccc3c3cc(-c4ccc5c(c4)c4ccccc4n5-c4ccc5sc6ccccc6c5c4)ccc32)cc1 ; c1ccc(-c2nc(-n3c4ccccc4c4c5c6ccccc6sc5c5ccccc5c43)nc3ccccc23)cc1 ; c1ccc(-c2nc(-n3c4ccccc4c4c5c6ccccc6oc5c5ccccc5c43)nc3ccccc23)cc1]

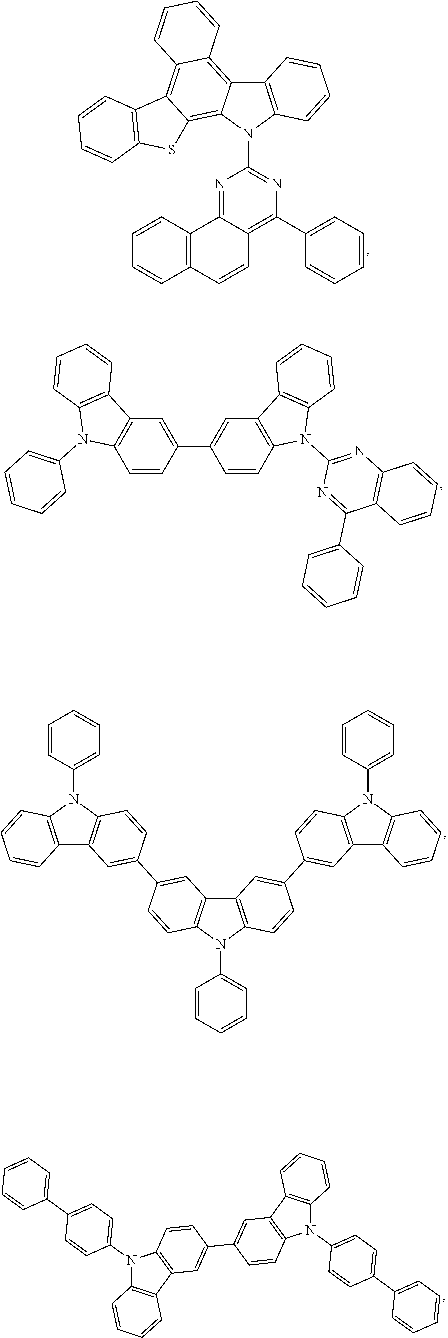 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

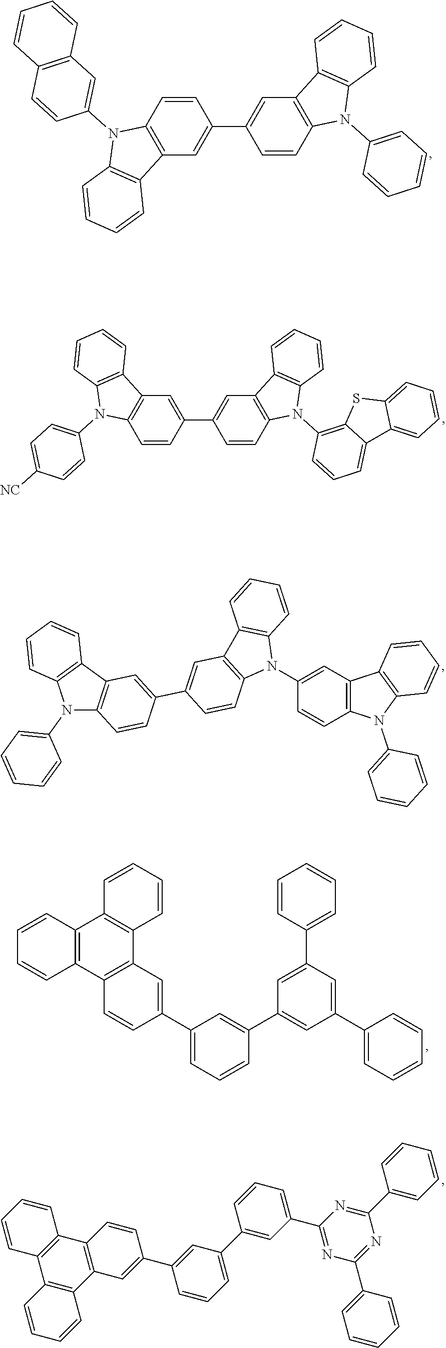

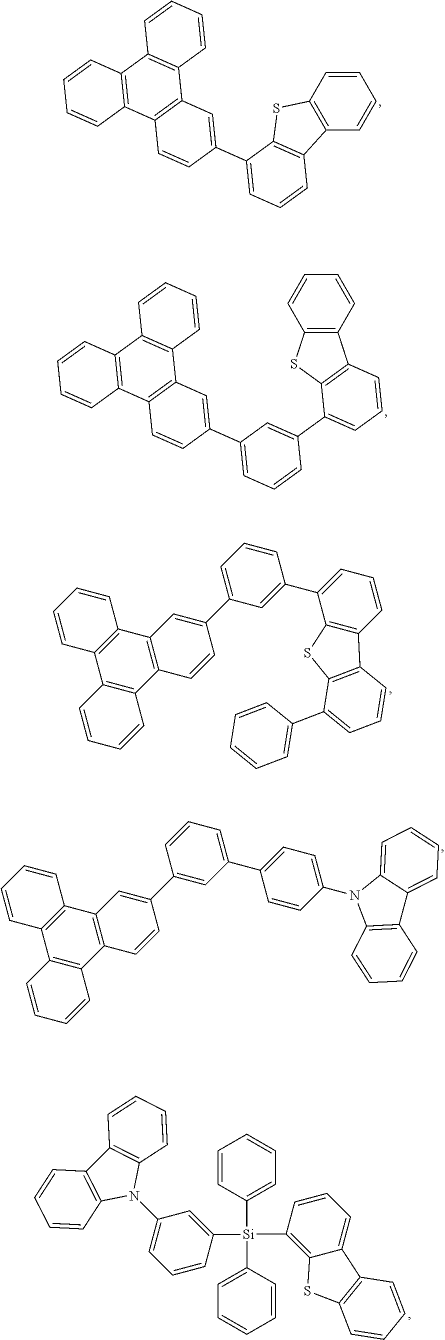 [SMILES: c1ccc2c(c1)sc1c(-c3ccc4c5ccccc5c5ccccc5c4c3)cccc12 ; c1cc(-c2ccc3c4ccccc4c4ccccc4c3c2)cc(-c2cccc3c2sc2ccccc23)c1 ; c1ccc(-c2cccc3c2sc2c(-c4cccc(-c5ccc6c7ccccc7c7ccccc7c6c5)c4)cccc23)cc1 ; c1cc(-c2ccc(-n3c4ccccc4c4ccccc43)cc2)cc(-c2ccc3c4ccccc4c4ccccc4c3c2)c1 ; c1ccc([Si](c2ccccc2)(c2cccc(-n3c4ccccc4c4ccccc43)c2)c2cccc3c2sc2ccccc23)cc1]

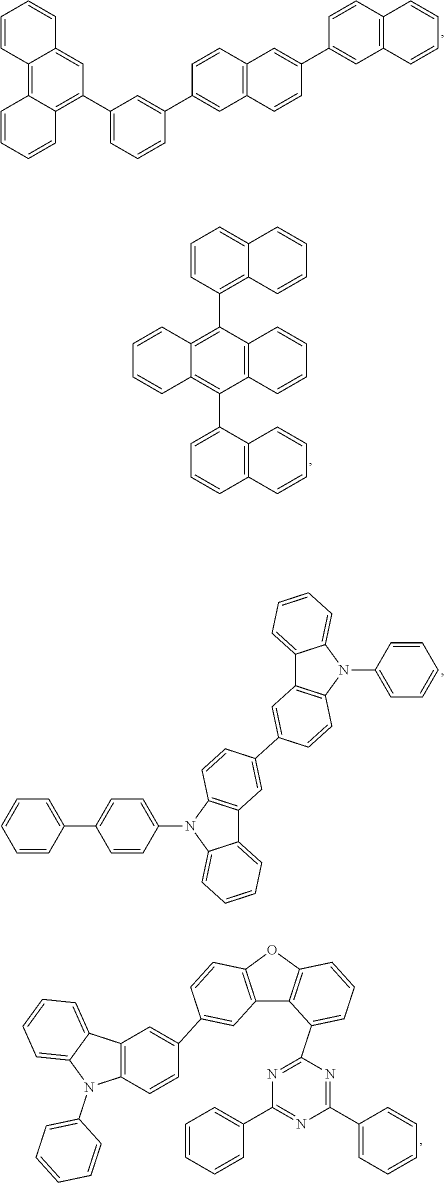

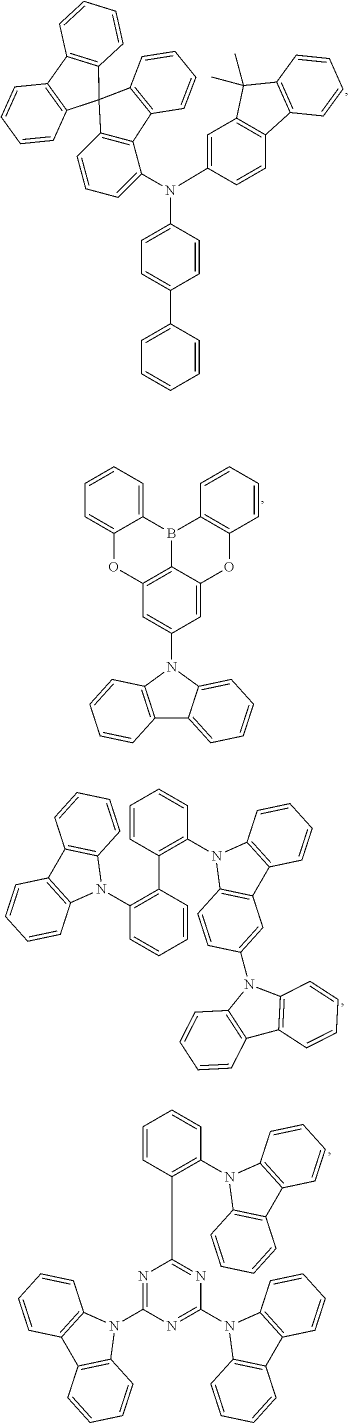

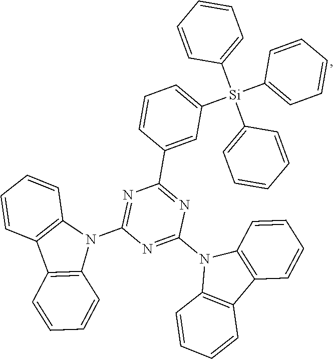 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1]

and combinations thereof.

In some embodiments, the organic layer may further comprise a host, wherein the host comprises a metal complex.

In some embodiments, the emissive layer can comprise two hosts, a first host and a second host. In some embodiments, the first host is a hole transporting host, and the second host is an electron transporting host. In some embodiments, the first host and the second host can form an exciplex.

In some embodiments, the compound as described herein may be a sensitizer, wherein the device may further comprise an acceptor; and wherein the acceptor may be selected from the group consisting of fluorescent emitter, delayed fluorescence emitter, and combination thereof.

In yet another aspect, the OLED of the present disclosure may also comprise an emissive region containing a compound as disclosed in the above compounds section of the present disclosure.

In some embodiments, the emissive region can comprise a compound of formula (I):

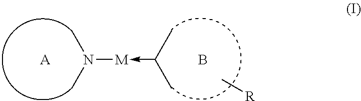

wherein
M is a metal;
ring B is a carbene ligand;
R represents mono to the maximum allowable substitution;
each R is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; wherein any two adjacent R are optionally joined or fused together to form a ring which is optionally substituted;
ring A is an amide ligand selected from the group consisting of formula (A-1) and formula (A-2);

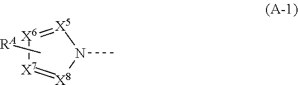

wherein, in formula (A-1),
the dashed line represents coordination to M;
each X³, X⁶, X⁷, and X⁸ independently represents N or C;
R^{A} represents mono to the maximum allowable substitution;
wherein any two adjacent groups R^{A} may optionally together form a fused ring having the following formula:

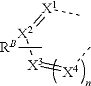

wherein each X¹, X², X³, and X⁴ independently represents N or C;
n is 0 or 1; wherein when n is 0, then X³ binds directly to formula (A-1);
R^{B} represents mono to the maximum allowable substitution;
each occurrence of R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano phosphino, and combinations thereof; wherein any two R^{B} are optionally joined or fused together to form a ring which is optionally substituted;

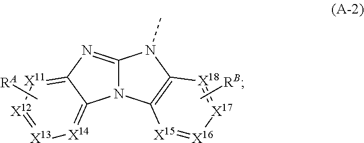

wherein, in formula (A-2);
each X¹¹ to X¹⁸ independently represents N or C;
R^{A} and R^{B} each represent mono to the maximum allowable substitution; and each occurrence of R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano phosphino, and combinations thereof; wherein any two adjacent R^{A} and R^{B} are optionally joined or fused together to form a ring which is optionally substituted.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for interventing layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fc, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand; the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a pluraility of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fc, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

In yet another aspect, the present disclosure also provides a consumer product comprising an organic light-emitting device (OLED) having an anode; a cathode; and an organic layer disposed between the anode and the cathode, wherein the organic layer may comprise a compound as disclosed in the above compounds section of the present disclosure.

In some embodiments, the consumer product comprises an OLED having an anode; a cathode; and an organic layer disposed between the anode and the cathode, wherein the organic layer may comprise a compound of formula (I) as described herein.

In some embodiments, the consumer product can be one of a flat panel display, a computer monitor, a medical monitor, a television, a billboard, a light for interior or exterior illumination and/or signaling, a heads-up display, a fully or partially transparent display, a flexible display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, a light therapy device, and a sign.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton.” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

Several OLED materials and configurations are described in U.S. Pat. Nos. 5,844,363, 6,303,238, and 5,707,745, which are incorporated herein by reference in their entirety.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently. OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75. No. 3, 4-6 (1999) (“Baldo-II”), are incorporated by reference in their entireties. Phosphorescence is described in more detail in U.S. Pat. No. 7,279,704 at cols. 5-6, which are incorporated by reference.

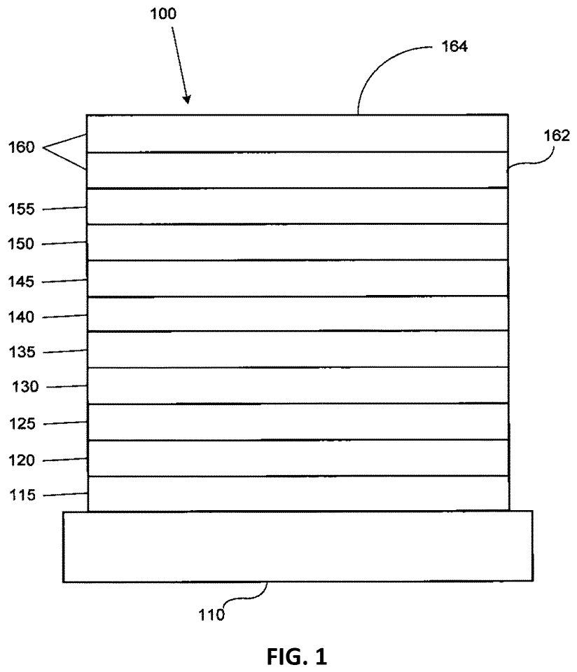

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

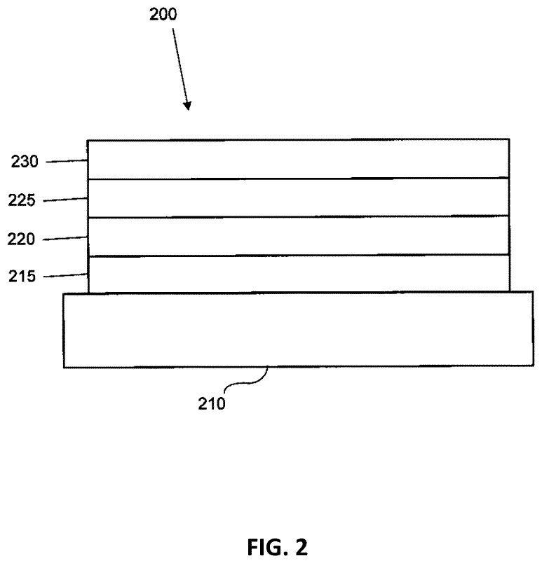

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the present disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP, also referred to as organic vapor jet deposition (OVJD)), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and organic vapor jet printing (OVJP). Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons are a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146. PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the present disclosure can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the present disclosure can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, rollable displays, foldable displays, stretchable displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, a light therapy device, and a sign. Various control mechanisms may be used to control devices fabricated in accordance with the present disclosure, including passive matrix and active matrix. Many of the devices are intended for use in a temperature range comfortable to humans, such as 18 degrees C. to 30 degrees C., and more preferably at room temperature (20-25° C.), but could be used outside this temperature range, for example, from −40 degree C. to +80° C.

More details on OLEDs, and the definitions described above, can be found in U.S. Pat. No. 7,279,704, which is incorporated herein by reference in its entirety.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence; see, e.g., U.S. application Ser. No. 15/700,352, which is hereby incorporated by reference in its entirety), triplet-triplet annihilation, or combinations of these processes. In some embodiments, the emissive dopant can be a racemic mixture, or can be enriched in one enantiomer. In some embodiments, the compound can be homoleptic (each ligand is the same). In some embodiments, the compound can be heteroleptic (at least one ligand is different from others). When there are more than one ligand coordinated to a metal, the ligands can all be the same in some embodiments. In some other embodiments, at least one ligand is different from the other ligands. In some embodiments, every ligand can be different from each other. This is also true in embodiments where a ligand being coordinated to a metal can be linked with other ligands being coordinated to that metal to form a tridentate, tetradentate, pentadentate, or hexadentate ligands. Thus, where the coordinating ligands are being linked together, all of the ligands can be the same in some embodiments, and at least one of the ligands being linked can be different from the other ligand(s) in some other embodiments.

In some embodiments, the compound can be used as a phosphorescent sensitizer in an OLED where one or multiple layers in the OLED contains an acceptor in the form of one or more fluorescent and/or delayed fluorescence emitters. In some embodiments, the compound can be used as one component of an exciplex to be used as a sensitizer. As a phosphorescent sensitizer, the compound must be capable of energy transfer to the acceptor and the acceptor will emit the energy or further transfer energy to a final emitter. The acceptor concentrations can range from 0.001% to 100%. The acceptor could be in either the same layer as the phosphorescent sensitizer or in one or more different layers. In some embodiments, the acceptor is a TADF emitter. In some embodiments, the acceptor is a fluorescent emitter. In some embodiments, the emission can arise from any or all of the sensitizer, acceptor, and final emitter

According to another aspect, a formulation comprising the compound described herein is also disclosed.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

In yet another aspect of the present disclosure, a formulation that comprises the novel compound disclosed herein is described. The formulation can include one or more components selected from the group consisting of a solvent, a host, a hole injection material, hole transport material, electron blocking material, hole blocking material, and an electron transport material, disclosed herein.

The present disclosure encompasses any chemical structure comprising the novel compound of the present disclosure, or a monovalent or polyvalent variant thereof. In other words, the inventive compound, or a monovalent or polyvalent variant thereof, can be a part of a larger chemical structure. Such chemical structure can be selected from the group consisting of a monomer, a polymer, a macromolecule, and a supramolecule (also known as supermolecule). As used herein, a “monovalent variant of a compound” refers to a moiety that is identical to the compound except that one hydrogen has been removed and replaced with a bond to the rest of the chemical structure. As used herein, a “polyvalent variant of a compound” refers to a moiety that is identical to the compound except that more than one hydrogen has been removed and replaced with a bond or bonds to the rest of the chemical structure. In the instance of a supramolecule, the inventive compound can also be incorporated into the supramolecule complex without covalent bonds.

### D. Combination of the Compounds of the Present Disclosure with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

### a) Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

Non-limiting examples of the conductivity dopants that may be used in an OLED in combination with materials disclosed herein are exemplified below together with references that disclose those materials: EP01617493, EP01968131, EP2020694, EP2684932, US20050139810, US20070160905, US20090167167, US2010288362, WO06081780, WO2009003455, WO2009008277, WO2009011327, WO2014009310, US2007252140, US2015060804, US20150123047, and US2012146012.

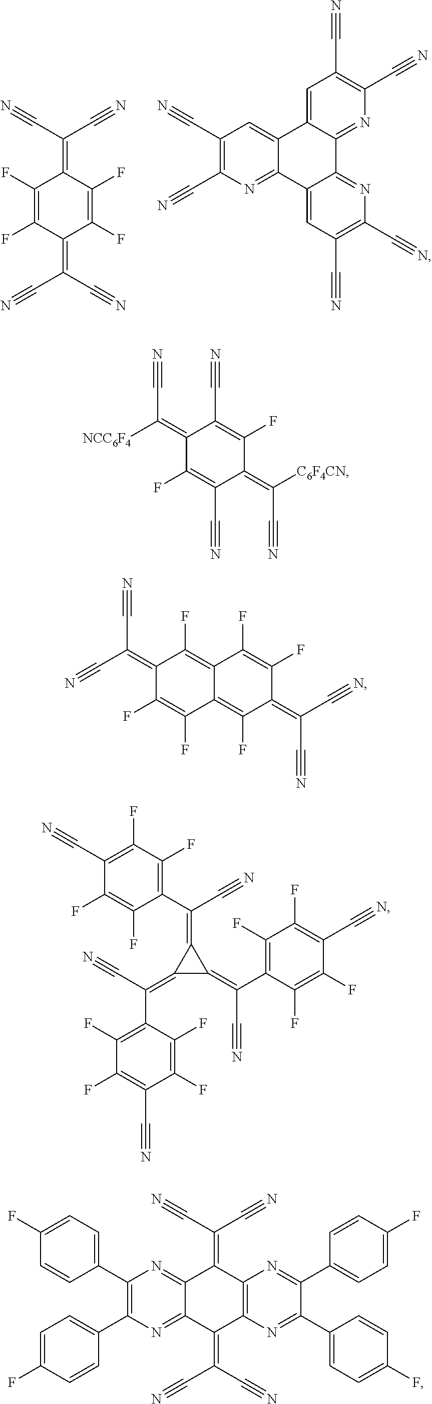

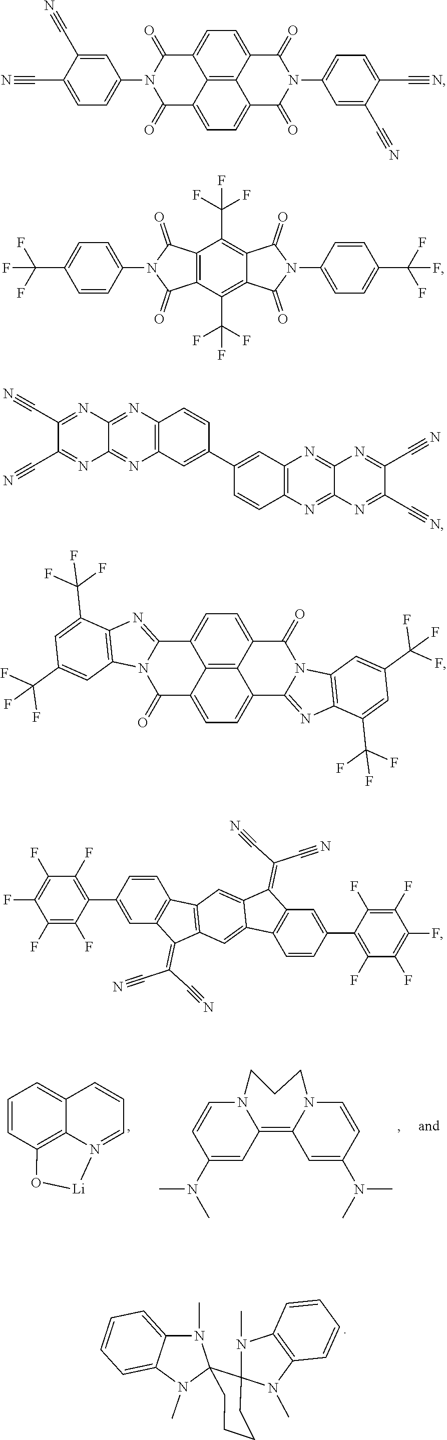

### b) HIL/HTL:

A hole injecting/transporting material to be used in the present disclosure is not particularly limited, and any compound may be used as long as the compound is typically used as a hole injecting/transporting material. Examples of the material include, but are not limited to: a phthalocyanine or porphyrin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and silane derivatives; a metal oxide derivative, such as MoOx; a p-type semiconducting organic compound, such as 1,4,5,8,9,12-Hexaazatriphenylenehexacarbonitrile; a metal complex, and a cross-linkable compounds.

Examples of aromatic amine derivatives used in HIL or HTL include, but not limit to the following general structures:

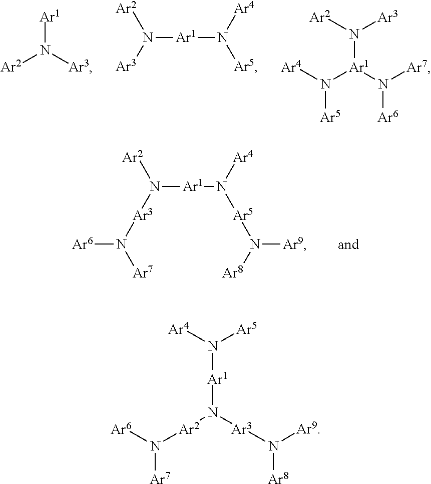

Each of Ar¹ to Ar⁹ is selected from the group consisting of aromatic hydrocarbon cyclic compounds such as benzene, biphenyl, triphenyl, triphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each Ar may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, Ar¹ to Ar⁹ is independently selected from the group consisting of:

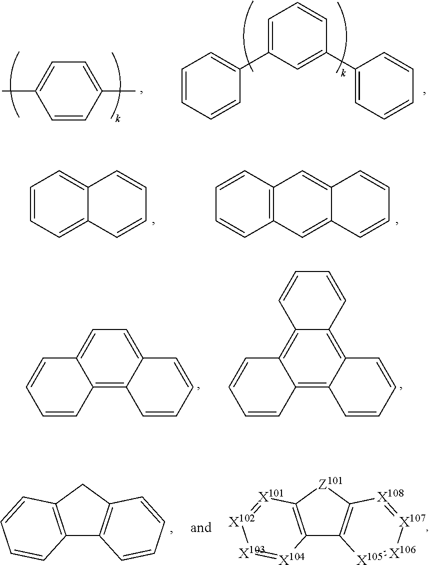

wherein k is an integer from 1 to 20; X¹⁰¹ to X¹⁰⁸ is C (including CH) or N; Z¹⁰¹ is NAr¹, O, or S; Ar¹ has the same group defined above.

Examples of metal complexes used in HIL or HTL include, but are not limited to the following general formula:

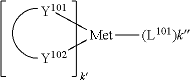

wherein Met is a metal, which can have an atomic weight greater than 40; (Y¹⁰¹-Y¹⁰²) is a bidentate ligand, Y¹⁰¹ and Y¹⁰² are independently selected from C, N, O, P, and S; L¹⁰¹ is an ancillary ligand; k′ is an integer value from 1 to the maximum number of ligands that may be attached to the metal; and k′+k″ is the maximum number of ligands that may be attached to the metal.

In one aspect, (Y¹⁰¹-Y¹⁰²) is a 2-phenylpyridine derivative. In another aspect, (Y¹⁰¹-Y¹⁰²) is a carbene ligand. In another aspect, Met is selected from Ir, Pt, Os, and Zn. In a further aspect, the metal complex has a smallest oxidation potential in solution vs. Fc⁺/Fc couple less than about 0.6 V.

Non-limiting examples of the HIL and HTL materials that may be used in an OLED in combination with materials disclosed herein are exemplified below together with references that disclose those materials: CN102702075, DE102012005215, EP01624500, EP01698613, EP01806334, EP01930964, EP01972613, EP01997799, EP02011790, EP02055700, EP02055701, EP1725079, EP2085382, EP2660300, EP650955, JP07-073529, JP2005112765, JP2007091719, JP2008021687, JP2014-009196, KR20110088898, KR20130077473, TW201139402, U.S. Pat. No. 6,517,957, US20020158242, US20030162053, US20050123751, US20060182993, US20060240279, US20070145888, US20070181874, US20070278938, US20080014464, US20080091025, US20080106190, US20080124572, US20080145707, US20080220265, US20080233434, US20080303417, US2008107919, US20090115320, US20090167161, US2009066235, US2011007385, US20110163302, US2011240968, US2011278551, US2012205642, US2013241401, US20140117329, US2014183517, U.S. Pat. Nos. 5,061,569, 5,639,914, WO05075451, WO07125714, WO08023550, WO08023759, WO2009145016, WO2010061824, WO2011075644, WO2012177006, WO2013018530, WO2013039073, WO2013087142, WO2013118812, WO2013120577, WO2013157367, WO2013175747, WO2014002873, WO2014015935, WO2014015937, WO2014030872, WO2014030921, WO2014034791, WO2014104514, WO2014157018.

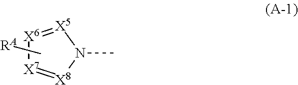

### c) EBL:

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and/or higher triplet energy than one or more of the hosts closest to the EBL interface. In one aspect, the compound used in EBL contains the same molecule or the same functional groups used as one of the hosts described below.

### d) Hosts:

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

Examples of metal complexes used as host are preferred to have the following general formula:

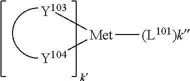

wherein Met is a metal; (Y¹⁰³-Y¹⁰⁴) is a bidentate ligand. Y¹⁰³ and Y¹⁰⁴ are independently selected from C, N, O, P, and S; L¹⁰¹ is an another ligand; k′ is an integer value from 1 to the maximum number of ligands that may be attached to the metal; and k′+k″ is the maximum number of ligands that may be attached to the metal.

In one aspect, the metal complexes are:

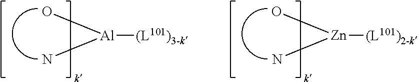

wherein (O—N) is a bidentate ligand, having metal coordinated to atoms O and N.

In another aspect, Met is selected from Ir and Pt. In a further aspect, (Y¹⁰³-Y¹⁰⁴) is a carbene ligand.

In one aspect, the host compound contains at least one of the following groups selected from the group consisting of aromatic hydrocarbon cyclic compounds such as benzene, biphenyl, triphenyl, triphenylene, tetraphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each option within each group may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, the host compound contains at least one of the following groups in the molecule:

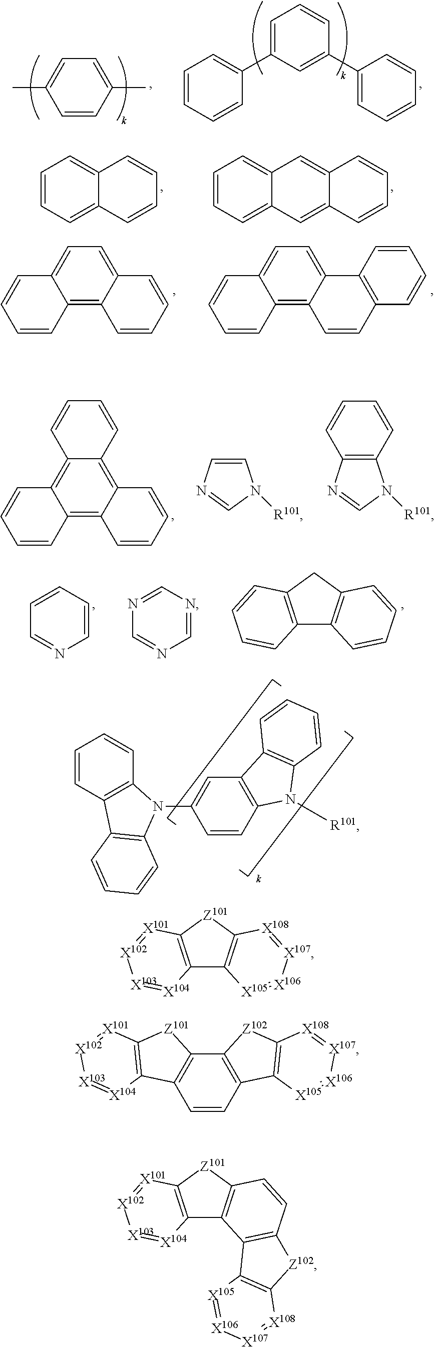

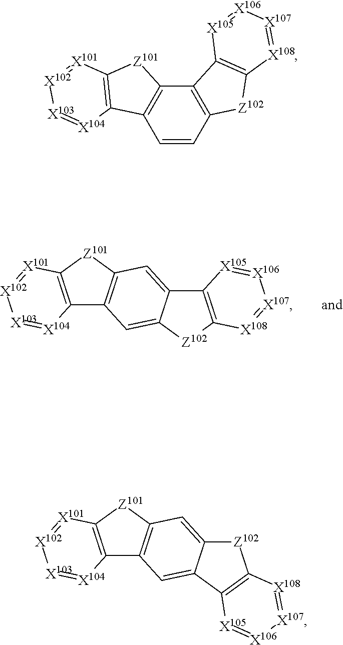

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, and when it is aryl or heteroaryl, it has the similar definition as Ar's mentioned above, k is an integer from 0 to 20 or 1 to 20. X¹⁰¹ to X¹⁰⁸ are independently selected from C (including CH) or N. Z¹⁰¹ and Z¹⁰² are independently selected from NR¹⁰¹, O, or S.

Non-limiting examples of the host materials that may be used in an OLED in combination with materials disclosed herein are exemplified below together with references that disclose those materials: EP2034538, EP2034538A, EP2757608, JP2007254297, KR20100079458, KR20120088644, KR20120129733, KR20130115564, TW201329200, US20030175553, US20050238919, US20060280965, US20090017330, US20090030202, US20090167162, US20090302743, US20090309488, US20100012931, US20100084966, US20100187984, US2010187984, US2012075273, US2012126221, US2013009543, US2013105787, US2013175519, US2014001446, US20140183503, US20140225088, US2014034914, U.S. Pat. No. 7,154,114, WO2001039234, WO2004093207, WO2005014551, WO2005089025, WO2006072002, WO2006114966, WO2007063754, WO2008056746, WO2009003898, WO2009021126, WO2009063833, WO2009066778, WO2009066779, WO2009086028, WO2010056066, WO2010107244, WO2011081423, WO2011081431, WO2011086863, WO2012128298, WO2012133644, WO2012133649, WO2013024872, WO2013035275, WO2013081315, WO2013191404, WO2014142472, US20170263869, US20160163995, U.S. Pat. No. 9,466,803,

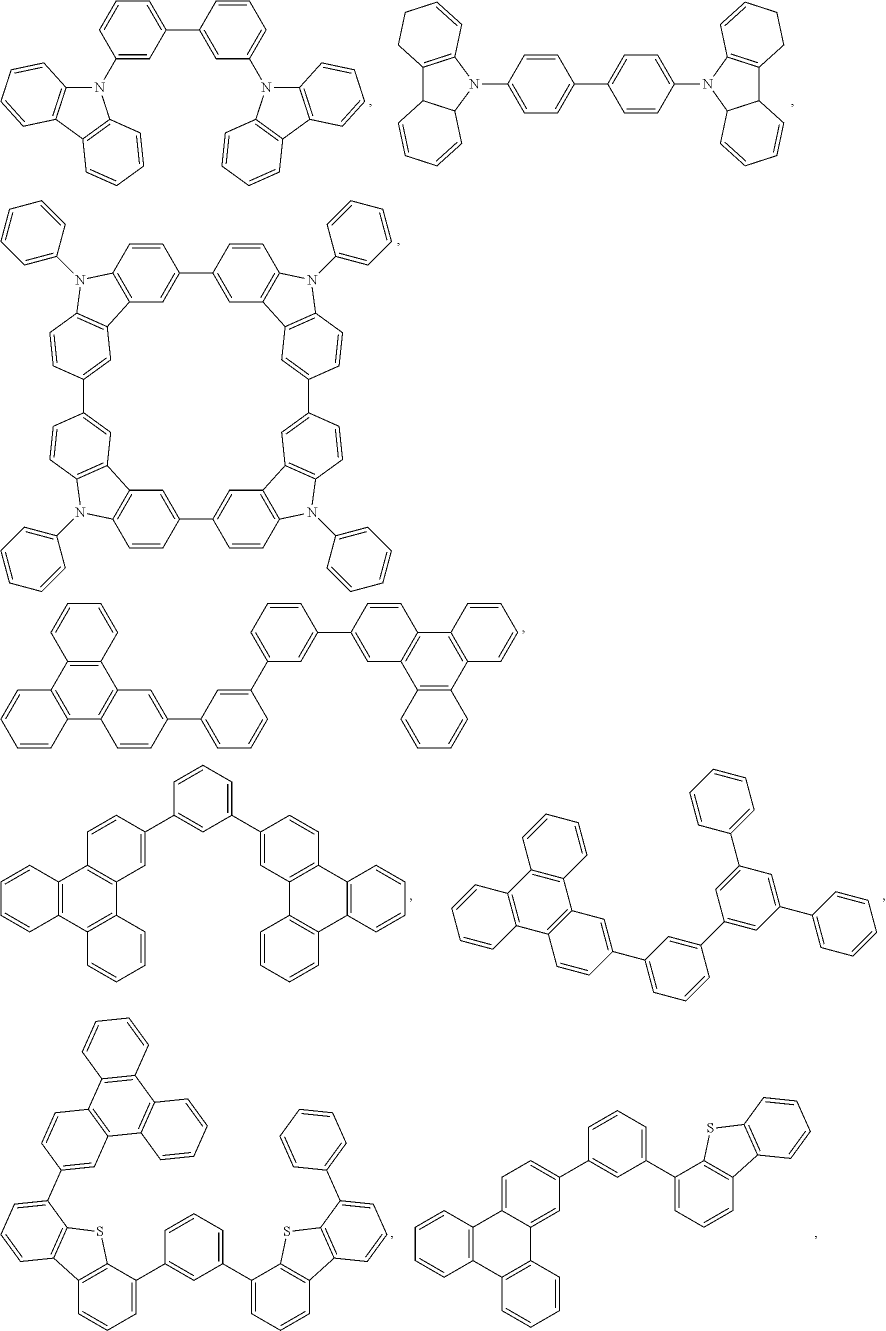

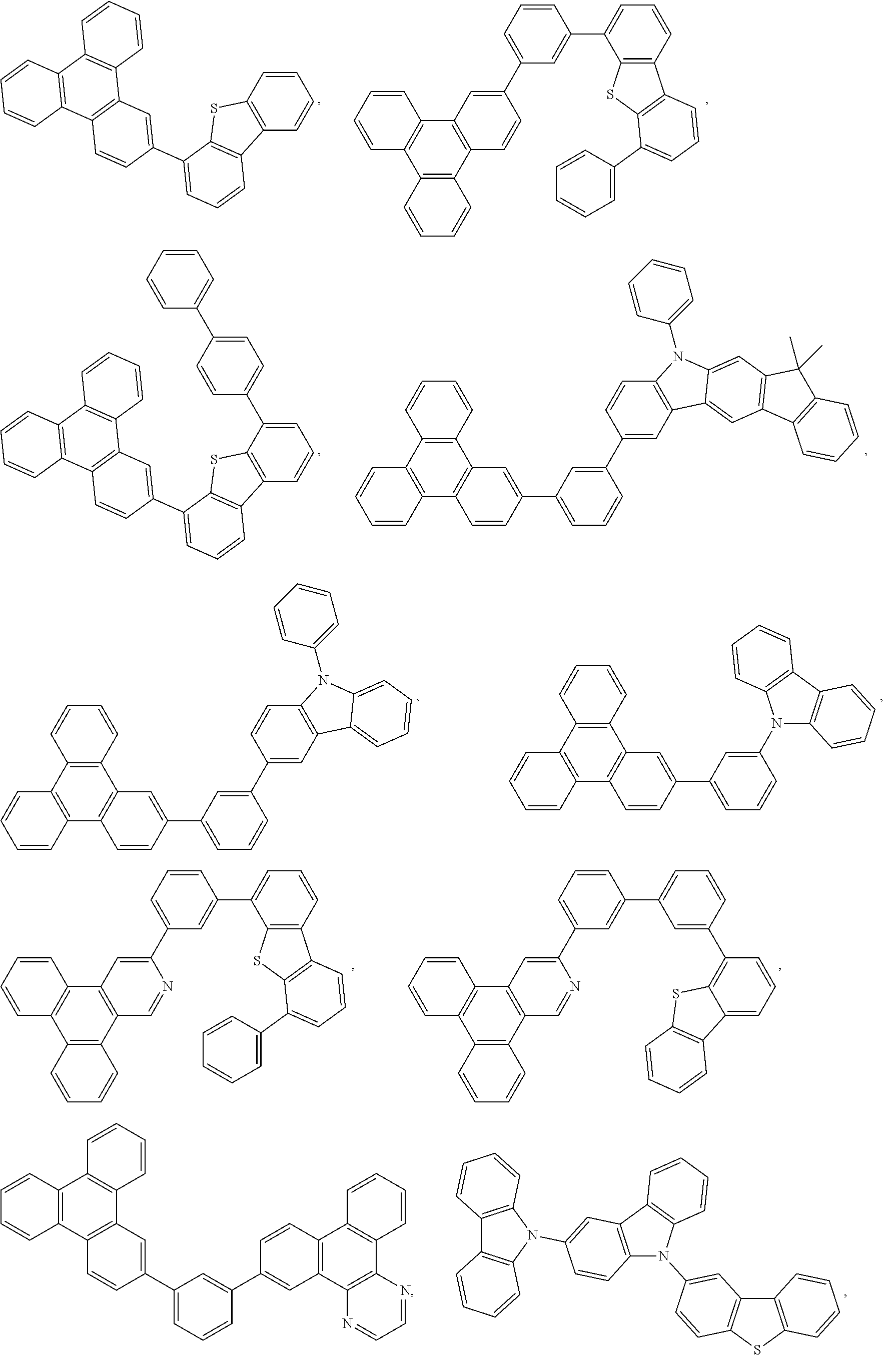

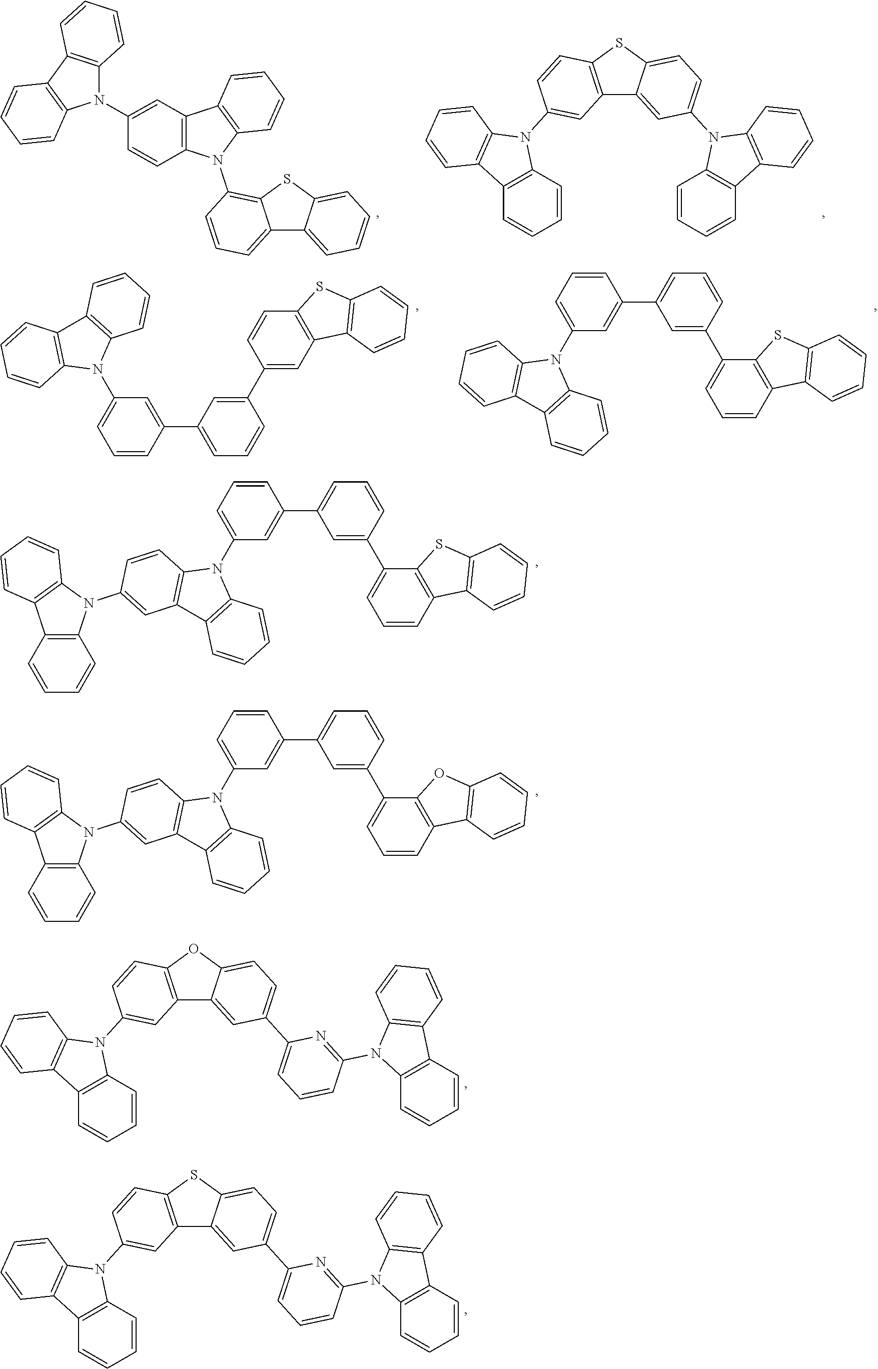

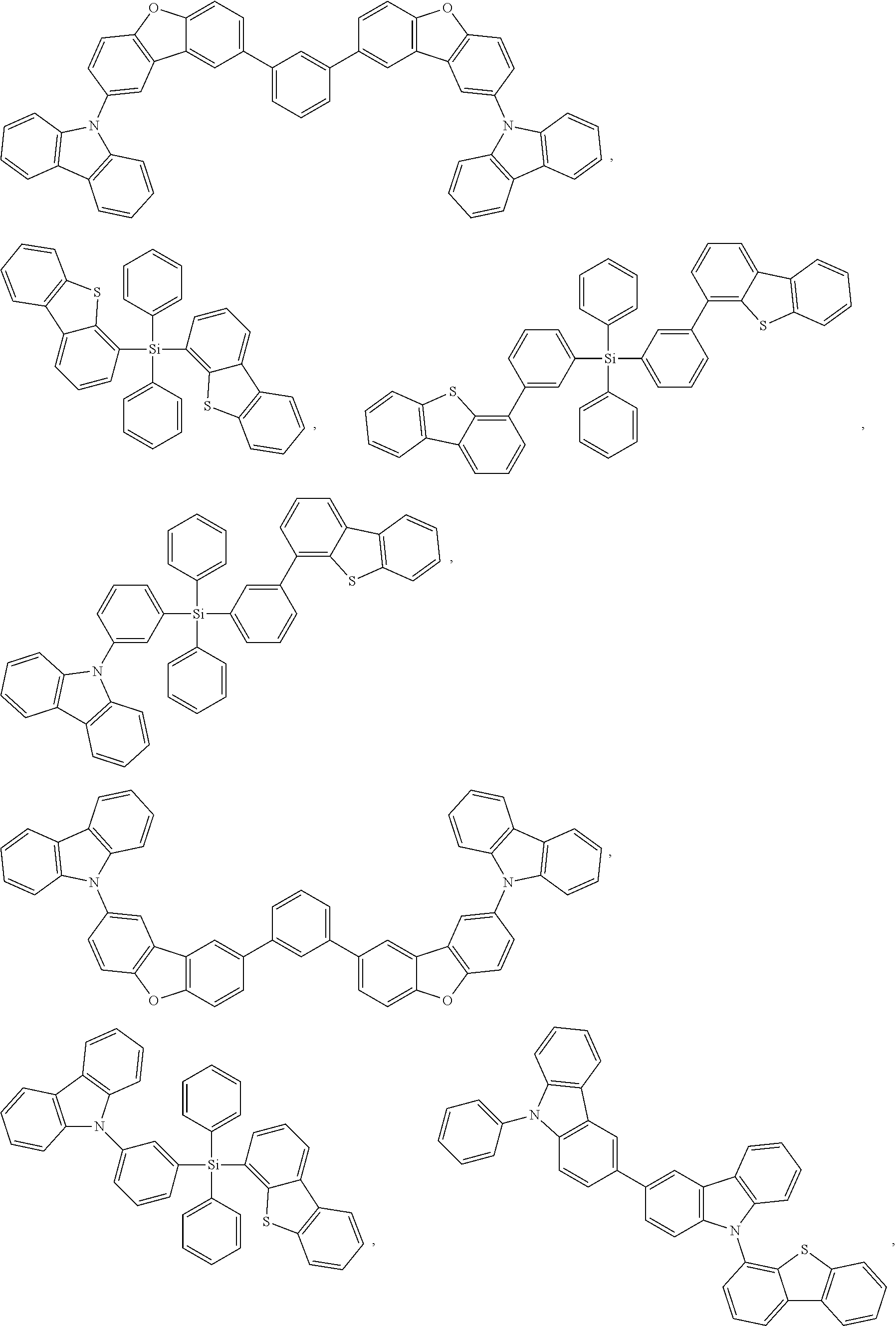

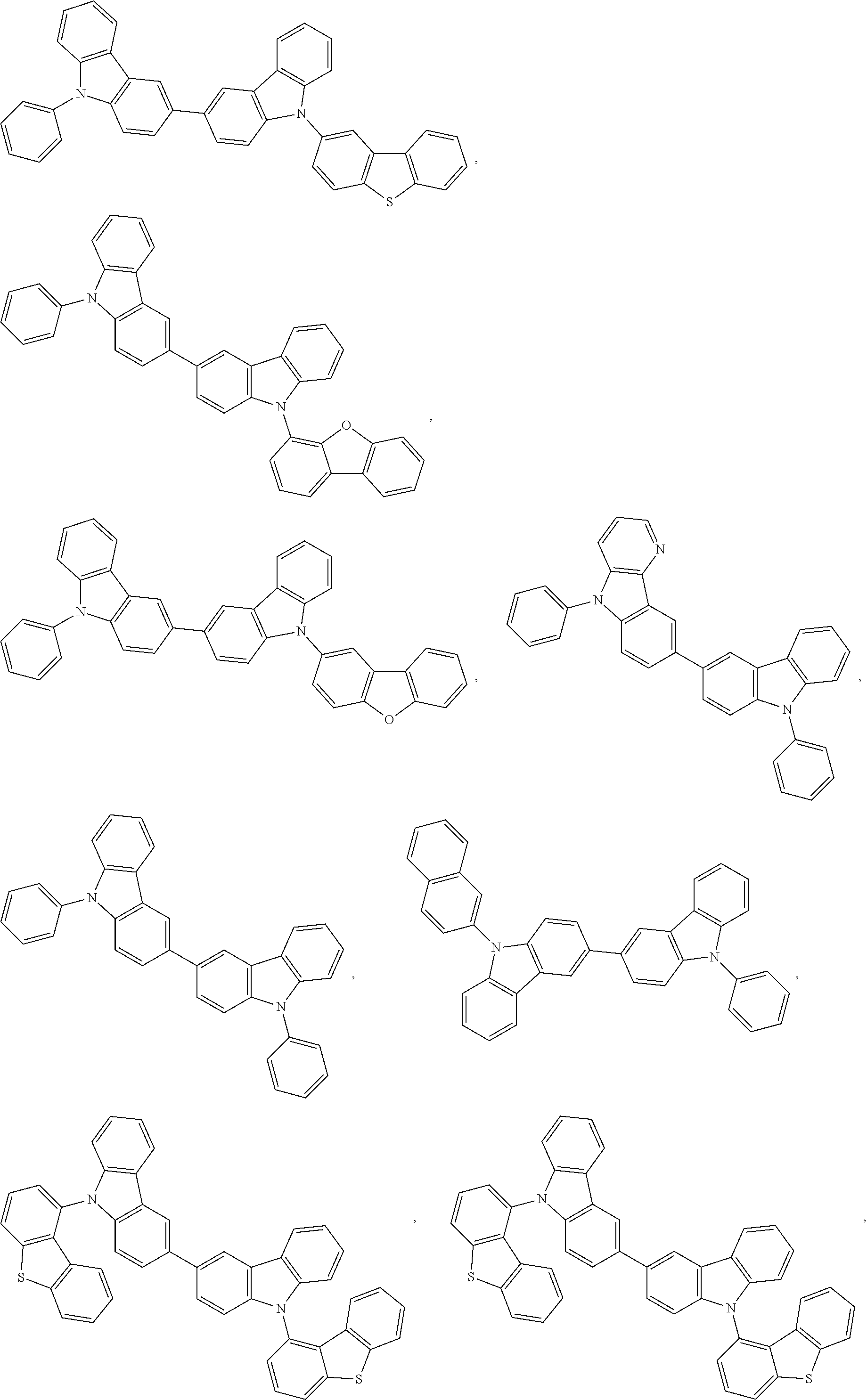

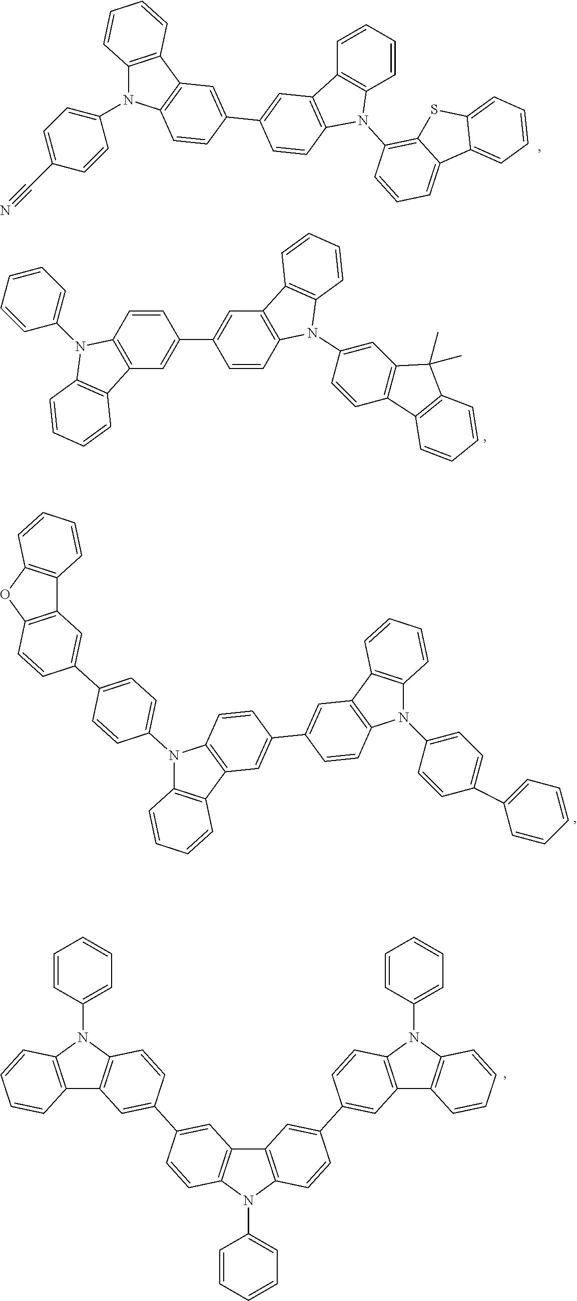 [SMILES: N#Cc1ccc(-n2c3ccccc3c3cc(-c4ccc5c(c4)c4ccccc4n5-c4cccc5c4sc4ccccc45)ccc32)cc1 ; CC1(C)c2ccccc2-c2ccc(-n3c4ccccc4c4cc(-c5ccc6c(c5)c5ccccc5n6-c5ccccc5)ccc43)cc21 ; c1ccc(-c2ccc(-n3c4ccccc4c4cc(-c5ccc6c(c5)c5ccccc5n6-c5ccc(-c6ccc7oc8ccccc8c7c6)cc5)ccc43)cc2)cc1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

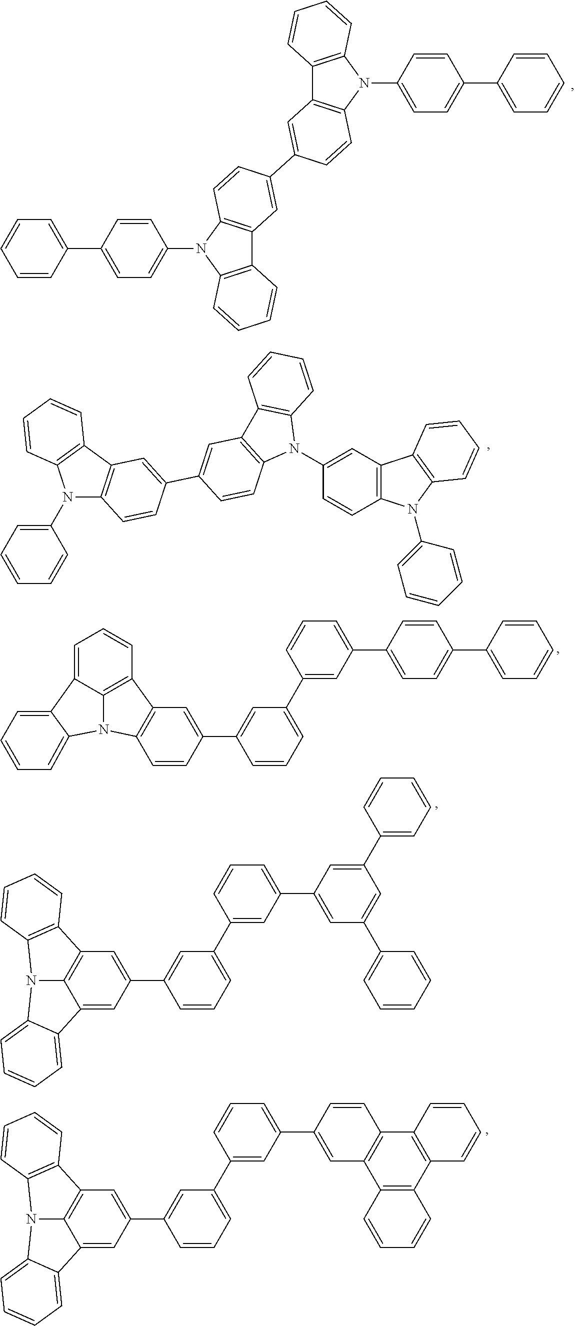

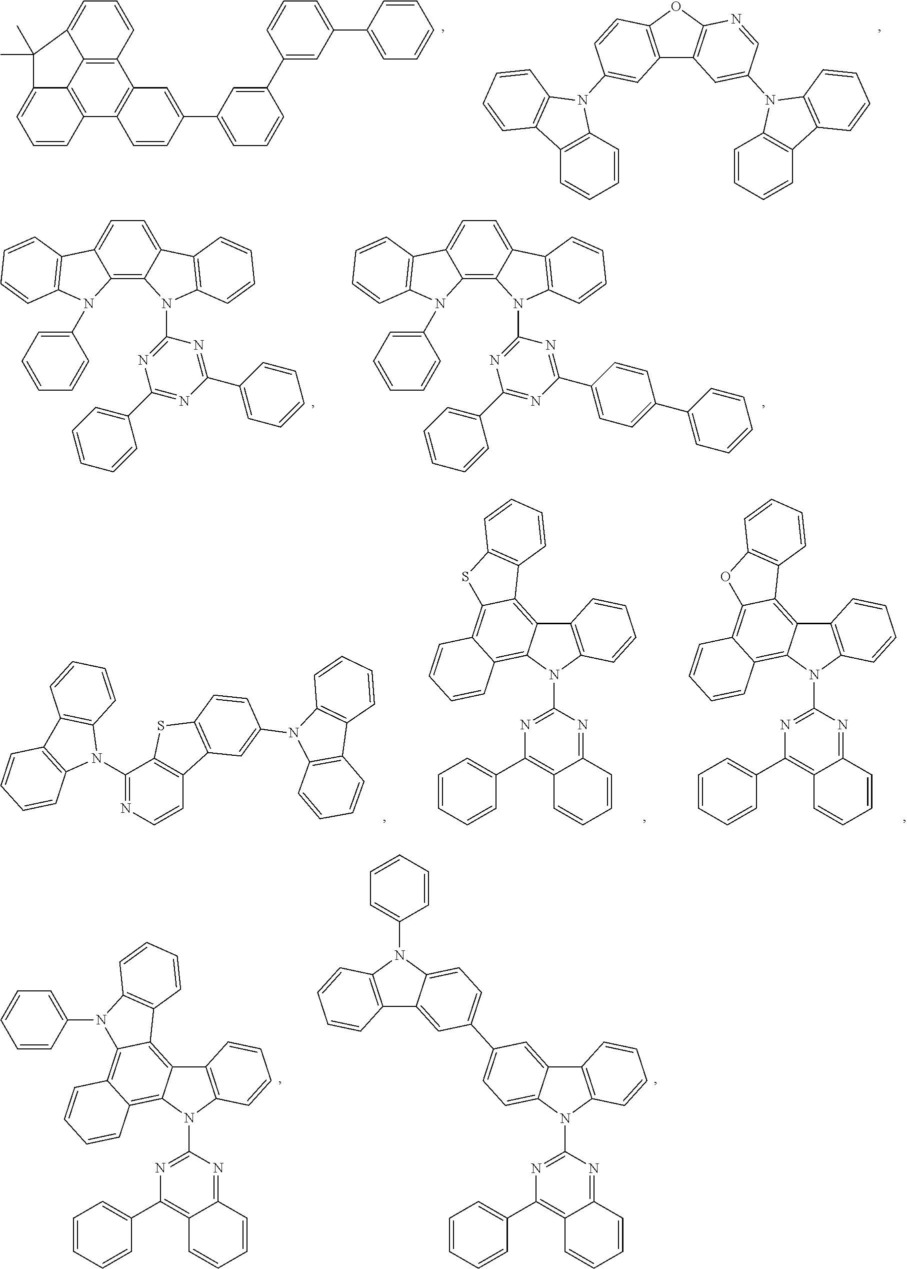

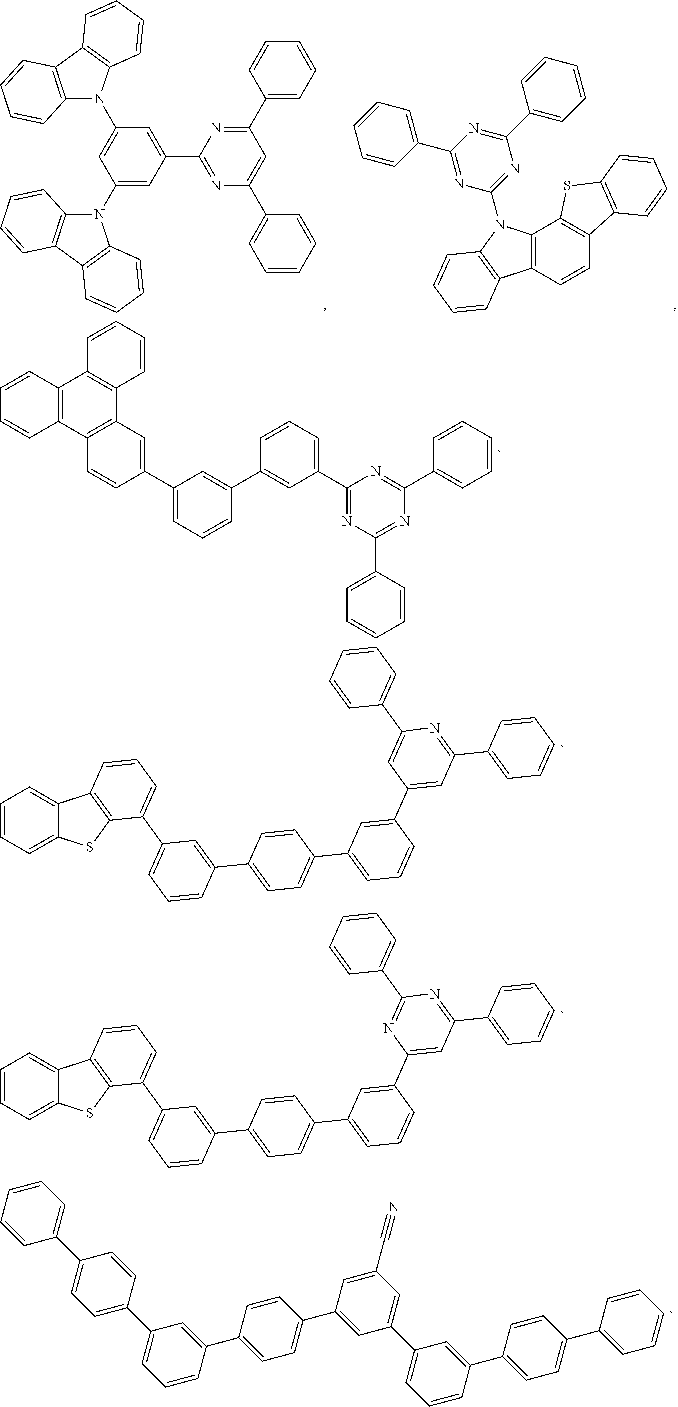

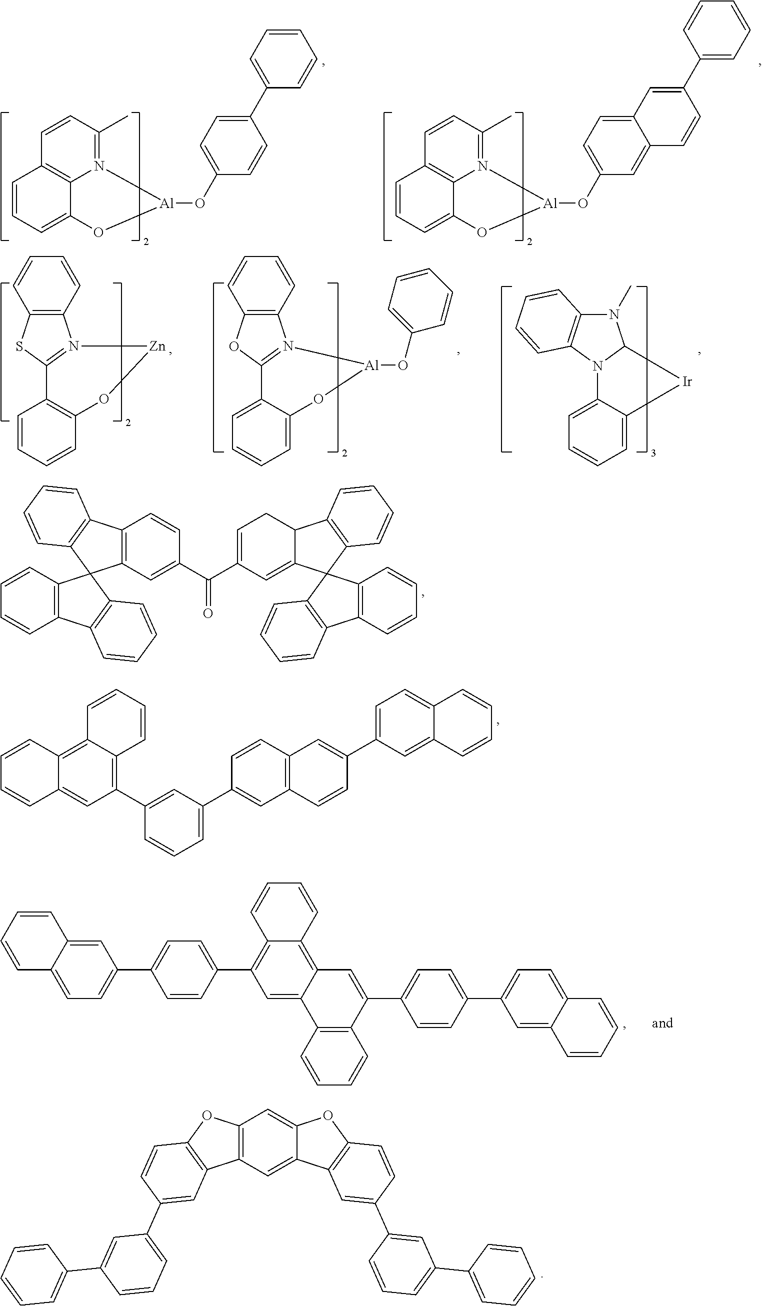

### e) Additional Emitters:

One or more additional emitter dopants may be used in conjunction with the compound of the present disclosure. Examples of the additional emitter dopants are not particularly limited, and any compounds may be used as long as the compounds are typically used as emitter materials. Examples of suitable emitter materials include, but are not limited to, compounds which can produce emissions via phosphorescence, fluorescence, thermally activated delayed fluorescence, i.e., TADF (also referred to as E-type delayed fluorescence), triplet-triplet annihilation, or combinations of these processes.

Non-limiting examples of the emitter materials that may be used in an OLED in combination with materials disclosed herein are exemplified below together with references that disclose those materials: CN103694277, CN1696137, EB01238981, EP01239526, EP01961743, EP1239526, EP1244155, EP1642951, EP1647554, EP1841834, EP1841834B, EP2062907, EP2730583, JP2012074444, JP2013110263, JP4478555, KR1020090133652, KR20120032054, KR20130043460, TW201332980, U.S. Pat. Nos. 6,699,599, 6,916,554. US20010019782, US20020034656, US20030068526, US20030072964, US20030138657, US20050123788, US20050244673, US2005123791, US2005260449, US20060008670, US20060065890, US20060127696, US20060134459, US20060134462, US20060202194, US20060251923, US20070034863, US20070087321, US20070103060, US20070111026, US20070190359, US20070231600, US2007034863, US2007104979, US2007104980, US2007138437, US2007224450, US2007278936, US20080020237, US20080233410, US20080261076, US20080297033, US200805851, US2008161567, US2008210930, US20090039776, US20090108737, US20090115322, US20090179555, US2009085476, US2009104472, US20100090591, US20100148663, US20100244004, US20100295032, US2010102716, US2010105902, US2010244004, US2010270916, US20110057559, US20110108822, US20110204333, US2011215710, US2011227049, US2011285275, US2012292601, US20130146848, US2013033172, US2013165653, US2013181190, US2013334521, US20140246656, US2014103305, U.S. Pat. Nos. 6,303,238, 6,413,656, 6,653,654, 6,670,645, 6,687,266, 6,835,469, 6,921,915, 7,279,704, 7,332,232, 7,378,162, 7,534,505, 7,675,228, 7,728,137, 7,740,957, 7,759,489, 7,951,947, 8,067,099, 8,592,586, 8,871,361, WO06081973, WO06121811, WO07018067, WO07108362, WO07115970, WO07115981, WO08035571, WO2002015645, WO2003040257, WO2005019373, WO2006056418, WO2008054584, WO2008078800, WO2008096609, WO2008101842, WO2009000673, WO2009050281, WO2009100991, WO2010028151, WO2010054731, WO2010086089, WO2010118029, WO2011044988, WO2011051404, WO2011107491, WO2012020327, WO2012163471, WO2013094620, WO2013107487, WO2013174471, WO2014007565, WO2014008982, WO2014023377, WO2014024131, WO2014031977, WO2014038456, WO2014112450.

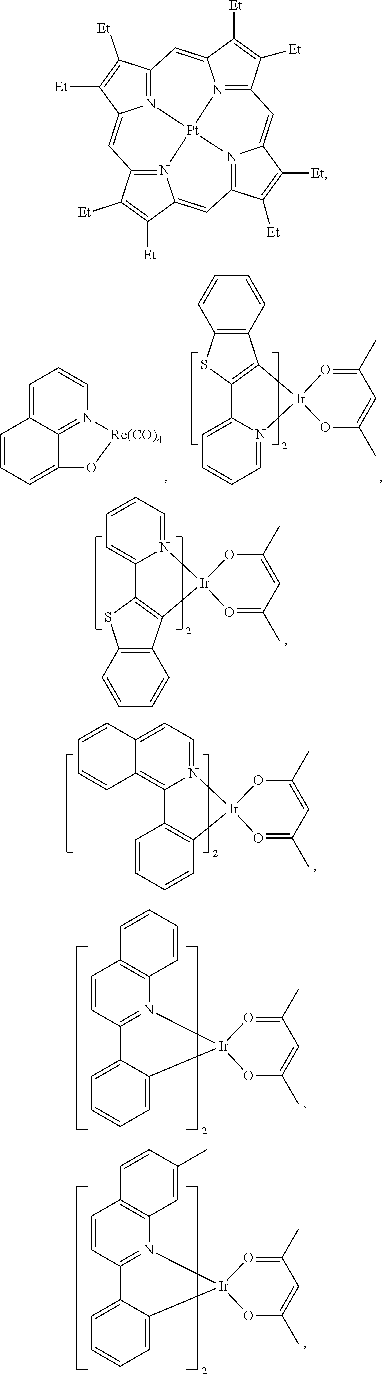

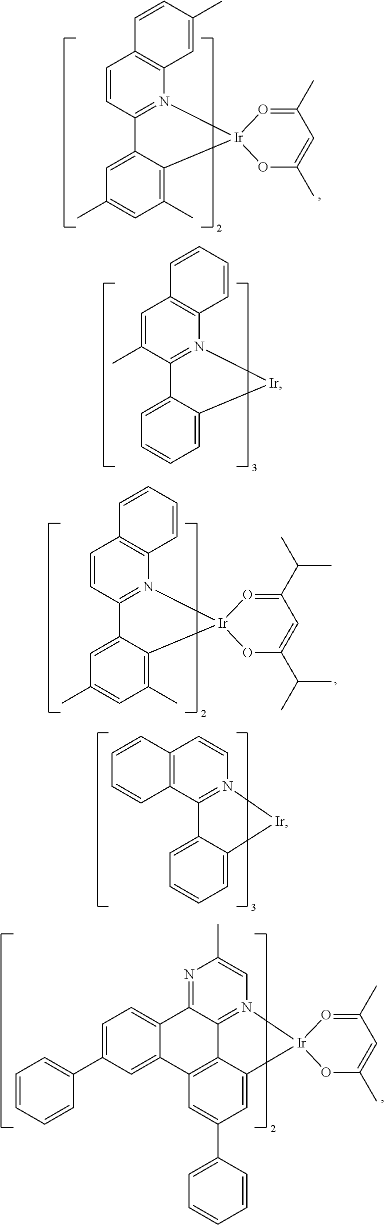

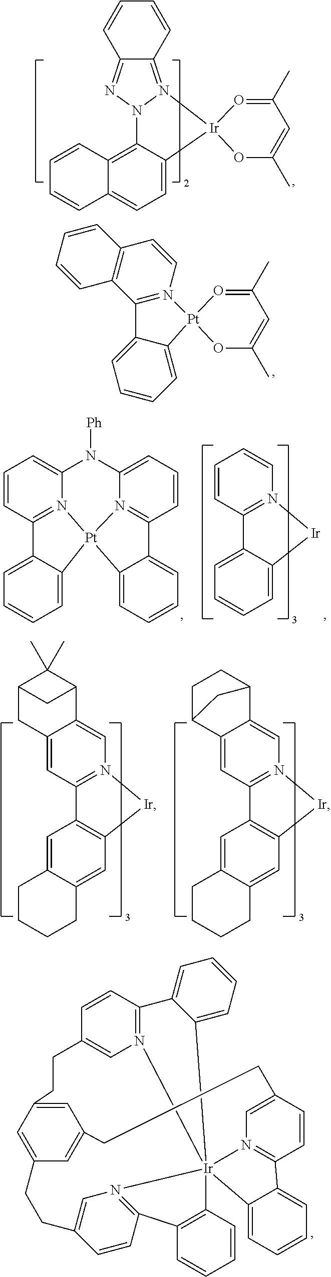

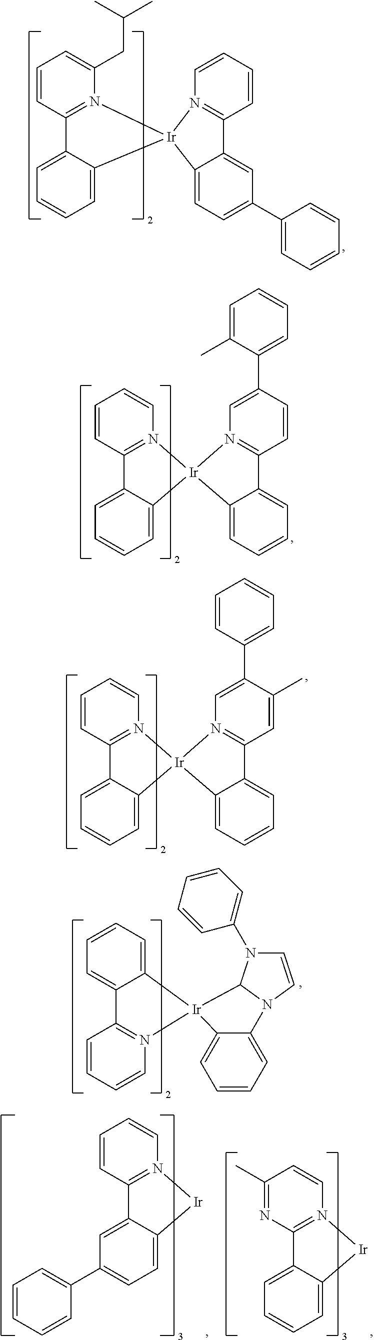

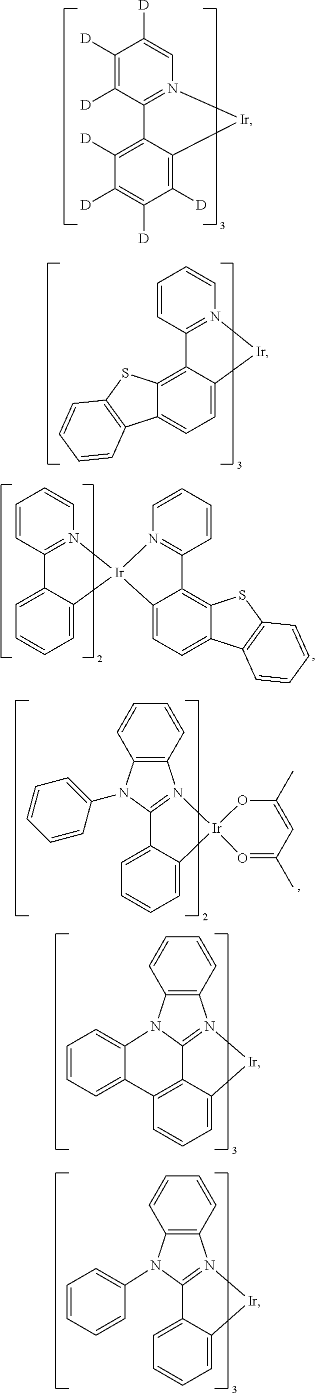

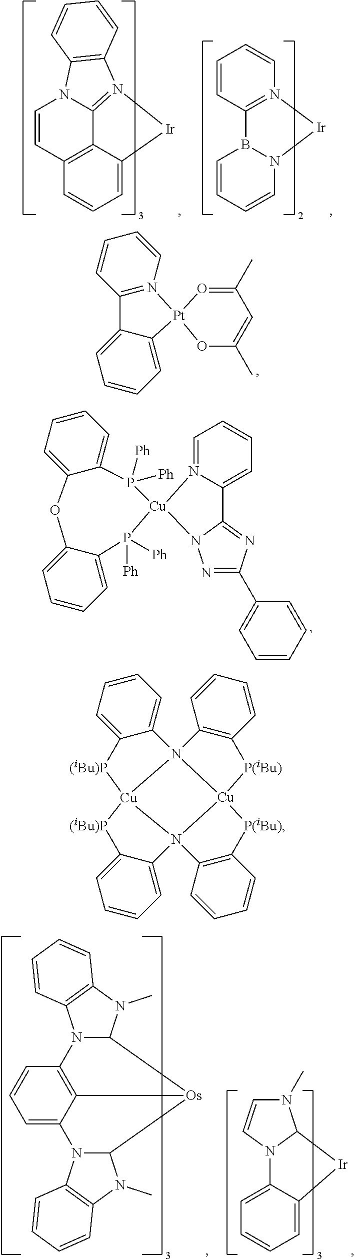

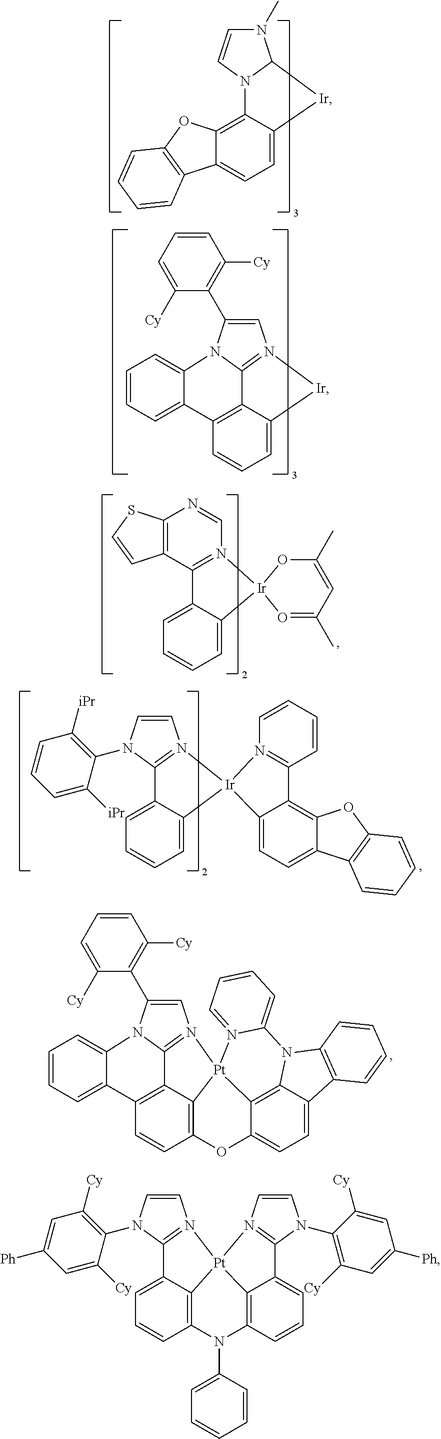

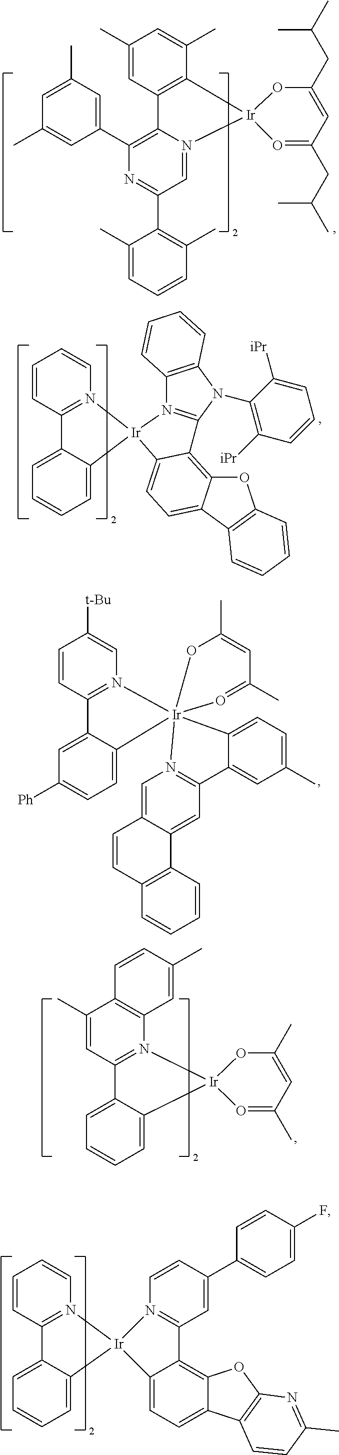

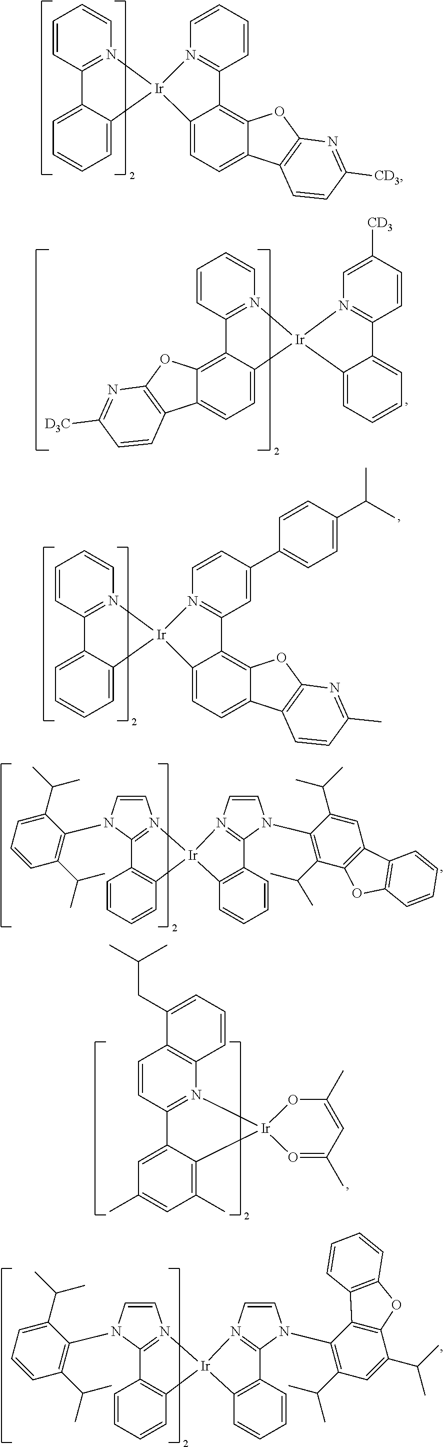

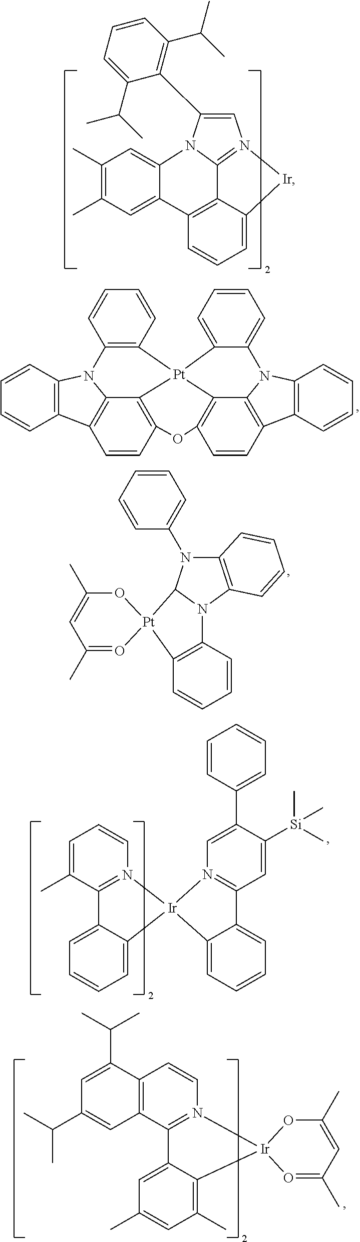

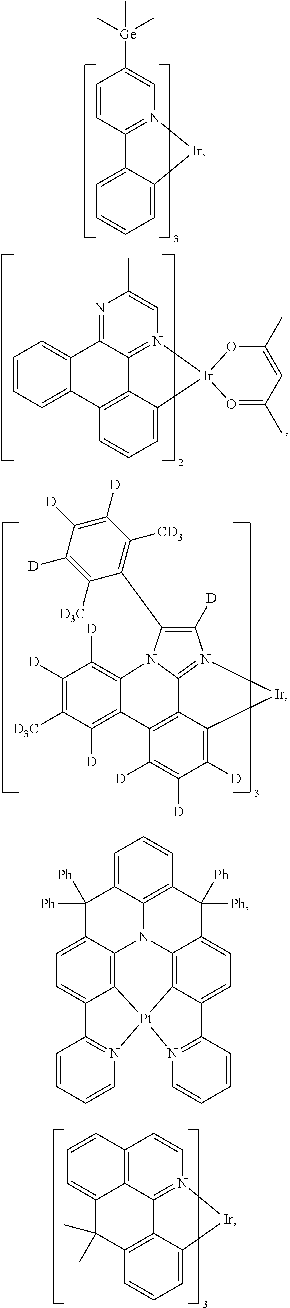

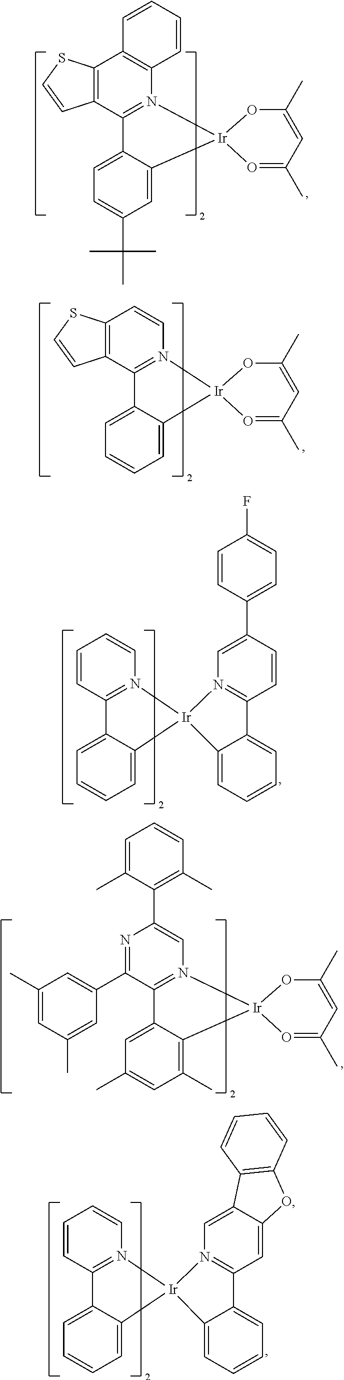

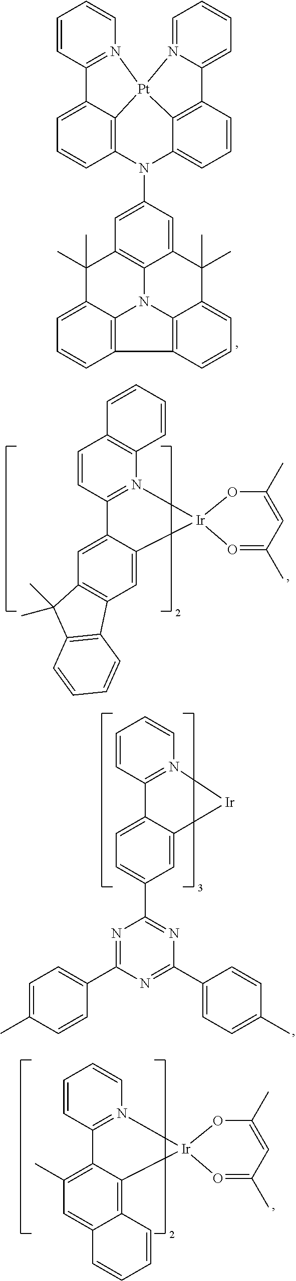

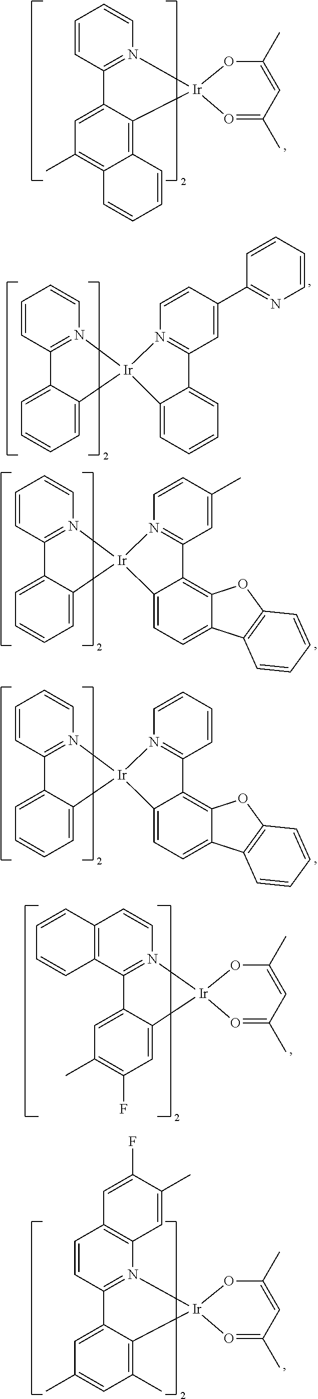

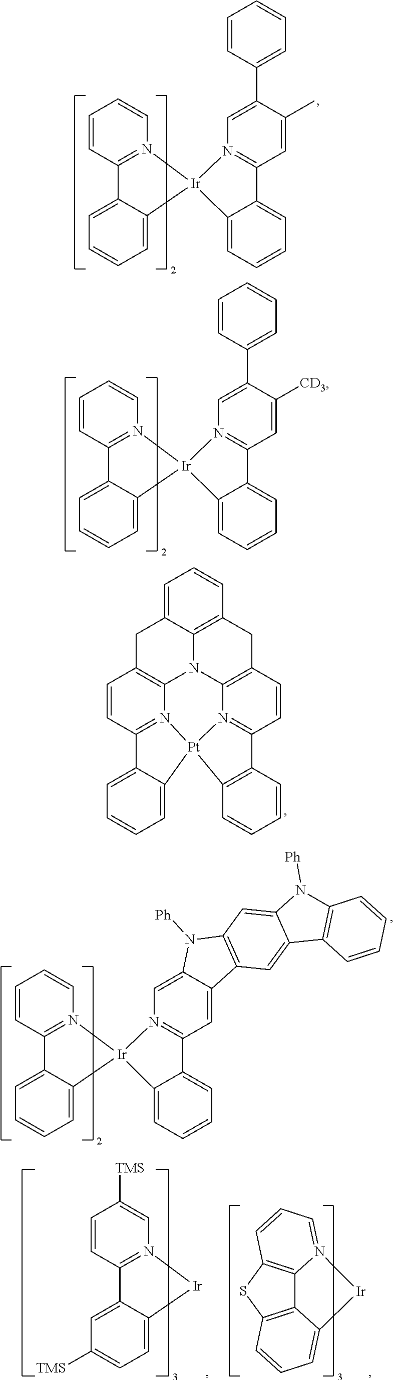

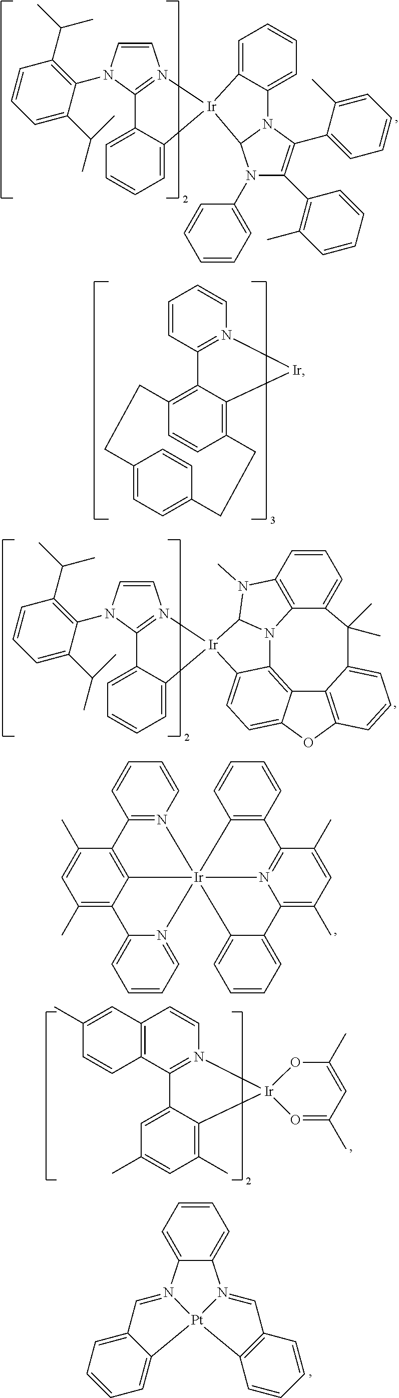

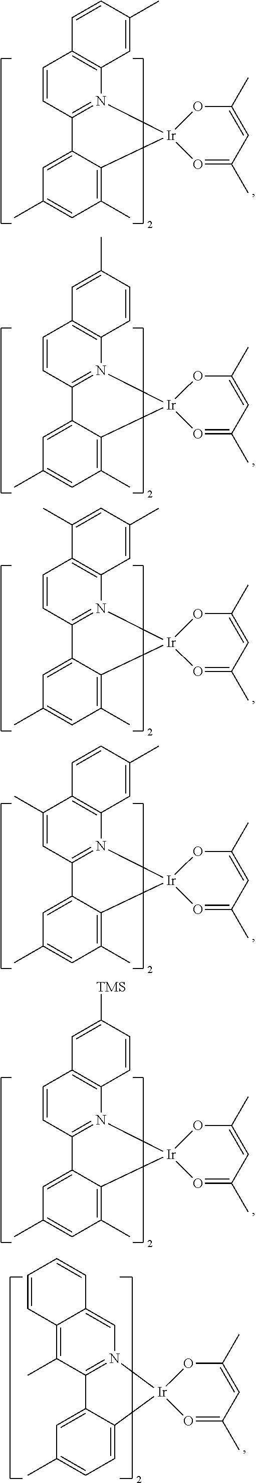

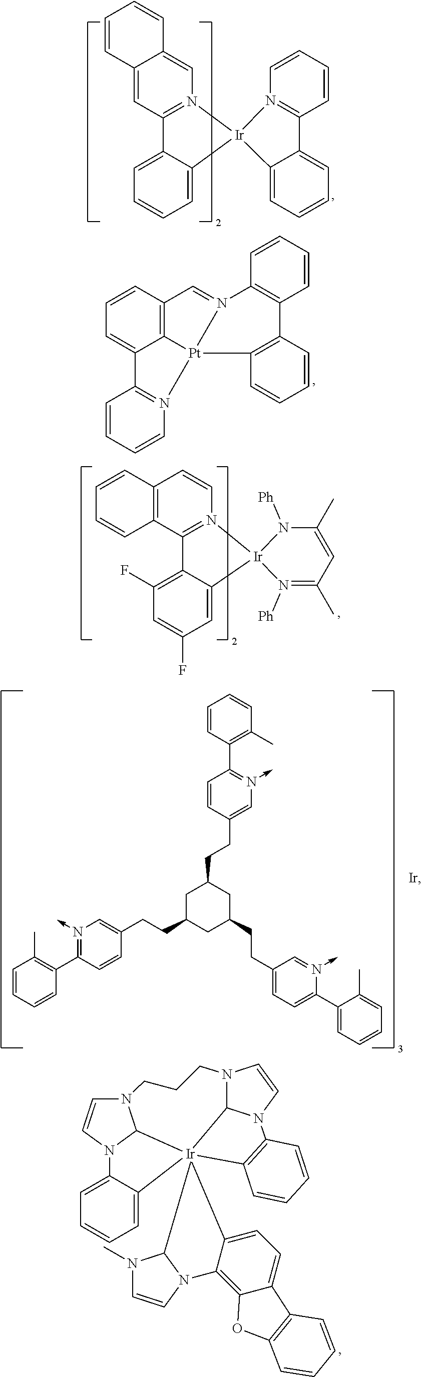

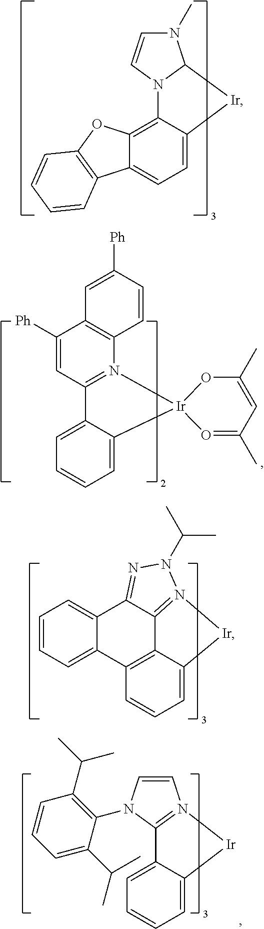

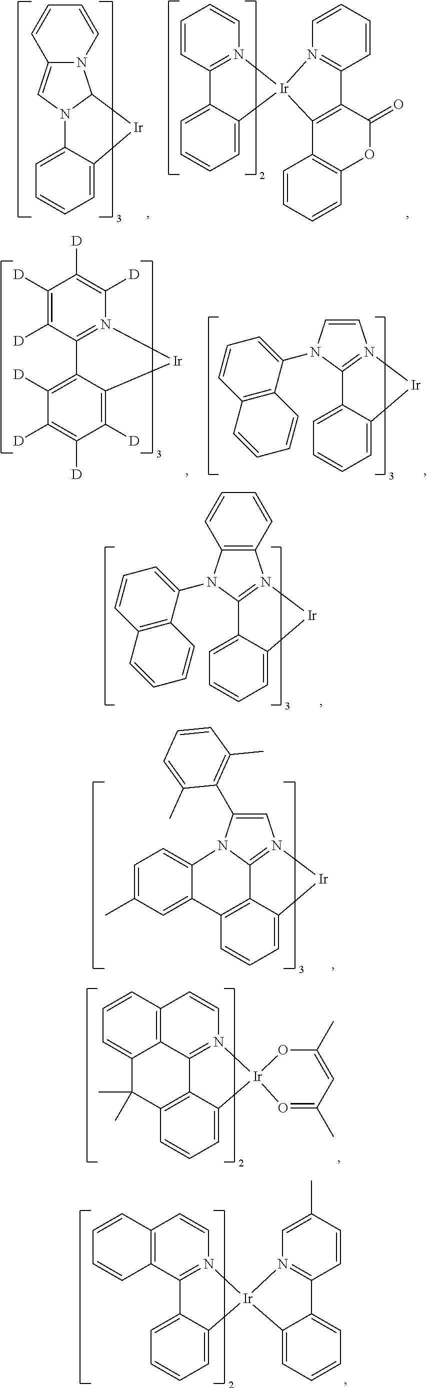

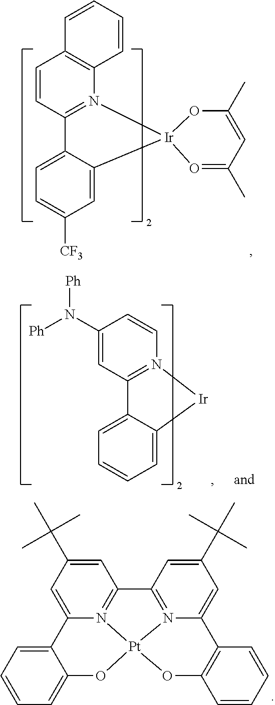

### f) HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and/or higher triplet energy than the emitter closest to the HBL interface. In some embodiments, the HBL material has a lower HOMO (further from the vacuum level) and/or higher triplet energy than one or more of the hosts closest to the HBL interface.

In one aspect, compound used in HBL contains the same molecule or the same functional groups used as host described above.

In another aspect, compound used in HBL contains at least one of the following groups in the molecule:

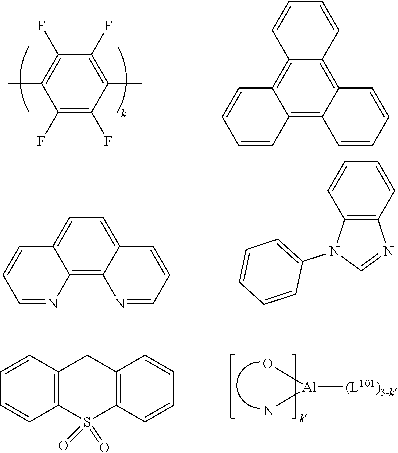

wherein k is an integer from 1 to 20; L¹⁰¹ is another ligand, k′ is an integer from 1 to 3.

### g) ETL:

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In one aspect, compound used in ETL contains at least one of the following groups in the molecule:

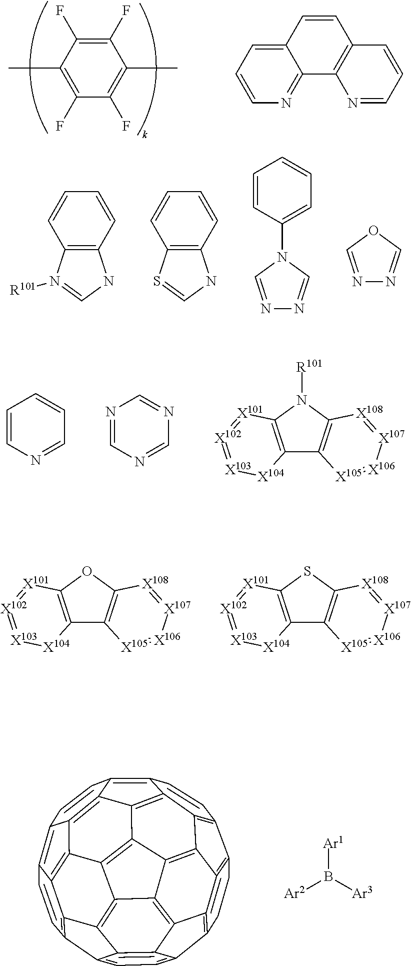

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, when it is aryl or heteroaryl, it has the similar definition as Ar's mentioned above. Ar¹ to Ar³ has the similar definition as Ar's mentioned above, k is an integer from 1 to 20. X¹⁰¹ to X¹⁰⁸ is selected from C (including CH) or N.

In another aspect, the metal complexes used in ETL contains, but not limit to the following general formula:

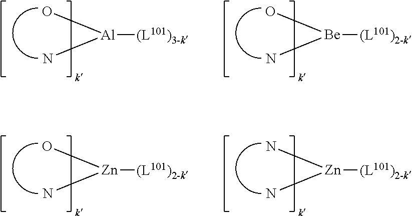

wherein (O—N) or (N—N) is a bidentate ligand, having metal coordinated to atoms O, N or N, N; L¹⁰¹ is another ligand; k′ is an integer value from 1 to the maximum number of ligands that may be attached to the metal.

Non-limiting examples of the ETL materials that may be used in an OLED in combination with materials disclosed herein are exemplified below together with references that disclose those materials: CN103508940, EP01602648, EP01734038, EP01956007, JP2004-022334, JP2005149918, JP2005-268199, KR0117693, KR20130108183, US20040036077, US20070104977, US2007018155, US20090101870, US20090115316, US20090140637, US20090179554, US2009218940, US2010108990, US2011156017, US2011210320, US2012193612, US2012214993, US2014014925, US2014014927, US20140284580, U.S. Pat. Nos. 6,656,612, 8,415,031, WO2003060956, WO2007111263, WO2009148269, WO2010067894, WO2010072300, WO2011074770, WO2011105373, WO2013079217, WO2013145667, WO2013180376, WO2014104499, WO2014104535.

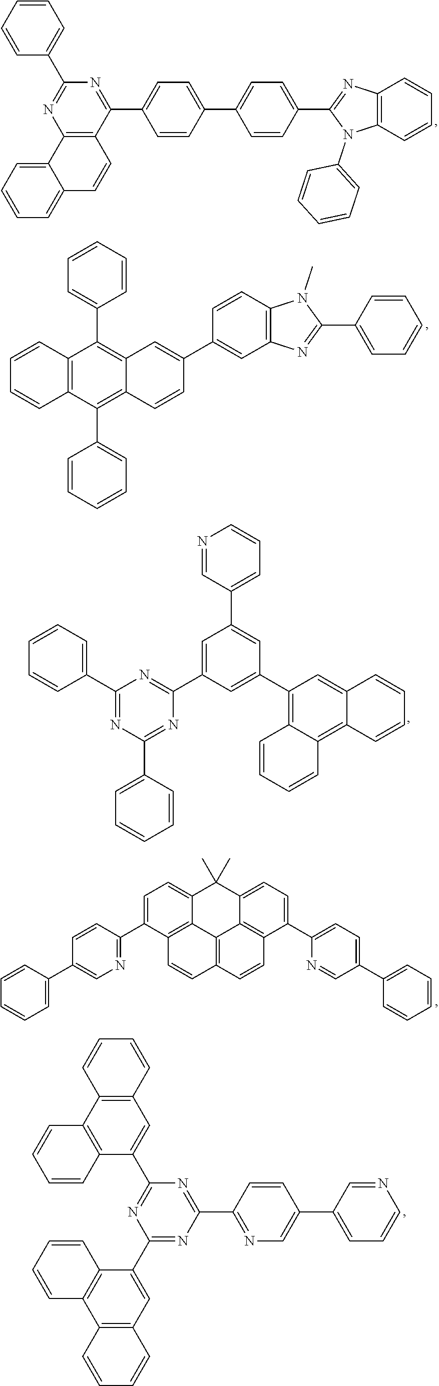

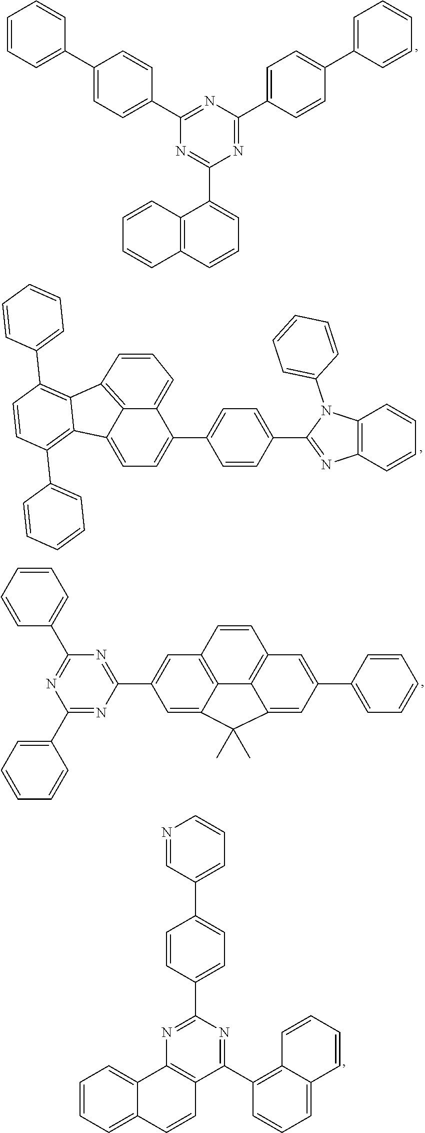

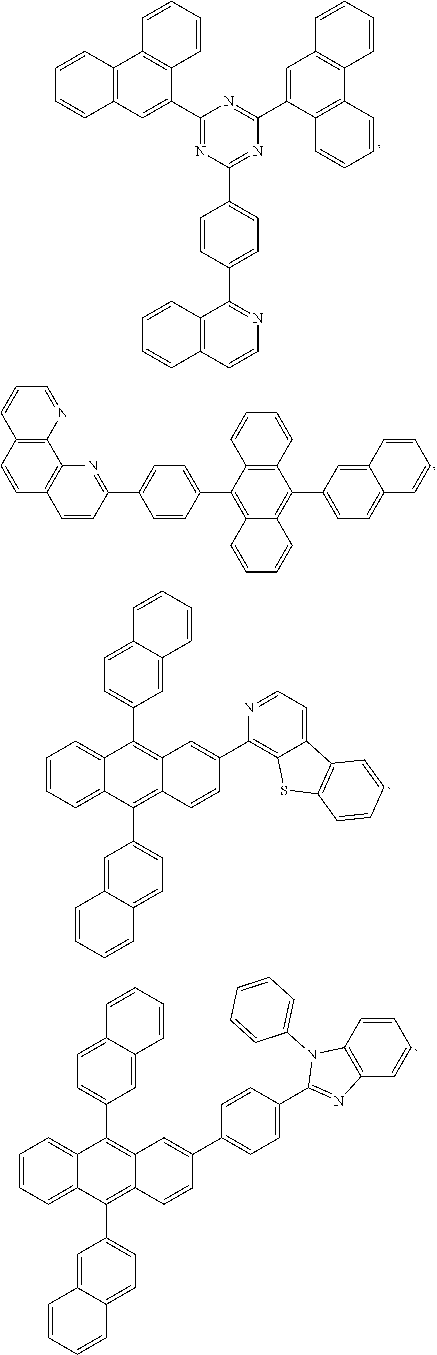

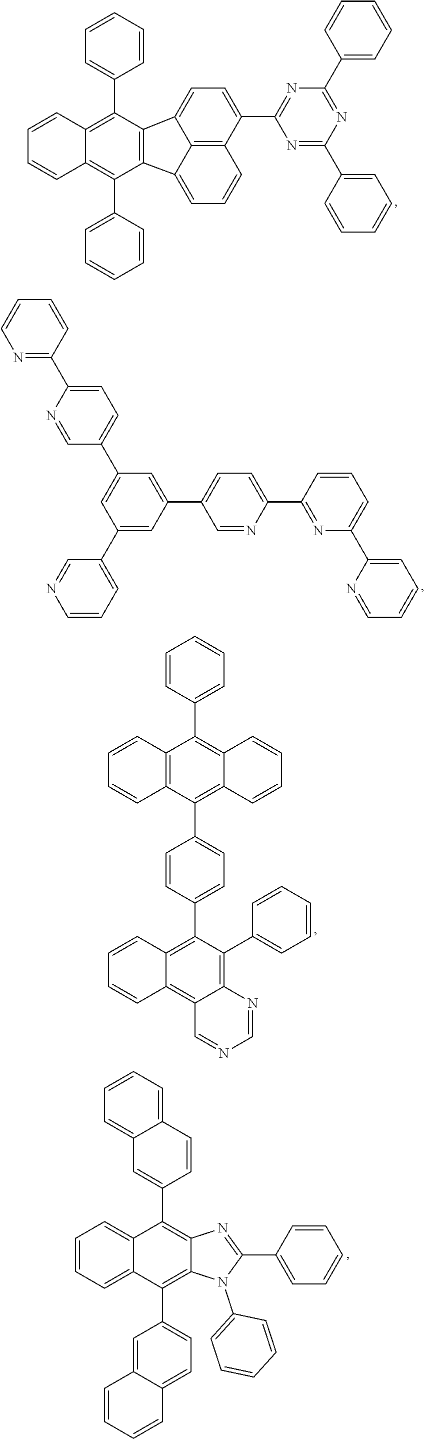 [SMILES: c1ccc(-c2nc(-c3ccccc3)nc(-c3ccc4c5c(cccc35)-c3c-4c(-c4ccccc4)c4ccccc4c3-c3ccccc3)n2)cc1 ; c1ccc(-c2ccc(-c3cc(-c4cccnc4)cc(-c4ccc(-c5cccc(-c6ccccn6)n5)nc4)c3)cn2)nc1 ; c1ccc(-c2c3ccccc3c(-c3ccc(-c4c(-c5ccccc5)c5ncncc5c5ccccc45)cc3)c3ccccc23)cc1 ; c1ccc(-c2nc3c(-c4ccc5ccccc5c4)c4ccccc4c(-c4ccc5ccccc5c4)c3n2-c2ccccc2)cc1]

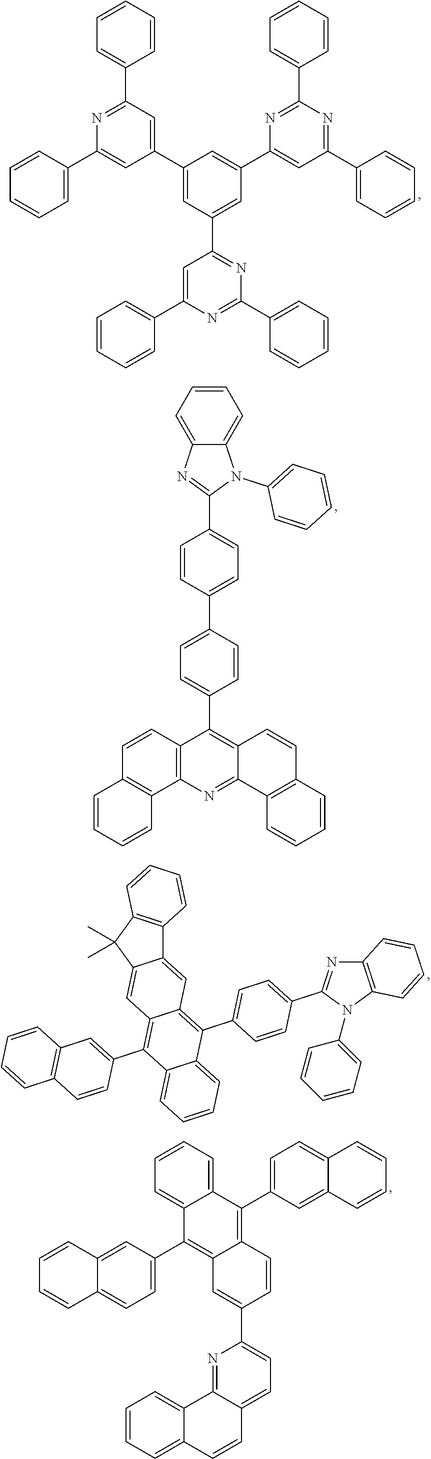

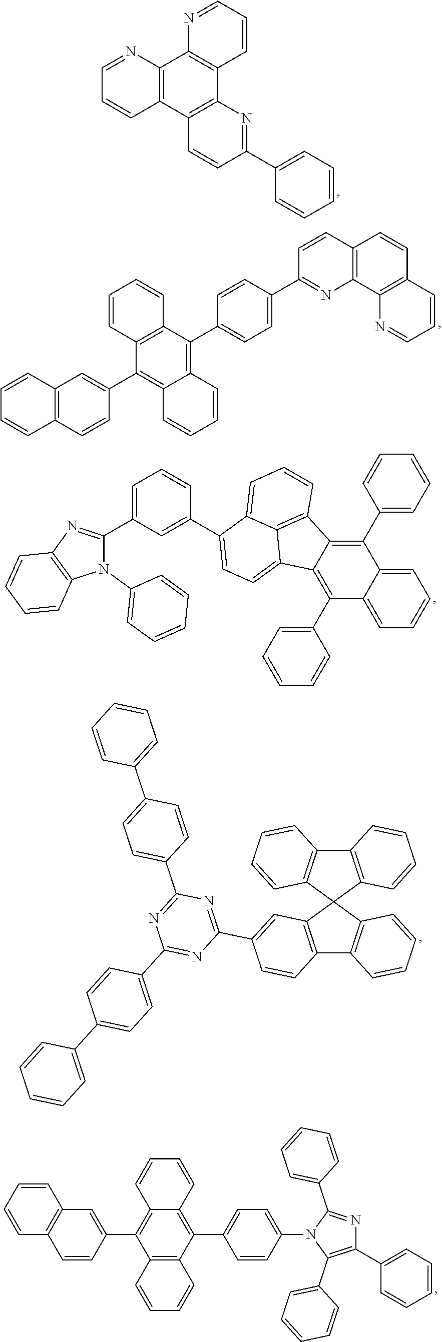

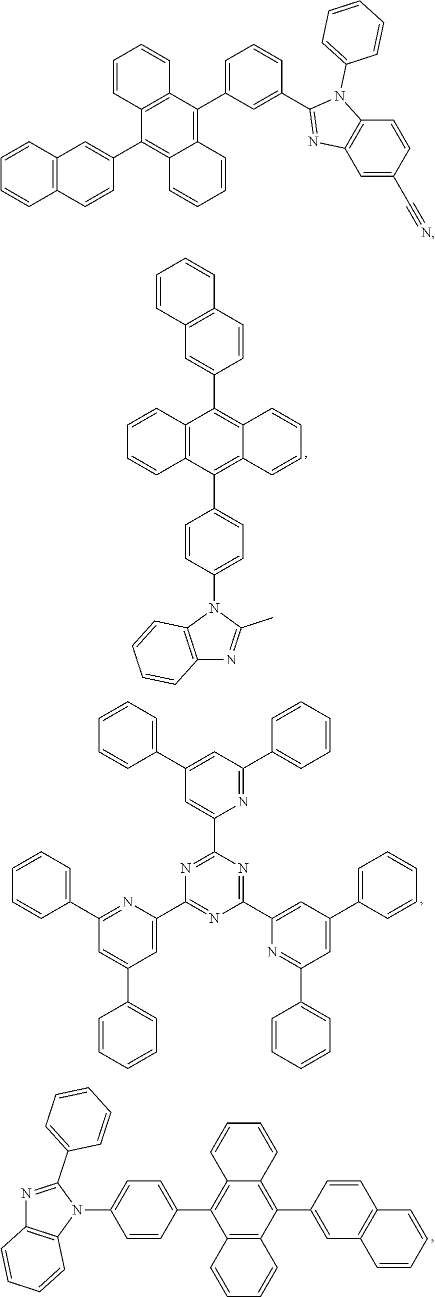

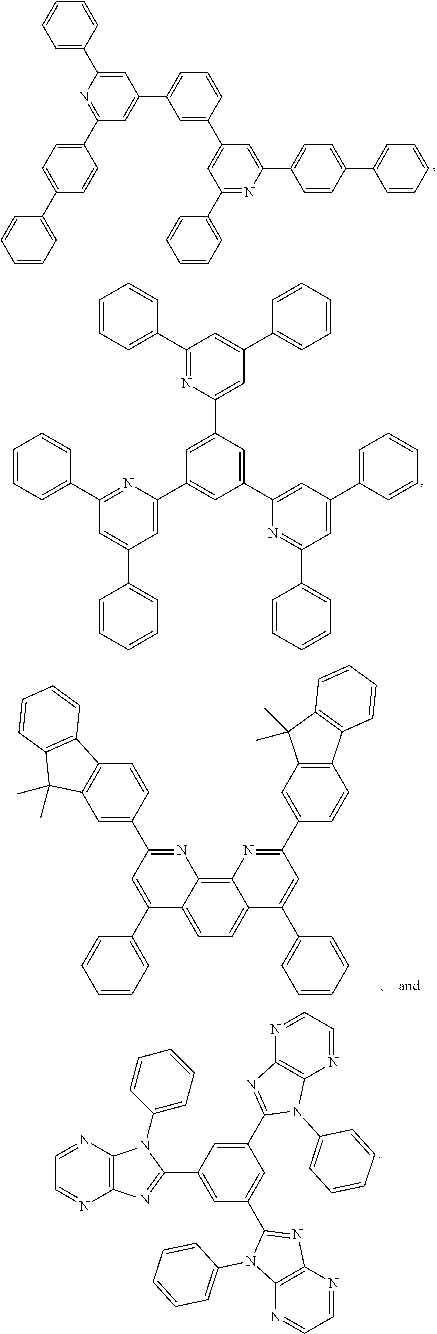

### h) Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

In any above-mentioned compounds used in each layer of the OLED device, the hydrogen atoms can be partially or fully deuterated. The minimum amount of hydrogen of the compound being deuterated is selected from the group consisting of 30%, 40%, 50%, 60%, 70%, 80%, 90%, 95%, 99%, and 100%. Thus, any specifically listed substituent, such as, without limitation, methyl, phenyl, pyridyl, etc. may be undeuterated, partially deuterated, and fully deuterated versions thereof. Similarly, classes of substituents such as, without limitation, alkyl, aryl, cycloalkyl, heteroaryl, etc. also may be undeuterated, partially deuterated, and fully deuterated versions thereof.

It is understood that the various embodiments described herein are by way of example only and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

### EXPERIMENTAL EXAMPLES

Two-coordinate carbene-M^{I}-amide (cMa, M^{I}=Cu, Ag, Au) complexes have emerged as highly efficient luminescent materials for use in a variety of photonic applications, due to their extremely fast radiative rates via thermally activated delayed fluorescence (TADF) from an interligand charge transfer (ICT) process. A series of cMa derivatives were prepared to examine the variables which affect the radiative rate with the goal of understanding the parameters that control the radiative TADF process in these materials. Blue emissive complexes with high photoluminescence efficiency (F_{PL}>0.95) and fast radiative rates (kᵣ=4×10⁶ s⁻¹) can be achieved by selectively extending the p-system of the carbene and amide ligands. Of note is the role played by increasing the separation between the hole and electron in the ICT excited state. Analysis of temperature dependent luminescence data along with theoretical calculations indicate that the hole-electron separation alters the energy gap between the lowest energy singlet and triplet states (DE_{ST}) while keeping the radiative rate for the singlet state unchanged. This interpretation provides guidelines for the design of new cMa derivatives with even faster radiative rates as well as those with slower radiative rates and thus extended excited state lifetimes.

The luminescent properties of coinage metal complexes (M^{(I)}=Cu, Ag and Au) were reported over fifty years ago (Ziolo et al., Journal of the Chemical Society D: Chemical Communications 1970, (17), 1124-1125), with the first report of emission from a two-coordinate d¹⁰ coinage metal complex in 1987 (Sorrell, et al., Inorganic Chemistry 1987, 26 (12), 1957-1964). Several papers have highlighted emission in the solid state and in solution for M^{(I)}L₂⁺ and LM^{(I)}X complexes (L=phosphine, carbene, X=halide, acetylide, aryl, amide) (Mercs, et al., Chemical Society Reviews 2010, 39 (6), 1903-1912; Visbal, et al., Chemical Society Reviews 2014·43 (10), 3551-3574; Wang, et al., Organometallics 1999, 18 (7), 1216-1223; King, et al., Inorganic Chemistry 1992, 31 (15), 3236-3238; Hong, et al., Journal of the Chemical Society. Dalton Transactions 1994, (13), 1867-1871; Wang, et al., Organometallics 2005, 24 (4), 486-493; Gimeno, et al., Organometallics 2012, 31 (20), 7146-7157; Gomez-Suarez, et al., Beilstein Journal of Organic Chemistry 2013, 9, 2216-23; Romanov, et al., Chemical Communications 2016, 52 (38), 6379-6382; Hamze, et al., Chemical Communications 2017, 53, 9008-9011; Shi, et al., Dalton Transactions 2017, 46 (3), 745-752; Romanov, et al., Chemistry—A European Journal 2017, 23 (19), 4625-4637; Yersin, et al., Chemphyschem 2017, 18 (24), 3508-3535; Gernert, et al., Journal of the American Chemical Society 2020, 142 (19), 8897-8909; Li, et al., Journal of the American Chemical Society 2020, 142 (13), 6158-6172). Of particular interest here is the promise of (carbene)M^{(I)}(amide)(cMa) complexes as efficient luminescent materials (Di, et al., Science 2017, 356 (6334), 159; Conaghan, et al., Advanced Materials 2018, 30 (35), 1802285; Romanov, et al., Advanced Optical Materials 2018, 6 (24), 1801347; Hamze, et al., Science 2019, 363 (6427), 601-606; Hamze, et al., Journal of the American Chemical Society 2019, 141 (21), 8616-8626; Shi, et al., Journal of the American Chemical Society 2019, 141 (8), 3576-3588; Romanov, et al., Chemistry of Materials 2019, 31 (10), 3613-3623; Chotard, et al., Chemistry of Materials 2020, 32 (14), 6114-6122; Romanov, et al., Chemical Science 2020, 11 (2), 435-446; Zeng, et al., Advanced Functional Materials 2020, 30 (9), 1908715; Hamze, et al., Frontiers in Chemistry 2020, 8 (401), 1-9), The cMa complexes can have high photoluminescent quantum yields (Φ_{PL}), short luminescence decay lifetimes (τ) in the μs regime and shorter, and emission color tunable over the entire visible spectrum in solid, solution and doped films (Conaghan, et al., Nature Communications 2020, 11 (1), 1758), These luminophores have properties similar to transition metal phosphors that contain Ru, Os, Ir and Pt used in a range of applications including organic electronics and LEDs (Yersin, In Transition Metal and Rare Earth Compounds. Topics in Current Chemistry, Springer: Berlin, 2004; Vol. 241, pp 1-26; Thompson, et al., In Comprehensive Organometallic Chemistry III, 1 ed.; O'Hare, D., Ed. Elsevier Ltd.: Oxford, UK, 2007; Vol. 12, pp 102-194; Bolink, et al., Inorganic Chemistry 2008, 47 20), 9149-9151; Mahoro, et al., Advanced Optical Materials 2020, 8 (16), 2000260; Yersin. In Transition Metal and Rare Earth Compounds: Excited States, Transitions, Interactions Iii, Yersin, H., Ed. Springer Berlin Heidelberg: Berlin, Heidelberg, 2004; pp 1-26.), photocatalysis (Kalyanasundaram, Coordination Chemistry Reviews 1982, 46, 159-244; Kim, et al., Journal of the American Chemical Society 2019, 141 (10), 4308-4315; Jazzar, et al., Chemical Reviews 2020, 120 (9), 4141-4168), chemo- and bio-sensing (Keefe, et al., Coordination Chemistry Reviews 2000, 205 (1), 201-228; Lo, et al., Coordination Chemistry Reviews 2010, 254 (21), 2603-2622; Liu, et al., Tetrahedron 2019, 75 (23), 3128-3134) and solar energy conversion.

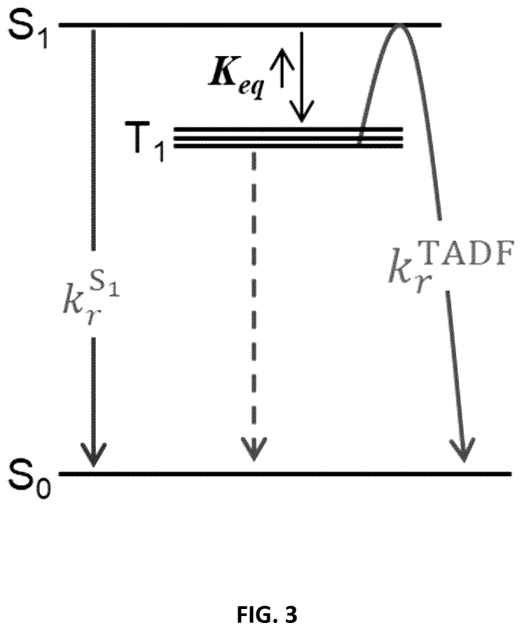

Unlike the noble metal phosphors which luminesce from triplet states, the majority of the reported cMa complexes emit via thermally assisted delayed fluorescence (TADF), FIG. 3. The carbene ligand serves as an electron acceptor (A) and amide ligand serves as an electron donor (D), The lowest energy (emitting) excited state is an interligand charge transfer (ICT) transition between the two ligands. The energy of the ICT state depends on the choice of ligands but is relatively insensitive to the identity of the metal atom. The linear geometry of the cMa complexes leads to a large spatial separation between the donor and acceptor groups/ligands of ˜4 Å. This spacing restricts the overlap between the π-orbitals of the two ligands, consequently limiting the exchange energy and thus the energy gap between lowest singlet (S₁) and triplet (T₁) states (ΔE_{ST}). A small ΔE_{ST} enhances thermal population of the singlet state, which improves the luminescence efficiency for TADF by increasing the radiative rate for emission (Ravinson, et al., Materials Horizons 2020, 7 (5), 1210-1217). Organic TADF molecules have distinct lifetimes for prompt (τ=1-100) ns) and delayed (τ=1-1000 μs) emission that are controlled by ΔE_{ST} and the rate of intersystem crossing S₁→T₁ (typically k_{ISC}<10⁷ s⁻¹, see Yang, et al., Chemical Society Reviews 2017, 46 (3), 915-1016; Li, et al., Angewandte Chemie International Edition 2019, 58 (33), 11301-11305; Li, et al., Angewandte Chemie International Edition 2019, 58 (27), 9088-9094; Hu, et al., Angewandte Chemie International Edition 2019, 58 (25), 8405-8409; Luo, et al., Advanced Materials 2020, 32 (32), 2001248; Izumi, et al., Journal of the American Chemical Society 2020, 142 (3), 1482-1491). In contrast, the intersystem crossing (ISC) rates in metal containing TADF complexes are fast enough (k_{ISC}≥10¹⁰ s⁻¹) to outcompete the radiative rates for the S₁ state, making delayed emission (TADF) independent of k_{ISC}. The result is extremely fast prompt emission (τ<200 ps) and comparatively short TADF lifetimes. τ_{TADF}=0.5-3 μs, leading to high luminescence efficiency (Gernert, et al., Chemistry—A European Journal 2017, 23 (9), 2206-2216).

For compounds where the ISC rate exceeds kᵣ^{S}^{₁}, a pre-equilibrium approximation can be made such that the equilibrium constant (K_{eq}, T₁⇄S₁) becomes a principal factor in determining kᵣ^{TADF} as shown in Eqn. 1:

$${k}_{r}^{T A D F} = {k}_{r}^{{S}_{1}} \cdot {K}_{e q} \qquad ( 1 )$$

In this equation, kᵣ^{TADF} is only dependent on kᵣ^{S}^{₁} and K_{eq}, with K_{eq} tied to ΔE_{ST}, Eqn. 2 (Jones, et al., Chemical Physics Letters 1971, 10 (4), 438-443).

$${K}_{e q} ( {T}_{1} ⇄ {S}_{1} ) = \frac{1}{3} {e}^{- \frac{Δ {E}_{S T}}{{k}_{b} T}} \qquad ( 2 )$$

Therefore, predictions can be made regarding the TADF properties for TADF emitters with fast ISC (high spin orbit coupling) without prior knowledge of the ISC rates since only kᵣ^{S}^{₁} and ΔE_{ST} are needed to estimate kᵣ^{TADF}. Boltzmann fits of temperature dependent luminescence data can be used to accurately derive ΔE_{ST} and kᵣ^{S}^{₁} values, and thus K_{eq} (Eqn. 2) (Li, et al., Journal of Materials Chemistry C 2022, 10 (12), 4674-4683). The values of kᵣ^{S}^{₁} can also be estimated experimentally from absorption spectra using the Strickler-Berg analysis (Strickler, et al., The Journal of Chemical Physics 1962, 37 (4), 814-822).

Being able to control the rate of TADF with ΔE_{ST} and kᵣ^{S}^{_{1 is useful when designing chromophores for different applications. A small ΔE}}_{ST} and large kᵣ^{S}^{₁} leads to a fast kᵣ^{TADF}, which is important for applications where a short excited state lifetime is important, such as organic LEDs. To that end, this paper describes cMa complexes with some of the shortest TADF lifetimes reported to date (τ˜250 ns). Conversely, one can design molecules where the ΔE_{ST} value is large, which will make K_{eq} (T₁⇄S₁) very small and push τ(TADF) in the 10-100 μs regime. These long-lived materials could be used as sensitizers for photoelectrochemical reactions where the diffusion of the excited species to an electrocatalysis in solution is a key step in the process. A ΔE_{ST} value of 1000 cm⁻¹ is sufficient to increase the TADF lifetime to the us regime, while only sacrificing ˜100 meV in electrochemical potential for the excited state.

Both kᵣ^{S}^{₁} and ΔE_{ST} parameters are related to the degree of overlap between the hole and electron wavefunctions that describe the excited state. This overlap can be evaluated using the natural transition orbitals (NTOs) and is referred to as Λ_{NTO} (Li, et al., Journal of Materials Chemistry C 2022, 10 (12), 4674-4683; Tadle, et al., Advanced Functional Materials 2021, 31 (27), 2101175; Chen, et al., Scientific Reports 2015, 5, 10923). While Λ_{NTO} appears to be useful in predicting both kᵣ^{S}^{₁} and K_{eq}, it affects the two parameters in opposite ways. A large Λ_{NTO} leads to a high value of kᵣ^{S}^{₁}, but it also increases the value for ΔE_{ST} and thus lowers K_{eq}. Λ_{NTO}=0.25-0.3 is an optimal range to give the fastest kᵣ^{TADF} for cMa complexes of Cu, Ag and Au with a variety of carbene and amide ligands. The lowest Λ_{NTO} values were obtained for silver based cMa complexes.

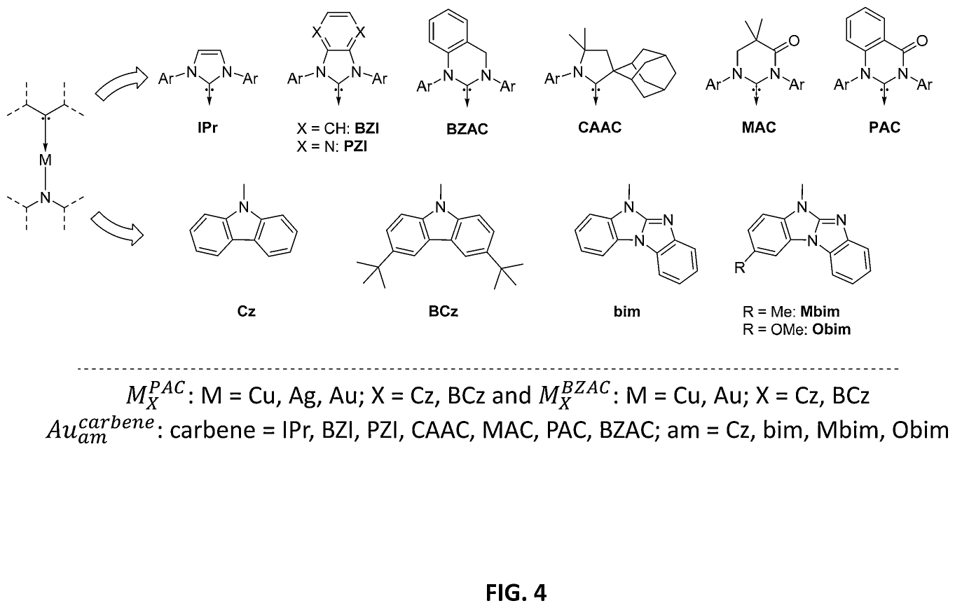

Herein is reported the synthesis and characterization of a family of new cMa materials and a study of their photophysical properties, with an eye to further explore how ligands can tune Λ_{NTO} and how these changes affect the excited state properties. The compounds discussed here are illustrated in FIG. 4. Neither the BZAC and PAC carbene ligands, nor the use of bim as the amide, in a cMa complex has been reported previously. The choice of carbene ligand affects the excited state energy but has a weaker influence on the photophysical properties and ΔE_{ST} of the cMa complexes. Interestingly, shifting from a carbazolide to a bim ligand markedly increases kᵣ^{TADF} even though the energy of the HOMO is effectively the same for both complexes.

The basic synthetic route is illustrated below. All of the compounds studied here are air stable in the solid state indefinitely and in solution for prolonged periods, with the exception of Ag_{BCz}^{PAC} which decomposes in air and solution over prolonged periods.

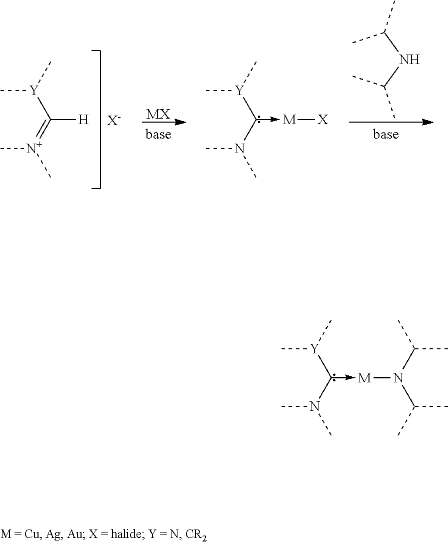

All chemicals, if not otherwise stated were used as received from chemical supplier. All inert reactions were done in dry nitrogen atmosphere. Flasks, cannula, stir bars and stoppers were dried prior usage at 140° C.

PAC-OTf: 1,3-bis(2,6-diisopropylphenyl)-1λ⁴-quinazolin-4(3H)-one, trifluoromethanesulfonate salt (PAC-OTf) was synthesized based on a modification of a literature procedure.¹ A 250 mL Schlenk flask with a stir bar was charged with 8.5 g (16.9 mmol) (E)-2-bromo-N-(2,6-diisopropylphenyl)-N-(((2,6-diisopropylphenyl)imino)methyl)benzamide (PrePAC), 4.36 g (25.34 mmol) NaOTf, and 10.8 g (29.73 mmol) Cu(OTf)₂ was connected to a reflux condenser and topped with a glass stopper. A vacuum of ˜300 mTorr was pulled on the solids followed by backfilling with nitrogen for a total of three cycles. The glass stopper was replaced with a rubber septum against positive N₂ pressure, and 100 mL of dry DMSO was canula transferred into the reaction vessel yielding a blue suspension. The reaction mixture was heated to 160° C. with an oil bath for 12 h (The suspension fully dissolved after the temperature passed 100° C.). The mixture became dark purple overnight. The mixture was raised out of the oil bath and 100 mL deionized water was added after the mixture reached room temperature. Products were extracted from the crude mixture with dichloromethane three times. The dichloromethane phases were combined and washed with 200 mL of brine a total of five times. The dichloromethane phase was further dried by mixing MgSO₄ and performing vacuum filtration to re-collect the dichloromethane filtrate. The solution was concentrated on the rotovap and the product was precipitated by addition of excess hexane. The product was vacuum filtered and further washed with hexane to afford PAC-OTf as a light blue powder (2.55 g, 30% yield); the light blue color likely comes from trace inorganic impurities the NMR matched the literature spectrum. ¹H NMR (400 MHz, acetone-d6): 10.98, (s, 1H); 8.63, (ddd, 1H); 8.24 (ddd, 1H); 8.10 (ddd, 1H); 7.81 (m, 1H); 7.65 (m, 4H); 7.52 (m, 3H); 7.38 (ddd, 1H); 3.03 (sept, 2H); 2.92 (sept, 2H); 1.29 (dd, 12H); 1.20 (d, 6H); 1.14 (d, 6H).

BZAC-OTf: 1,3-bis(2,6-diisopropylphenyl)-3,4-dihydroquinazolin-1-ium trifluoromethanesulfonate (BZAC-OTf) was synthesized based on a modification of a literature procedure.¹ A 250 mL Schlenk flask with a stir bar was charged with 15 g (28.11 mmol) (E)-N-(2-bromobenzyl)-N,N′-bis(2,6-diisopropylphenyl) formimidamide (PreBZAC), 8.46 g NaOTf (49.19 mmol), 20.33 g Cu(OTf)₂ (56.22 mmol), and 7.22 g AgOTf (28.11 mmol) was connected to a reflux condenser and topped with a glass stopper. A vacuum of ˜300 mTorr was pulled on the solids followed by backfilling with nitrogen for a total of three cycles. The glass stopper was replaced with a rubber septum against positive N₂ pressure, and 100 mL of dry DMSO was canula transferred into the reaction vessel yielding a blue suspension. The reaction mixture was heated to 160° C. with an oil bath for 12 h (The suspension fully dissolved after the temperature passed 100° C.). The mixture was cooled to room temperature and 100 mL DI water was added. The product was extracted from the crude mixture with dichloromethane three times. The dichloromethane phases were combined and washed with 200 mL of brine a total of five times. The dichloromethane phase was further dried by mixing MgSO₄ and performing vacuum filtration to re-collect the dichloromethane filtrate. The solution was concentrated on the rotovap and the product was precipitated by addition of excess hexane. The product was vacuum filtered and further washed with hexane to afford a peach colored BZAC-OTf powder (5.93 g, 35% yield). The NMR matched the literature spectrum. ¹H NMR (400 MHz, acetone-d6); 9.10 (s, 1H); 7.69 (m, 1H); 7.61 (dd, 1H); 7.54 (m, 2H); 7.50 (m, 3H); 7.45 (m, 2H); 6.60 (m, 1); 5.48 (s, 2H); 3.46 (sept, 2H); 3.17 (sept, 2H); 1.39 (d, 6H); 1.30 (dd, 12H); 1.15 (d, 6H).

### PZI—HCl:

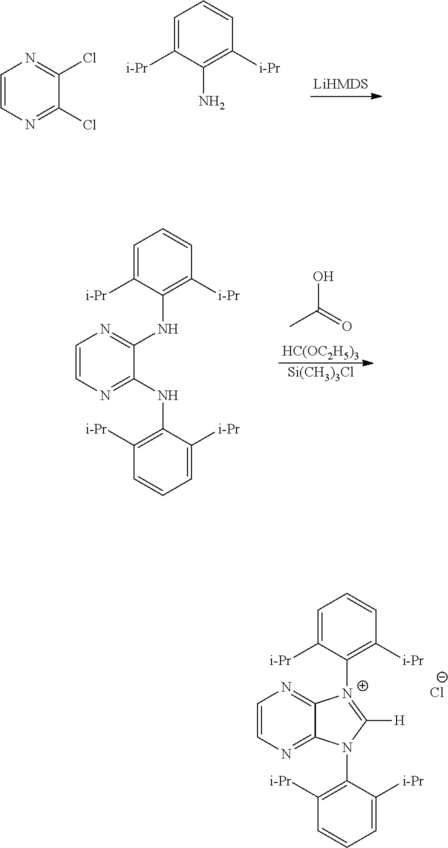

Pyrazine-di(2,6-diisopropylaniline) (1.29 g, 3.0 mmol, 1.0 eq) dissolved in 300 ml Triethylorthoformate and acetic acid (0.17 ml, 3 mmol, 1.0 eq). Triethylorthoformate and ethanol was slowly, over the course of 4-5 h, nearly fully distilled off at 150° C. Reaction was cooled to room temperature, trimethylsilylchloride (43 mL, 340 mmol, 113 eq) and 50 mL of fresh triethylorthoformate was added and the reaction mixture was heated to 70° C. overnight. All solvents were removed until a solid crude was left behind, which was first washed with diethyl ether followed with ispropyl alcohol, yielding the pure off-white product in 75% yield. ¹H NMR (400 MHz, CD₃CN) δ 10.52 (s, 1H), 8.97 (s, 3H), 7.78 (d, J=7.8 Hz, 2H), 7.59 (d, J=7.9 Hz, 4H), 2.40 (sept, J=6.8 Hz, 4H), 1.19 (dd, J=20.5, 6.8 Hz, 24H).

### 1H-Bim (5H-benzo[4,5]imidazo[1,2]imidazole)

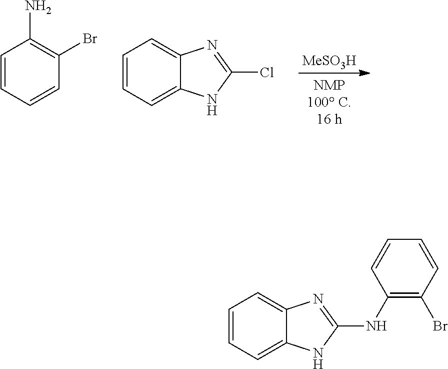

This compound was synthesized based on modified literature procedure.³ The following synthesis was carried out under Schlenk conditions in a 500 mL 3-neck flask with additional funnel. 2-Chloro-benzimidazole (50.0 g, 328 mmol, 1.0 eq) was charged in the flask and the system was pump-purged; N-methylpyrrolidine (180 mL) was added via cannula transfer and bubble degassed for 20 min. Under vigorously stirring, methanesulfonic acid (31.5 g, 21.3 mL, 328 mmol, 1.0 eq) was added dropwise using an additional funnel. After 1 h stirring at ambient temperature. 2-bromoaniline (56.4 g, 328 mmol, 1.0 eq) was added and heated to react at 100° C. overnight. (Tip: preheat everything which gets in contact with bromoaniline, like the beaker and funnel, which facilitates the transfer). After cooling down, the reaction was quenched with 100 mL water, and afterwards neutralized using 30 wt % aqueous KOH solution. Precipitate was filtered and dried at 90° C. in vacuum overnight. N-(2-bromophenyl)-1H-benzo[d]imidazol-2-amine was obtained NMR pure in 80% yield (76.5 g, 265 mmol). [6.93 (td, 1H); 7.01 (dd, 2H); 7.33 (dd, 2H); 7.39 (td, 1H); 7.62 (dd, 1H); 8.62 (d, 1H); 11.25 (s, 2H)]

### 1H-Bim (5H-benzo[d]benzo[4,5]imidazo[1,2-a]imidazole)

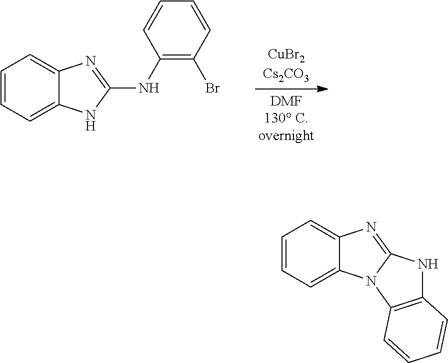 [SMILES: Brc1ccccc1Nc1nc2ccccc2[nH]1 ; c1ccc2c(c1)nc1[nH]c3ccccc3n12]

This compound was synthesized based on modified literature procedure.³ N-(2-bromophenyl)-1H-benzo[d]imidazol-2-amine (76.5 g, 265 mmol, 1.0 eq). Cs₂CO₃ (130 g, 398 mmol, 1.5 eq) and CuBr₂ (1.19 g, 5.3 mmol, 0.02 eq) was added to a Schlenk flask and pump purged. 275 mL dry, bubble degassed DMF was added via a cannula. After reaction at 130° C. overnight, reaction was cooled down and quenched with water. Vacuum filtration yielded the crude product, which was recrystallized in hot acetic acid. The acetic acid was removed by distillation and the remaining solid was NMR pure bim and was used directly in further reactions. Alternatively, the crude bim can be sublimed in a high-vacuum sublimator starting at 230° C. with steady increase to 290° C. over 4-5 h to yield a high purity snow-white product in 90% yield (49.5 g, 265.5 mmol). ¹H NMR (400 MHz, DMSO) δ 11.99 (s, 1H), 8.06 (dd, J=7.8, 0.8 Hz, 2H), 7.46 (d, J=7.9 Hz, 2H), 7.23 (dtd, J=24.3, 7.5, 1.2 Hz, 4H).

### 1H-MeBim

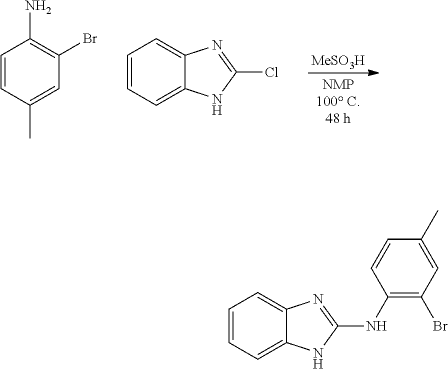

The following synthesis was carried out under Schlenk conditions in a 3-neck flask with additional funnel. 2-Chloro-benzimidazole (1.52 g, 10 mmol, 1.0 eq) and 2-bromo-4-methylaniline (1.86 g, 11 mmol, 1.1 eq)) was charged in the flask and the system was pump-purged; NMP was added via cannula transfer and bubble degassed for 20 min. Under vigorously stirring, methanesulfonic acid (1.06 g, 11 mmol, 1.1 eq) was added dropwise with the additional funnel and was reacted at 100° C. for 48 h. After cooling down, the reaction was quenched with deionized water, and afterwards neutralized using 30 wt. % NaOH solution. Precipitate was filtered and purified on a silica column with ethylacetate and hexanes. Removing the solvent yielded N-(2-bromo-4-methylphenyl)-1H-benzo[d]imidazol-2-amine NMR pure in 46% yield (1.40 g).

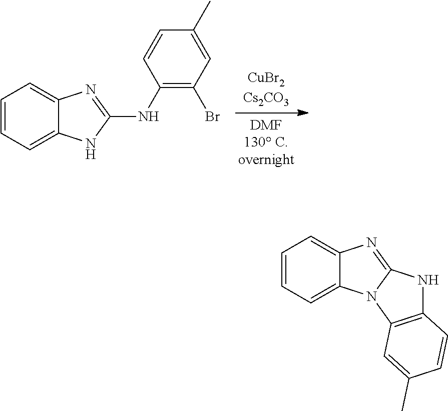 [SMILES: Cc1ccc(Nc2nc3ccccc3[nH]2)c(Br)c1 ; Cc1ccc2[nH]c3nc4ccccc4n3c2c1]

N-(2-bromo-4-methylphenyl)-1H-benzo[d]imidazol-2-amine (previous step) (1.4 g, 4.6 mmol, 1.0 eq). Cs₂CO₃ (2.25 g, 6.9 mmol, 1.5 eq) and CuBr₂ (51 mg, 0.23 mmol, 0.05 eq) was added to a Schlenk flask and pump purged. 30 mL dry, bubble degassed DMF was added via a cannula. After heating at 130° C. overnight, the reaction was cooled down and quenched with water. Filter off precipitate. Crude was dissolved in dry THF and loaded on a silica column and was eluted with a gradient (0-20%) dichloromethane with 5% MeOH. Hexanes were used as unipolar solvent. Remove solvent and wash with acetone yielded the snow-white product in 72% yield (742 mg). ¹H NMR (400 MHz, DMSO) § 11.86 (s, 1H), 8.04 (d, J=7.7 Hz, 1H), 7.90 (s, 1H), 7.45 (d, J=7.8 Hz, 1H), 7.32 (d, J=8.1 Hz, 1H), 7.24 (tt, J=7.8, 1.3 Hz, 1H), 7.18 (tt, J=7.6, 1.3 Hz, 1H), 7.07 (d, J=8.1 Hz, 1H), 2.46 (s, 3H).

### 1H-MeO-Bim

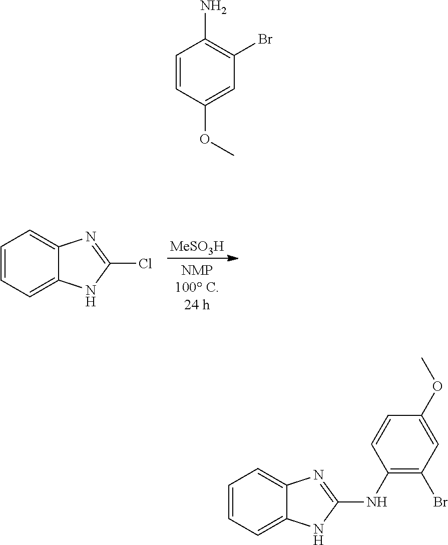

The following synthesis was carried out under Schlenk conditions in a 50 mL 3-neck flask with additional funnel. 2-Chloro-benzimidazole (2.29 g, 15 mmol, 1.0 eq) and 2-bromo-4-methoxyaniline was charged in the flask and the system was pump-purged; N-methylpyrrolidine was added via cannula transfer and bubble degassed for 20 min. Under vigorously stirring, methanesulfonic acid (1.59 g, 1.1 mL, 16.5 mmol, 1.1 eq) was added dropwise with the additional funnel and was reacted at 100° C. for 24 h. After cooling down, the reaction was quenched with deionized water, and afterwards neutralized using concentrated KHCO₃ solution. Precipitate was filtered and dried at 90° C. under vacuum overnight. N-(2-bromo-4-methoxyphenyl)-1H-benzo[d]imidazol-2-amine was obtained NMR pure in 27% yield (1.30 g, 4.1 mmol).

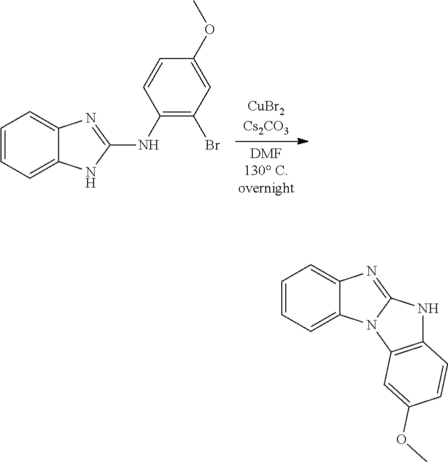 [SMILES: COc1ccc(Nc2nc3ccccc3[nH]2)c(Br)c1 ; COc1ccc2[nH]c3nc4ccccc4n3c2c1]

N-(2-bromo-4-methoxyphenyl)-1H-benzo[d]imidazol-2-amine (previous step) (820 mg, 2.58 mmol, 1.0 eq). Cs₂CO₃ (1.26 g, 3.86 mmol, 1.5 eq) and CuBr₂ (12 mg, 0.052 mmol, 0.02 eq) was added to a Schlenk flask and pump purged. 15 mL dry, bubble degassed DMF was added via a cannula. After reaction at 130° C. overnight, reaction was cooled down and quenched with water. Vacuum filtration yielded the snow-white product in 55% yield (340 mg, 2.58 mmol). ¹H NMR (400 MHz, DMSO) δ 11.78 (s, 1H), 8.14 (d, J=7.8 Hz, 1H), 7.69 (d, J=2.5 Hz, 1H), 7.43 (d, J=7.9 Hz, 1H), 7.35 (d, J=8.7 Hz, 1H), 7.25 (td, J=7.7, 1.3 Hz, 1H), 7.18 (td, J=7.6, 1.2 Hz, 1H), 6.86 (dd, J=8.7, 2.5 Hz, 1H), 3.85 (s, 3H).

Cu_{Cl}^{PAC}: A 250 mL Schlenk flask with a stir bar was charged with 1.1 g (1.78 mmol) of PAC-OTf and capped with a glass stopper. A vacuum of ˜300 mTorr was pulled on the solid followed by backfilling with nitrogen for a total of three cycles. The glass stopper was replaced by a rubber septum and 100 mL of dry THF from our solvent purification system was directly added through the septum. The PAC-OTf dissolved within 5 minutes. Next, 4.6 mL (2.32 mmol) of 0.5M potassium hexamethylsilylamide in THF was added through the septum and the reaction was stirred for an additional 5 minutes. The rubber septum was removed against positive N₂ pressure and 240 mg of CuCl was added (2.43 mmol). The dark green reaction mixture was covered with aluminum foil and stirred for 12 hrs. Removing the aluminum foil revealed a brown suspension which was filtered through Celite. The filtrate was concentrated on the rotovap and the product was precipitated out by addition of excess hexane to yield 1,3-bis(2,6-diisopropylphenyl)-4-oxo-3,4-dihydroquinazolin-1-ium-2-ide copper(I) chloride Cu_{Cl}^{PAC} as an off-white solid (390 mg, 39% yield). ¹H NMR (400 MHz, acetone-d6): 8.43 (ddd, 1H); 7.98 (ddd, 1H); 7.79 (ddd, 1H); 7.67 (m, 1H); 7.52 (m, 3H); 7.39 (m, 2H); 6.95 (ddd, 1); 2.91 (sept, 2H); 2.80 (sept, 2H); 1.33 (dd, 12H); 1.18 (d, 6H); 1.09 (d, 6H).

Ag_{BF}_{₄}^{BAC}: The synthesis and workup was the same as (PAC)Cu(Cl) except 318 mg (0.52 mmol) PAC-OTf was used, 129 mg (0.67 mmol) AgBF₄ and 1.3 mL (0.67 mmol) 0.5 M potassium hexamethylsilylamide in THF was used to yield 1,3-bis(2,6-diisopropylphenyl)-4-oxo-3,4-dihydroquinazolin-1-ium-2-ide silver (I) tetrafluoroborate Ag_{BF}_{₄}^{PAC} (100 mg, 29% yield) (400 MHz, acetone-d6): 8.45 (ddd, 1H); 8.02 (ddd, 1H); 7.83 (t, 1H); 7.68 (t, 0.95); 7.54 (m, 3H); 7.42 (m, 2H); 7.00 (m, 1H); 2.93 (sept, 2H); 2.78 (sept, 2H); 1.32 (d, 12H); 1.18 (d, 6H); 1.09 (d, 6H).

Au_{Cl}^{PAC}: A 100 mL Schlenk flask with a stir bar was charged with 500 mg (0.81 mmol) of PAC-OTf and capped with a glass stopper. A vacuum of ˜300 mTorr was pulled on the solid followed by backfilling with nitrogen for a total of three cycles. The glass stopper was replaced by a rubber septum and 50 mL of dry THF from our solvent purification system was directly added through the septum. The PAC-OTf dissolved within 5 minutes. Next, 2.1 mL (1.05 mmol) of 0.5 M potassium hexamethylsilylamide in THF was added through the septum and the reaction was stirred for an additional 5 minutes. The rubber septum was removed against positive N₂ pressure and 307 mg of AuS(CH₃)₂Cl was added (1.05 mmol). The dark red reaction mixture was covered with aluminum foil and stirred for 12 hrs. Removing the aluminum foil revealed a gold solution which was filtered through celite and dried using the Schlenk line vacuum yielding a light brown solid. The solid was washed with ethanol and vacuum filtered to yield 1,3-bis(2,6-diisopropylphenyl)-4-oxo-3,4-dihydroquinazolin-1-ium-2-ide gold(I) chloride Au_{CL}^{PAC} as a white powder (+40 mg, 78% yield). (400 MHz, acetone-d6): 8.43 (ddt, 1H); 7.99 (dddd, 1H); 7.81 (m, 1H); 7.61 (m, 1H); 7.52 (m, 3H); 7.39 (m, 2H); 6.98 (ddd, 1H); 2.98 (sept, 2H); 2.78 (sept, 2H); 1.38 (dd, 12H); 1.17 (dd, 6H); 1.07 (d, 6H).

Cu_{Cl}^{BZAC} A 200 mL Schlenk flask with a stir bar was charged with 1.0 g (1.66 mmol) of BZAC-OTf and capped with a glass stopper. A vacuum of ˜300 mTorr was pulled on the solid followed by backfilling with nitrogen for a total of three cycles. The glass stopper was replaced by a rubber septum and 100 mL of dry THF from our solvent purification system was directly added through the septum. The BZAC-OTf dissolved within 5 minutes yielding a transparent solution. Next, 3.07 mL (2.14 mmol) of 0.7 M potassium hexamethylsilylamide in THF was added through the septum and the reaction was stirred for an additional 5 minutes. The solution immediately became dark green as the potassium hexamethylsilylamide was added but quickly returned to transparent. The rubber septum was removed against positive N₂ pressure and 223 mg of CuCl was added (2.24 mmol). The reaction mixture was covered with aluminum foil and stirred for 12 h. Removing the aluminum foil revealed an orange solution which was filtered through Celite. The filtrate was concentrated on the rotovap yielding a dark orange solid. The crude solid was washed with ethanol to afford 1,3-bis(2,6-diisopropylphenyl)-1,4-dihydroquinazolin-3-ium-2-ide copper(I) chloride Cu_{Cl}^{BZAC} as a white solid (694 mg, 76% yield). (400 MHz, acetone-d6: 7.53 (dd, 1H); 7.39 (m, 5H); 7.25 (m, 3H); 6.33 (m, 1H); 4.96 (s, 2H); 3.37 (sept, 2H); 3.17 (sept, 2H); 1.36 (m, 18H); 1.12 (dd, 6H)

Au_{Cl}^{BZAC}: The synthesis and workup was the same as (BZAC)Cu(Cl) except with 390 mg (0.65 mmol) of BZAC-OTf, 1.0 mL (0.70 mmol) of 0.7 M potassium hexamethylsilylamide in THF, and 189 mg (0.73 mmol) of AuS(CH₃)₂Cl. The reaction mixture was covered with aluminum foil and stirred for 12 h. Removing the aluminum foil revealed a brown suspension which was filtered through celite to yield a clear, green filtrate. The filtrate was concentrated on the rotovap yielding a dark green solid. The crude solid was washed with ethanol to afford 1,3-bis(2,6-diisopropylphenyl)-1,4-dihydroquinazolin-3-ium-2-ide gold(I) chloride Au_{Cl}^{BZAC} as a white solid (285 mg, 60% yield). (400 MHz, acetone-d6: 7.54 (m, 1H); 7.46 (dd, 1H); 7.40 (m, 2H); 7.36 (dd, 2H); 7.27 (m, 3H); 6.35 (m, 1H); 5.00 (d, 2H); 3.35 (sept, 2H); 3.13 (sept, 2H); 1.42 (dd, 12H); 1.35 (d, 6H); 1.10 (dd, 6H).

Au_{Cl}^{PZI}:

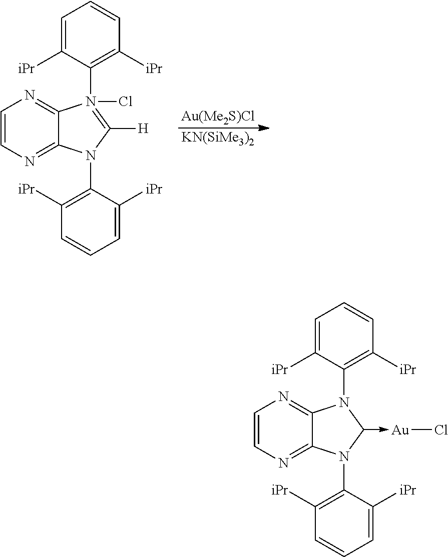

PZI—HCl (400 mg, 0.838 mmol, 1.0 eq) were pump purged and dissolved in bubble degassed THF. 0.7 M potassium hexamethylsilylamide in THF (1.26 mL, 0.880 mmol, 1.05 eq) was added and solution steered for 1 hour. Au(Me2S)Cl (272 mg, 0.922 mmol, 1.10 eq) was added and solution was stirred overnight. The reaction mixture was filtered through Celite to yield a dark red filtrate, the solvents were removed, and the residue was dissolved in minimal CH₂Cl₂ and precipitated with hexanes to yield the light brown Auer product in 34% yield (190 mg, 0.282 mmol). 1H NMR (400 MHz, acetone-d6: 7.54 (m, 1H); 7.46 (dd, 1H); 7.40 (m, 2H); 7.36 (dd, 2H); 7.27 (m, 3H); 6.35 (m, 1H); 5.00 (d, 2H); 3.35 (sept, 2H); 3.13 (sept, 2H); 1.42 (dd, 12H); 1.35 (d, 6H); 1.10 (dd, 6H).

Au_{Cz}^{PAC}: A 100 mL Schlenk flask with a stir bar was charged with 57 mg (0.34 mmol) 1H-carbazole and capped with a glass stopper. A vacuum of ˜300 mTorr was pulled on the solid followed by backfilling with nitrogen for a total of three cycles. The glass stopper was replaced by a rubber septum and 38 mL of dry THF from our solvent purification system was directly added through the septum. The carbazole dissolved after 5 minutes of stirring which gave a transparent solution, and 0.19 mL (0.37 mmol) of 2 M sodium tert-butoxide was added through the septum. The reaction was stirred for 30 minutes. The mixture went from transparent to slightly green over the duration of stirring. The rubber septum was removed against positive N₂ pressure and 238 mg of Au_{Cl}^{PAC} was added (0.34 mmol). The solution was immediately yellow emissive under UV lamp upon addition of Au_{Cl}^{PAC}. The reaction stirred for an additional 12 h yielding a dark green suspension. The solution was filtered through celite and dried using the rotovap. The resultant gel-like solid was redissolved in 80 mL of a 50/50 dichloromethane/hexane mixture and re-dried on the rotovap three times which changed the texture of the solid from gel-like to powdery. The dried solid was washed copiously with methanol and collected via vacuum filtration to yield Au_{Cz}^{PAC} as a yellow powder (129 mg, 46% yield). ¹H NMR (400 MHz, acetone-d6) δ 8.47 (ddd, J=7.9, 1.6, 0.5 Hz, 1H), 8.02 (ddd, J=8.6, 7.3, 1.6 Hz, 1H), 7.96 (t, J=7.8 Hz, 1H), 7.87-7.77 (m, 4H), 7.72 (d, J=7.9 Hz, 2H), 7.59 (d, J=7.8 Hz, 2H), 7.05 (dt, J=8.5, 0.8 Hz, 1H), 6.96 (ddd, J=8.2, 7.0, 1.3 Hz, 2H), 6.78 (ddd, J=7.8, 7.0, 1.0 Hz, 2H), 6.13 (dt, J=8.1, 0.9 Hz, 2H), 3.04 (sept, J=6.9 Hz, 2H), 2.94 (sept, J=7.0 Hz, 2H), 1.33 (dd, J=13.3, 6.8 Hz, 12H), 1.22 (d, J=6.8 Hz, 6H), 1.12 (d, J=6.8 Hz, 6H), ¹³C {¹H} NMR (100 MHz, acetone-d6) δ 206.3, 206.3, 206.3, 201.4, 160.0, 150.6, 147.5, 147.2, 142.9, 137.9, 137.8, 132.5, 131.5, 129.9, 129.7, 127.0, 125.8, 125.0, 124.2, 120.1, 120.0, 119.8, 117.0, 115.3, 30.6, 30.4, 30.2, 30.2, 30.0, 30.0, 29.8, 29.6, 29.5, 24.9, 24.8, 24.7, 24.4. CHN: C: 62.76%; H: 5.75%; N: 4.87%; calculated: C: 63.69%; H: 5.59%; N: 5.06%.

Au_{Cz}^{BZAC}: The same synthesis and workup as Au_{Cz}^{PAC} was used except with 61 mg (0.36 mmol) 1H-carbazole, 0.2 mL (0.4 mmol) of 2 M sodium tert-butoxide, and 250 mg (0.36 mmol) of (BZAC)Au(Cl). The dark grey suspension was immediately bright blue emissive under UV lamp upon addition of (BZAC)Au(Cl). The final Au_{Cz}^{BZAC} was an off-white powder (157 mg, 53% yield). ¹H NMR (400 MHz, acetone-d6) δ 7.87-7.70 (m, 4H), 7.61 (d, J=7.8 Hz, 2H), 7.56 (d, J=7.7 Hz, 2H), 7.38-7.25 (m, 3H), 6.91 (ddd, J=8.2, 7.0, 1.3 Hz, 2H), 6.76 (ddd, J=7.9, 7.0, 1.0 Hz, 2H), 6.49-6.41 (m, 1H), 6.11 (dt, J=8.2, 0.9 Hz, 2H), 5.12 (d, J=0.9 Hz, 2H), 5.12 (s, 2H), 3.50 (sept, J=6.9 Hz, 2H), 3.29 (sept, J=6.9 Hz, 2H), 1.39 (dd, J=12.3, 6.9 Hz, 18H), 1.17 (d, J=6.8 Hz, 6H). ¹³C {¹H} NMR (100 MHz, acetone-d6) δ 206.3, 206.3, 206.3, 206.2, 196.8, 150.7, 148.4, 147.0, 142.0, 138.4, 135.9, 131.4, 130.9, 130.1, 128.3, 127.5, 126.5, 124.8, 124.0, 119.7, 119.2, 117.5, 116.5, 115.2, 52.5, 30.6, 30.4, 30.2, 30.0, 29.8, 29.8, 29.7, 29.5, 25.3, 25.2, 25.1, 24.7. Crystal structure data is presented in the next section (therefore no CHN)

Cu_{BCz}^{PAC}: A 100 mL Schlenk flask with a stir bar was charged with 182 mg (0.65 mmol) 3,6-di-tert-butyl-9H-carbazole and 62 mg (0.65 mmol) sodium tert-butoxide and capped with a glass stopper. A vacuum of ˜300 mTorr was pulled on the solid followed by backfilling with nitrogen for a total of three cycles. The glass stopper was replaced by a rubber septum and 38 mL of dry THF from our solvent purification system was directly added through the septum. The carbazole dissolved after 5 minutes of stirring which gave a transparent solution. The reaction was stirred for 30 minutes. The rubber septum was removed against positive N₂ pressure and 350 mg (0.62 mmol) of (Cu_{Cl}^{PAC} was added. The solution was immediately red in color, and red emissive under UV lamp upon addition of Cu_{Cl}^{PAC}. The reaction stirred for an additional 12 h yielding a dark brown suspension. The solution was filtered through Celite yielding a clear red solution. The resultant gel-like solid was redissolved in 80 mL of a 50/50 dichloromethane/hexane mixture and re-dried on the rotovap three times which changed the texture of the solid from a gel to a yellow-emissive powder. The dried solid was dissolved in ethanol and the filtrate was collected via vacuum filtration. Water was added to the ethanol solution which caused the precipitation of a yellow powder. The yellow powder was vacuum filtered and washed with methanol which afforded Cu_{BCz}^{PAC} as a yellow powder (40 mg, 8% yield). The relatively low yield is likely due to the unconventional workup; the cMa complexes are not typically isolated by precipitation from ethanol using water. The product is also quite soluble in methanol which was used as a rinse solvent. ¹H NMR (400 MHz, acetone-d6) δ 8.47 (dd, J=8.0, 1.4 Hz, 1H), 8.01 (td, J=7.3, 1.9 Hz, 2H), 7.89-7.78 (m, 4H), 7.76 (d, J=7.9 Hz, 2H), 7.62 (d, J=7.8 Hz, 2H), 6.95 (td, J=8.8, 8.4, 1.9 Hz, 3H), 5.64 (dd, J=8.5, 0.6 Hz, 2H), 3.08 (sept, J=6.8 Hz, 2H), 2.99 (sept, J=6.8 Hz, 2H), 1.34 (s, 18H), 1.30-1.23 (m, 18H), 1.16 (d, J=6.8 Hz, 6H), ¹³C {¹H} NMR (100 MHz, acetone-d6) δ 206.3, 206.3, 206.3, 206.3, 206.3, 206.2, 159.7, 149.7, 147.5, 147.2, 142.9, 138.3, 137.5, 137.5, 132.7, 131.6, 129.7, 129.6, 127.2, 126.1, 125.1, 121.4, 120.5, 119.7, 115.5, 115.3, 35.1, 32.9, 30.7, 30.6, 30.4, 30.2, 30.0, 29.8, 29.6, 29.5, 25.4, 24.9, 24.5, 24.3. Crystal structure data presented elsewhere herein.

Ag_{BCz}^{PAC}: A 100 mL Schlenk flask with a stir bar was charged with 145 mg (0.52 mmol) 3,6-di-tert-butyl-9H-carbazole and 50 mg (0.52 mmol) sodium tert-butoxide and capped with a glass stopper. A vacuum of ˜300 mTorr was pulled on the solid followed by backfilling with nitrogen for a total of three cycles. The glass stopper was replaced by a rubber septum and 40 mL of dry THF from our solvent purification system was directly added through the septum. The solids dissolved after 30 minutes of stirring which gave a transparent solution. The rubber septum was removed against positive N₂ pressure and 326 mg (0.49 mmol) of Ag_{BF}_{₄}^{PAC} was added. The solution was immediately red in color, upon addition of Ag_{BF}_{₄}^{PAC}. The reaction stirred for an additional 12 h yielding a red suspension. The crude solution was immediately dried on the rotovap. The resultant gel-like solid was redissolved in 80 mL of a 50/50 dichloromethane/hexane mixture and re-dried on the rotovap three times which changed the texture of the solid from a gel to a yellow-emissive powder. The dried yellow solid was dissolved in ether and filtered through celite to yield a bright red solution. The ether solution was dried on the rotovap and the resulting yellow solid was washed copiously with methanol over a vacuum filtration setup to afford Ag_{BCz}^{PAC} as a yellow powder (116 mg, 28% yield). ¹H NMR (400 MHz, acetone-d6) δ 8.51 (dd, J=7.9, 1.3 Hz, 1H), 8.06 (ddd, J=8.7, 7.3, 1.6 Hz, 1H), 7.96 (t, J=7.8 Hz, 1H), 7.91-7.78 (m, 3H), 7.74 (d, J=7.8 Hz, 2H), 7.61 (d, J=7.8 Hz, 2H), 7.48-7.36 (m, 1H), 7.09 (d, J=8.4 Hz, 1H), 7.05 (dd, J=8.5, 2.0 Hz, 2H), 6.07 (dd, J=8.5, 0.6 Hz, 2H), 3.07 (sept, J=7.2 Hz, 2H), 2.95 (sept, J=6.7 Hz, 2H), 1.38-1.07 (m, 42H), ¹³C {¹H} NMR (100 MHz, acetone-d6) δ 206.3, 206.2, 150.3, 150.2, 147.2, 146.9, 137.8, 137.6, 132.7, 131.6, 130.1, 129.8, 127.1, 126.1, 124.9, 121.5, 120.6, 120.3, 115.6, 115.1, 35.1, 32.9, 30.8, 30.6, 30.4, 30.2, 30.0, 29.8, 29.6, 29.5, 25.3, 24.8, 24.8, 24.6.]. CHN: C: 72.57%; H: 7.48%; N: 4.74%; calculated: C: 73.22%; H: 7.33%; N: 4.93%

Au_{BCz}^{PAC}: A 100 mL Schlenk flask with a stir bar was charged with 84 mg (0.30 mmol) 3,6-di-tert-butyl-9H-carbazole and 32 mg (0.33 mmol) sodium tert-butoxide and capped with a glass stopper. A vacuum of ˜300 mTorr was pulled on the solid followed by backfilling with nitrogen for a total of three cycles. The glass stopper was replaced by a rubber septum and 38 mL of dry THF from our solvent purification system was directly added through the septum. The reaction was stirred for 30 minutes yielding a transparent solution. The rubber septum was removed against positive N₂ pressure and 210 mg (0.30 mmol) of Au_{Cl}^{PAC} was added. The solution was immediately red in color, upon addition of Au_{Cl}^{PAC} and was yellow luminescent under the UV lamp. The reaction stirred for an additional 12 h yielding a red suspension. The crude solution was filtered through Celite and concentrated on the rotovap, then precipitated with addition of excess hexane. The resulting yellow solid was washed copiously with methanol over a vacuum filtration setup to afford Au_{Cl}^{PAC} as a yellow powder (136 mg, 48% yield). ¹H NMR (400 MHz, acetone-d6) δ 8.48 (ddd, J=7.9, 1.6, 0.5 Hz, 1H), 8.07-7.94 (m, 2H), 7.86 (dt, J=2.4, 1.2 Hz, 2H), 7.87-7.78 (m, 2H), 7.74 (d, J=7.8 Hz, 2H), 7.60 (d, J=7.8 Hz, 2H), 7.10-7.01 (m, 3H), 6.10 (dd, J=8.5, 0.7 Hz, 2H), 3.04 (sept, J=6.8 Hz, 2H), 2.94 (sept, J=6.9 Hz, 2H), 1.37-1.32 (m, 30H), 1.23 (d, J=6.8 Hz, 6H), 1.14 (d, J=6.8 Hz, 6H). ¹³C {¹H} NMR (100 MHz, acetone-d6) δ 206.3, 206.3, 206.3, 206.3, 206.2, 149.2, 147.4, 147.1, 139.2, 132.5, 131.4, 129.6, 126.9, 125.8, 124.9, 121.7, 120.0, 115.7, 114.7, 35.1, 32.8, 30.6, 30.4, 30.2, 30.0, 29.8, 29.6, 29.4, 24.9, 24.8, 24.6, 24.5; CHN: C: 67.23%; H: 6.67%; N: 4.54%; calculated: C: 66.30%; H: 6.63%; N: 4.46%.

Cu_{BCz}^{BZAC}: A 100 mL Schlenk flask with a stir bar was charged with 165 mg (0.36 mmol) 3,6-di-tert-butyl-9H-carbazole and 65 mg (0.43 mmol) sodium tert-butoxide and capped with a glass stopper. A vacuum of ˜300 mTorr was pulled on the solid followed by backfilling with nitrogen for a total of three cycles. The glass stopper was replaced by a rubber septum and 50 mL of dry THF from our solvent purification system was directly added through the septum. The reaction was stirred for 30 minutes yielding a transparent solution. The rubber septum was removed against positive N₂ pressure and 375 mg (0.41 mmol) of Cu_{Cl}^{BZAC} was added. The solution immediately became lime green upon addition of Cu_{Cl}^{BZAC} and was bright green luminescent under the UV lamp. The reaction stirred for an additional 12 h while covered with aluminum foil which yielded a green suspension. The crude solution was immediately dried on the rotovap, then dissolved in diethyl ether and filtered through Celite. The ether phase was dried on the rotovap, then redissolved in 50 mL acetonitrile. Hexane was used to extract the product out of the acetonitrile phase (15 extractions with 50 mL hexane). The hexane phases were combined and dried on the rotovap. The solid was redissolved in 40 mL methanol and four additional 20 mL hexane extractions were performed, this time keeping the methanol phase and discarding the hexane phases. The methanol phase was dried on the Schlenk line yielding Cu_{BCz}^{BZAC} as an off-white powder (26 mg, 6% yield). ¹H NMR (400 MHz, acetone-d6) δ 7.86 (t, J=7.8 Hz, 1H), 7.81-7.73 (m, 4H), 7.63 (d, J=7.8 Hz, 2H), 7.58 (d, J=7.8 Hz, 2H), 7.38-7.22 (m, 3H), 6.91 (dd, J=8.6, 2.1 Hz, 2H), 5.58 (dd, J=8.6, 0.7 Hz, 2H), 5.06 (s, 2H), 3.54 (sept, J=6.9 Hz, 2H), 3.33 (sept, J=6.8 Hz, 2H), 1.42 (d, J=7.0 Hz, 6H), 1.33 (s, 18H), 1.29 (dd, J=6.9, 2.0 Hz, 12H), 1.18 (d, J=6.8 Hz, 6H), ¹³C {¹H} NMR (100 MHz, acetone-d6) δ 206.3, 206.3, 206.3, 206.2, 206.1, 149.3, 148.4, 147.0, 142.0, 138.6, 138.3, 136.0, 131.4, 130.8, 130.1, 128.3, 127.4, 126.5, 124.7, 121.5, 119.2, 117.5, 115.5, 114.6, 52.5, 35.1, 32.9, 30.6, 30.4, 30.2, 30.0, 29.8, 29.7, 29.5, 25.3, 25.2, 25.1, 24.7. CHN: C: 72.32%; H: 7.76%; N: 4.63%; calculated: C: 72.37%; H: 7.56%; N: 4.78% (CHN-Analysis includes one cocrystalized CH₂Cl₂ molecule per Cu_{BCz}^{BZAC} molecule.)

Au_{BCz}^{BZAC}: A 100 mL Schlenk flask with a stir bar was charged with 102 mg (0.36 mmol) 3,6-di-tert-butyl-9H-carbazole and 42 mg (0.43 mmol) sodium tert-butoxide and capped with a glass stopper. A vacuum of ˜300 mTorr was pulled on the solid followed by backfilling with nitrogen for a total of three cycles. The glass stopper was replaced by a rubber septum and 50 mL of dry THF from our solvent purification system was directly added through the septum. The reaction was stirred for 30 minutes yielding a transparent solution. The rubber septum was removed against positive N₂ pressure and 285 mg (0.41 mmol) of Au_{Cl}^{BZAC} was added. The solution immediately became lime green upon addition of Au_{Cl}^{BZAC} and was bright blue luminescent under the UV lamp. The reaction stirred for an additional 12 h while covered with aluminum foil which yielded a green suspension. The crude solution was immediately dried on the rotovap, then dissolved in diethyl ether and filtered through Celite. The ether phase was dried on the rotovap, then redissolved in 50 mL acetonitrile. Hexane was used to extract the product out of the acetonitrile phase (15 extractions with 50 mL hexane). The hexane phases were combined and dried on the rotovap. The solid was redissolved in 40 mL methanol and four additional 20 mL hexane extractions were performed, this time keeping the methanol phase and discarding the hexane phases. The methanol phase was dried on the Schlenk line yielding Au_{BCz}^{BZAC}: as an off-white powder (82 mg, 24% yield). ¹H NMR (400 MHz, acetone-d6) δ 7.88-7.79 (m, 3H), 7.74 (t, J=7.8 Hz, 1H), 7.61 (d, J=7.8 Hz, 2H), 7.56 (d, J=7.8 Hz, 2H), 7.37-7.30 (m, 1H), 7.34-7.24 (m, 2H), 7.01 (dd, J=8.6, 2.1 Hz, 2H), 6.48-6.41 (m, 1H), 6.06 (dd, J=8.5, 0.6 Hz, 2H), 5.13-5.08 (m, 2H), 3.50 (sept, J=6.8 Hz, 2H), 3.28 (sept, J=6.8 Hz, 2H), 1.45-1.36 (m, 18H), 1.33 (s, 18H), 1.17 (d, J=6.8 Hz, 6H); ¹³C {¹H} NMR (100 MHz, acetone-d6) δ 205.1, 205.1, 205.1, 205.1, 204.9, 148.2, 147.3, 145.8, 140.9, 137.5, 137.2, 134.8, 130.2, 129.7, 129.0, 127.2, 126.3, 125.3, 123.6, 120.3, 118.1, 116.4, 114.4, 113.5, 51.3, 34.0, 31.7, 29.5, 29.3, 29.1, 28.9, 28.7, 28.5, 28.3, 24.2, 24.0, 24.0, 23.6. CHN: C: 66.80%; H: 6.94%; N: 4.49%; calculated: C: 67.3%; H: 6.95%; N: 4.53%

Au_{Cl}^{PZI}:

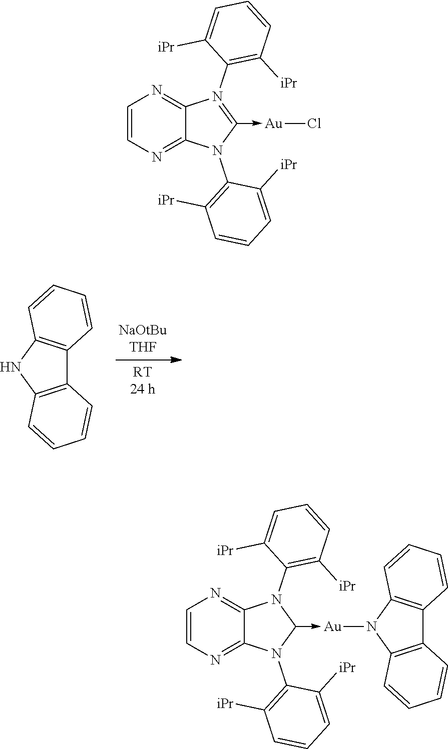

A 25 mL Schlenk flask with a stir bar with 52 mg (0.311 mmol, 1.1 eq) 1H-carbazole was pump purged and bubble degassed dry THF (10 mL) was added via cannula transfer. 0.155 mL (0.311 mmol, 1.1 eq) 2 M sodium tert-butoxide (NaOtBu) solution was added dropwise. After 1 h stirring. Au_{Cl}^{PZI} (190 mg, 0.282 mmol, 1.0 eq) was added and reaction was stirred overnight. Filtration through Celite, washed with dichloromethane and solvent was removed. Product was precipitated from dichloromethane by adding hexanes. Solid was filtered and washed with diethyl ether, yielding to the colorless Au_{Cz}^{PZI} in 90% yield (205 mg, 0.282 mmol). Under a UV light the solid is orange/green emissive. ¹H NMR (400 MHz, CDCl3) δ 8.59 (s, 2H), 7.95 (ddd, J=7.7, 1.4, 0.7 Hz, 2H), 7.78 (t, J=7.9 Hz, 2H), 7.53 (d, J=7.8 Hz, 4H), 7.07 (ddd, J=8.2, 7.0, 1.3 Hz, 2H), 6.92 (ddd, J=7.9, 7.0, 1.1 Hz, 2H), 6.65 (dt, J=8.1, 0.9 Hz, 2H), 2.48 (sept, J=6.8 Hz, 4H), 1.33 (d, J=6.8 Hz, 12H), 1.17 (d, J=6.9 Hz, 12H), ¹³C NMR (100 MHz, CDCl₃) δ 149.2, 146.7, 141.1, 140.4, 131.5, 130.4, 124.7, 123.9, 123.5, 119.4, 116.1, 113.4, 65.9, 29.7, 24.3, 24.0, 23.8, 15.3. CHN: C: 56.63%; H: 5.15%; N: 7.88%; calculated: C: 56.76%; H: 5.22%; N: 7.88%. (CHN-Analysis includes one cocrystalized CH₂Cl₂ molecule per Au_{Cz}^{PZI} molecule.)

Au_{Bim}^{BZAC}:

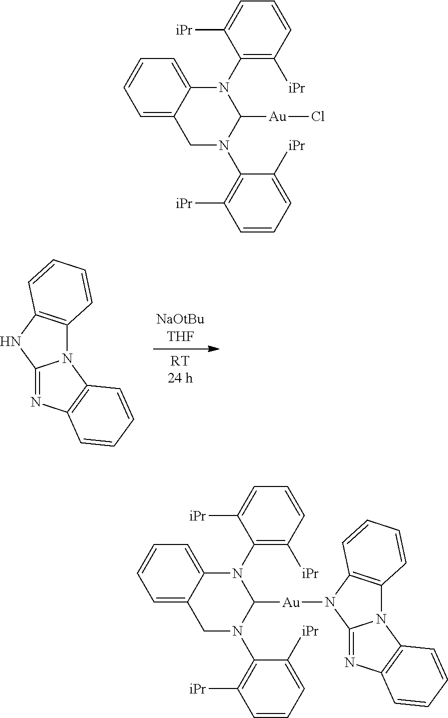

A 100 mL Schlenk flask with a stir bar was charged with 258 mg (1.25 mmol, 1.05 eq) 1H-bim ligand was pump purged and bubble degassed dry THF (50 mL) was added via cannula transfer. 120 mg (1.25 mmol, 0.624 mL, 1.05 eq) sodium tert-butoxide (NaOtBu) was added as 2 M solution. After 1 h stirring. Au_{Cl}^{BZAC} (815 mg, 1.19 mmol, 1.0 eq) was added and reaction was stirred overnight. Filtration through Celite, washing with dichloromethane and removing of solvent yielded to a solid, which was precipitated from dichloromethane/hexanes. If necessary, washing again with pure dichloromethane, dissolves Au_{Bim}^{BZAC} but does not dissolve remaining bim ligand. Au_{Bim}^{BZAC} could be isolated as an colorless powder in 88% yield (902 mg, 1.05 mmol). Under a UV light the solid is blue emissive. This compound was crystallized with vapor diffusion of hexanes into a dichloromethane solution of the compound. Crystallographic data can be obtained in the next section. ¹H NMR (400 MHz, CDCl₃): δ 7.67 (d, J=7.8 Hz, 1H), 7.58 (d, J=8.4 Hz, 2H), 7.53-7.45 (m, 4H), 7.41 (d, J=7.8 Hz, 2H), 7.23-7.19 (m, 2H), 7.18-7.11 (m, 2H), 6.98 (dd, J=7.5, 1.2 Hz, 1H), 6.90 (dd, J=7.5, 1.5 Hz, 2H), 6.51-6.46 (m, 1H), 6.05 (dd, J=7.4, 1.6 Hz, 1H), 4.94 (s, 2H), 3.32 (d, J=6.8 Hz, 2H), 3.13 (d, J=6.8 Hz, 2H), 1.44 (dd, J=6.8, 3.4 Hz, 12H), 1.40 (d, J=6.8 Hz, 6H), 1.16 (d, J=6.8 Hz, 6H), ¹³C {¹H} NMR (101 MHz, CDCl₃) δ 194.5, 162.5, 149.3, 146.7, 145.4, 145.3, 140.4, 136.8, 135.0, 130.6, 130.1, 129.3, 128.4, 127.1, 126.7, 126.5, 125.6, 121.1, 120.6, 117.4, 117.2, 117.1, 117.1, 116.5, 113.5, 109.1, 108.9, 51.7, 29.0, 28.9, 25.1, 24.9, 24.6.

Au_{Bim}^{BZI}:

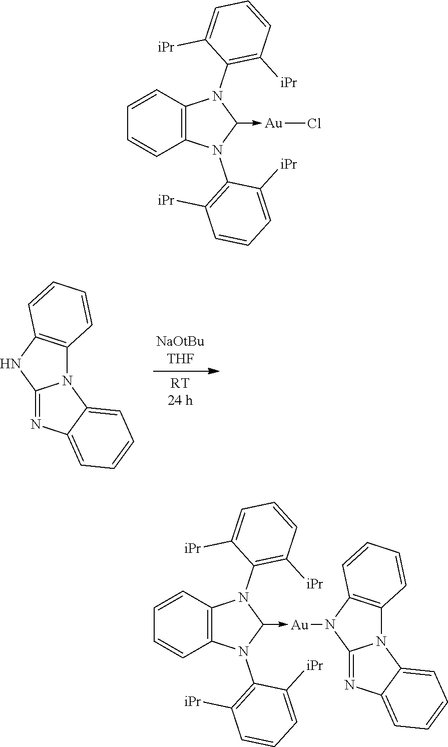

A 50 mL Schlenk flask with a stir bar with 56.5 mg (0.25 mmol, 1.0 eq) 1H-bim ligand was pump purged and bubble degassed dry THF (20 mL) was added via cannula transfer. 24 mg (0.25 mmol, 1.0 eq) sodium tert-butoxide (NaOtBu) was added as 2M solution. After 1 h stirring. Au_{Cl}^{BZI} (167 mg, 0.25 mmol, 1.0 eq) was added and reaction was stirred overnight. Filtration through Celite, washing with dichloromethane and recrystallization from dichloromethane with layered pentane yielded to the colorless Au_{Bim}^{BZI} in 84% yield (110 mg, 0.21 mmol). Under a UV light the solid is blue emissive. ¹H NMR (400 4 MHz, CDCl₃) δ 7.68 (t, J=7.8 Hz, 2H), 7.62 (d, J=7.7 Hz, 1H), 7.58 (d, J=7.5 Hz, 1H), 7.53-7.40 (m, 7H), 7.15 (dq, J=6.1, 3.5, 2.8 Hz, 3H), 7.06-6.87 (m, 3H), 6.38 (d, J=7.9 Hz, 1H), 2.54 (sept, J=6.7 Hz, 4H), 1.40 (d, J=6.9 Hz, 13H), 1.14 (d, J=6.8 Hz, 13H), ¹³C {¹H} NMR (101 MHz, CDCl₃) δ 183.0, 162.3, 148.7, 146.8, 145.4, 135.0, 131.5, 131.3, 128.3, 127.0, 125.5, 125.0, 121.5, 121.0, 117.7, 117.1, 117.0, 113.5, 112.2, 109.2, 29.3, 24.9, 24.1. CHN: C: 62.54%; H: 5.52%; N: 8.29%; calculated: C: 62.78%; H: 5.51%; N: 8.32%.

Au_{Bim}^{CAAC}:

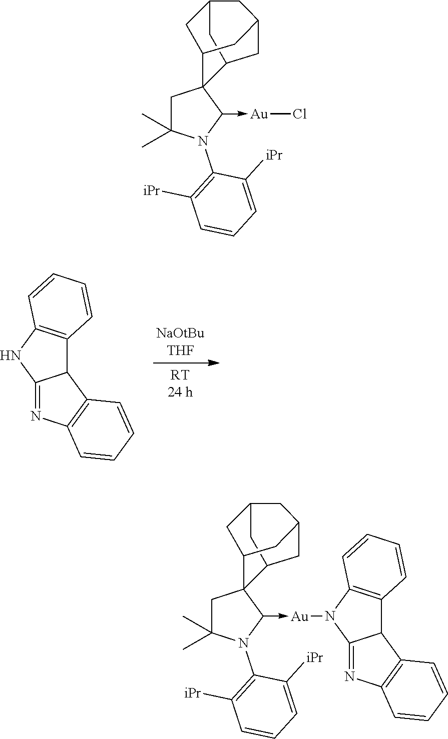

A 50 mL Schlenk flask with a stir bar with 60 mg (0.29 mmol, 1.0 eq) 1H-bim ligand was pump purged and bubble degassed dry THF (20 mL) was added via cannula transfer. 28 mg (0.29 mmol, 1.0 eq) sodium tert-butoxide (NaOtBu) was added as 2 M solution. After 1 h stirring. Au_{Cl}^{CAAC} (180 mg, 0.29 mmol, 1.0 eq) was added and reaction was stirred overnight. Filtration through Celite, washing with dichloromethane and recrystallization in hot acetone yielded to the colorless Au_{Bim}^{CAAC} in 77% yield (192 mg, 0.31 mmol). Under a UV light the solid is blue emissive. This compound was crystallized with vapor diffusion of hexanes into a dichloromethane solution of the compound. Crystallographic data can be obtained in the next section. ¹H NMR (400 MHz, CDCl₃) δ 7.66-7.60 (m, 2H), 7.58 (dd, J=7.9, 1.1 Hz, 2H), 7.40 (d, J=7.8 Hz, 2H), 7.18 (dd, J=7.7, 1.2 Hz, 1H), 7.04 (dd, J=7.5, 1.1 Hz, 1H), 6.95 (dd, J=7.5, 1.1 Hz, 1H), 6.86 (dd, J=7.6, 1.3 Hz, 1H), 5.89 (d, J=7.8 Hz, 1H), 4.28 (d, J=12.9 Hz, 2H), 3.48 (s, 1H), 2.87 (sept, J=6.7 Hz, 2H), 2.54 (s, 1H), 2.43 (s, 2H), 2.04 (d, J=24.3 Hz, 7H), 1.91 (s, 3H), 1.43 (s, 6H), 1.35 (dd, J=13.8, 6.7 Hz, 12H), ¹³C {¹H} NMR (126 MHz, CDCl₃) δ 149.2, 145.9, 145.2, 136.6, 129.9, 128.5, 127.2, 125.4, 121.4, 121.2, 117.8, 116.8, 113.6, 110.0, 109.3, 109.1, 77.7, 64.2, 59.8, 48.2, 39.2, 37.1, 35.7, 34.5, 29.5, 29.4, 29.2, 29.1, 28.9, 28.8, 28.6, 28.0, 27.5, 26.0, 22.7, 20.0, 13.7.

Au_{Bim}^{MAC}:

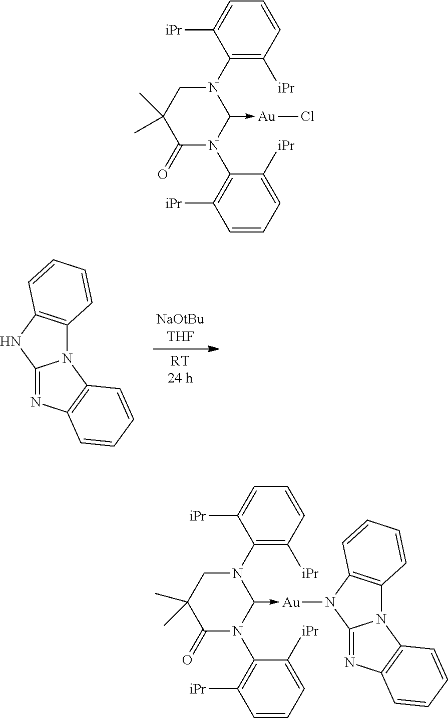

A 25 mL Schlenk flask with a stir bar with 43 mg (0.206 mmol, 1.0 eq) 1H-bim ligand was pump purged and bubble degassed dry THF (10 mL) was added via cannula transfer. 0.10 mL (0.206 mmol, 1.0 eq) 2M sodium tert-butoxide (NaOtBu) solution was added dropwise. After 1 h stirring. Au_{Cl}^{MAC} (140 mg, 0.206 mmol, 1.0 eq) was added and reaction was stirred overnight. Filtration through Celite, washing with dichloromethane and removing solvent. Product was purified by layered recrystallization of dichloromethane and pentane. Removing of solvent yielded to the lightly yellow Au_{Bim}^{MAC} in 85% yield (148 mg, 0.174 mmol). Under a UV light the solid is sky-blue emissive. ¹H NMR (400 MHz, CDCl₃) δ 7.64-7.54 (m, 3H), 7.48 (dd, J=7.5, 1.4 Hz, 1H), 7.43 (dd, J=8.0, 1.0 Hz, 1H), 7.39 (dd, J=7.8, 1.1 Hz, 4H), 7.14 (dd, J=7.8, 1.2 Hz, 1H), 6.98 (dd, J=7.6, 1.1 Hz, 1H), 6.90 (td, J=7.6, 1.4 Hz, 1H), 6.85 (td, J=7.6, 1.4 Hz, 1H), 5.95 (dd, J=7.7, 1.3 Hz, 1H), 3.86 (s, 2H), 3.25 (sept, J=6.9 Hz, 2H), 3.01 (sept, J=6.8 Hz, 2H), 1.62 (s, 6H), 1.44 (d, J=6.8 Hz, 6H), 1.39 (dd, J=6.9, 3.7 Hz, 12H), 1.24 (d, J=6.8 Hz, 6H); ¹³C {¹H} NMR (101 MHz, CDCl₃) δ 203.9, 171.4, 162.2, 149.0, 145.7, 145.1, 144.5, 140.1, 135.8, 130.7, 130.5, 128.4, 127.1, 125.8, 124.9, 121.3, 120.8, 117.5, 117.2, 116.8, 113.4, 109.1, 109.0, 62.1, 38.1, 29.5, 29.1, 25.0, 24.7, 24.5, 23.9.

Au_{Bim}^{PAC}:

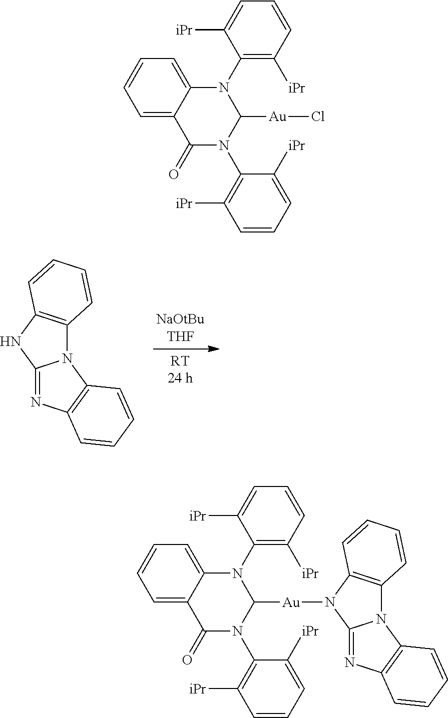

A 25 mL Schlenk flask with a stir bar with 62 mg (0.300 mmol, 1.05 eq) 1H-bim ligand was pump purged and bubble degassed dry THF (12 mL) was added via cannula transfer. 0.150 mL (0.300 mmol, 1.05 eq) 2M sodium tert-butoxide (NaOtBu) solution was added dropwise. After 1 h stirring. Au_{Cl}^{PAC} (200 mg, 0.285 mmol, 1.0 eq) was added and reaction was stirred overnight. Filtration through Celite, washing with dichloromethane and removing solvent. Product was purified by layered recrystallization of dichloromethane and pentane. Removing of solvent yielded to the yellow Au_{Bim}^{PAC} in 75% yield (186 mg, 0.214 mmol). Under a UV light the solid is green emissive. ¹H NMR (400 MHz, acetone-d6) δ 8.49 (ddd, J=7.9, 1.6, 0.5 Hz, 1H), 8.05 (ddd, J=8.6, 7.3, 1.6 Hz, 1H), 7.86 (td, J=7.6, 1.1 Hz, 1H), 7.79 (ddt, J=8.3, 7.4, 0.5 Hz, 1H), 7.69 (ddd, J=7.8, 1.3, 0.7 Hz, 1H), 7.67-7.60 (m, 4H), 7.51 (d, J=7.8 Hz, 2H), 7.36 (ddd, J=8.0, 1.1, 0.6 Hz, 1H), 7.13-7.05 (m, 2H), 6.99-6.87 (m, 3H), 6.31-6.25 (m, 1H), 3.03 (sept, J=6.8 Hz, 2H), 2.92 (sept, J=6.8 Hz, 2H), 1.45 (dd, J=15.1, 6.8 Hz, 12H), 1.22 (d, J=6.8 Hz, 6H), 1.12 (d, J=6.8 Hz, 6H), 0.14 (d, J=6.6 Hz, 4H), ¹³C {¹H} NMR (100 MHz, CDCl₃) δ 158.7, 145.3, 145.1, 141.7, 135.9, 131.6, 130.6, 129.4, 128.3, 125.9, 124.9, 121.1, 120.6, 118.8, 118.5, 117.4, 117.0, 116.6, 113.3, 109.0, 108.9, 77.2, 29.4, 29.1, 24.5, 24.4, 24.3, 23.9, 1.0.
   Au_{Bim}^{iPr}:

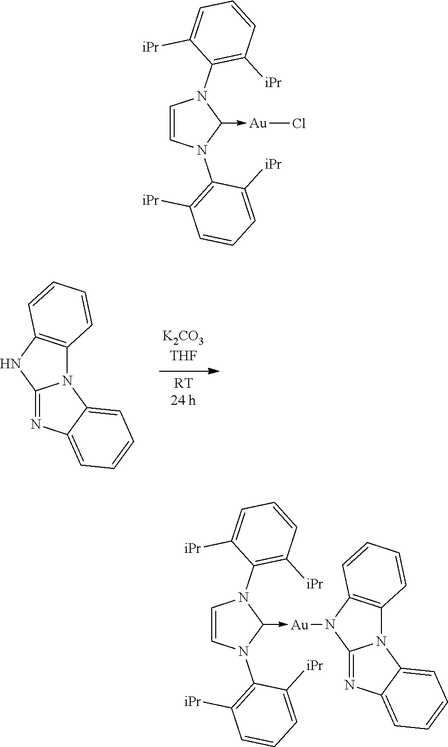

A 25 mL Schlenk flask with a stir bar with 70 mg (0.337 mmol, 1.05 eq) 1H-bim ligand was pump purged and bubble degassed dry THF (10 mL) was added via cannula transfer. 0.17 mL (0.338 mmol, 1.05 eq) 2M sodium tert-butoxide (NaOtBu) solution was added dropwise. After 1 h stirring. Au_{Cl}^{iPr} (200 mg, 0.322 mmol, 1.0 eq) was added and reaction was stirred overnight. Filtration through Celite, washing with dichloromethane and removing solvent. Product was first washed with Diethyl ether and then dissolved in as little dichloromethane as possible. Remaining bim ligand, does not dissolve. Removing of solvent yielded to the colorless Au_{Bim}^{iPr} in 80% yield (205 mg, 0.259 mmol). Under a UV light the solid is blue emissive. ¹H NMR (400 MHz, acetone-d6) δ 7.92 (s, 2H), 7.73-7.65 (m, 2H), 7.60 (ddd, J=8.3, 7.2, 0.5 Hz, 2H), 7.50-7.44 (m, 4H), 7.29 (ddd, J=8.0, 1.2, 0.7 Hz, 1H), 7.06 (ddd, J=8.0, 7.3, 1.3 Hz, 1H), 6.97-6.87 (m, 3H), 6.68-6.59 (m, 1H), 2.83 (sept, J=6.8 Hz, 4H), 1.46 (d, J=6.9 Hz, 12H), 1.30 (d, J=6.9 Hz, 12H), ¹³C NMR (100 MHz, CDCl₃) δ 207.0, 145.8, 145.6, 134.1, 130.8, 124.5, 124.3, 123.5, 121.4, 120.8, 117.5, 116.9, 116.8, 113.3, 109.0, 77.2, 30.9, 29.0, 28.8, 24.5, 24.1, 24.0. CHN: C: 60.75%; H: 5.59%; N: 8.73%; calculated: C: 60.68%; H: 5.60%; N: 8.85%

Au_{Bim}^{PZI}:

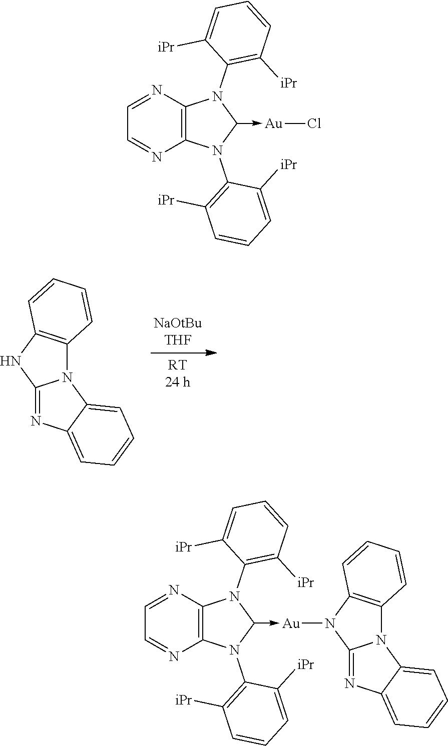

A 25 mL Schlenk flask with a stir bar with 65 mg (0.311 mmol, 1.1 eq) 1H-bim ligand was pump purged and bubble degassed dry THF (10 mL) was added via cannula transfer. 0.155 mL (0.311 mmol, 1.1 eq) 2M sodium tert-butoxide (NaOtBu) solution was added dropwise. After 1 h stirring. Au_{Cl}^{PZI} (190 mg, 0.282 mmol, 1.0 eq) was added and reaction was stirred overnight. Filtration through Celite, washed with dichloromethane and solvent was removed. Product was precipitated from dichloromethane by adding hexanes. Solid was filtered and washed with diethyl ether, yielding to the colorless Au_{Bim}^{PZI} in 76% yield (182 mg, 0.216 mmol). Under a UV light the solid is green emissive. ¹H NMR (400 MHz, acetone-d6) δ 8.76 (s, 2H), 7.81-7.66 (m, 4H), 7.61 (d, J=7.8 Hz, 4H), 7.33 (d, J=7.9 Hz, OH), 7.09 (td, J=7.9, 1.2 Hz, 1H), 7.01-6.92 (m, 3H), 6.58-6.49 (m, 1H), 2.67 (sept, J=6.9 Hz, 4H), 1.45 (d, J=6.8 Hz, 12H), 1.15 (d, J=6.8 Hz, 12H), ¹³C NMR (100 MHz, acetone-d6) δ 161.7, 148.7, 146.9, 144.7, 142.2, 140.3, 131.5, 130.7, 128.1, 126.7, 124.7, 121.4, 121.3, 118.1, 116.9, 116.7, 112.9, 109.2, 109.2, 29.2, 23.9, 23.7, 23.3, 23.2. CHN: C: 59.83%; H: 5.24%; N: 11.56%; calculated: C: 59.78%; H: 5.26%; N: 11.62%

Au_{MeBim}^{BZI}:

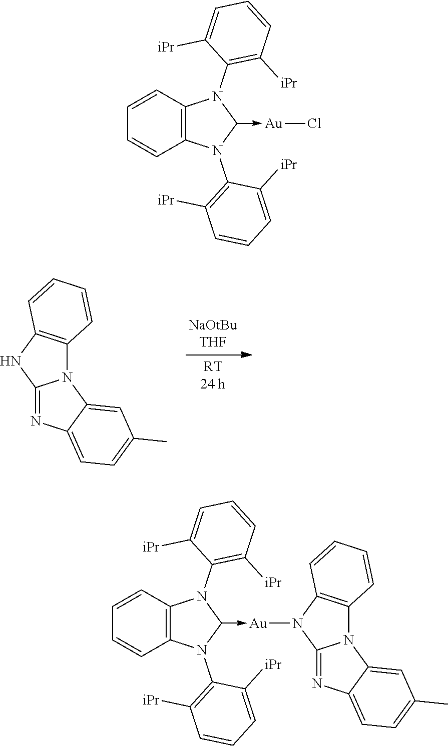

A 25 mL Schlenk flask with a stir bar with 33 mg (0.149 mmol, 1.0 eq) 1H-Mbim ligand was pump purged and bubble degassed dry THF (10 mL) was added via cannula transfer. 0.075 mL (0.149 mmol, 1.0 eq) 2 M sodium tert-butoxide (NaOtBu) solution was added dropwise. After stirring for 1 h, Au_{Cl}^{BZI} (100 mg, 0.149 mmol, 1.0 eq) was added and reaction was stirred overnight. Filtration through Celite, washing with dichloromethane and recrystallization in hot acetone yielded to the colorless Au_{MeBim}^{BZI} in 76% yield (116 mg, 0.217 mmol). Under a UV light the solid is blue emissive. This compound was crystallized with vapor diffusion of hexanes into a dichloromethane solution of the compound. Crystallographic data can be obtained in the next section. The NMR spectra showed a 50/50 mixture of both possible tautomers. The proton integrations are for a mixture of both tautomers. ¹H NMR (400 MHz, CDCl₃) δ 7.68 (t, J=7.8 Hz, 2H), 7.62 (d, J=7.7 Hz, 1H), 7.57 (d, J=7.0 Hz, 1H), 7.53-7.40 (m, 7H), 7.15 (dq, J=6.1, 3.5, 2.8 Hz, 3H), 7.06-6.87 (m, 3H), 6.38 (d, J=7.2 Hz, 1H), 5.30 (s, 1H), 2.54 (sept, J=6.7 Hz, 4H), 1.40 (d, J=6.9 Hz, 13H), 1.14 (d, J=6.8 Hz, 13H), ¹³C {¹H} NMR (101 MHz, CDCl₃) δ 183.0, 162.3, 148.7, 146.8, 145.4, 135.0, 131.5, 131.3, 128.3, 127.0, 125.5, 125.0, 121.5, 121.0, 117.7, 117.1, 117.0, 113.5, 112.2, 109.2, 29.3, 24.9, 24.1.

Au_{MeOBim}^{BZI}:

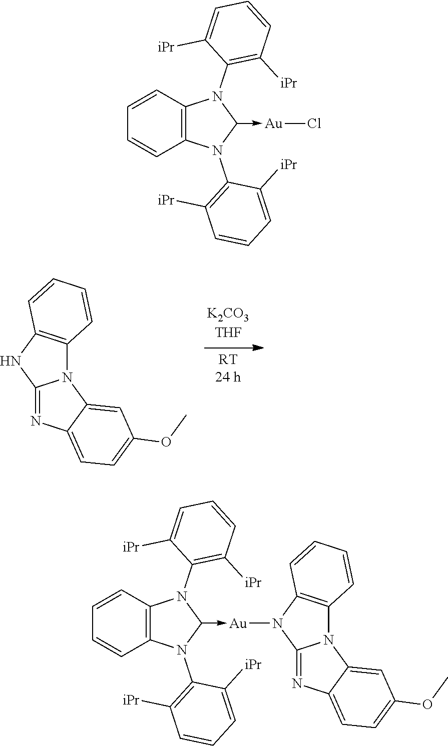

A 25 mL round-bottom flask with stir bar was charged with Au_{Cl}^{BZI} (200 mg, 0.30 mmol, 1.0 eq), 71 mg (0.30 mmol, 1.0 eq) 1H-Obim ligand and fine ground K₂CO₃ (125 mg, 0.9 mmol, 3.0 eq) was dissolved in minimal acetone and stirred for 24 h at room temperature. Solution was filtered through Celite, washed with dichloromethane and dried under vacuum. Sonicating in diethylether and collecting the precipitate yielded to the colorless Au_{MeOBim}^{BZI} in 85% yield (140 mg, 0.255 mmol). Under a UV light the solid is blue emissive. The NMR spectra showed a 50/50 mixture of both possible tautomers. The proton integrations are for a mixture of both tautomers. [¹H NMR (400 MHz, CDCl₃) δ 7.67 (t, J=7.8 Hz, 1H), 7.62-7.56 (m, 2H), 7.53-7.45 (m, 4H), 7.41 (d, J=7.8 Hz, 2H), 7.23-7.19 (m, 2H), 7.18-7.11 (m, 2H), 6.98 (td, J=7.5, 1.2 Hz, 1H), 6.90 (pd, J=7.4, 1.5 Hz, 2H), 6.51-6.46 (m, 1H), 6.05 (dd, J=7.4, 1.6 Hz, 1H), 4.94 (s, 2H), 3.32 (sept, J=6.8 Hz, 2H), 3.13 (sept, J=6.8 Hz, 2H), 1.44 (dd, J=6.8, 3.4 Hz, 12H), 1.40 (d, J=6.8 Hz, 6H), 1.16 (d, J=6.8 Hz, 6H), ¹³C {¹H} NMR (101 MHz, CDCl₃) δ 194.5, 162.5, 149.3, 146.7, 145.4, 145.3, 140.4, 136.8, 135.0, 130.6, 130.1, 129.3, 128.4, 127.1, 126.7, 126.5, 125.6, 121.1, 120.6, 117.4, 117.2, 117.1, 117.1, 116.5, 113.5, 109.1, 108.9, 51.7, 29.0, 28.9, 25.1, 24.9, 24.6. CHN: C: 61.79%; H: 5.56%; N: 7.96%; calculated: C: 61.99%; H: 5.55%; N: 8.03%

### Structural Data

All crystals were grown by recrystallization. Vapor diffusion of hexanes or pentane into a solution of the compound in dichloromethane. A Cryo-Loop was used to mount the sample with Paratone oil.

TABLE 1
Selected bond lengths and angles for the(carbene)M(amide) complexes.

| com- | C-M | M-N | C-M-N | Torsion (°) | Conformer | CCDC |
|---|---|---|---|---|---|---|
| pound | (A) | (A) | (°) | NC-M-NC | ratio | # |
| Au_{Cz}^{BZAC} | 2.004(7) | 2.020(6) | 179.1(3) | 3.7 | 100/0 | 2168084 |
| | 1.984(8) | 1.999(7) | 1.79.5(3) | | | |
| Cu_{BCz}^{PAC} | 1.879(2) | 1.854(2) | 173.9(1) | 6.1 | 100/0 | 2170320 |
| Au_{bim}^{BZAC} | 2.005(1) | 2.025(7) | 176.1(4) | 2.7 | 100/0 | 2182717 |
| Au_{bim}^{CAAC} | 1.974(4) | 2.014(3) | 178.1(2) | 7.2 | 100/0 | 2155241 |
| Au_{bim}^{MAC} | 1.992(7) | 2.023(6) | 178.8(3) | 4.0 | 90/10 | 2167514 |
| Au_{bim}^{PAC} | 1.995(3) | 2.018(3) | 178.6(2) | 7.3 | 100/0 | 2170000 |
| Au_{Mbim}^{BZI} | 2.005(7) | 2.031(6) | 174.1(3) | 0.7 | 84/16 | 2168086 |

The single crystal structures were determined at 100 K with Rigaku Xta LAB Synergy S, equipped with an HyPix-600HE detector and an Oxford Cryostream 800 low temperature unit, using a Cu K_{α} PhotonJet-S X-ray radiation source. The structures were solved using OLEX2 with the SHELXTL software package.¹⁶ Details of the data collection and structure solution are given in in supporting information. Each structure was deposited in the Cambridge Crystallographic Data Centre with the following accension codes: Au_{Cz}^{BZAC} 2168084, Cu_{BCz}^{PAC} 2170320, Au_{bim}^{BZAC} 2182717, Au_{bim}^{CAAC} 2155241, Au_{bim}^{MAC} 2167514, Au_{bim}^{PAC} 2170000 and Au_{Mbim}^{BZI} 2168086.

TABLE S2
Crystallographic parameters for BZAC-Au-Cz, PAC-Cu-BCz, BZAC-Au-bim and CAAC-Au-bim.

| Identification code | BZAC-Au-Cz | PAC-Cu-BCz | BZAC-Au-bim | CAAC-Au-bim |
|---|---|---|---|---|
| Empirical formula | C₁₇₆H₁₉₂Au₄N₁₂ | C₁₀₄H₁₂₄Cu₂N₆O₂ | C₄₅H₄₈AuN₅ | C₄₀H₄₇AuN₄ |
| Formula weight | 191.96 | 1613.16 | 855.883 | 780.78 |
| Temperature/K | 293(2) | 100.00(10) | 100.01(10) | 107(11) |
| Crystal system | triclinic | triclinic | orthorhombic | monoclinic |
| Space group | P-1 | P-1 | Fdd2 | I2/a |
| a/Å | 9.0083(2) | 16.5805(2) | 57.2043(10) | 23.3536(3) |
| b/Å | 19.3190(3) | 17.3257(2) | 30.8094(5) | 9.61920(10) |
| c/Å | 23.0688(2) | 20.0203(2) | 8.8252(1) | 33.2792(4) |
| α/° | 82.1710(10) | 68.7580(10) | 90 | 90 |
| β/° | 80.8960(10) | 72.6580(10) | 90 | 100.5580(10) |
| γ/° | 83.406(2) | 62.0990(10) | 90 | 90 |
| Volume/Å³ | 3909.28(11) | 4679.32(11) | 15553.8(4) | 7349.37(15) |
| Z | 2 | 2 | 16 | 8 |
| ρ_{calc} g/cm³ | 1.386 | 1.145 | 1.462 | 1.411 |
| μ/mm⁻¹ | 7.306 | 0.934 | 7.389 | 7.752 |
| F(000) | 1648 | 1724 | 6870.6 | 3152 |
| Crystal size/mm³ | 0.549 × | 0.25 × | 0.118 × | 0.138 × |
| | 0.058 × 0.029 | 0.195 × 0.135 | 0.025 × 0.015 | 0.098 × 0.029 |
| Radiation | Cu Kα (λ = 1.54184) | Cu Kα (λ = 1.54184) | Cu Kα (λ = 1.54184) | Cu Kα (λ = 1.54184) |
| 2Θ range for data | 5.694 to 163.426 | 5.984 to 161.91 | 6.18 to 160.66 | 5.402 to 161.006 |
| collection/° | | | | |
| Index ranges | −11 ≤ h ≤ 11, | −21 ≤ h ≤ 21, | −68 ≤ h ≤ 72, | −29 ≤ h ≤ 29, |
| | −24 ≤ k ≤ 24, | −21 ≤ k ≤ 22, | −39 ≤ k ≤ 37, | −12 ≤ k ≤ 8, |
| | −27 ≤ l ≤ 29 | −25 ≤ l ≤ 25 | −7 ≤ l ≤ 10 | −42 ≤ l ≤ 42 |
| Reflections collected | 92189 | 301930 | 24795 | 60195 |
| Independent | 16775[Rᵢₙₜ = 0.1410, | 20281[Rᵢₙₜ = 0.0668, | 6414[Rᵢₙₜ = 0.0343, | 7981[Rᵢₙₜ = 0.0901, |
| reflections | R_{sigma} = 0.0759] | R_{sigma} = 0.0231] | R_{sigma} = 0.0274] | R_{sigma} = 0.0472] |
| Data/restraints/ | 16775/0/882 | 20281/0/1055 | 6414/1/468 | 7981/0/412 |
| parameters | | | | |
| Goodness-of-fit on F² | 1.14 | 1.052 | 1.038 | 1.085 |
| Final R indexes | R₁ = 0.0791, | R₁ = 0.0675, | R₁ = 0.0359, | R₁ = 0.0364, |
| [I >= 2σ (I)] | wR₂ = 0.2219 | wR₂ = 0.1654 | wR₂ = 0.0946 | wR₂ = 0.0915 |
| Final R indexes [all | R₁ = 0.0911, | R₁ = 0.0725, | R₁ = 0.0377, | R₁ = 0.0431, |
| data] | wR₂ = 0.2383 | wR₂ = 0.1689 | wR₂ = 0.0953 | wR₂ = 0.0960 |
| Largest diff. peak/ | 4.79/−3.15 | 1.59/−1.48 | 2.12/−1.16 | 2.49/−1.83 |
| hole/e Å⁻³ | | | | |
| #CCDC | 2168084 | 2170320 | 2182717 | 2155241 |

TABLE S3
Crystallographic parameters for MAC-Au-bim, PAC-Au-bim and BZI-Au-Mbim.

| Identification code | MAC-Au-bim | PAC-Au-bim | BZI-Au-Mbim |
|---|---|---|---|
| Empirical formula | C₄₃H₅₀AuN₅O | C₄₅H₄₆AuN₅O | C₄₅H₄₈AuN₅ |
| Formula weight | 849.876 | 869.83 | 855.85 |
| Temperature/K | 123(30) | 100.5(8) | 100(90) |
| Crystal system | monoclinic | monoclinic | monoclinic |
| Space group | C2/c | P2₁/n | P2₁/c |
| a/Å | 15.9731(1) | 13.61560(10) | 8.91960(10) |
| b/Å | 22.6254(2) | 18.11870(10) | 29.5199(5) |
| c/Å | 21.5638(2) | 16.34850(10) | 15.2229(3) |
| α/° | 90 | 90 | 90 |
| β/° | 93.533(1) | 109.8980(10) | 99.193(2) |
| γ/° | 90 | 90 | 90 |
| Volume/Å³ | 7778.30(11) | 3792.35(5) | 3956.79(11) |
| Z | 8 | 4 | 4 |
| ρ_{calc} g/cm³ | 1.451 | 1.523 | 1.437 |
| μ/mm⁻¹ | 7.4 | 7.609 | 7.263 |
| F(000) | 3419.4 | 1752 | 1728 |
| Crystal size/mm³ | 0.27 × 0.14 × 0.13 | 0.104 × 0.083 × 0.043 | 0.29 × 0.059 × 0.032 |
| Radiation | Cu Kα (λ = 1.54184) | Cu Kα (λ = 1.54184) | Cu Kα (λ = 1.54184) |
| 2Θ range for data | 6.78 to 161.6 | 7.33 to 160.548 | 5.988 to 176.412 |
| collection/° | | | |
| Index ranges | −20 ≤ h ≤ 20, | −17 ≤ h ≤ 16, | −9 ≤ h ≤ 11, |
| | −28 ≤ k ≤ 28, | −23 ≤ k ≤ 23, | −37 ≤ k ≤ 37, |
| | −24 ≤ l ≤ 27 | −20 ≤ l ≤ 20 | −19 ≤ l ≤ 19 |
| Reflections collected | 132598 | 128799 | 80685 |
| Independent | 8489 [Rᵢₙₜ = 0.0702, | 8259 [Rᵢₙₜ = 0.0596, | 8698 [Rᵢₙₜ = 0.1226, |
| reflections | R_{sigma} = 0.0200] | R_{sigma} = 0.0195] | R_{sigma} = 0.0429] |
| Data/restraints/ | 8489/0/471 | 8259/0/477 | 8698/0/476 |
| parameters | | | |
| Goodness-of-fit on F² | 0.945 | 1.178 | 1.128 |
| Final R indexes [I >= 2σ | R₁ = 0.0634, | R₁ = 0.0314, | R₁ = 0.0622, |
| (I)] | wR₂ = 0.1472 | wR₂ = 0.0852 | wR₂ = 0.1347 |
| Final R indexes [all | R₁ = 0.0639, | R₁ = 0.0334, | R₁ = 0.0701, |
| data] | wR₂ = 0.1474 | wR₂ = 0.0863 | wR₂ = 0.1549 |
| Largest diff. peak/ | 2.20/−2.14 | 1.10/−1.51 | 2.41/−2.89 |
| hole/e Å⁻³ | | | |
| #CCDC | 2167514 | 2170000 | 2168086 |

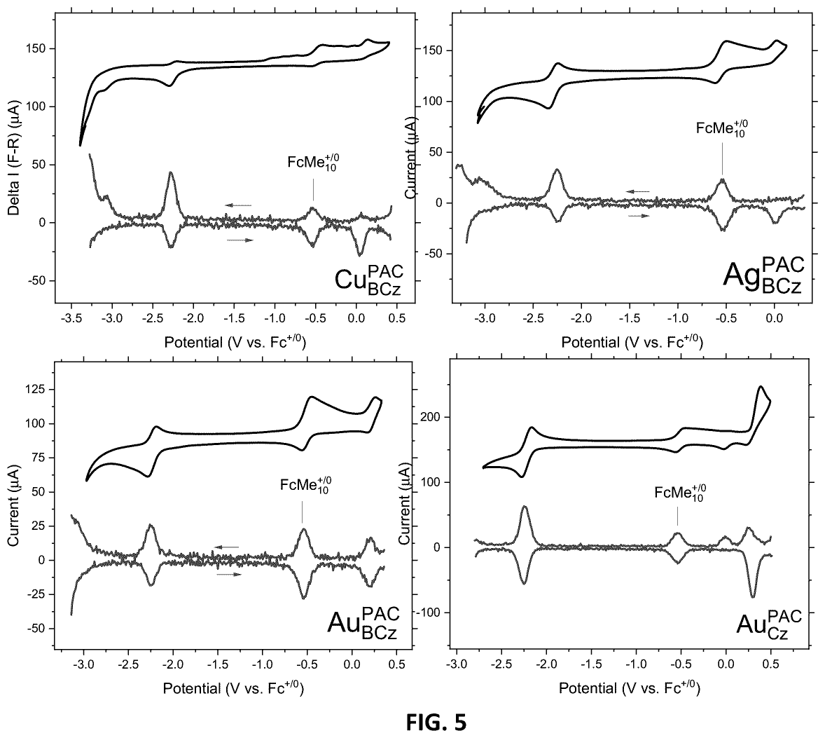

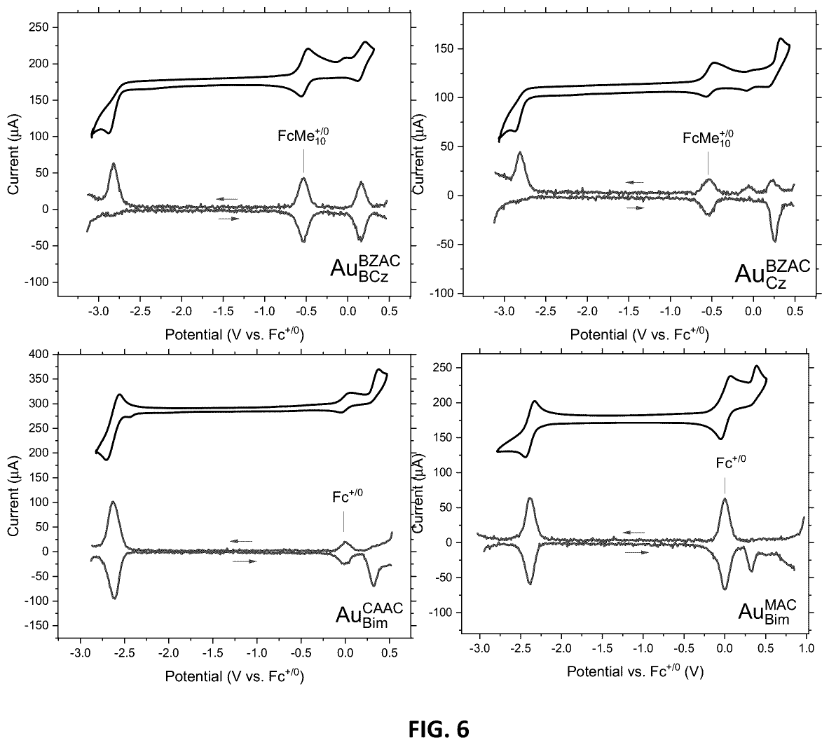

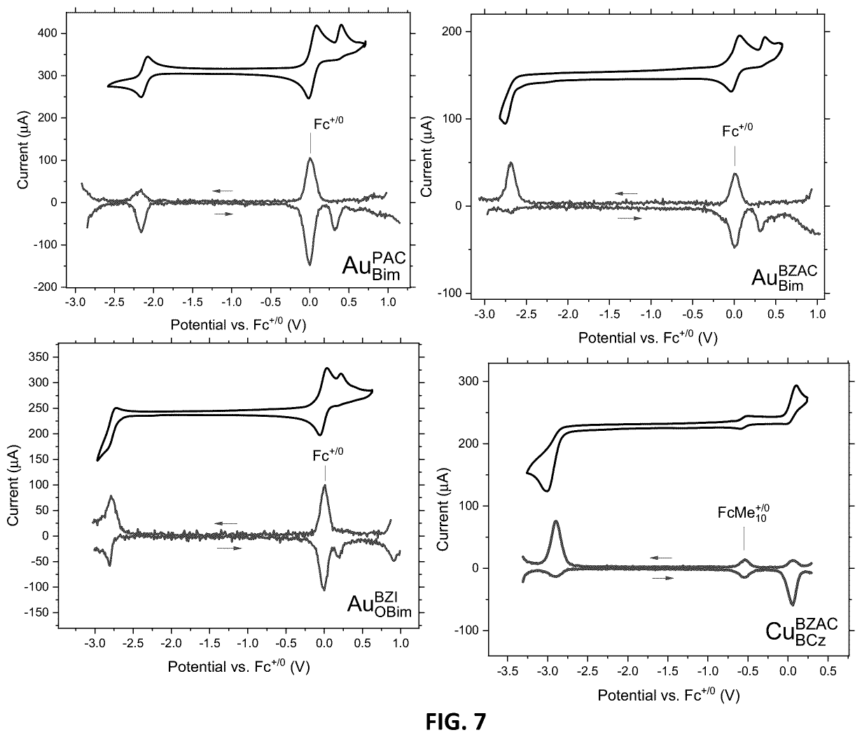

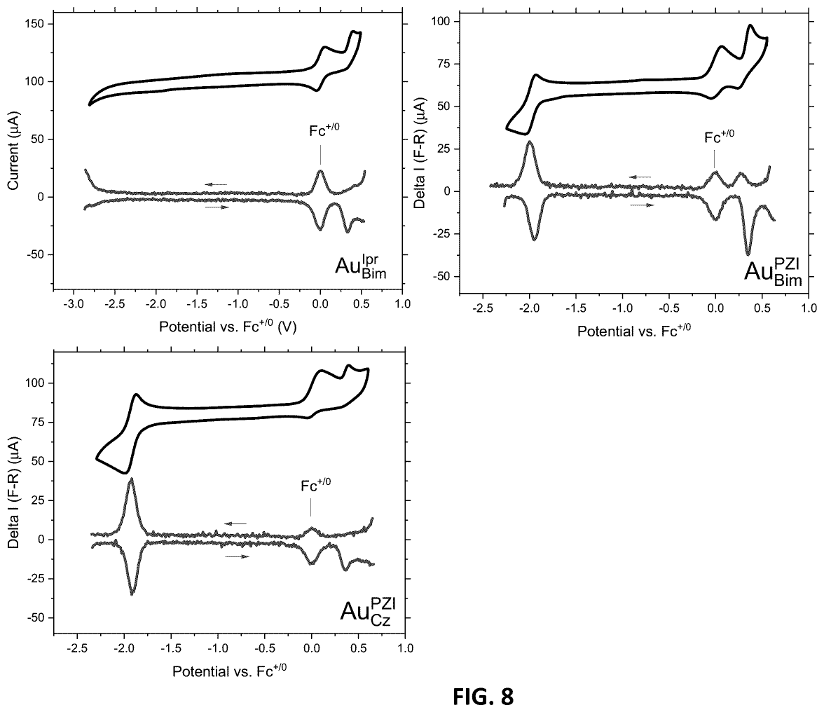

Cyclic voltammetry and differential pulsed voltammetry were performed using a VersaSTAT potentiostat measured at 100 mV/s scan. Anhydrous dimethylformamide was used as the solvent, with 0.1 M tetra(n-butyl)ammonium hexafluorophosphate as the supporting electrolyte. The redox potentials are based on values measured from differential pulsed voltammetry and are reported relative to the ferrocenium/ferrocene (Cp₂Fe⁺/Cp₂Fe) redox couple using either ferrocene or decamethylferrocene as an internal reference. Electrochemical reversibility was determined using cyclic voltammetry. Cyclic voltammograms and differential pulse voltammograms are presented in FIGS. 5, 6, 7, and 8. Electrochemical data are presented in Table 4

TABLE 4
Electrochemical data. Electrochemical measurements were carried out
in DMF solution with 0.1M NBu₄PF₆ electrolyte, and the potentials
are listed relative to a ferrocene internal reference. The absorption
edge is taken as the point where ICT absorbance has dropped to 10%
of the peak absorbance for a toluene solution of the cMa.

| Complex | Eₒₓ (V) | E_{red} (V) | ΔE_{redox} (V) | Abs. edge (eV) |
|---|---|---|---|---|
| Cu_{BCz}^{BZAC} | 0.06 | −2.90 | 2.96 | 2.74 |
| Au_{BCz}^{BZAC} | 0.15 | −2.83 | 2.98 | 2.77 |
| Au_{Cz}^{BZAC} | 0.26 | −2.81 | 3.07 | 2.89 |
| Cu_{BCz}^{PAC} | 0.12 | −2.28 | 2.40 | 2.25 |
| Ag_{BCz}^{PAC} | 0.02 | −2.24 | 2.26 | 2.27 |
| Au_{BCz}^{PAC} | 0.21 | −2.24 | 2.45 | 2.33 |
| Au_{Cz}^{PAC} | 0.29 | −2.24 | 2.53 | 2.49 |
| Au_{Cz}^{PZI} | 0.29 | −1.99 | 2.30 | 2.36 |
| Au_{bim}^{PZI} | 0.36 | −1.92 | 2.28 | 2.38 |
| Au_{bim}^{PAC} | 0.32 | −2.16 | 2.48 | 2.52 |
| Au_{bim}^{MAC} | 0.33 | −2.37 | 2.70 | 2.65 |
| Au_{bim}^{CAAC} | 0.32 | −2.62 | 2.94 | 2.86 |
| Au_{bim}^{BZAC} | 0.31 | −2.69 | 3.00 | 2.99 |
| Au_{bim}^{BZI} | 0.33 | −2.79 | 3.12 | 3.08 |
| Au_{Mbim}^{BZI} | 0.26 | −2.75 | 3.01 | 3.00 |
| Au_{Obim}^{BZI} | 0.18 | −2.81 | 2.99 | 2.93 |
| Au_{bim}^{Ipr} | 0.33 | * | * | 3.59 |

* The reduction potential of Au_{bim}^{Ipr} was outside of the solvent window. This is consistent with it having the largest optical LUMO of all compounds in this study.

### Modeling Methods

The electronic properties of the complexes were modelled using Density Functional Theory (DFT) and Time Dependent DFT (TDDFT). Geometry optimization was performed using the B3LYP functional and LACVP* basis set using crystallographic coordinates as starting points when possible. TDDFT calculations were performed on the geometry-optimized structures using the CAM-B3LYP exchange, LACVP effective core potential, with the random phase approximation enabled and the omega value set to 0.2 arbitrary units. The full carbene ligand, but only the parent Cz and bim ligands were investigated in these modeling studies. Natural transition orbitals (NTOs) were generated by performing a singular value decomposition on the transition density matrix using the Q-Chem v5.0 software package.

The spatial overlap of the hole and electron NTO (Λ_{NTO}) for a particular excited state is defined here by Eqn 3.

$${Λ}_{N T O} \approx \vert {φ}_{h +} \vert \vert {φ}_{e -} \vert d τ \qquad ( 3 )$$

where φₕ₊ and φₑ₋ are the hole and electron NTOs, respectively, for the excited state. Both φₕ₊ and φₑ₋ are orthonormal which ensures that Λ_{NTO} falls between 0 and 1, which represent 0% and 100% overlap respectively. Values for Λ_{NTO} were calculated for these compounds using a script that draws from the integration methods developed by Herman, et al.,¹⁸ and Castro, et al.,¹⁹ using a method reported previously (See equation S1 in the supporting info for full equation).^{13, 15a}

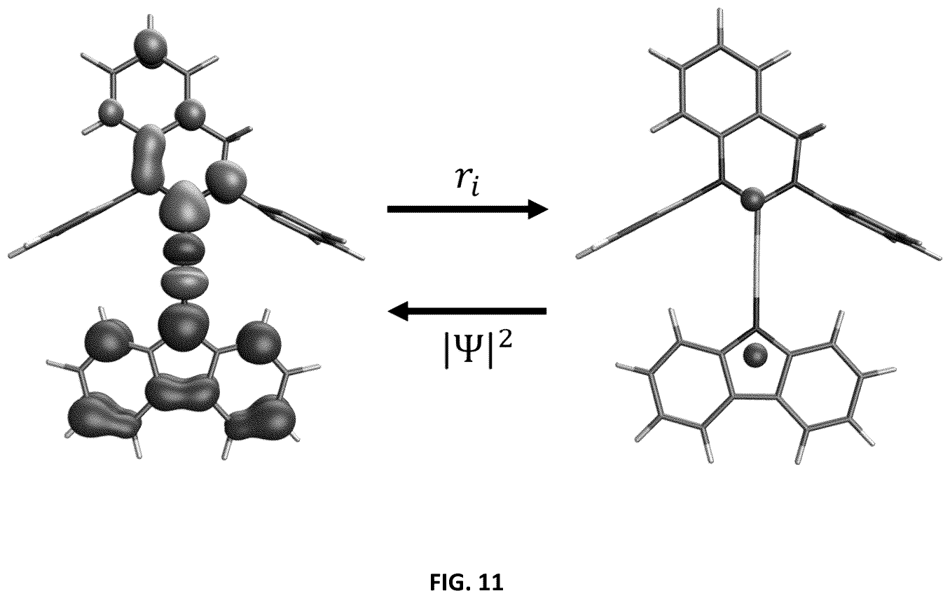

The center of charge for the hole and electron NTOs of a given excited state are extracted from the expectation values of the respective wavefunction positions. Eqns. 4 and 5.

$$〈 {r}_{h +} 〉 = 〈 {Ψ}_{h +} \vert \hat{r} \vert {Ψ}_{h +} 〉 \qquad ( 4 )$$

$$〈 {r}_{e -} 〉 = 〈 {Ψ}_{e -} \vert \hat{r} \vert {Ψ}_{e -} 〉 \qquad ( 5 )$$

where |Ψₕ₊ [symbol] and |ₑ₋ [symbol] represent the hole and electron NTO wavefunctions. The centers of charge are calculated component-wise to extract two vectors, whose termini are the center of charge for the hole or electron, h⁺_{xyz} and e⁻_{xyz}, respectively. The positions of these centers of charge are illustrated in FIG. 11 by placing an atom at the coordinates of h⁺_{xyz} and e⁻_{xyz}. The distance between the charges [d(h⁺, e⁻)] for each cMa are determined algebraically from h⁺_{xyz} and e⁻_{xyz}.

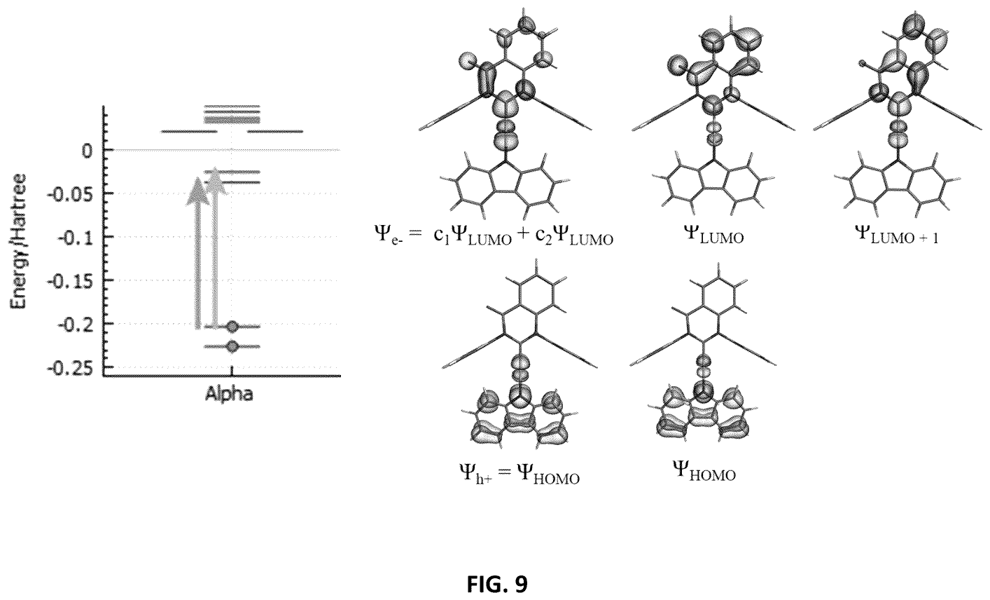

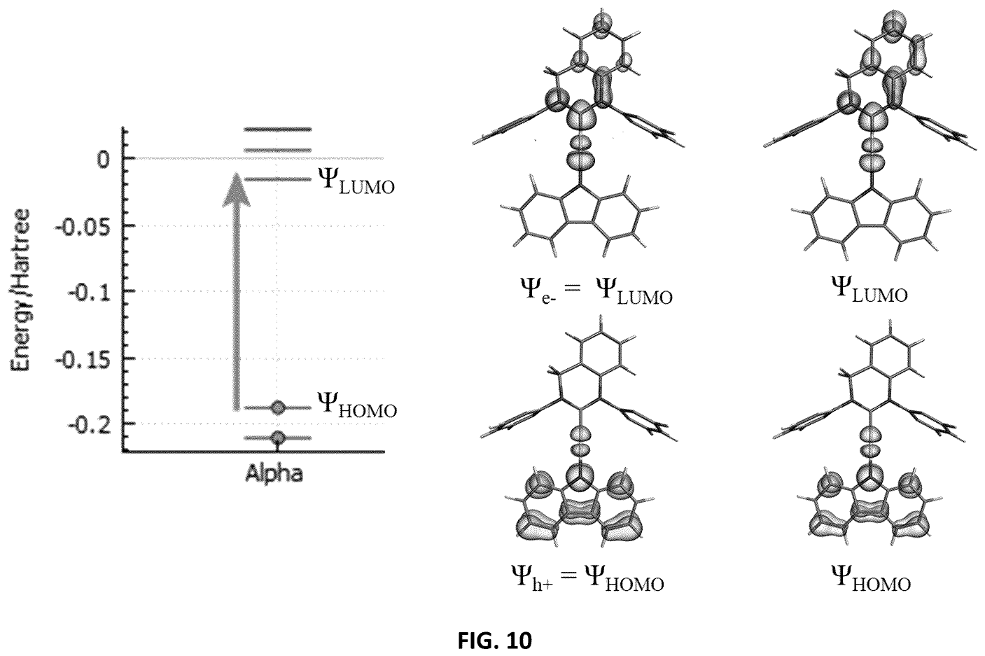

Natural transition orbitals were generated by performing a singular value decomposition on the transition density matrix using the Q-Chem software package. The resultant eigenstates are a linear combination of molecular orbitals involved in the S₀→Sₙ transition which are separated into hole and electron pairs. The advantage of NTOs is that electronic transitions are often composed of more than two molecular orbitals (i.e., HOMO to LUMO). Interestingly, the HOMO and LUMO of the compounds in this work make up >99.9% of the S₀→S₁ transition, aside from the PAC complexes which mix the LUMO+1 into the electron NTO. This is demonstrated with Au_{Cz}^{BZAC} and Au_{Cz}^{PAC} as example compounds in FIG. 9 and FIG. 10 respectively.

All PAC compounds give a mixed LUMO/LUMO+1 behavior in the electron NTO which is consistent with the electron NTO being consistent for a given carbene across different metals and donors. However, the Ipr, CAAC, BZAC, BZI, and MAC complexes all have S₁→S₀ NTOs that are described purely by the HOMO and LUMO, localized on the amide and carbene ligands, respectively. Further, all compounds in this study are described by a single hole and electron NTO pair. This simplifies overlap integral calculations which will be described in the next section.

### Overlap

The spatial NTO overlap integrals Λ_{NTO} were calculated for these compounds. This calculation makes use of the integral below, which computes a weighted average of spatial overlap of all NTO pairs that contribute to the excited state

$${Λ}_{N T O} \approx \frac{{Σ}_{k} {c}_{k} \vert {φ}_{k , h +} \vert \vert {φ}_{k , e -} \vert d τ}{{Σ}_{k} {c}_{k}} \qquad ( 6 )$$

As aforementioned, all compounds in the study only require one electron/hole NTO pair to describe the excited state which simplifies the integral to equation 3. However, it should be noted that all computed integrals were performed rigorously using the above equation and not the simplified version seen in equation 3 of the manuscript. The overlap calculations reveal the drawbacks of relying on isovalue representations of the wavefunction. All NTO/MO visualizations with isovalue=0.1 suggest that the hole and electron wavefunctions have very poor spatial overlap, and that most of the overlap comes from the metal d orbital. Certainly, one would not expect the calculated Λ_{NTO} values of 26-43% based on the wavefunction images in FIGS. 9 and 10. Thus, iso-value representations must be viewed with caution because the viewer does not know the probability of finding an electron within that surface, but only the isosurface corresponding to a probability per unit volume. In the case of cMa complexes, the volume within isovalue=0.1 only contains 15% probability of finding an electron within the surface, which explains why the overlap integral can be large despite the isovalue=0.1 visualization.

While overlap integrals give a more quantitative and accurate picture of the spatial overlap of hole and electron NTOs, it still fails to be a reliable parameter in predicting the parameters that account for the TADF rate kᵣ(S₁) and ΔE_{ST}. The problem is that the integrals that govern kᵣ(S₁) and ΔE_{ST} are not purely overlap integrals of Ψₕ₊ and Ψₑ₋. For example, the Strickler-Berg relationship¹⁰ is related to the transition dipole between two states by¹¹

$${k}_{r} ( {Ψ}_{1} \to {Ψ}_{2} ) = \frac{8 {π}^{2} {〈 {\tilde{ν}}_{f} 〉}^{3}}{3 {h}^{2}} {\vert 〈 {Ψ}_{1} \vert \hat{μ} \vert {Ψ}_{2} 〉 \vert}^{2} \qquad ( 7 )$$

and ΔE_{ST} is governed by the exchange integral

$$Δ {E}_{S T} = 2 〈 {Ψ}_{1} \vert \frac{1}{r} \vert {Ψ}_{2} 〉 \qquad ( 8 )$$

Many research groups identify the integrals in (7) and (8) and make the assumption that they trend well with the ordinary overlap integral Λ_{NTO}. However, this is only true in the limit of complete charge separation, where equation S1, S2, and S3 all converge to 0. Since the overlap calculations for two-coordinate cMa complexes with coplanar ligands is typically between 23-46%, this assumption cannot be made.

### Center of Charge and +/−Separation

The integrals in equations 7 and 8 both have operators that completely change the outcome of integration. Integration relies heavily on symmetry and operators, thus a more straightforward parameter is desirable to predict kᵣ(S₁) and ΔE_{ST}, and kᵣ(TADF). The problem can be reduced to the center of charge of the hole and electron wavefunctions. The center of charge for the hole and electron NTOs of a given transition are extracted from the position expectation values of the respective wavefunctions

$$〈 {r}_{h +} 〉 = 〈 {Ψ}_{h +} \vert \hat{r} \vert {Ψ}_{h +} 〉 \qquad ( 9 )$$

$$〈 {r}_{e -} 〉 = 〈 {Ψ}_{e -} \vert \hat{r} \vert {Ψ}_{e -} 〉 \qquad ( 10 )$$

where |Ψₕ₊ [symbol] and |Ψₑ₋ [symbol] represent the hole and electron NTO wavefunctions. This can be calculated component-wise to extract the vectors

$${\vec{r}}_{h +} = {\sum }_{j} 〈 {Ψ}_{h +} \vert {\hat{r}}_{j} \vert {Ψ}_{h +} 〉 \vert j 〉 \qquad ( 11 )$$

$${\vec{r}}_{e -} = {\sum }_{j} 〈 {Ψ}_{e -} \vert {\hat{r}}_{j} \vert {Ψ}_{e -} 〉 \vert j 〉 \qquad ( 12 )$$

where j represents a direction in a coordinate system. The +/−separation is the difference of equation 11 and 12

$$d ( {h}^{+} , {e}^{-} ) = \vert {\vec{r}}_{h +} - {\vec{r}}_{e -} \vert \qquad ( 13 )$$

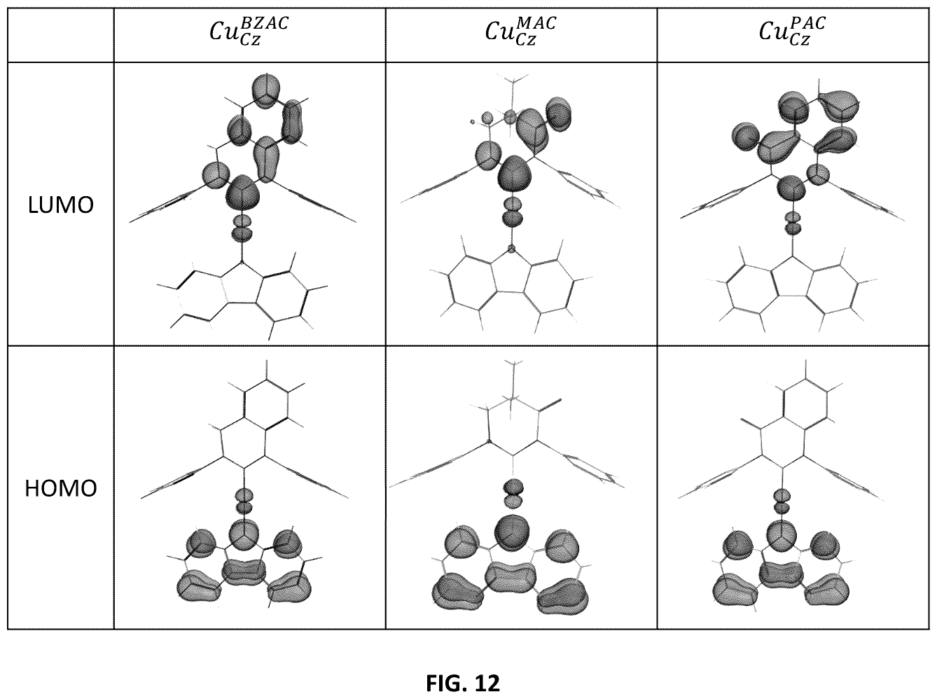

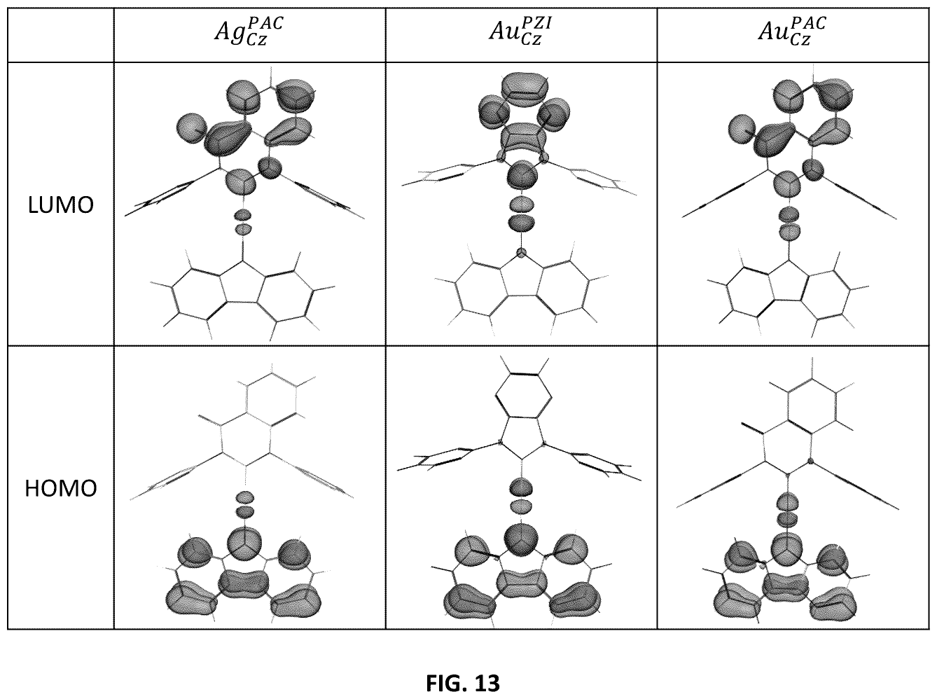

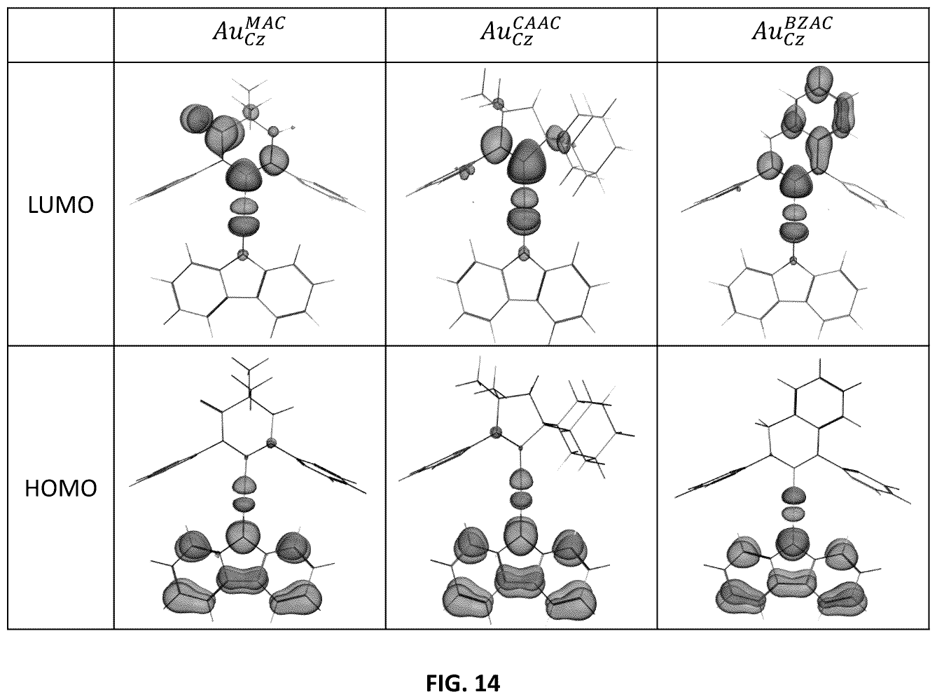

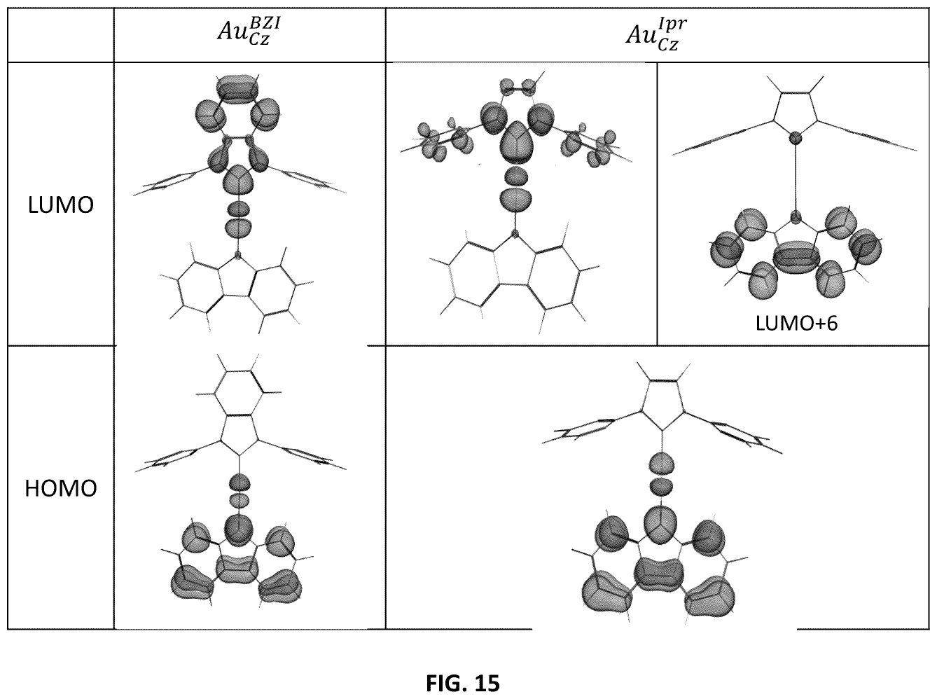

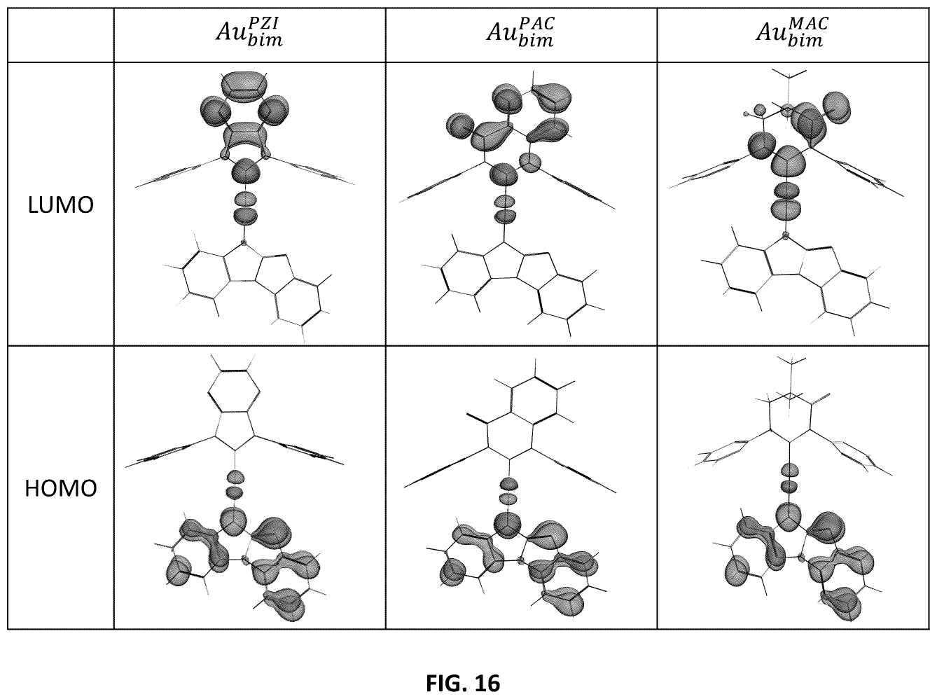

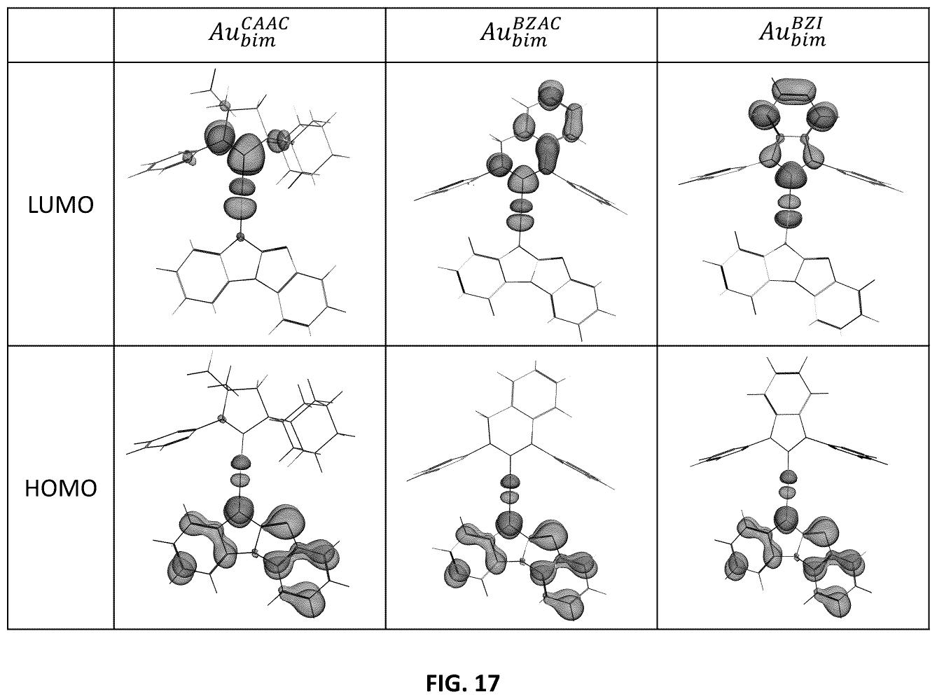

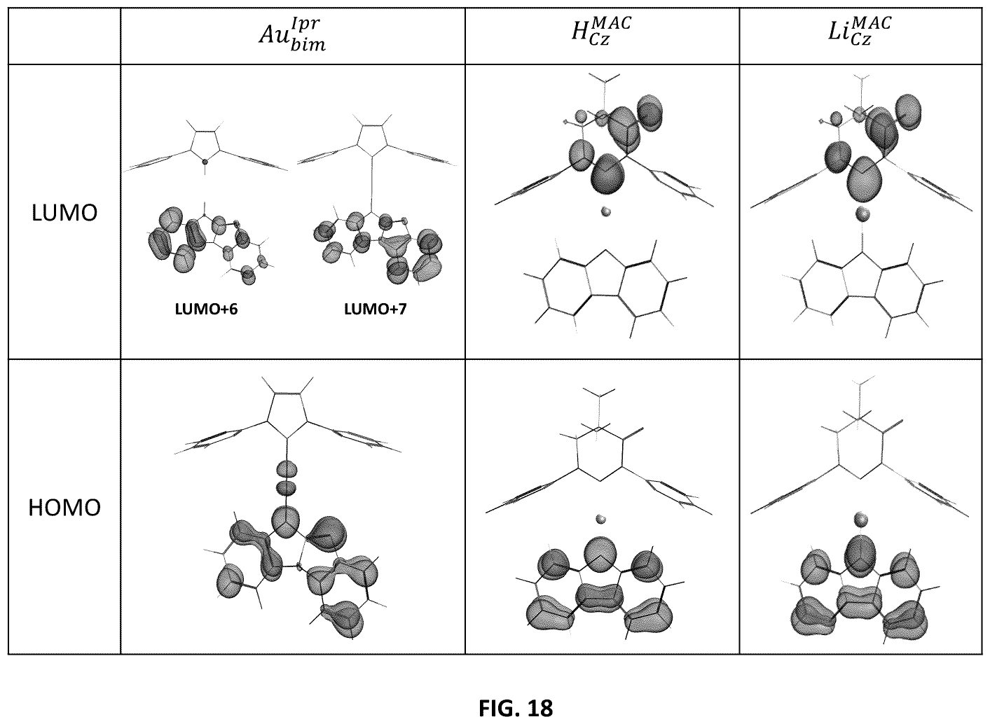

which describes the separation between the hole and electron charges that constitute the exciton. Equations 11 and 12 are useful for visualizing the charges because a pseudo-particle can be imposed on the corresponding molecule by letting |j [symbol] represent molecular coordinates as demonstrated in FIG. 11. Again, the centers of charge are readily determined with the QChem software package. Center of charge descriptions are a much simpler parameter to understand compared to the wavefunction overlap Λ_{NTO}. Similar behavior can be expected; as the +/−separation increases, the exchange integral and the Einstein radiative rate should decrease. The utility of the center of charge descriptor is that it simply describes where the wavefunctions are centered, rather than integrating their products. HOMO and LUMO orbitals of the compounds studied are depicted in FIGS. 12 to 18.

TABLE 5
Hole/electron separation distances
for (carbene)Au(amide) complexes.

d(h⁺, e⁻) (Å)

| Au_{amide}^{Carbene} | Cz | bim |
|---|---|---|
| Ipr | 3.94 | 4.31 |
| BZI | 5.15 | 5.51 |
| BZAC | 5.08 | 5.36 |
| CAAC | 4.43 | 4.74 |
| MAC | 5.16 | 5.47 |
| PAC | 5.55 | 5.86 |
| PZI | 6.54 | 6.96 |

TABLE 6
Compositions of the S₁ and T₁ states for the cMa complexes. The percent composition
was calculated by normalizing square of the relative amplitudes of MOs involved
in the transition to the sum of the squares of the relative amplitudes.

| | S₁ Decomposition | T₁ Decomposition |
|---|---|---|
| Cu_{Cz}^{BZAC} | HOMO → LUMO: 100% | HOMO → LUMO: 94% |
| | | HOMO → LUMO + 6: 6% |
| Cu_{Cz}^{MAC} | HOMO → LUMO: 100% | HOMO → LUMO: 100% |
| Cu_{Cz}^{PAC} | HOMO → LUMO: 70% | HOMO → LUMO: 58% |
| | HOMO → LUMO + 1: 30% | HOMO → LUMO + 1: 42% |
| Ag_{Cz}^{PAC} | HOMO → LUMO: 73% | HOMO → LUMO: 63% |
| | HOMO → LUMO + 1: 27% | HOMO → LUMO + 1: 37% |
| Au_{Cz}^{PAC} | HOMO → LUMO: 72% | HOMO → LUMO: 59% |
| | HOMO → LUMO + 1: 28% | HOMO → LUMO + 1: 41% |
| Au_{Cz}^{MAC} | HOMO → LUMO: 100% | HOMO → LUMO: 100% |
| Au_{Cz}^{CAAC} | HOMO → LUMO: 100% | HOMO → LUMO: 100% |
| Au_{Cz}^{BZAC} | HOMO → LUMO: 100% | HOMO → LUMO: 94% |
| | | HOMO → LUMO + 6: 6% |
| Au_{Cz}^{BZI} | HOMO → LUMO: 100% | HOMO → LUMO: 93% |
| | | HOMO → LUMO + 6: 7% |
| Au_{Cz}^{Ipr} | HOMO → LUMO: 100% | HOMO → LUMO: 54% |
| | | HOMO → LUMO + 6: 45% |
| Au_{bim}^{PAC} | HOMO → LUMO: 72% | HOMO → LUMO: 62% |
| | HOMO → LUMO + 1: 28% | HOMO → LUMO + 1: 38% |
| Au_{bim}^{MAC} | HOMO → LUMO: 100% | HOMO → LUMO: 100% |
| Au_{bim}^{CAAC} | HOMO → LUMO: 100% | HOMO → LUMO: 100% |
| Au_{bim}^{BZAC} | HOMO → LUMO: 100% | HOMO → LUMO: 100% |
| Au_{bim}^{BZI} | HOMO → LUMO: 100% | HOMO → LUMO: 100% |
| Au_{bim}^{Ipr} | HOMO → LUMO: 100% | HOMO-2 → LUMO + 11: 11% |
| | | HOMO-1→ LUMO + 6: 7% |
| | | HOMO-1→ LUMO + 7: 9% |
| | | HOMO → LUMO + 6: 38% |
| | | HOMO → LUMO + 7: 35% |
| H_{Cz}^{MAC} | HOMO → LUMO: 100% | HOMO → LUMO + 1: 87% |
| | | HOMO → LUMO + 2: 6% |
| | | HOMO → LUMO + 3: 6% |
| Li_{Cz}^{MAC} | HOMO → LUMO: 100% | HOMO → LUMO: 100% |

TABLE 7
Dipole moments of the ground, S1 and T1 states. These values
were determined form DFT and TDDFT modeling studies. Ground
state dipoles are oriented along the M—N bond, from
the metal toward the amide. Excited state dipoles are oriented
in the opposite direction, toward the carbene.

| | μ - S₀ | μ - S₁ | μ - T₁ | Δμ (S₀-S₁) | Δμ (S₀-T₁) |
|---|---|---|---|---|---|
| | (D) | (D) | (D) | (D) | (D) |
| Cu_{Cz}^{BZAC} | 11.6 | −12.4 | −10.4 | 24 | 22 |
| Cu_{Cz}^{MAC} | 10.1 | −15.3 | −13.6 | 25.4 | 23.7 |
| Cu_{Cz}^{PAC} | 10.4 | −16.8 | −14.4 | 27.2 | 24.8 |
| Ag_{Cz}^{PAC} | 11.9 | −19.3 | −17.7 | 31.2 | 29.6 |
| Au_{Cz}^{PAC} | 10.0 | −17.6 | −15.2 | 27.6 | 25.2 |
| Au_{Cz}^{MAC} | 9.8 | −15.9 | −14.5 | 25.7 | 24.3 |
| Au_{Cz}^{CAAC} | 15.3 | −10.1 | −8.84 | 25.4 | 24.14 |
| Au_{Cz}^{BZAC} | 11.4 | −12.8 | −10.7 | 24.2 | 22.1 |
| Au_{Cz}^{BZI} | 11.2 | −13.4 | −10.7 | 24.6 | 21.9 |
| Au_{bim}^{PAC} | 8.2 | −20.2 | −17.8 | 28.4 | 26 |
| Au_{bim}^{MAC} | 10.3 | −18.3 | −16.8 | 28.6 | 27.1 |
| Au_{bim}^{CAAC} | 10.6 | −12.7 | −11.0 | 23.3 | 21.6 |
| Au_{bim}^{BZAC} | 10.7 | −15.0 | −12.5 | 25.7 | 23.2 |
| Au_{bim}^{BZI} | 10.8 | −15.8 | −13.1 | 26.6 | 23.9 |
| Au_{bim}^{Ipr} | 11.0 | −9.9 | 12.3* | 20.9 | −1.3 |
| H_{Cz}^{MAC} | 11.6 | −18.2 | −15.8 | 29.8 | NA |
| Li_{Cz}^{MAC} | 11.5 | −15.7 | −15.4 | 27.2 | NA |

*The T₁ for Au_{bim}^{Ipr} is not an ICT state but is localized on the bim ligand.

### Photophysical Measurements

Samples in fluid solution were both sparged and examined under N₂. Doped polystyrene thin films were prepared from a solution of polystyrene in toluene, drop cast onto a quartz substrate and measured under N₂. The UV-visible spectra were recorded on a Hewlett-Packard 4853 diode array spectrometer. Steady state excitation and emission spectra were obtained using a Photon Technology International QuantaMaster spectrofluorimeter. Photoluminescence quantum yields were recorded using a Hamamatsu C9920 integrating sphere equipped with a xenon lamp. Luminescence lifetimes were measured using Time-Correlated Single Photon Counting (TCSPC) on an IBH Fluorocube apparatus interfaced to a Horiba FluoroHub+ controller.

Variable temperature photophysical measurements were carried out on a Janis SHI-4-2 (0.2 W 4K) optical cryocooler. The IBH Fluorocube was used as a detector for luminescence lifetimes and the Photon Technology International QuantaMaster spectrofluorimeter as a detector for steady state emission spectra with 375 nm LED (Thorlabs M375L4, 1270 mW) as excitation source. Doped polystyrene thin films were spin coated onto a round sapphire substrate that was used to insure good thermal conductivity at low temperatures.

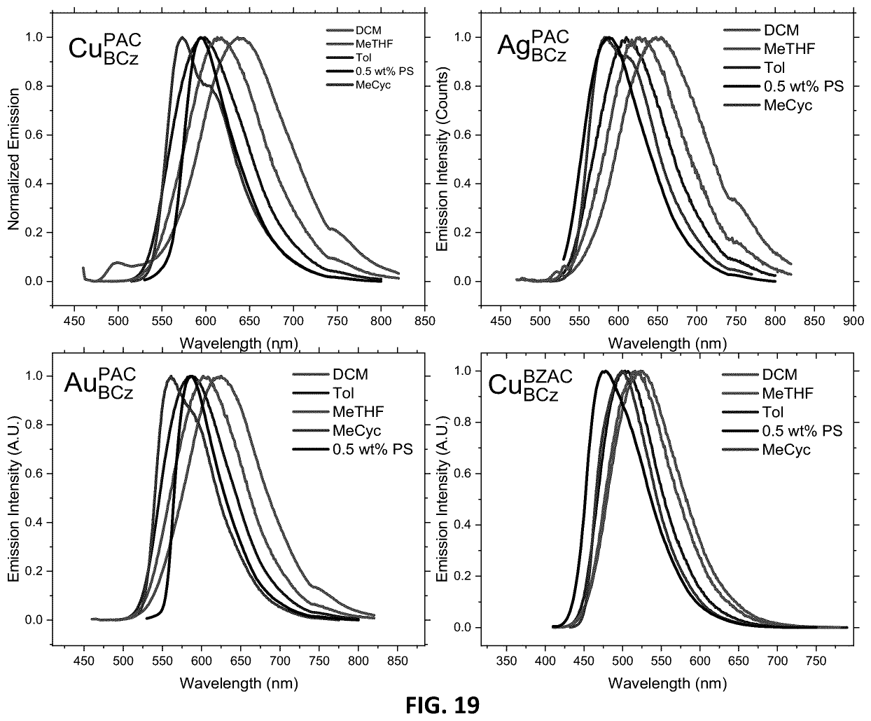

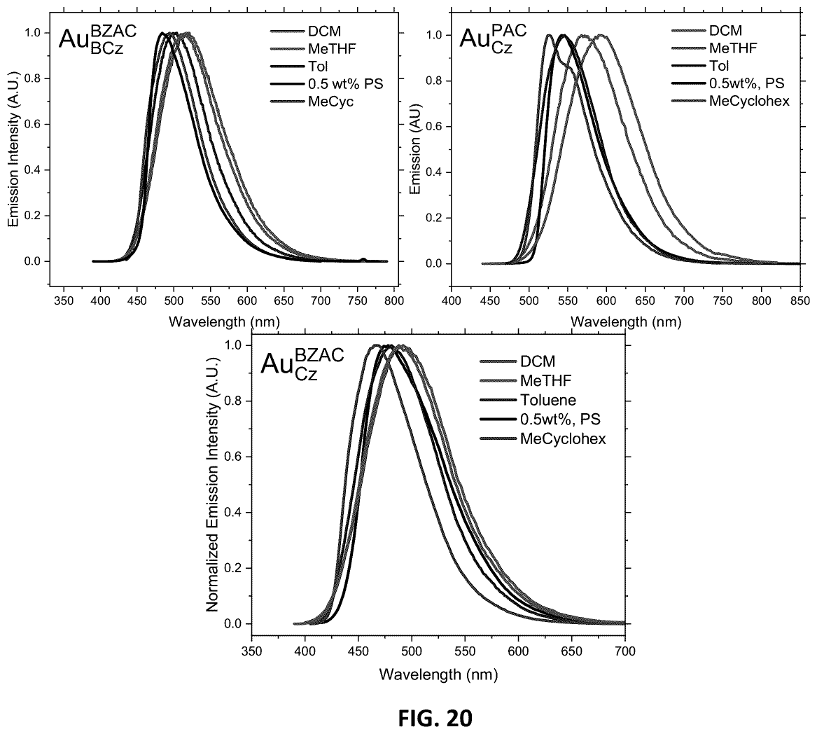

The photophysical data are depicted in FIG. 19 and FIG. 20.

### Temperature Dependent Photophysics and Boltzmann Fitting

Cryogenic photophysical measurements were carried out on a Janis SHI-4-2 cryostat with a Lakeshore 335 Temperature controller and evacuated by an Drytel 31 Turbomolecular pump to 1.2×10⁻⁴ mTorr. Doped polystyrene thin films spin coated on a round sapphire substrate were used for good thermal conductivity. Experiments showed that the thermal conductivity of the quartz substrates was too low and only sapphire is thermally conductive enough to effectively reach 4 K inside the polystyrene film. This was checked by measuring the lifetime of fac-Ir (ppy) 3 doped into polystyrene and PMMA films (Hofbeck, T.; Yersin, H., The Triplet State of fac-Ir(ppy)3. Inorganic Chemistry 2010, 49 (20), 9290-9299).

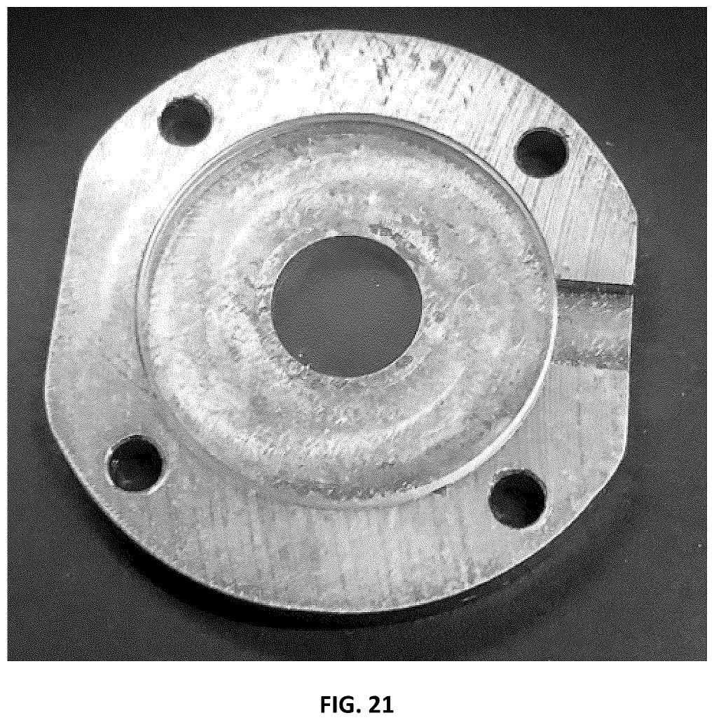

The original sample holder was modified in a way, that the emitted light can be collected from the side of the sapphire substrate, as the outcoupling efficiency is highest and the unwanted collected excitation light is minimal in this set-up geometry. A modified sample holder is shown in FIG. 21.

The emitted light was collimated by an Edmund Optics 45-716 Lens (Focus: 75 mm. Ø 50 mm, VIS—NIR coating for 400-1000 nm) and focused with an Edmund Optics 47-393 Lens (Focus: 125 mm, Ø 50 mm, VIS—NIR coating for 400-1000 nm) Lens onto a Thorlabs BF13LSMA02 (400-2200 nm, Ø 1.3 mm) optical fiber connected to a Thorlabs bifurcated fiber BF19Y2LS02 (250-1200 nm, 19 Fiber, Ø 200 μm) with 10 fibers ending in the TCSPC and 9 fibers in the fluorimeter.

Emission spectra were collected with a Photon Technology International QuantaMaster spectrofluorimeter. As Excitation source a 365 nm LED (Thorlabs M365L3 365 nm LED, 1000 mW) equipped with the Thorlabs SM1U25-A Adjustable Collimation Adapter and driven with a Thorlabs LEDD1B driver.

For luminescence lifetime studies a Horibia Fluorohub+ with a Horiba Jobin Yvon detector with monochromator was used. As excitation source a NanoLED 407N (405 nm) or IBH SpectraLED S-03 (372 nm) was used.

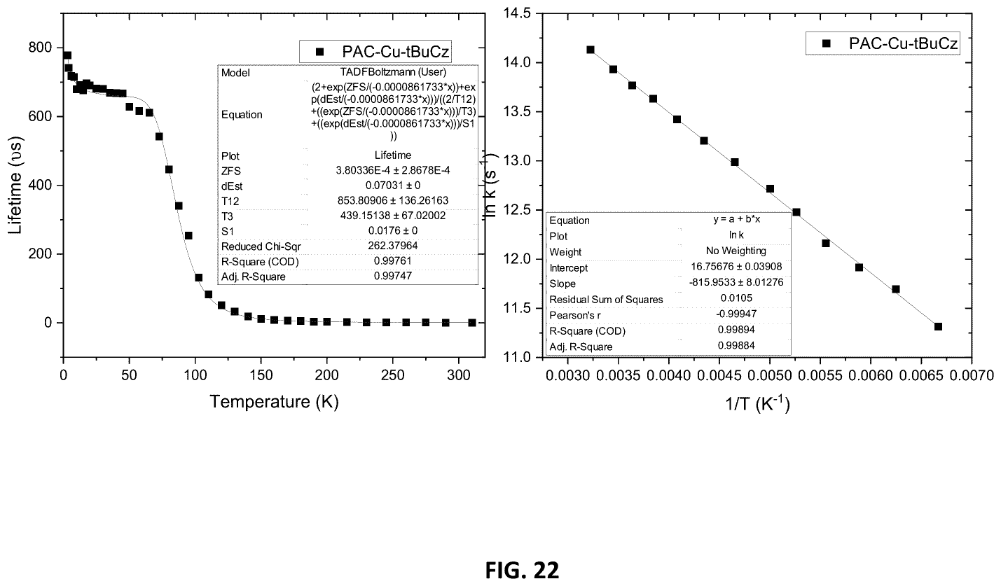

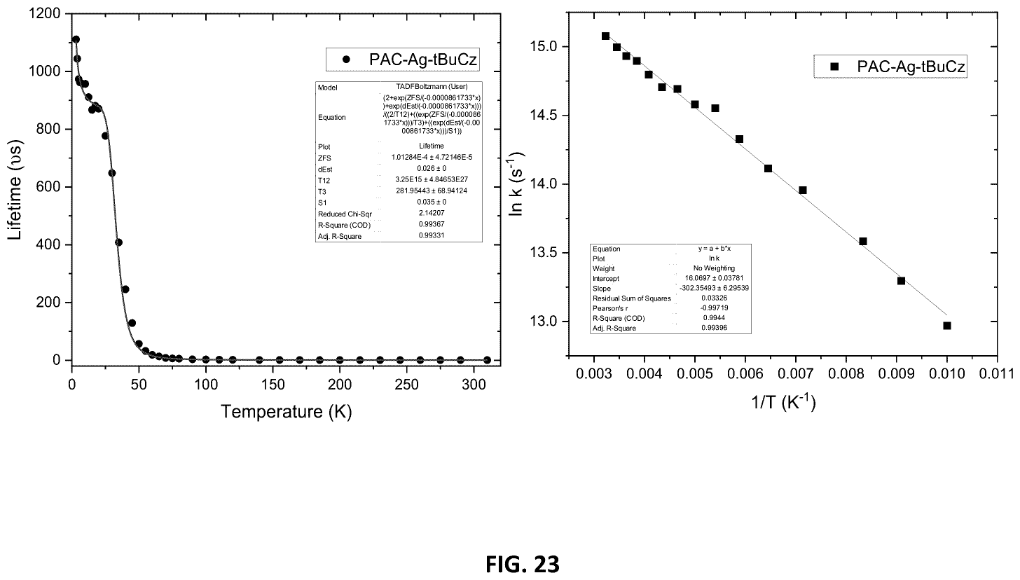

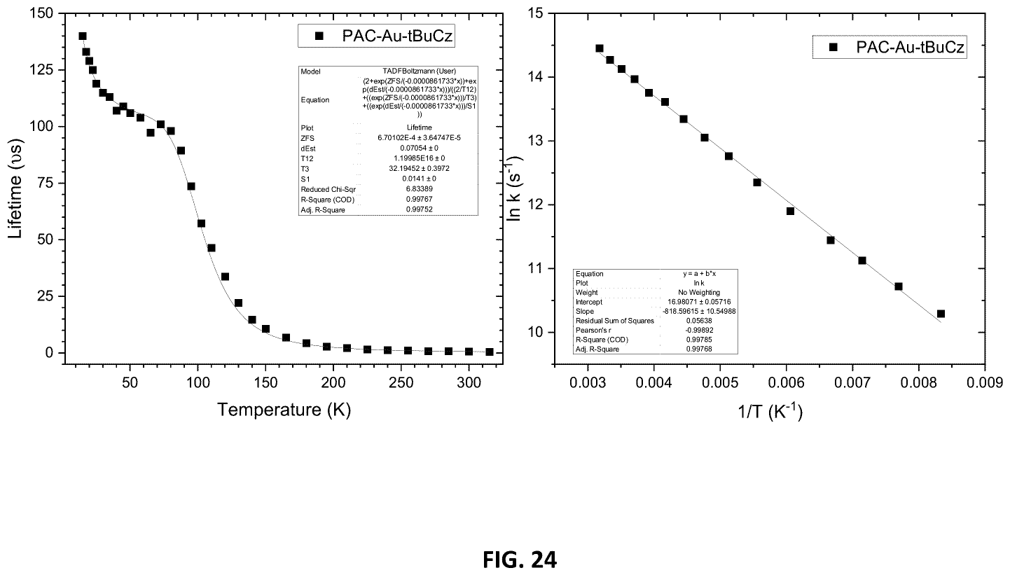

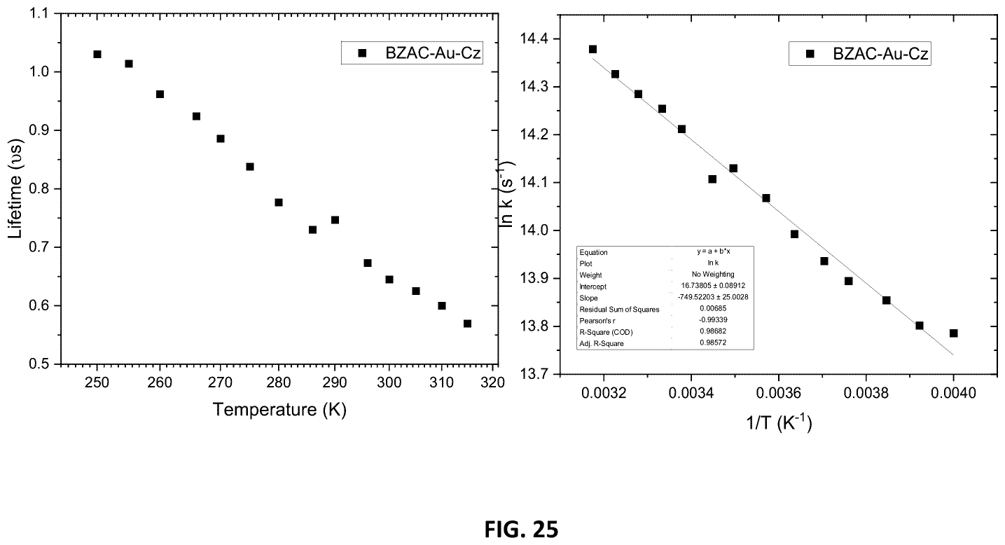

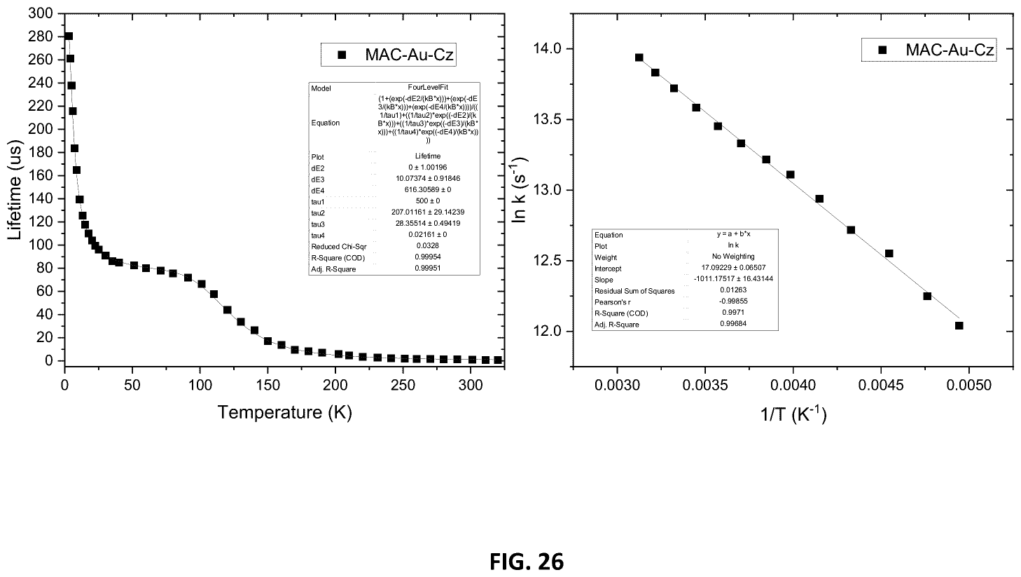

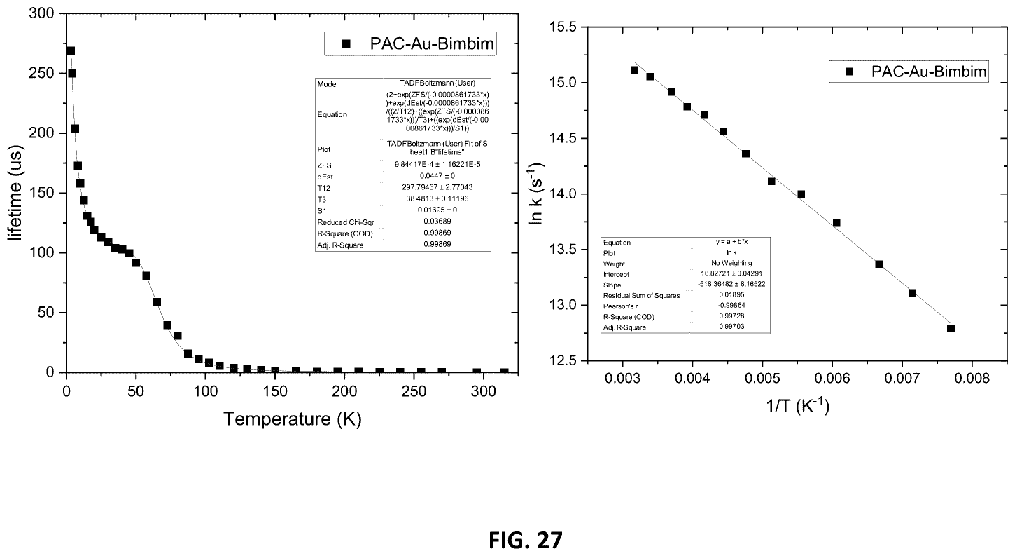

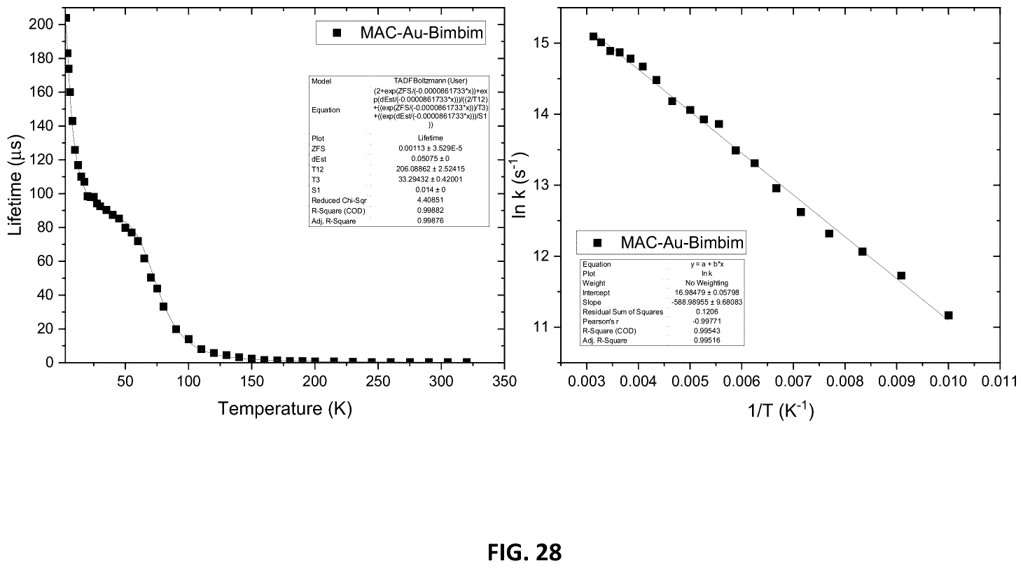

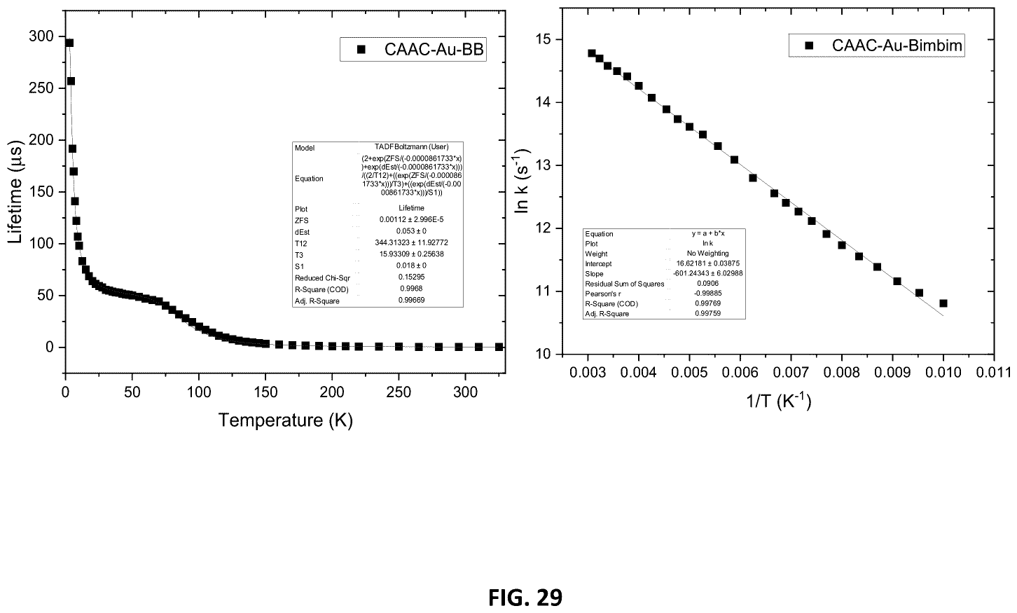

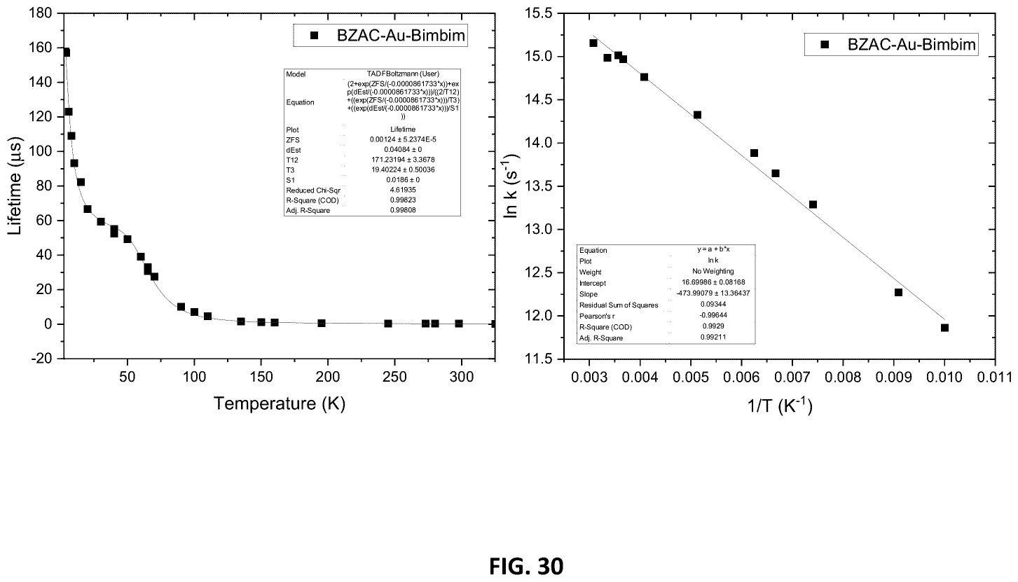

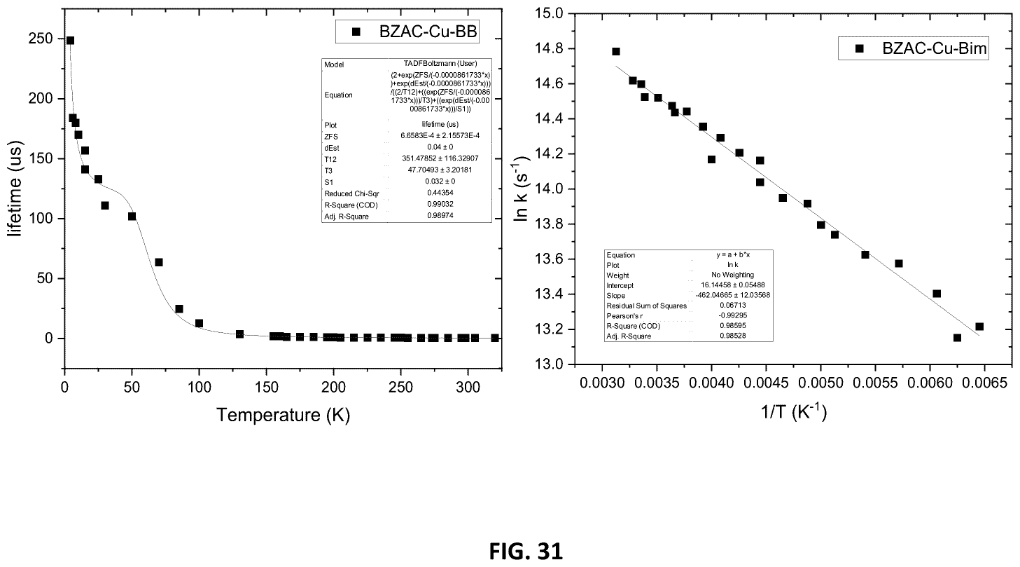

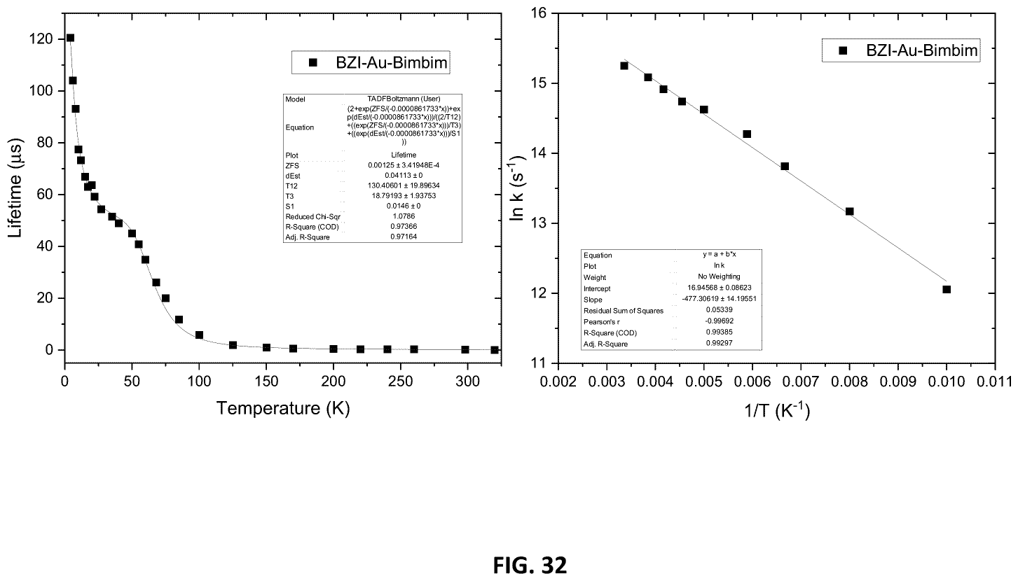

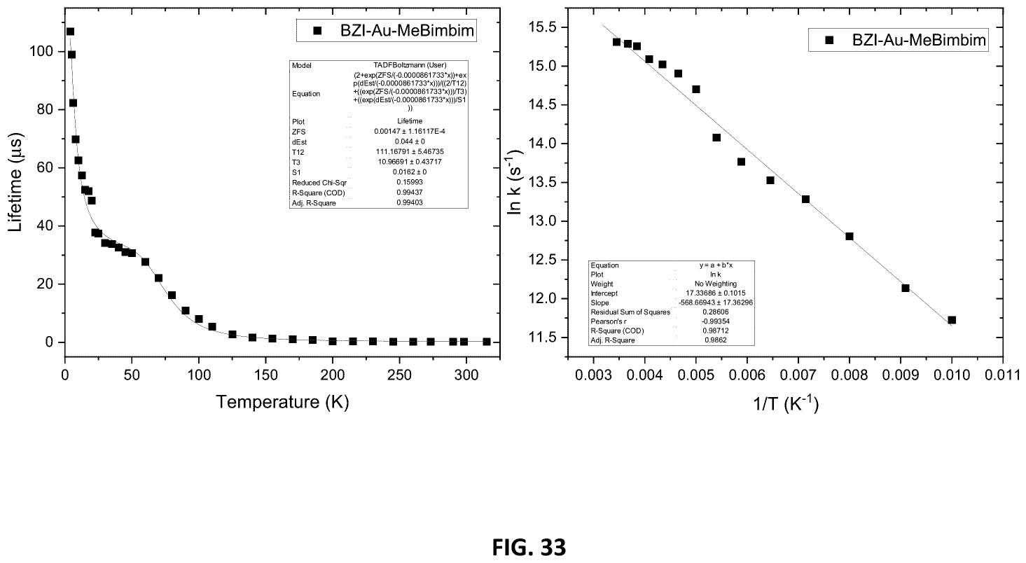

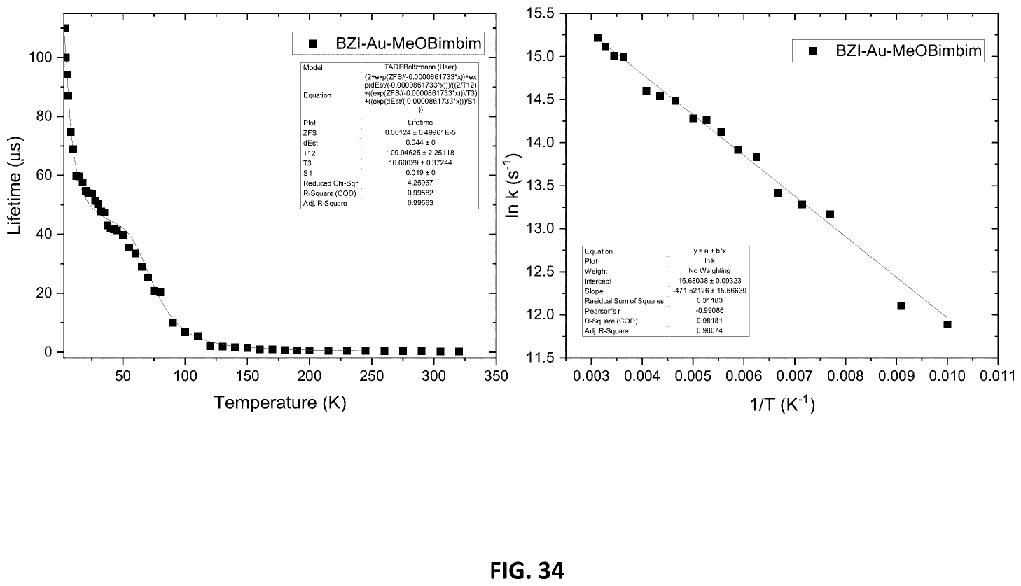

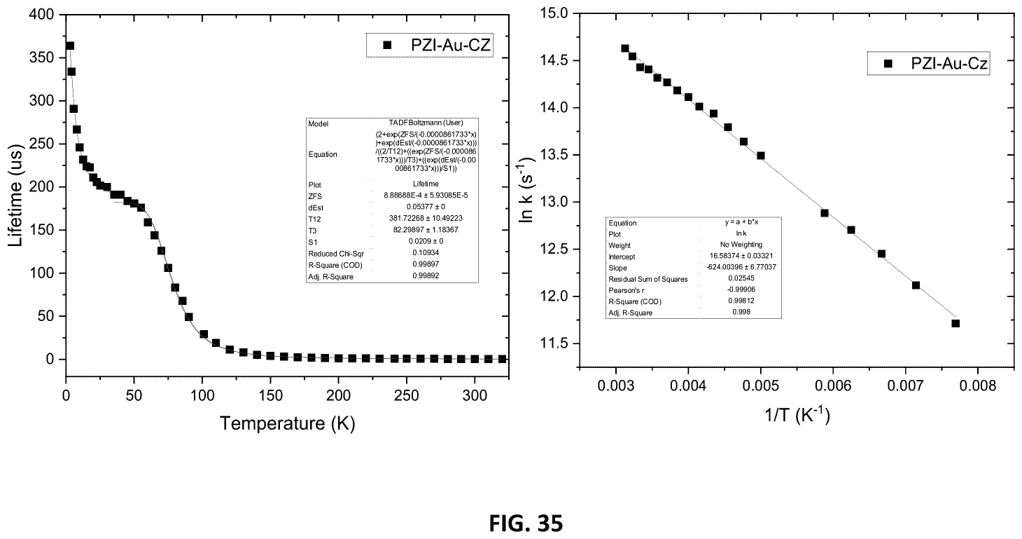

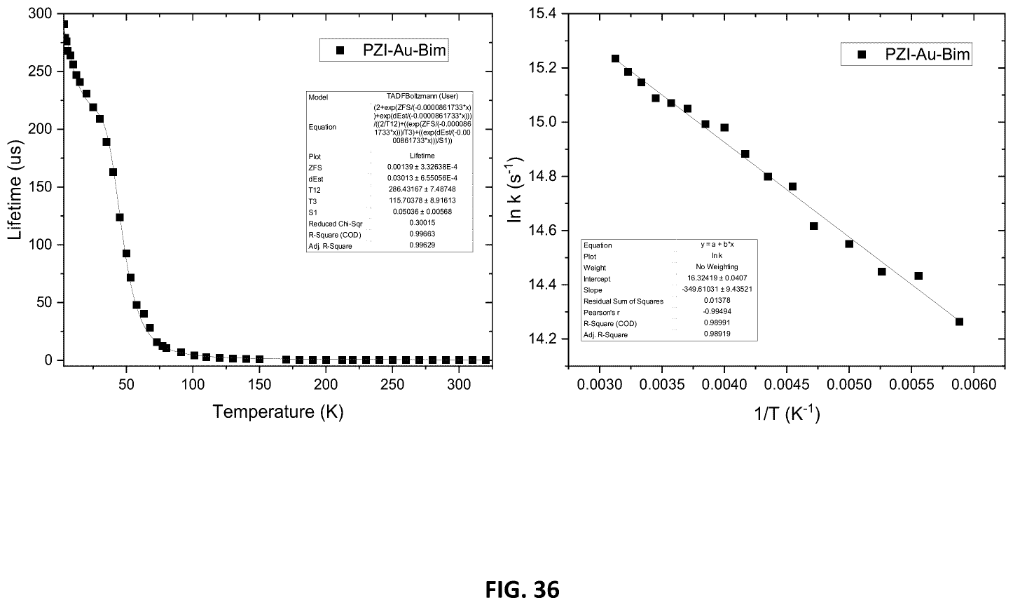

Values for the measured lifetime were plotted against temperature to obtain the plots FIGS. 22 to 36. High temperature data from 150 K-300 K were fitted to an Arrhenius equation (Hamze, et al. Journal of the American Chemical Society 2019, 141 (21), 8616-8626). The plots of ln(k_{TADF}) vs. 1/T are given below with their linear fit values. ΔE_{ST} and τ_{S1} was obtained from the slope and intercept respectfully.

Zero-Field Splitting (ZFS) and τ_{T3} was obtained from Boltzmann fits of the plots lifetime vs, temperature using the following equation:

$$τ = \frac{2 + {e}^{- \frac{Δ E ( III - I , II )}{{k}_{B} T}} + {e}^{- \frac{Δ E ( {S}_{1} - I , II )}{{k}_{B} T}}}{2 ( \frac{1}{{k}_{I , II}} ) + ( \frac{1}{{k}_{III}} ) {e}^{- \frac{Δ E ( III - I , II )}{{k}_{B} T}} + ( \frac{1}{{k}_{fl}} ) {e}^{- \frac{Δ E ( {S}_{1} - I , II )}{{k}_{B} T}}}$$

Statistical weighing was used in fits to prevent a higher contribution of long lifetimes. The previously determined ΔE_{ST} and τ_{S1} were used as fixed parameters in the equation. τ_{T1,2} could not be reliably determined due to insufficient data below 4 K. The Temperature dependent lifetimes (Boltzmann fit at left; Arrhenius plot at right) for the cMa complexes considered herein are presented in FIGS. 22 to 36.

### Results

### Synthesis and Characterization

A range of cMa complexes have been prepared (FIG. 4). In these materials we have varied the carbene fairly extensively and looked at both N-carbazolide (Cz) and N-benzo[d]benzo[4,5]imidazo[1,2-a]imidazolyl (bim) amides. Part of this study is to investigate two new carbene ligands for cMa complexes, i.e. BZAC and PAC, so the carbazolide complexes were made for these two carbenes with Cu. Ag and Au to compare to other (carbene)M(Cz) compounds. Although we were able to prepare pure samples of the PAC-based materials for all three metals, we were only able to synthesize the Cu and Au complexes with BZAC. It appears that thermal instability of Ag_{Cz}^{BZAC} and Ag_{BCz}^{BZAC} preclude their isolation. While the BZAC and PAC carbazolide cMa complexes have not been reported, the (carbene)Au(Cz) complexes for IPr, BZI, PZI, CAAC and MAC have been reported previously and are considered here as well (Yang, et al., Chemistry-A European Journal 2021, 27 (71), 17834-17842; Tang, et al., Angewandte Chemie International Edition 2022, 61 (33), e202203982). Although much of the previous work involved unsubstituted carbazole groups. The addition of tBu groups to the 3,6-positions of the carbazole (BCz) led to greater solubility which facilitated solution and thin film photophysical studies. The solubility of the bim based cMa complexes are similar to their BCz analogs.

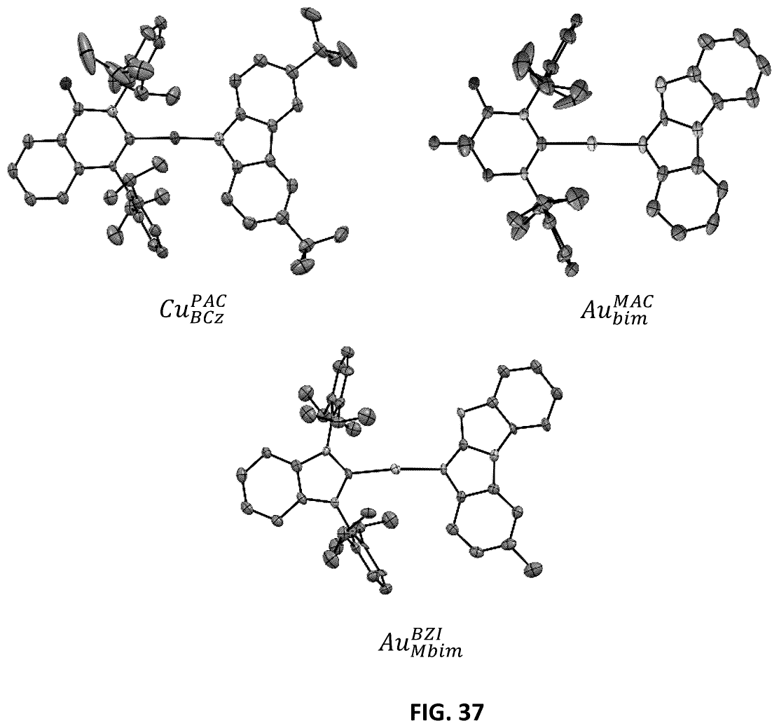

Single crystal X-ray diffraction was used to determine the molecular structures of Cu_{BCz}^{PAC}, Au_{Cz}^{BZAC}, Au_{bim}^{BZAC}, Au_{bim}^{CAAC}, Au_{bim}^{MAC}, Au_{bim}^{PAC} and Au_{Mbim}^{BZI}. Crystallographic data for Cu_{BCz}^{PAC}, Au_{bim}^{MAC} and Au_{bim}^{BZI} are shown in FIG. 37. All the complexes have a coplanar conformation of carbene and amide ligands (dihedral angles=0.7-7.3°) and close to 180° angle around the metal center (C—Au—N=174-179°). The C—Au bond lengths are in the range 1.97-2.01 Å and the Au—N bond is 2.01-2.03 Å. Values for the C—Au and Au—N bond lengths are similar to analogous (carbene)M(Cz) complexes published previously. The Cu compound structurally characterized in this report. Cu_{BCz}^{PAC}, has C—Cu and Cu—N bond lengths of 1.89 Å and 1.85 Å, respectively, that are shorter than the Au based compounds and consistent with the difference in ionic radii of the metals. Two different conformers are possible for Au_{bim}^{MAC}, one with the carbonyl anti to the phenylene (pictured in FIG. 37) and the other where the carbonyl is syn to the phenylene. Both conformers were present in the crystal and the diffraction data was best fit by treating the crystal as disordered with a 10% “impurity” of the syn-conformer in a crystal of the anti-conformer. Only a single conformer for Au_{Bim}^{BZAC}, Au_{Bim}^{PAC} and Au_{Bim}^{CAAC} was observed, even though a similar stereocenter to that of Au_{Bim}^{MAC} was present in these molecules. The crystals of Au_{Mbim}^{BZI} contain two tautomers, with the major component (84%) having the methyl group closest to the Au—N bond (pictured in FIG. 37). The ratio of tautomers in the single crystals is close to the 75:25 ratio observed using NMR spectroscopy.

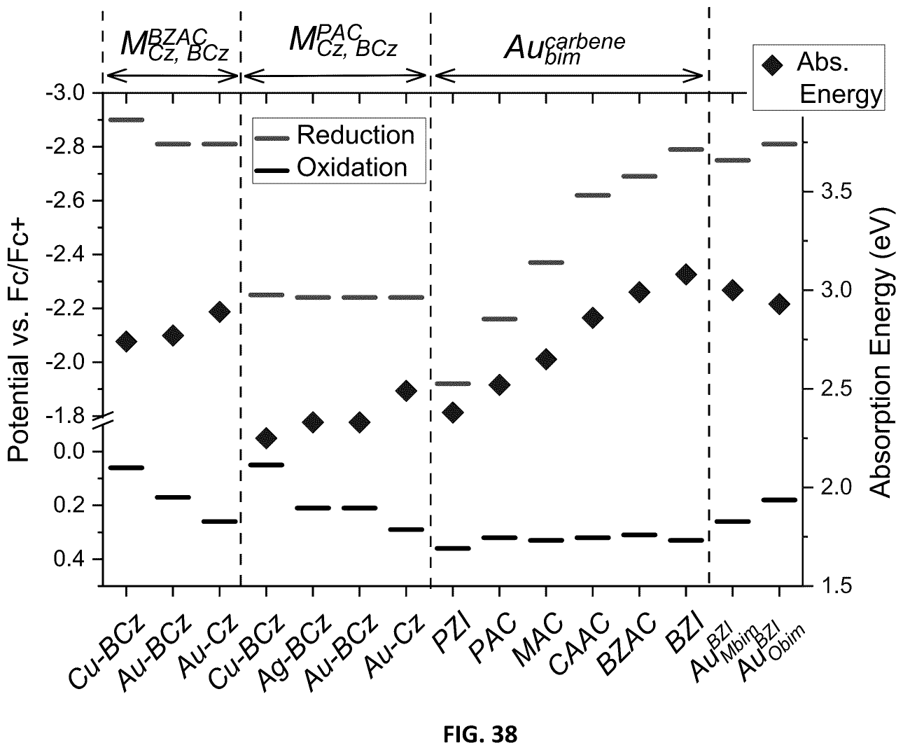

The redox properties of the cMa complexes were examined by cyclic and differential pulse voltammetry in dimethylformamide (DMF), and the potentials relative to an internal ferrocene reference are listed in Table 4 and graphically presented in FIG. 38. Oxidations are irreversible for all cMa complexes with Cz and bim amides. A common decomposition pathway for carbazoles upon oxidation is dimerization at the 3,6-positions. Alkyl substitution at these sites inhibits this reaction pathway (Karon, et al., Journal of Solid State Electrochemistry 2015, 19 (9), 2601-2610), leading to reversible oxidation for the Au_{BCz}^{BZAC} and Au_{BCz}^{PAC} complexes. The oxidation potentials for silver and gold derivatives of M_{BCz}^{PAC} are similar; however, the copper analog is easier to oxidize. This is contrary to what was observed for the M_{Cz}^{MAC} and M_{Cz}^{CAAC} complexes, where the oxidation and reduction potentials were unaffected by the choice of metal ion. A similar trend is observed for M_{BCz}^{BZAC} where the oxidation potential is lower for the copper derivative than the gold analog. Addition of the tBu groups to Cz destabilizes the oxidation potential for a given complex by ˜100 mV, e.g. Au_{Cz}^{BZAC}/Au_{Cz}^{BZAC} and Au_{Cz}^{PAC}/Au_{BCz}^{PAC}. This effect parallels the shift observed for the energy for the longest wavelength absorption band in the two complexes, which also decreases by roughly 100 mV. The oxidation potentials for complexes with bim ligands are ca. 60 mV greater than those of the analogous Cz based complexes, leading to a similar shift in the absorption energies. The dependence of the absorption energy on the oxidation and reduction potentials of the complex is consistent with an interligand charge transfer (ICT) transition for these complexes, as seen for other cMa complexes. Reduction waves were observed for all complexes except Au_{bim}^{Ipr}, which falls outside the solvent window for DMF. All reductions are reversible, except for derivatives with BZAC ligands. The identity of the metal ion for the complex does not affect the reduction potential (see M_{BCz}^{PAC}). A gradual shift to more negative potentials, along with a concomitant increase in energy for the lowest absorption band, is found upon going from complexes with the PZI, PAC, MAC, CAAC, BZAC and BZI carbenes, which is again consistent with an ICT assignment for the transition.

### Computer Modeling

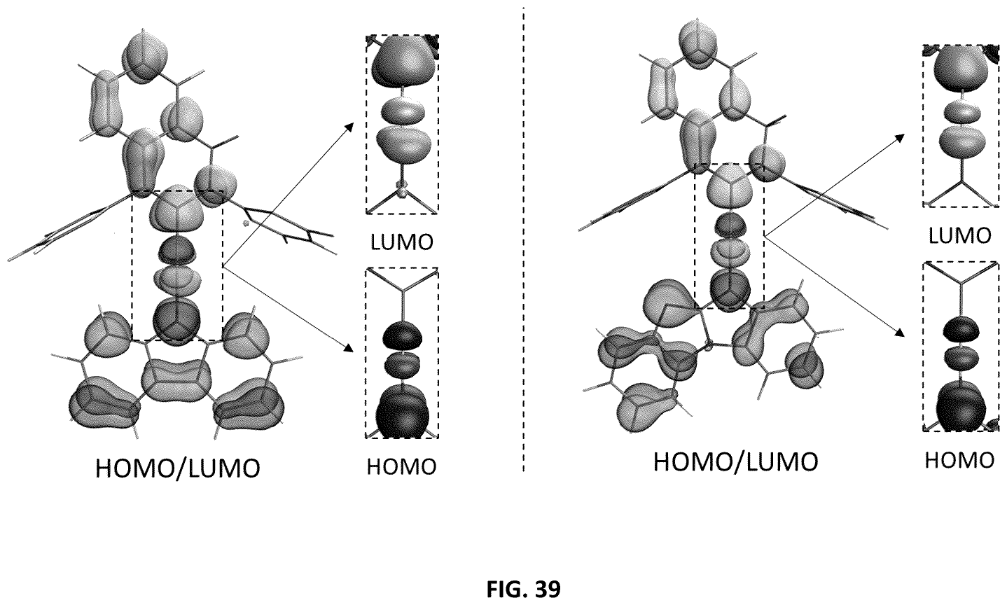

The electronic properties of the complexes were modeled using Density Functional Theory (DFT) and Time Dependent DFT (TDDFT), details are given in the Experimental section. The HOMO and LUMO energies from these calculations are listed in Table 8 and representative orbital isosurfaces shown in FIG. 39. TDDFT methods were used to estimate the oscillator strengths for the singlet transitions, as well as vertical energies and dipole moments for the singlet and triplet excited states. In all cases but Au_{bim}^{Ipr} the transitions from S₀ to the S₁ are ICT in nature and have >99.5% HOMO (amide)→LUMO (carbene) character (Table 6). For the majority of the cMa complexes the T₁ state is comprised of the same orbitals as the S₁ state. The Au_{bim}^{Ipr} and Au_{Cz}^{Ipr} complexes are a special case where the energy of the LUMO is sufficiently destabilized that the lowest triplet state is ³bim and ³Cz, respectively, rather than ³ICT (Tzouras, et al., Chemistry—A European Journal 2021, 27 (46), 11904-11911). The dipole moments for the ground. ¹ICT and ³ICT states are large in magnitude (μ=10-20 D); however, the excited state dipoles are antiparallel to those of the ground state (Table 7). This feature is common in cMa complexes and is a consequence of the high degree of charge transfer in the ICT excited state (FIG. 39). The antiparallel alignment of dipoles gives rise to hypsochromic shifts in absorption and bathochromic shifts for emission in solvents with increasing polarity (FIGS. 19 and 20). The natural transition orbitals (NTOs) for the S₁ state were calculated using the S₀ optimized geometry and the overlap between the hole and electron wavefunctions (Λ_{NTO}) determined as described in the experimental section (Table 8).

TABLE 8
Parameters obtained from DFT and
TDDFT modeling of the cMa complexes.

| | HOMO | LUMO | ΔΕ_{LU-HO} | S₁→S₀ | T₁→S₀ | ΔE_{ST}^{a} | Λ_{NTO} |
|---|---|---|---|---|---|---|---|
| | (eV) | (eV) | (eV) | (eV/f) | (eV) | (eV) | (S₁) |
| Cu_{Cz}^{BZAC} | −4.04 | −1.39 | 2.65 | 2.95/0.12 | 2.76 | 0.19 | 0.36 |
| Au_{Cz}^{BZAC} | −4.18 | −1.41 | 2.76 | 3.10/0.19 | 2.87 | 0.23 | 0.39 |
| Cu_{Cz}^{PAC} | −4.19 | −2.20 | 1.99 | 2.43/0.13 | 2.21 | 0.22 | 0.36 |
| Ag_{Cz}^{PAC} | −4.07 | −2.29 | 1.78 | 2.39/0.09 | 2.27 | 0.11 | 0.26 |
| Au_{Cz}^{PAC} | −4.35 | −2.20 | 2.15 | 2.61/0.19 | 2.36 | 0.25 | 0.39 |
| Au_{Cz}^{PZI} | −4.38 | −2.54 | 1.84 | 2.36/0.20 | 2.13 | 0.23 | 0.37 |
| Cu_{Cz}^{MAC} | −4.17 | −1.99 | 2.17 | 2.48/0.11 | 2.27 | 0.21 | 0.36 |
| Au_{Cz}^{MAC} | −4.32 | −1.99 | 2.33 | 2.66/0.16 | 2.41 | 0.25 | 0.40 |
| Au_{Cz}^{CAAC} | −4.29 | −1.60 | 2.68 | 2.86/0.16 | 2.56 | 0.30 | 0.43 |
| Au_{Cz}^{BZI} | −4.22 | −1.46 | 2.76 | 3.09/0.20 | 2.87 | 0.22 | 0.40 |
| Au_{Cz}^{Ipr} | −4.16 | −0.81 | 3.35 | 3.44 | 3.15^{b} | 0.29 | 0.42 |
| Au_{bim}^{PZI} | −4.44 | −2.58 | 1.85 | 2.45/0.16 | 2.29 | 0.16 | 0.32 |
| Au_{bim}^{PAC} | −4.43 | −2.21 | 2.22 | 2.75/0.17 | 2.56 | 0.19 | 0.35 |
| Au_{bim}^{MAC} | −4.41 | −2.0 | 2.41 | 2.81/0.14 | 2.63 | 0.18 | 0.35 |
| Au_{bim}^{CAAC} | −4.39 | −1.61 | 2.78 | 3.02/0.15 | 2.80 | 0.22 | 0.38 |
| Au_{bim}^{BZAC} | −4.29 | −1.42 | 2.87 | 3.25/0.17 | 3.08 | 0.17 | 0.35 |
| Au_{bim}^{BZI} | −4.30 | −1.50 | 2.80 | 3.22/0.21 | 3.04 | 0.18 | 0.35 |
| Au_{bim}^{Ipr} | −4.27 | −0.82 | 3.46 | 3.62/0.16 | 3.32^{b} | 0.30 | 0.36 |
| H_{Cz}^{MAC} | −3.99 | −2.15 | 1.84 | 2.35/0.001 | 2.34 | 0.01 | 0.06 |
| Li_{Cz}^{MAC} | −3.83 | −2.08 | 1.75 | 2.17/0.03 | 2.11 | 0.06 | 0.18 |

^{a}ΔE_{ST} is based on energies calculated for the Si and T1 states.
^{b}The T₁ state for this compound has substantial ³amide character as opposed to the ³ICT state observed for the other complexes.

The transition energies in the series of Group 11 metals in M_{Cz}^{PAC} follow the same trends as reported previously for M_{Cz}^{CAAC} and M_{Cz}^{MAC}.^{4e} The energies for the S₁ and T₁ states are independent of the metal center, whereas values for ΔE_{ST} fall in the order Au>Cu>Ag, which mirror Λ_{NTO} values of 0.39, 0.36 and 0.26, respectively. The interligand ^{carbene}C^{⋅⋅⋅}N distances for the three complexes fall in the order Ag>Au>Cu. A long interligand distance might be expected to give rise to a small Λ_{NTO}, but the higher value for the Au complex suggests a greater participation of the metal ion in the excited state than for the Cu and Ag complexes.

Examining the data for the Au_{bim}^{carbene} complexes it is apparent that the carbene ligand markedly affects the S₁ and T₁ energies, whereas the ΔE_{ST}, Λ_{NTO} and oscillator strengths for the S₁ state are only moderately altered by the nature of this ligand. Small differences in ΔE_{ST} and Λ_{NTO} among the complexes with various carbene ligands suggests that the stabilization imparted on the carbene-system by addition of electron withdrawing carbonyl groups (MAC and PAC) or benzannulated arene rings (BZI, PZI, BZAC and PAC) does not markedly alter overlap between the electron and hole wavefunctions. In contrast, both ΔE_{ST} and Λ_{NTO} decrease upon shifting from a Cz to a bim donor, despite there being only a minor increase in energy for the S₁ and T₁ states.

The lowest energy excited state in these cMa complexes is best characterized as interligand, not metal-to-ligand, charge-transfer in character. In the cMa complexes the metal ion contributes equally to both the HOMO and LUMO in the ICT state, so there is no net charge transfer between the metal and the ligands. However, the metal ion is still an important participant in these transitions. This can be seen in comparing the modeling data for the complexes in Table 8 to data for H_{Cz}^{MAC} and Li_{Cz}^{MAC}. The separation between the central ion (neither of which have accessible d-orbitals available for bonding) and the ligands was kept at the same distance as for the copper ion in the geometry optimized structure of Cu_{Cz}^{MAC}. Predictably, the values for ΔE_{ST} and Λ_{NTO} decrease precipitously in these two complexes, illustrating the contribution of the metal ion to the valence orbitals of the cMa complexes.

### Photophysical Properties

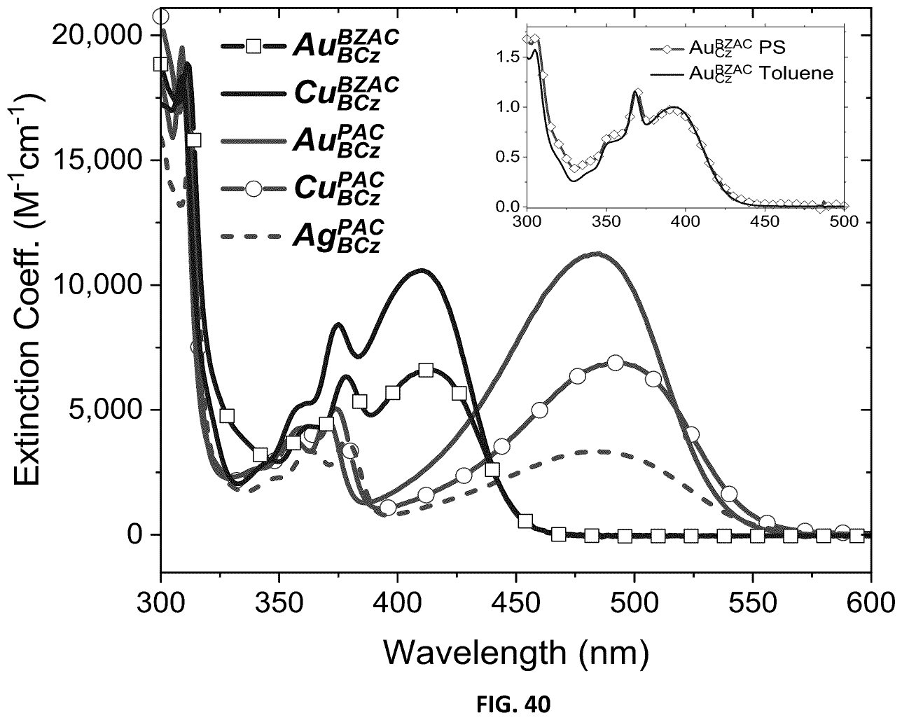

The UV-visible absorption spectra of the complexes were recorded in toluene solution. Spectra for the carbazole-based cMa complexes with BZAC and PAC are shown in FIG. 40. The absorption spectra of the M_{BCz}^{BZAC} and M_{BCz}^{PAC} complexes display bands at high energy (λ<325 nm) that are assigned to transitions localized on the carbene and carbazolide ligands. Structured bands at 375 nm are assigned transitions on the carbazolide ligand, whereas bands assigned to absorption from the ¹ICT state are centered at 410 and 480 nm for the BZAC and PAC complexes, respectively. As observed for other cMa complexes, values for the extinction coefficients of the ICT bands fall in the order Au>Cu>Ag. Changing the methylene moiety in BZAC to carbonyl in PAC stabilizes the LUMO and leads to a marked red shift for complexes with the PAC ligand.

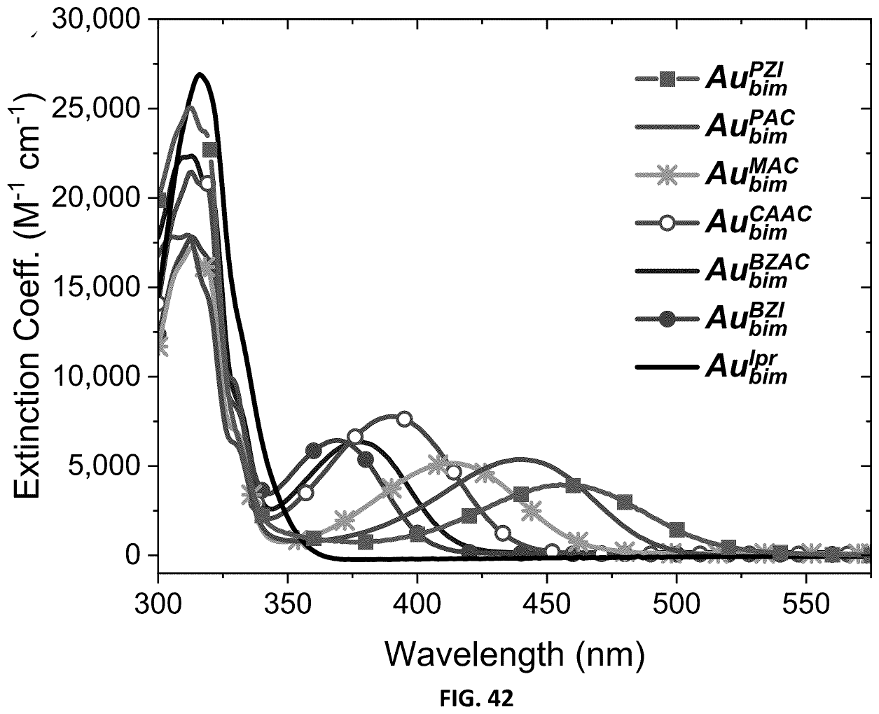

The absorption energies of the ICT state vary depending on the carbene ligands used here, which can best be seen by comparing spectra of the Au complexes using the bim donor (Au_{bim}^{carbene}). FIG. 42. In these complexes the absorption transitions localized on the amide (bim) ligand that appear at 310 nm ensures minimal overlap with the ICT band of the complexes. An exception is in Au_{bim}^{Ipr} where the LUMO is destabilized sufficiently to raise the energy of the ICT transition to be comparable to that of the bim ligand. For the other complexes the ICT bands are distinct and have energies that fall in the order BZI>BZAC>CAAC>MAC>PAC>PZI.

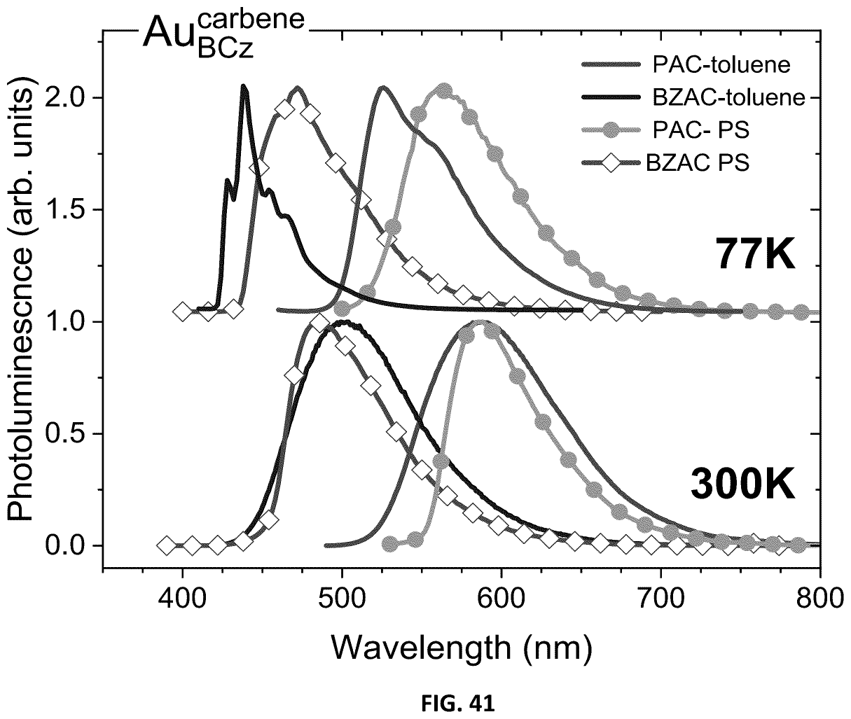

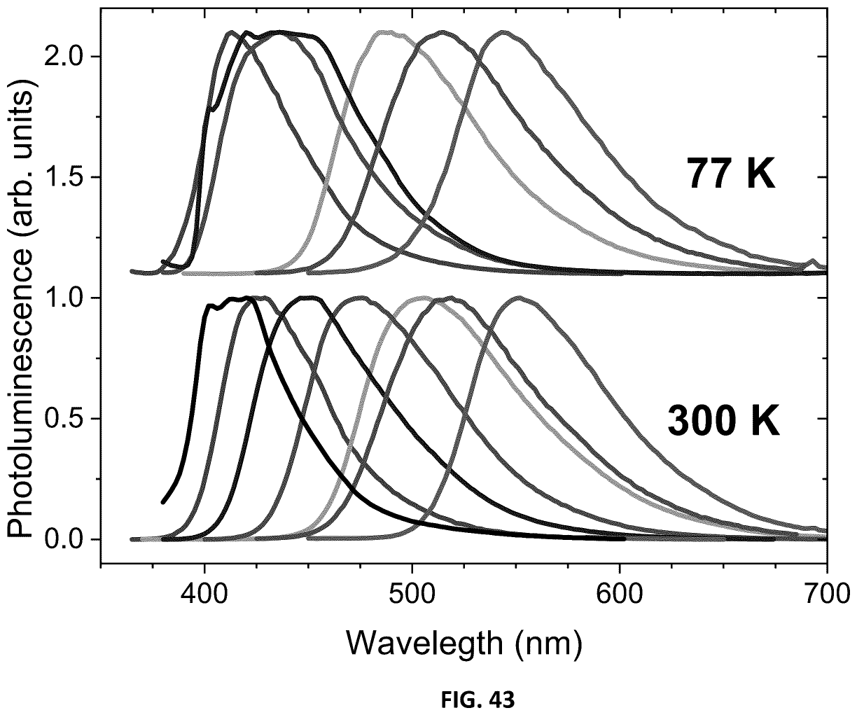

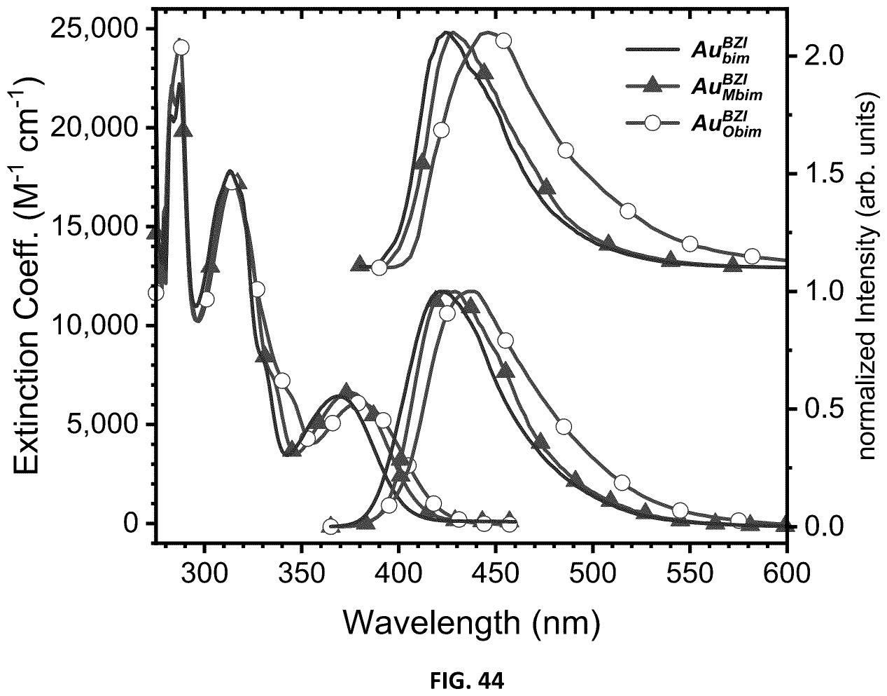

The absorption spectra of Au_{Cz}^{BZAC} in toluene, overlaid with that in polystyrene at 1 wt % loading and normalized at 375 nm, is shown in the inset to FIG. 40. The close match in absorption profiles confirm that the two media have similar solvation properties. However, the polystyrene matrix is expected to hinder geometric rearrangement, particularly rotation around the metal-ligand bond axis. Luminescence spectra for all cMa complexes were thus recorded in toluene and polystyrene (FIG. 41 and FIG. 43). The spectra are broad and featureless at room temperature, indicative of emission from an ICT state. Spectra for complexes measured in toluene are slightly red shifted relative to the same compounds in polystyrene (Table 9), suggesting that only minor structural changes take place in the excited state; however, the shift is greater for the complexes with the bim donor. This difference in the rigidochromic effects in polystyrene suggests that the bim-based cMa complexes undergo a greater structural distortion in their ICT state than do the carbazole-based materials. The emission energies from the cMa complexes parallel values observed for the absorption energies of the ICT state (Table 9). Compounds ligated with the electrophilic PZI and PAC ligands emit orange-red whereas those with BZI and BZAC luminesce in the blue spectral region. For Au derivatives sharing a common carbene, the spectra with BCz are red-shifted relative to their Cz analogs, whereas the bim congeners emit at higher energies. Addition of methyl or methoxy groups to the bim ligand destabilizes the HOMO and leads to a concomitant red shift in emission relative to the parent Au_{bim}^{BZI} complex (FIG. 44). The M_{BCz}^{PAC} complexes display only minor variation in emission energy with respect to the identity of the metal center. The luminescence properties Au_{bim}^{Ipr} are consistent with assignment to a combined ICT/ligand-triplet transition, as observed for Au_{Cz}^{BZI,4k} leading to a slow radiative rate relative to the ICT emitters.

TABLE 9
Photophysical parameters for cMa complexes in toluene (tol) solution and polystyrene
(PS) thin film (1% by weight).

| | λₘₐₓ (PL) (nm) | | Φ_{PL} (%) | | τ (μs) | | kᵣ (10⁶ s⁻¹) | | kₙᵣ (10⁶ s⁻¹) | |
|---|---|---|---|---|---|---|---|---|---|---|
| | tol | PS | tol | PS | tol | PS | tol | PS | tol | PS |
| Cu_{BCz}^{BZAC} | 502 | 459 | >95 | 93 | 0.71 | 1.24^{a} | 1.4 | — | 0.04 | — |
| Au_{BCz}^{BZAC} | 500 | 484 | >95 | >95 | 0.56 | 0.72 | 1.7 | 1.4 | 0.07 | <0.01 |
| Cu_{BCz}^{PAC} | 595 | 594 | 47 | 75 | 0.56 | 0.95 | 0.84 | 0.79 | 0.95 | 0.26 |
| Ag_{BCz}^{PAC} | 610 | 588 | 10 | 51 | 0.58 | 0.26 | 0.17 | 1.0 | 1.5 | 0.33 |
| Au_{BCz}^{PAC} | 588 | 586 | 42 | 76 | 0.44 | 0.74 | 0.95 | 1.0 | 1.3 | 0.33 |
| Au_{Cz}^{PZI} | 600 | 570 | 62 | 92 | 0.41 | 0.45 | 1.5 | 2.0 | 0.94 | 0.22 |
| Au_{Cz}^{PAC} | 546 | 546 | 73 | >95 | 0.74 | 0.81 | 1.0 | 1.2 | 0.36 | 0.04 |
| Au_{Cz}^{MAC} | — | 508 | — | 85 | — | 0.8 | — | 1.0 | — | 0.18 |
| Au_{_{Cz}}^{CAAC} _{b} | — | 472 | — | >95 | — | 1.14 | — | 0.88 | — | < 0.01 |
| Au_{Cz}^{BZAC} | 480 | 479 | >95 | >95 | 0.69 | 1.98^{a} | 1.5 | — | <0.01 | — |
| Au_{Cz}^{BZI} | 448 | 432 | 94 | >95 | 1.11 | 2.28^{a} | 0.85 | — | 0.05 | — |
| Au_{bim}^{PZI} | 600 | 552 | 31 | 91 | 0.21 | 0.24 | 1.5 | 3.8 | 3.2 | 0.37 |
| Au_{bim}^{PAC} | 562 | 532 | 30 | 81 | 0.17 | 0.27 | 1.8 | 3.0 | 4.2 | 0.7 |
| Au_{bim}^{MAC} | 548 | 506 | 19 | 88 | 0.17 | 0.40 | 1.1 | 2.2 | 4.8 | 0.3 |
| Au_{bim}^{CAAC} | 514 | 476 | 87 | >95 | 0.63 | 0.55 | 1.4 | 1.8 | 0.02 | <0.01 |
| Au_{bim}^{BZAC} | 484 | 452 | >95 | >95 | 0.43 | 0.28 | 2.3 | 3.7 | <0.01 | <0.01 |
| Au_{bim}^{BZI} | 454 | 429 | >95 | >95 | 0.42 | 0.25 | 2.3 | 4.0 | <0.01 | <0.01 |
| Au_{bim}^{Ipr} | 340 | 400 | <1 | <5 | ^{c} | 13 | ^{c} | 0.004 | ^{c} | ^{c} |
| Au_{Mbim}^{BZI} | 460 | 436 | >95 | >95 | 0.42 | 0.29 | 2.4 | 3.4 | <0.01 | <0.01 |
| Au_{Obim}^{BZI} | 480 | 450 | 92 | >95 | 0.37 | 0.38^{a} | 2.5 | — | 0.2 | — |

^{a}The lifetime given is the weighted average of a biexponential fit; Cu_{BCz}^{BZAC}: 0.79 (73%), 2.47 (27%); Au_{BCz}^{BZAC} 0.84 (57%), 3.40 (43%); Au_{Cz}^{BZI}: 0.74 (46%); 3.6 (54%); Au_{Obim}^{BZI}: 0.25 (80%), 0.90 (20%).
^{b}The CAAC ligand on thiscomplex has a menthyl instead of the adamantyl group.
^{c}Values cannot be accurately determined.

Cooling solutions of the M_{BCz}^{BZAC} complexes to 77 K leads to a marked change in the luminescence spectrum with a structured band appearing to the blue of the room temperature spectrum (FIG. 41). This rigidochromic transformation upon freezing the solvent has previously been shown to come about from destabilization of the ICT state to an energy higher than that of the triplet state localized on the carbazolide ligand (³Cz). The ICT state is destabilized to a lesser extent in a rigid polystyrene matrix such that it remains the lowest energy state upon cooling to 77 K. Cooling both toluene and polystyrene samples of M_{BCz}^{PAC} leads to a blue shift of the ICT band, but this change in energy is not large enough to access the ³Cz state. In contrast, the energy of the triplet state for bim (E_{T}=365 nm) is much higher than that of carbazole (E_{T}=415 nm) (Figure S11). The ligand localized triplet states of the carbene ligands are also in the UV region so the Au_{bim}^{carbene} complexes emit from largely featureless ICT transitions with Gaussian line shapes at all temperatures (FIG. 43).

The photoluminescence efficiency for several of the cMA complexes are high (Φ_{PL}>0.95) in both fluid toluene and rigid polystyrene, and all have microsecond to sub-microsecond emission lifetimes. The Ag complex has a low φ_{PL} in solution which may be related to photodecomposition of this derivative. Lower values for Φ_{PL} in toluene solution owe largely to increased nonradiative rates in fluid solutions, likely ligand rotation and/or excimer/exciplex formation. The radiative rates for the bim based cMa complexes are 1.8-4×10⁶ s⁻¹, which are some of the highest values reported for TADF emitters and lead to radiative lifetimes as fast as 250 ns. In the cases where an analogous carbazole based complex is available for comparison, the radiative rate for the bim based cMa complexes are two-fold faster than the Cz analogs. Unfortunately, the near degeneracy in energy between the ICT and ³Cz states in Au_{Cz}^{BZAC} and Au_{Cz}^{BZI} leads to non-first order behavior in the luminescence decay traces for these derivatives precluding direct comparisons with the bim analogs.

The radiative rate of TADF from luminophores with effective spin orbit coupling (SOC) is controlled by the radiative rate from the S₁ state and the equilibrium constant between the T₁ and S₁ states. For M_{Cz}^{MAC} and M_{Cz}^{CAAC} complexes, the principal factor that leads to faster TADF rates for the silver complexes over the copper and gold analogs is that the silver complex has larger equilibrium constant, owing to its smaller ΔE_{ST}. The modeling presented above suggests that the ΔE_{ST} values for bim based cMa complexes should be lower than their carbazolide counterparts, which may account for their faster TADF rates. To validate this conjecture, temperature dependent photophysical measurements were performed between 4-300 K to determine the two parameters that control kᵣ^{TADF} (i.e., kᵣ^{S}^{₁} and ΔE_{ST}). These measurements were conducted using polystyrene thin films doped at ˜1 wt % with the cMa complex. Fitting the temperature dependent lifetimes to a three-level model gives values for ΔE_{ST}, the zero-field splitting (ZFS) and the radiative rate from the S₁ and T₁ states. The high Φ_{PL} in these cMa complexes allows one to neglect nonradiative processes in our model. In this analysis, the ZFS is the energy difference between the two closely spaced triplet sublevels and the highest energy triplet sublevel. The energy spacing between the two lowest sublevels could not be determined from data obtained at temperatures down to 4 K, which is the limit of the cryogenic system. The fits to the data are shown for each complex in the supporting information, and the energy and rate data derived from the fits is given in Table 10.

TABLE 10
Energy and rate data from variable temperature photophysical
measurements on 1% doped polystyrene films

| | ZFS | ΔE_{ST} | τ_{S}_{₁} | τ_{T}_{₁} |
|---|---|---|---|---|
| | (meV/cm⁻¹) ± | (meV/cm⁻¹) ± | (ns) ± | (μs) ± |
| | 10% | 3% | 9% | 5% |
| Au_{Cz}^{BZAC} | ^{a} | 65/520 | 18 | ^{a} |
| Cu_{BCz}^{PAC} | ^{b} | 70/570 | 18 | ^{b} |
| Ag_{BCz}^{PAC} | ^{b} | 26/210 | 35 | ^{b} |
| Au_{BCz}^{PAC} | 0.9/7 | 72/580 | 14 | 36 |
| Au_{Cz}^{MAC} | 1.2/10 | 87/700 | 13 | 28 |
| Au_{Cz}^{PZI} | 0.9/7 | 54/440 | 21 | 82 |
| Au_{bim}^{PZI} | 1.1/9 | 31/250 | 26 | 76 |
| Au_{bim}^{PAC} | 1.0/8 | 45/360 | 17 | 38 |
| Au_{bim}^{MAC} | 2.0/16 | 51/410 | 14 | 38 |
| Au_{bim}^{CAAC} | 1.1/9 | 53/430 | 18 | 16 |
| Au_{bim}^{BZAC} | 1.2/10 | 41/330 | 19 | 19 |
| Au_{bim}^{BZI} | 1.5/12 | 41/330 | 15 | 19 |
| Au_{Mbim}^{BZI} | 1.5/12 | 44/350 | 16 | 11 |
| Au_{Obim}^{BZI} | 1.2/10 | 41/330 | 19 | 17 |

^{a} Luminescence from the ³Cz state at temperatures below 250 K prevents accurate Boltzmann fits for the ³ICT parameters.
^{b} Insufficient data was available at low temperature. Data below 4 K would be required to determine accurate values for these parameters.

The M_{BCz}^{PAC} complexes show the same trends in TADF parameters observed previously for the MAC and CAAC analogs.^{4e} The copper and gold complexes give similar values for ΔE_{ST} and S₁ radiative rates, but the silver complex gives a smaller ΔE_{ST} and slower kᵣ^{S}^{₁}, leading to comparable rates of TADF for complexes with the three different metals. The M_{bim}^{carbene} complexes show similar values for kᵣ^{S}^{₁} to their carbazole analogs (compare the MAC and PAC derivatives in Table 10), but the ΔE_{ST} values for the bim based cMa complexes are uniformly lower than those of the analogous carbazole based materials by 30% or more. The fast kᵣ^{TADF} for the bim based cMa complexes is thus due largely to a significant increase in K_{eq} caused by the small ΔE_{ST}. There is a clear connection to the smaller Λ_{NTO} for the bim based complexes.

The values of ZFS for the M_{Cz}^{MAC} and M_{Cz}^{CAAC} complexes in Table 10 are much lower than values we presented in previous reports. Previous reports used a cryostat that had poor thermal regulation below 80 K, which led to incorrect data collected at the low temperatures needed to extract the ZFS parameters. The present results were collected using a cryogenic system that is more reliable (see supporting information for details of the system), providing reproducible data on repeated heating and cooling cycles, which gives us confidence that the ZFS values reported here are accurate.

### DISCUSSION

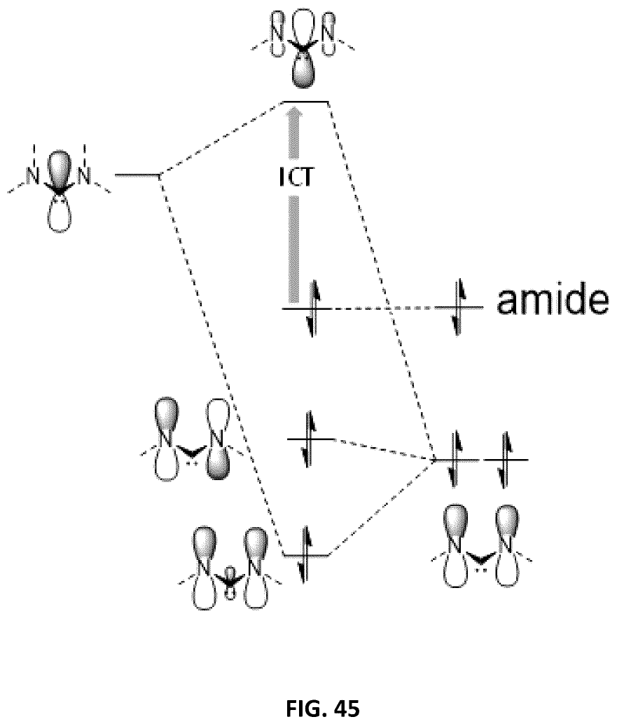

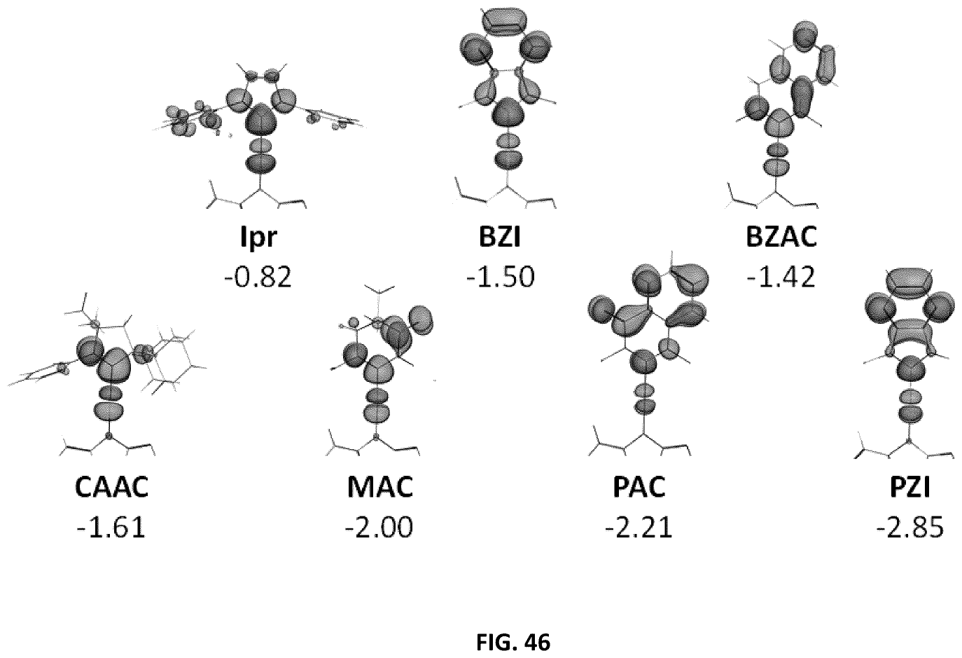

The ICT transition in the cMa complexes is essentially an electron transfer from the amide group to the carbene. While the transition utilizes the full spatial extent of the HOMO and LUMO (FIG. 39), one can consider the process as simply being a charge transfer from the nitrogen lone pair of the amide to the vacant p-orbital of the N-heterocyclic carbene. With this line of reasoning, it is apparent that if the amide is kept constant, the energy of the vacant p-orbital on the carbene will determine the energy of the ICT state. The energy of the LUMO in the carbene ligands chosen for the present study span a range of values (Table 8. FIG. 38). The LUMO energy in N-heterocyclic carbene ligands is destabilized by electron donation from the nitrogen(s) adjacent to the p-orbital of the carbene [FIG. 45]. Orbital contours from DFT calculations illustrate the antibonding nature of the N—C^{carbene} bond in the LUMO [FIG. 46], consistent with the energy diagram presented in FIG. 45. The carbene p-orbital will be destabilized by greater the participation of the nitrogen(s) in this MO, thus raising the transition energy of the ICT state. The CAAC ligand has only a single N-atom, whereas the others have two N-atoms destabilizing the carbene p-orbital, which explains the significant stabilization of the CAAC LUMO relative to that of the closest analog (Ipr). The benzannulated phenyl ring of BZI accepts electron density from the imidazolium nitrogen atoms and leads to less mixing of the N lone pair with the carbene p-orbital, stabilizing the LUMO relative to Ipr. Nitrogen substitution into the arene ring of BZI (forming PZI) leads to even greater interaction with the imidazolium nitrogens, stabilizing the carbene LUMO further. The BZAC ligand would be expected to have a LUMO between that of Ipr and BZI, since only one nitrogen is attenuated by the benzannulation, however, the ring expansion from a five- to a six-membered ring stabilizes the carbene p-orbital (Weinstein, et al., Journal of the American Chemical Society 2018, 140 (29), 9255-9260), leading to similar LUMO energies for BZI and BZAC. The carbonyl groups of MAC and PAC compete effectively for the nitrogen lone pair, therefore the LUMO energies for these two carbenes are lower than for BZAC. It is evident upon comparison of BZAC and MAC that the carbonyl group leads to a much greater stabilization of the LUMO than does benzannulation. The LUMO energy for PAC is lowered due to stabilization of the π-system by both benzannulation and the carbonyl group.

An important set of observations that deserves further discussion are the short lifetimes for the cMa complexes coordinated to the bim ligand. In all cases, the radiative rate for the Au_{bim}^{carbene} complex is a factor of two faster that the analogous Au_{Cz}^{carbene} complex. This difference occurs despite both derivatives having similar excited state energies and extinction coefficients. Based on modeling studies (Table 8), the Au_{bim}^{carbene} complexes have lower Λ^{NTO} and ΔE_{ST} values than their Au_{Cz}^{carbene} counterparts (excluding the Ipr complex, which emits form a ³bim state). The latter trend is mirrored in the data from variable temperature photophysical measurements that show the Au_{bim}^{carbene} complexes do indeed have lower ΔE_{ST} values than their Au_{Cz}^{carbene} analogs (Table 10). Thus, since values of kᵣ^{S}^{₁} are similar for complexes with both types of amide, the principal source of the fast kᵣ^{TADF} values for the Au_{bim}^{carbene} complexes are the low values for ΔE_{ST}.

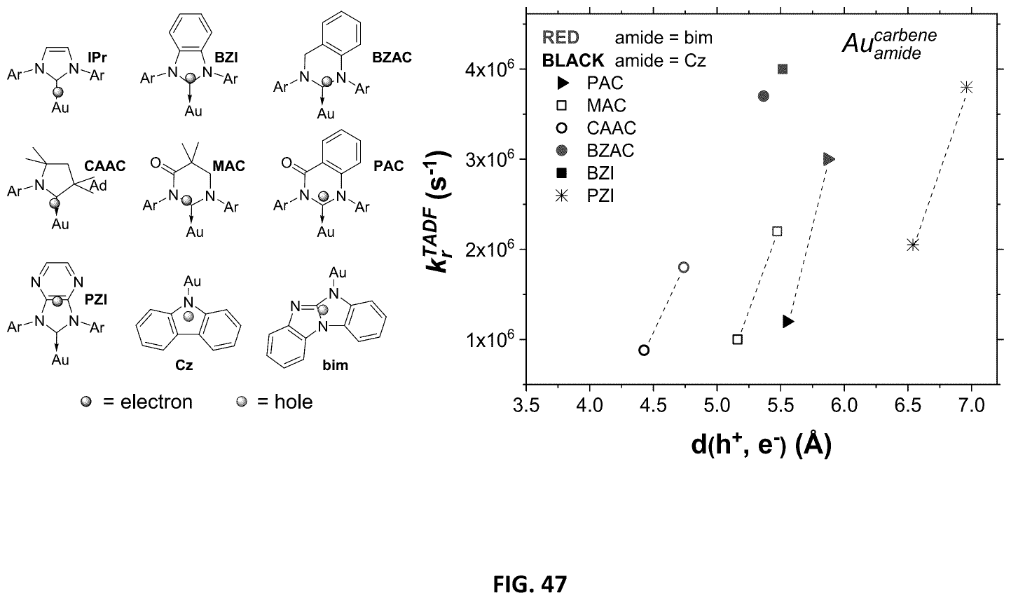

A key difference between Cz and bim in the cMa complexes is the location of the center of positive charge in the ICT excited states of the two amides. The positions calculated for the electron and hole for the M_{amide}^{carbene} complexes discussed here are illustrated in FIG. 47. The two charges lie within the plane of the carbene and amide ligand, respectively. For Cz the center of positive charge lies near the N atom, whereas in M_{bim}^{carbene} complexes the three nitrogen atoms of the core guanidinium unit disperse the positive charge and shift the center away from the nitrogen atom bound to the metal. The position of the electron in each carbene for the ICT excited state is nearly independent on the choice of Cz or bim, and similarly the position of the hole for each amide is unaffected by the choice of carbene. The center of electron charge resides within the C-M bond for Ipr and CAAC, whereas the charge shifts into the carbene ligand for BZI, BZAC, MAC, PAC and PZI, see FIG. 47 (left). This is consistent with the enhanced delocalization in the LUMO by π-extending the carbene backbone. The distance between the centers of positive and negative charge, d(h⁺, e⁻), for each cMa is given in Table 5. FIG. 47 (right) shows the relationship of d(h⁺, e⁻) for M_{amide}^{carbene} complexes to kᵣ^{TADF}. Values for d(h⁺, e⁻) are spaced further apart for the bim complexes than the Cz-based ones.

Radiative rates for both bim and Cz complexes show a dependence on d(h⁺, e⁻), with larger separations leading to faster kᵣ^{TADF} (FIG. 47, right); however, the degree to which kᵣ^{TADF} increases with d(h⁺, e⁻) differ for the two derivatives. In all cases where data are available for a given carbene, the kᵣ^{TADF} values are markedly faster for the bim-based cMa complexes than for the Cz-based analogs (see dashed lines in FIG. 47, right). The Au_{Cz}^{BZI} and Au_{Cz}^{BZAC} complexes were not included in FIG. 47, right because the triplet excited states for these two compounds have a mixed ICT/ligand-localized character. The energies of the ICT and ³Cz states are nearly degenerate in both of these complexes, which promotes mixing of the states and a concomitant increase in the measured lifetime, so we cannot unequivocally determine kᵣ^{TADF}. Although the energy separation between the ³ICT and ligand localized triplet states for the M_{bim}^{carbene} and M_{Cz}^{carbene} complexes with PAC, MAC, CAAC and PZI carbenes is large enough to prevent mixing between these excited states, the bim complexes still display a marked increase in the radiative rate relative to their carbazole analogs. The large d(h⁺, e⁻) separations for the bim complexes are consistent with lower Λ_{NTO} values, and thus the lower ΔE_{ST} values, for the bim complexes relative to their carbazole counterparts. At first glance an increase in d(h⁺, e⁻) might also be expected to decrease kᵣ^{S}^{₁}, as observed upon substituting Ag⁺ (with a large ionic radius) in place of Cu⁺ and Au⁺ for the M_{BCz}^{PAC} complexes, as well as for the M_{Cz}^{MAC} and M_{Cz}^{CAAC} derivatives.^{4e} However, this is not the case for Au_{bim}^{carbene} complexes since kᵣ^{S}^{₁} remains nearly constant (in the 15-20 ns range) for complexes with either carbazole or bim ligands (Table 10). Thus, the decrease in ΔE_{ST} brought about by the enhanced d(h⁺, e⁻) is the principal factor leading to the fast kᵣ^{TADF} values for the Au_{bim}^{carbene} complexes. Interestingly, considering all of the complexes other than Au_{bim}^{PZI}, values for kᵣ^{S}^{₁} are near constant and do not show an increase by the cube of the emission energy as predicted by the Einstein relationship (Hilborn, American Journal of Physics 1982, 50 (11), 982-986), even though the complexes span a range of emission energies from 2.2-2.9 eV. It is also, noteworthy that even though Au_{bim}^{PZI} has a substantially larger d(h⁺, e⁻) than Au_{bim}^{BZI} and Au_{bim}^{BZAC}, all three complexes have comparable rates for kᵣ^{TADF}. For the PZI based cMa complexes, low values for ΔE_{ST} are compensated by S₁ lifetimes that are slower than the other Au(I) derivatives. This suggests that the d(h⁺, e⁻) value observed for Au_{bim}^{PZI} (6.8 Å) is approaching a limit for enhancing kᵣ^{TADF}, and we therefore anticipate that any further increase in d(h⁻, e⁻) will continue to increase the radiative lifetime for the S₁ state.

### CONCLUSION

Two-coordinate, coinage metal (carbene)M^{(I)}(amide) complexes have attracted a great deal of attention recently, due in part to their excellent photophysical and electroluminescent properties. These cMa complexes give high photoluminescent and electroluminescent efficiencies and have very short phosphorescence (TADF) lifetimes. Most of the work published to date for these complexes has focused on CAAC. MAC and BZI type ligands, with the most common amide being a carbazolide. This study explored the impact of π-extending the carbene and amide ligands on the physical and photophysical properties of cMa complexes. The carbene ligand was π-extended via benzannulation (BZI, BZAC and PAC). The amide ligand was π-extended via replacement of the central “pyrrole” moiety of carbazole with a guanidinium group (i.e., the bim ligand). By π-extending the carbene and amide together, some of the highest radiative rates can be observed for a triplet-controlled emission process, with rates as high as 4×10⁶ s⁻¹.

The lowest energy absorption and emission bands in the M_{Cz}^{carbene} complexes are due to transitions involving the amide (HOMO) and carbene (LUMO). The energy of the LUMO shifts significantly across the series of carbenes explored here, leading to the ordering of energies for the ICT bands of M_{Cz}^{carbene} being BZI>BZAC>CAAC>MAC>PAC. Other than this shift in energy, the choice of carbene in the M_{Cz}^{carbene} complex has a modest impact on the photophysical properties since the complexes have similar values for extinction coefficients, as well as for radiative and nonradiative decay rates. In contrast, the effect of π-extending the amide ligand (M_{Cz}^{carbene}→M_{bim}^{carbene}) has almost no effect on the energy of the ICT transition, but other photophysical properties are markedly altered. The radiative decay rate (kᵣ^{TADF}) for a given M_{bim}^{carbene} is between two-to-four times greater than the rate for the M_{Cz}^{carbene} complex of the same carbene. The principal source of the rate enhancement for bim-based cMa complexes comes from a decrease in the ΔE_{ST} for these complexes compared to the Cz counterparts. This decrease in ΔE_{ST} is related to the smaller Λ_{NTO} for M_{bim}^{carbene} complexes, brought about by a shift of the hole density (HOMO) away from the electron localized on the carbene. While this picture explains the difference between Cz- and bim-based complexes with a common carbene ligand, it does not explain the differences in radiative rates seen for the M_{bim}^{carbene} complexes. The calculated values of ΔE_{ST} and Λ_{NTO} for the M_{bim}^{carbene} complexes are similar, but their radiative rates differ by more than a factor of two in comparing MAC to BZI complexes. Consistent with the experimental kᵣ^{TADF} data, values for ΔE_{ST} are lowest for M_{bim}^{carbene} complexes with π-extended carbene ligands, i.e. BZI, BZAC and PAC. Interestingly, kᵣ^{S}^{₁} for the M_{bim}^{carbene} complexes only marginally decreases with a decrease in Λ_{NTO} and increase in hole/electron separation. Therefore, the increase kᵣ^{TADF} for M_{bim}^{carbene} complexes versus their M_{Cz}^{carbene} analogs owes primarily to a large increase in K_{eq}, rather than to a change in kᵣ^{S}^{₁}, and is most prominent for the complexes with benzannulated carbene ligands. Thus, π-extension of both ligands (carbene and amide) imparts the most significant enhancements in radiative rate.

While this report has focused on achieving fast radiative lifetimes, it is important to stress that knowledge of Λ_{NTO} and d(h⁺, e⁻) can be used to tailor the ICT excited states in related compounds for use as sensitizers in photoelectrochemical processes. A small Λ_{NTO} will lead to a large ΔE_{ST} value and small K_{eq}, as described above, but the large Λ_{NTO} will conversely improve hole/electron overlap, and thus increase extinction coefficients for light absorption. Therefore, it should be possible to achieve both long lifetimes and high molar absorptivity from other cMa complexes.

We claim:

1. A compound of formula (I): 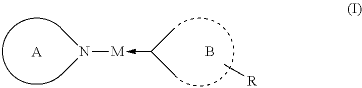
wherein
M is a metal;
ring B is a carbene ligand;
R represents mono to the maximum allowable substitution;
each R is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; wherein any two adjacent R are optionally joined or fused together to form a ring which is optionally substituted;
ring A is an amide ligand selected from the group consisting of formula (A-1) and formula (A-2); 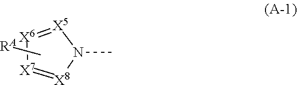
wherein, in formula (A-1),
the dashed line represents coordination to M;
each X³, X⁶, X⁷, and X⁸ independently represents N or C;
R^{A} represents mono to the maximum allowable substitution;
wherein any two adjacent groups R^{A} may optionally together form a fused ring having the following formula: 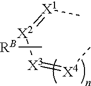
wherein each X¹, X², X³, and X⁴ independently represents N or C;
n is 0 or 1; wherein when n is 0, then X³ binds directly to formula (A-1);
R^{B} represents mono to the maximum allowable substitution;
each occurrence of R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano phosphino, and combinations thereof; wherein any two R^{B} are optionally joined or fused together to form a ring which is optionally substituted; 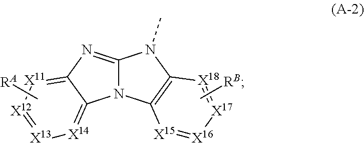
wherein, in formula (A-2);
each X¹¹ to X¹⁸ independently represents N or C;
R^{A} and R^{B} each represent mono to the maximum allowable substitution; and
each occurrence of R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano phosphino, and combinations thereof; wherein any two adjacent R^{A} and R^{B} are optionally joined or fused together to form a ring which is optionally substituted.

2. The compound of claim 1, wherein M is selected from the group consisting of Cu, Ag, and Au.

3. The compound of claim 1, wherein ring A is represented by formula (A-2).

4. The compound of claim 1, wherein ring A is represented by one of the following structures:

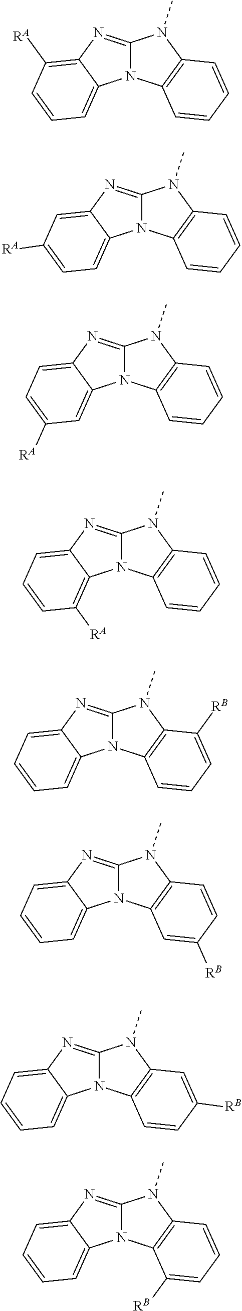

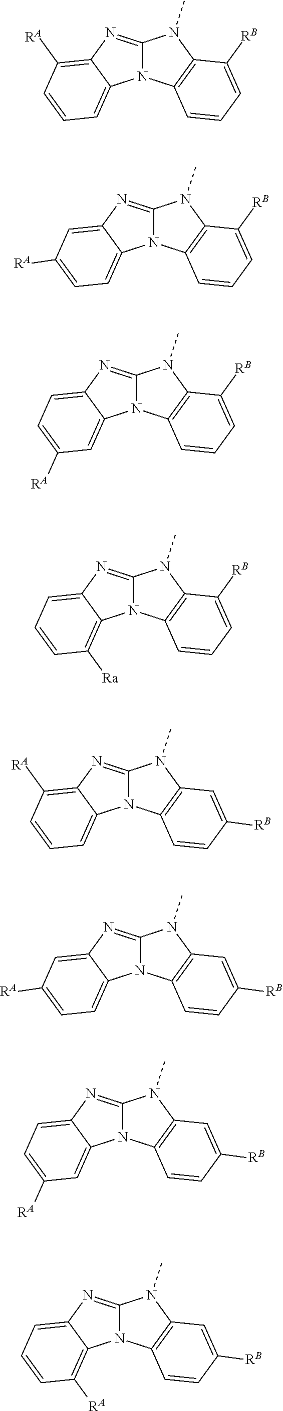

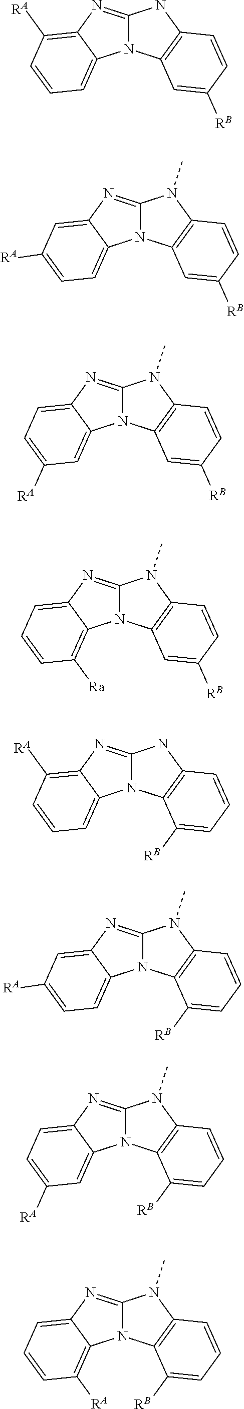

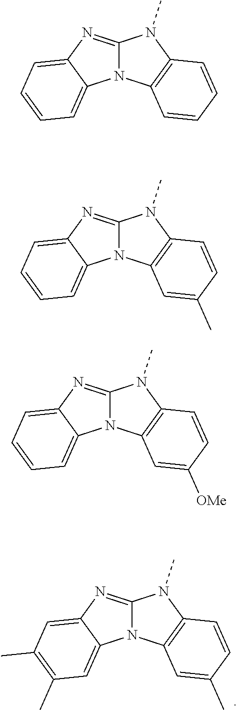

5. The compound of claim 1, wherein ring B is selected from the group consisting of Formula A, Formula B, Formula C, Formula D, Formula E, and Formula F: 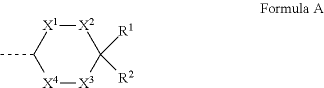
wherein
each X¹ to X⁴ independently represents NR¹, CR¹R², C═O, C═S, O, or S; and
each occurrence of R¹ and R² is independently selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof;
wherein any two adjacent R¹ and R² are optionally joined or fused together to form a ring which is optionally substituted. 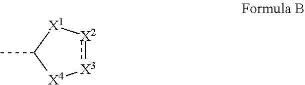
wherein each X¹ and X⁴ independently represents N, NR¹, CR¹, CR¹R², SiR¹, SiR¹R², PR¹, B, BR¹, BR¹R², O, or S; and
each X² and X³ independently represents CR¹, CR¹R², SiR¹, SiR¹R², N, NR¹, P, PR¹, B, BR¹, O, or S;
each occurrence of R¹ and R² is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof;
wherein any two adjacent R¹ and R² are optionally joined or fused together to form a ring which is optionally substituted; and
the dashed line inside the five-member ring represents zero or one double-bond. 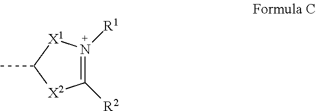
wherein each X¹ and X² independently represents NR¹, CR¹R², O, or S;
each occurrence of R¹ and R² is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; and
wherein any two adjacent R¹ and R² are optionally joined or fused together to form a ring which is optionally substituted. 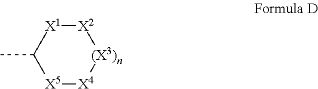
wherein
each X¹ to X⁵ independently represents N, P, NR¹, PR¹, B, BR¹, CR¹, SiR¹, CR¹R², SiR¹R², C═O, C═S, O, or S;
n is 0 or 1;
each occurrence of R¹ and R² is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof;
wherein any two adjacent R¹ and R² are optionally joined or fused together to form a ring which is optionally substituted; 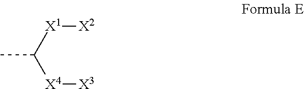
wherein
each X¹ and X⁴ independently represents NR¹, CR¹, SiR¹, CR¹R², SiR¹R², PR¹, BR¹, C═O, C═S, O, or S;
each X² and X³ is independently present or absent, and if present, independently represents H, NR¹R², CR¹, CR¹R², C═O, C═S, O, or S;
each occurrence of R¹ and R² is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof;
wherein any two adjacent R¹ and R² are optionally joined or fused together to form a ring which is optionally substituted 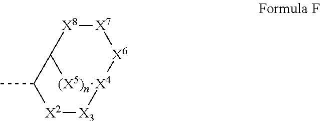
wherein each occurrence of X¹ to X⁸ independently represents N, P, NR¹, PR¹, B, BR¹, CR¹, SiR¹, CR¹R², SiR¹R², C═O, C═S, O, or S;
n is 1 or 2;
each occurrence of R¹ and R² is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof;
wherein any two adjacent R¹ and R² are optionally joined or fused together to form a ring which is optionally substituted.

6. The compound of claim 1, wherein ring B is represented by one of the following structures: 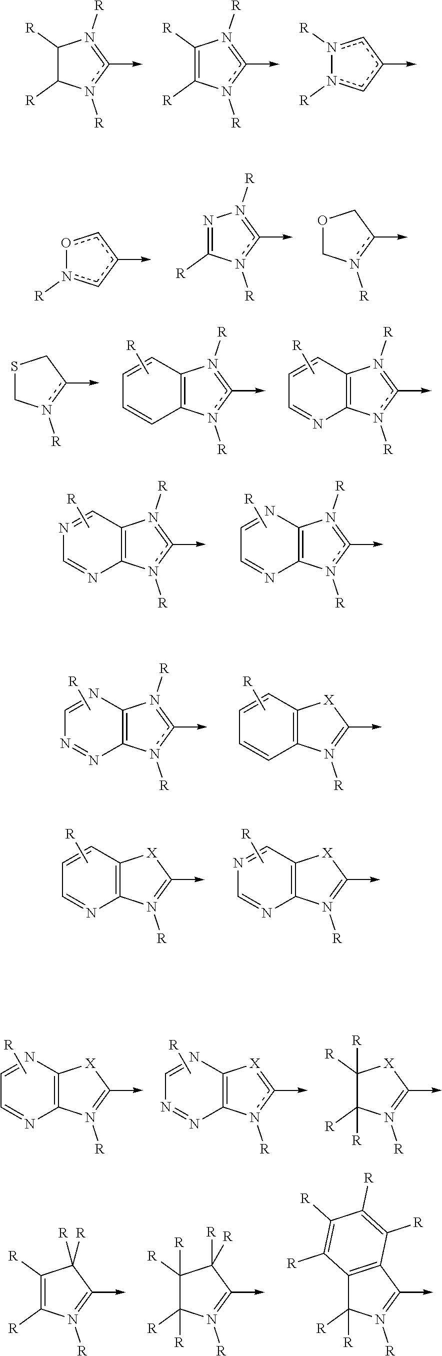 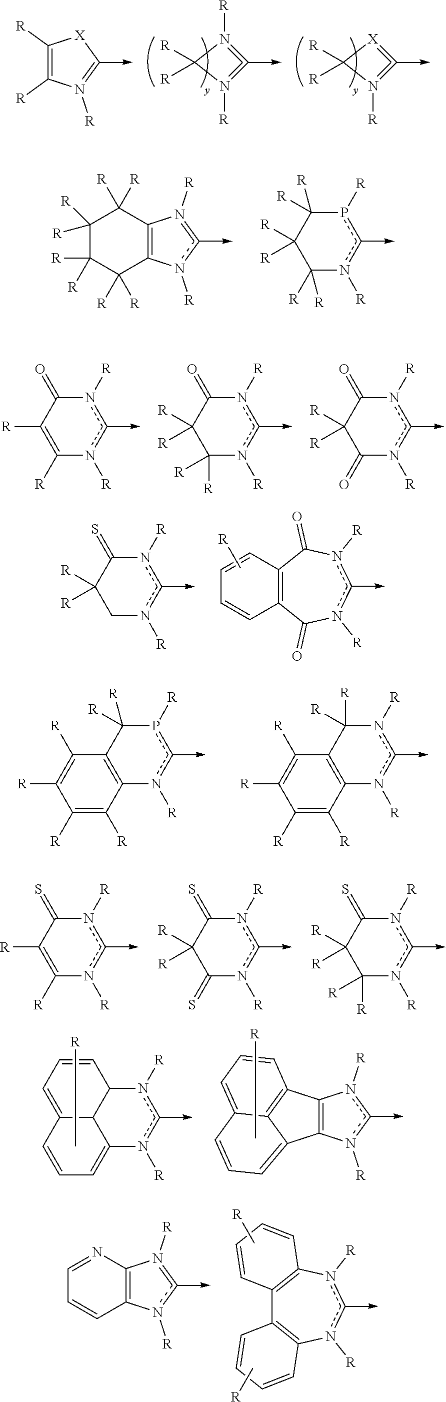 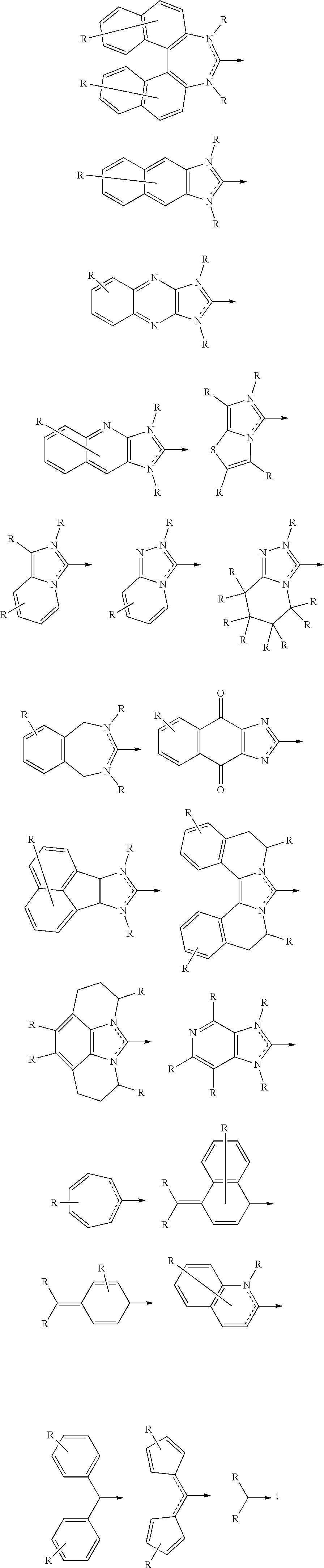
wherein each R is independently selected from the group consisting of hydrogen, deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitro, nitrile, isonitrile, sulfanyl, boryl, acyl, carboxylic acid, benzoyl, ether, ester, vinyl, ketone, sulfinyl, sulfonyl, cyano, phosphino, and combinations thereof; wherein any two adjacent substituents may together join to form a ring.

7. The compound of claim 1, wherein ring B is represented by one of the following structures: 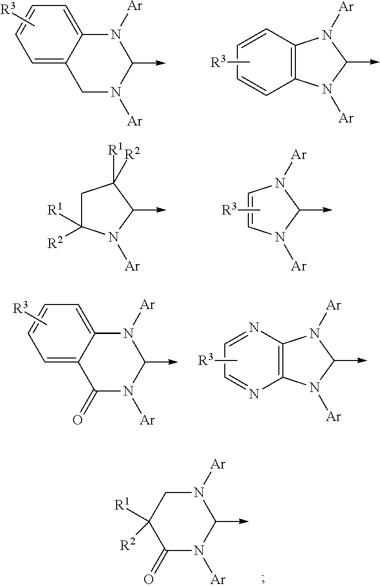
wherein each R¹, R², and R³ is independently selected from the group consisting of hydrogen, deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitro, nitrile, isonitrile, sulfanyl, boryl, acyl, carboxylic acid, benzoyl, ether, ester, vinyl, ketone, sulfinyl, sulfonyl, cyano, phosphino, and combinations thereof; wherein any two adjacent substituents may together join to form a heteroaryl ring, an aryl ring, a cycloalkyl ring, or a bicyclic ring; and
wherein each Ar independently represents aryl or heteroaryl which is optionally further substituted with one or more substituents independently selected from the group consisting of hydrogen, deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitro, nitrile, isonitrile, sulfanyl, boryl, acyl, carboxylic acid, benzoyl, ether, ester, vinyl, ketone, sulfinyl, sulfonyl, cyano, phosphino, and combinations thereof; wherein any two adjacent substituents may together join to form a ring.

8. The compound of claim 1, wherein ring B is represented by one of the following structures: 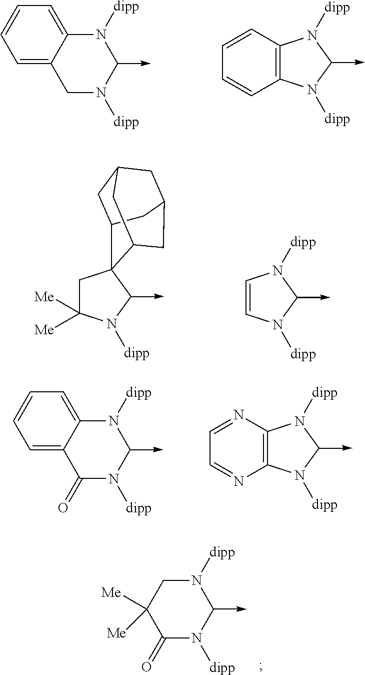
wherein dipp=2,6-disopropylphenyl.

9. The compound of claim 1, wherein the compound has one of the following structures: [chemical structure] 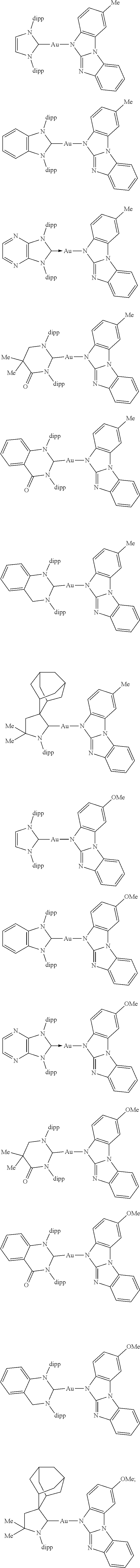
wherein dipp=2,6-disopropylphenyl.

10. The compound of claim 1, wherein ring B is represented by formula (B-1): 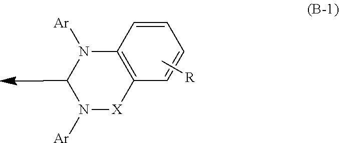
wherein
X represents CR¹R², SiR¹R², C═O, or C═S;
each Ar independently represents an aryl group or a heteroaryl group which may be further substituted with one or more substituents selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; wherein any two adjacent substituents are optionally joined or fused together to form a ring which is optionally substituted;
R represents mono to the maximum allowable substitution; and
each R, R¹, and R² is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; wherein any two adjacent R, R¹, or R² are optionally joined or fused together to form a ring which is optionally substituted.

11. The compound of claim 10, wherein ring A is represented by formula (A-3): 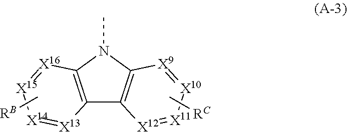
wherein
the dashed line represents coordination to M;
each occurrence of X¹ to X¹⁶ independently represents C or N;
each occurrence of R^{B} and R^{C} independently represents mono to the maximum allowable substitution;
each occurrence of R^{B} and R^{C} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof;
wherein any two adjacent R^{B} and R^{C} are optionally joined or fused together to form a ring which is optionally substituted.

12. The compound of claim 10, wherein ring A is selected from the group consisting of:

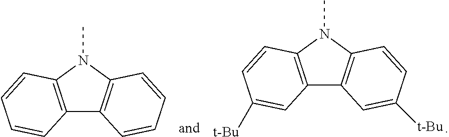

13. The compound of claim 10, wherein the compound is represented by one of the following structures: 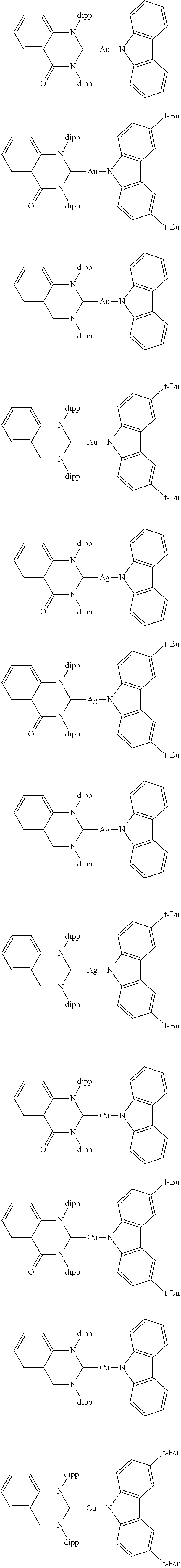
wherein dipp=2,6-disopropylphenyl.

14. An organic light emitting device (OLED) comprising:
an anode;
a cathode; and
an organic layer, disposed between the anode and the cathode, comprising a compound of formula (I) 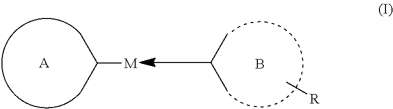
wherein
M is a metal;
ring B is a carbene ligand;
R represents mono to the maximum allowable substitution;
each R is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; wherein any two adjacent R are optionally joined or fused together to form a ring which is optionally substituted;
ring A is an amide ligand selected from the group consisting of formula (A-1) and formula (A-2); 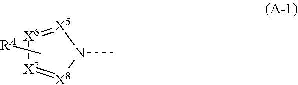
wherein, in formula (A-1),
the dashed line represents coordination to M;
each X³, X⁶, X⁷, and X⁸ independently represents N or C;
R^{A} represents mono to the maximum allowable substitution;
wherein any two adjacent groups R^{A} may optionally together form a fused ring having the following formula: 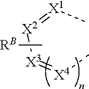
wherein each X¹, X², X³, and X⁴ independently represents N or C;
n is 0 or 1; wherein when n is 0, then X³ binds directly to formula (A-1);
R^{B} represents mono to the maximum allowable substitution;
each occurrence of R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano phosphino, and combinations thereof; wherein any two R^{B} are optionally joined or fused together to form a ring which is optionally substituted; 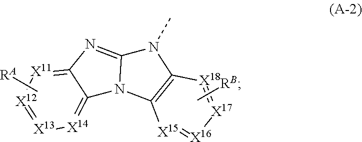
wherein, in formula (A-2);
each X¹¹ to X¹⁸ independently represents N or C;
R^{A} and R^{B} each represent mono to the maximum allowable substitution; and
each occurrence of R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, carboxylic acid, ether, ester, sulfinyl, sulfonyl, cyano phosphino, and combinations thereof; wherein any two adjacent R^{A} and R^{B} are optionally joined or fused together to form a ring which is optionally substituted.

15. The OLED of claim 15, wherein the organic layer further comprises a host, wherein the host comprises at least one chemical group selected from the group consisting of triphenylene, carbazole, dibenzothiophene, dibenzofuran, dibenzoselenophene, azatriphenylene, azacarbazole, aza-dibenzothiophene, aza-dibenzofuran, and aza-dibenzoselenophene.

16. The OLED of claim 15, wherein the host is selected from the group consisting of; 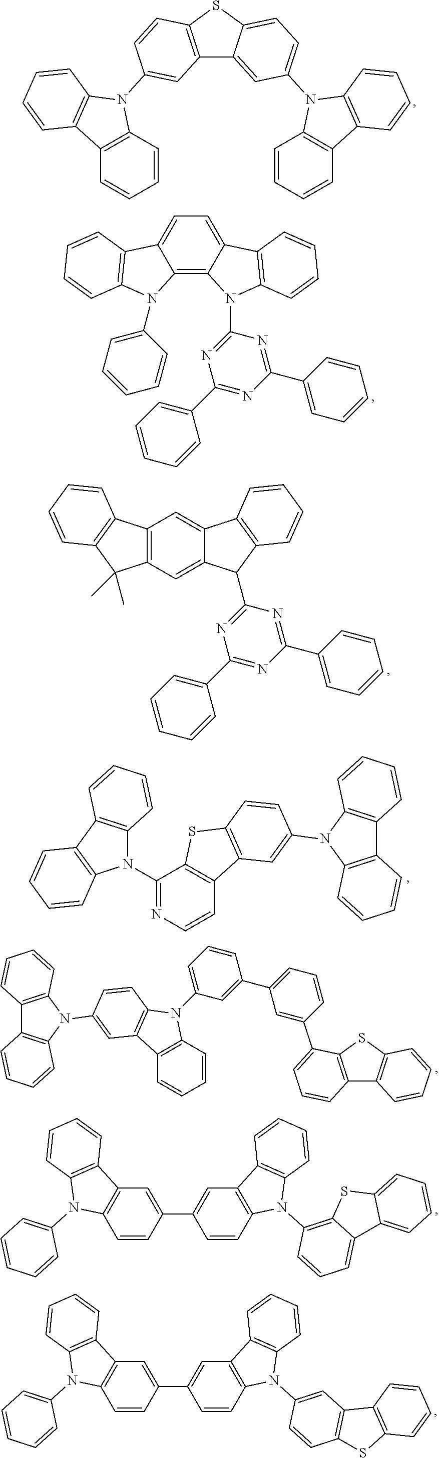 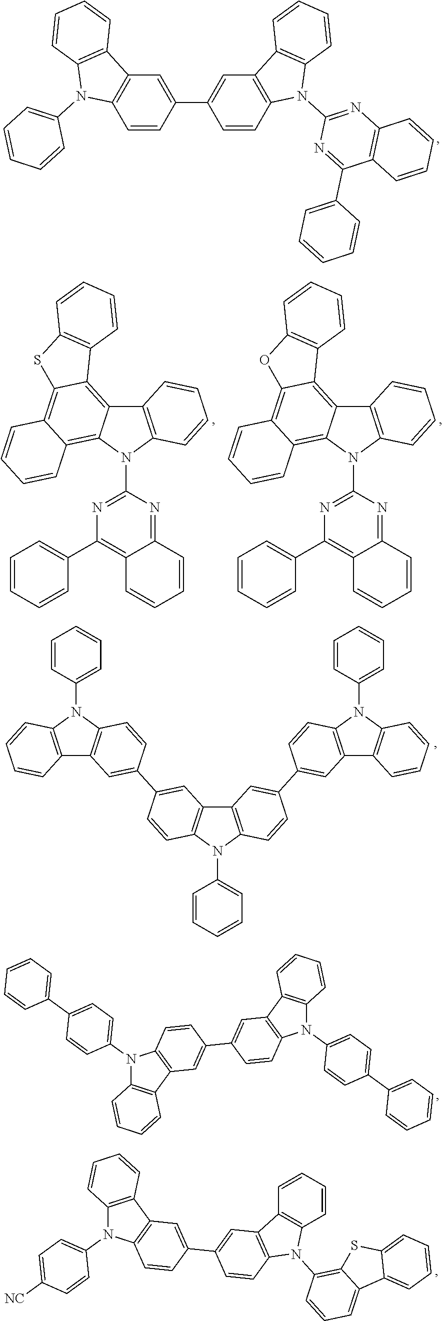 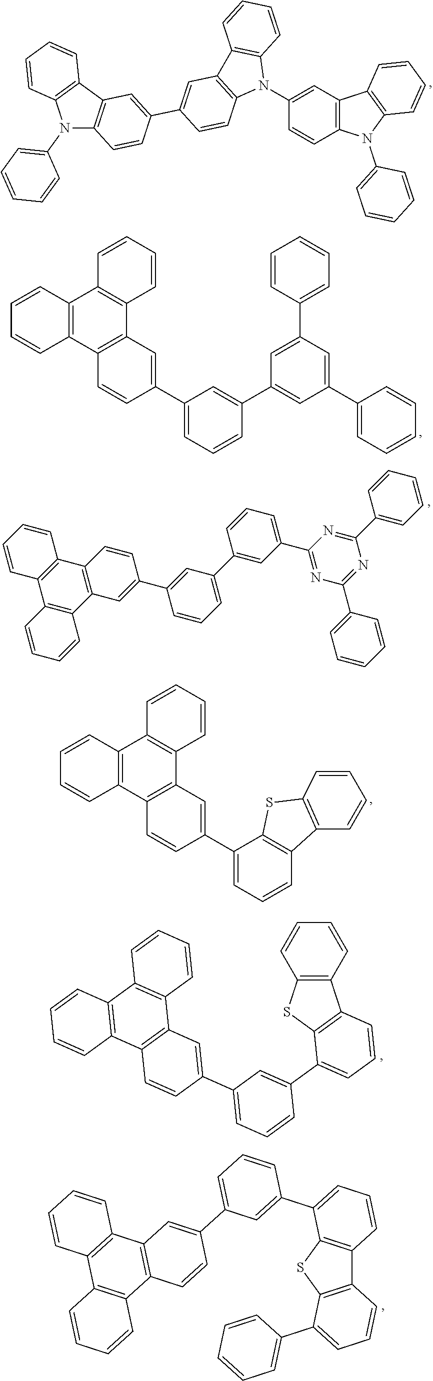 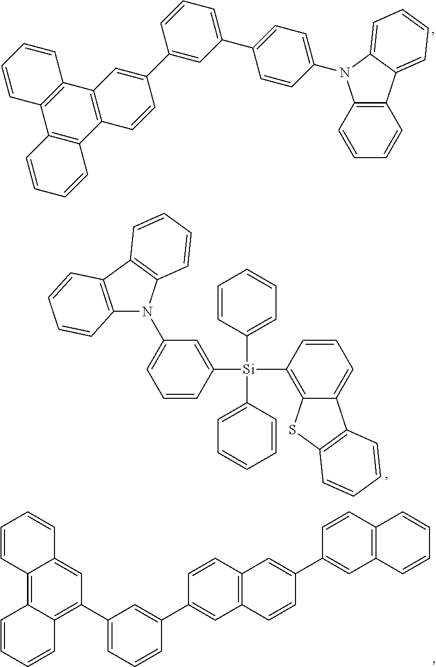
and combinations thereof.

17. A consumer product comprising an organic light-emitting device (OLED) comprising:
an anode;
a cathode; and
an organic layer, disposed between the anode and the cathode, comprising a compound of formula (I): 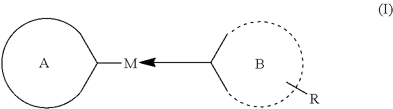
wherein
M is a metal;
ring B is a carbene ligand;
R represents mono to the maximum allowable substitution;
each R is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; wherein any two adjacent R are optionally joined or fused together to form a ring which is optionally substituted;
ring A is an amide ligand selected from the group consisting of formula (A-1) and formula (A-2); 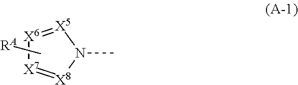
wherein, in formula (A-1),
the dashed line represents coordination to M;
each X³, X⁶, X⁷, and X⁸ independently represents N or C;
R^{A} represents mono to the maximum allowable substitution;
wherein any two adjacent groups R^{A} may optionally together form a fused ring having the following formula: 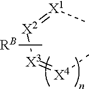
wherein each X¹, X², X³, and X⁴ independently represents N or C;
n is 0 or 1; wherein when n is 0, then X³ binds directly to formula (A-1);
R^{B} represents mono to the maximum allowable substitution;
each occurrence of R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano phosphino, and combinations thereof; wherein any two R^{B} are optionally joined or fused together to form a ring which is optionally substituted; 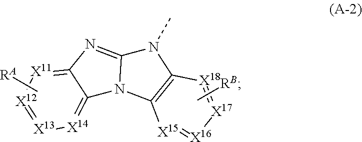
wherein, in formula (A-2);
each X¹¹ to X¹⁸ independently represents N or C;
R^{A} and R^{B} each represent mono to the maximum allowable substitution; and
each occurrence of R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, carboxylic acid, ether, ester, sulfinyl, sulfonyl, cyano phosphino, and combinations thereof; wherein any two adjacent R^{A} and R^{B} are optionally joined or fused together to form a ring which is optionally substituted.

18. The consumer product of claim 18, wherein the consumer product is a flat panel display, curved display, computer monitor, medical monitor, television, billboard, lights for interior or exterior illumination and/or signaling, heads-up display, fully or partially transparent display, flexible display, rollable display, foldable display, stretchable display, laser printer, telephone, mobile phone, tablet, phablet, personal digital assistant (PDA), wearable device, laptop computer, digital camera, camcorder, viewfinder, micro-display (display that is less than 2 inches diagonal), 3-D display, virtual reality or augmented reality display, vehicle, video wall comprising multiple displays tiled together, theater or stadium screen, light therapy device, or a sign.

19. A formulation comprising the compound of claim 1.
